(19) United States
(12) Patent Application Publication
(10) Pub. No.: US 2026/0096341 A1
(43) Pub. Date: Apr. 2, 2026

(54) ORGANIC ELECTROLUMINESCENT MATERIAL AND DEVICE THEREOF

(71) Applicant: BEIJING SUMMER SPROUT TECHNOLOGY CO., LTD., Beijing (CN)

(72) Inventors: Han ZHANG, Beijing (CN); Cuifang ZHANG, Beijing (CN); Qi ZHANG, Beijing (CN); Zhihong DAI, Beijng (CN); Chi Yuen Raymond Kwong, Beijing (CN); Cuanjun Xia, Beijing (CN)

(21) Appl. No.: 19/343,639

(22) Filed: Sep. 29, 2025

(30) Foreign Application Priority Data
Sep. 30, 2024 (CN) 202411386583.6

(51) Int. Cl. H10K 85/30; C07F 15/00; C09K 11/02; C09K 11/06; H10K 50/11

(52) U.S. Cl. CPC H10K 85/342; C07F 15/0033; C09K 11/02; C09K 11/06; C09K 2211/1007; C09K 2211/1011; C09K 2211/1029; C09K 2211/1037; C09K 2211/185; H10K 50/11

(57) ABSTRACT

Provided are an organic electroluminescent material and a device. The organic electroluminescent material is a metal complex comprising a ligand having a structure of Formula 1 and a ligand having a structure of Formula 3, and in particular, Formula 1 comprises a specific biphenylene structure. These new metal complexes can achieve deep red and near-infrared light emission, have a strong hole trapping ability, have application potentials to become excellent deep red to near-infrared emissive materials, and can be used as emissive materials in organic electroluminescent devices. Further provided are an organic electroluminescent device comprising the metal complex and a composition comprising the metal complex.

### CROSS-REFERENCE TO RELATED APPLICATION(S)

This application claims priority to Chinese Patent Application No. 202411386583.6 filed on Sep. 30, 2024, the disclosure of which is incorporated herein by reference in its entirety.

### TECHNICAL FIELD

The present disclosure relates to compounds for organic electronic devices such as organic light-emitting devices. More particularly, the present disclosure relates to a metal complex comprising a ligand having a structure of Formula 1, an organic electroluminescent device comprising the metal complex, and a compound composition.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation (VTE method). Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

CN111269269A discloses an iridium complex having a general structure of Formula I

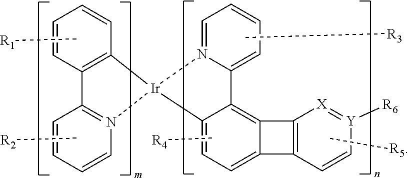

The iridium complex disclosed in the prior art must have a ligand structure in which pyridine is attached to a specific position of biphenylene. However, the application of ligands formed by attaching biphenylene and similar structures to other carbocyclic or heterocyclic rings in metal complexes is not disclosed or taught, and the unique advantages of such metal complexes are not found.

### SUMMARY

The present disclosure aims to provide a series of metal complexes comprising a ligand having a structure of Formula 1 and a ligand having a structure of Formula 3 to solve at least part of the above-mentioned problems. These metal complexes can achieve deep red and near-infrared light emission and have strong hole trapping abilities. These metal complexes have excellent properties and potential application prospects of becoming excellent deep red emissive materials.

According to an embodiment of the present disclosure, a metal complex is disclosed, which has a general formula of M(Lₐ)ₘ (L_{b}), (L_{c})_{q}; wherein the metal M is selected from a metal with a relative atomic mass greater than 40, and Lₐ, L_{b}, and L_{c} are a first ligand, a second ligand, and a third ligand coordinated to the metal M, respectively;

Lₐ, L_{b}, and L_{c} can be optionally joined to form a multidentate ligand;
m is selected from 1 or 2, n is selected from 1 or 2, q is selected from 0 or 1, and m+n+q equals the oxidation state of the metal M; when m is equal to 2, two Lₐ are the same or different; when n is equal to 2, two L_{b} are the same or different;
the first ligand Lₐ has a structure represented by Formula 1:

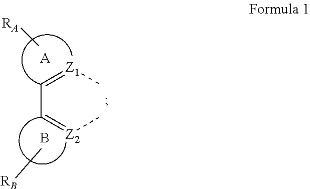

wherein Z₁ and Z₂ are each independently selected from C or N, and Z₁ is different from Z₂;
the ring A is selected from an unsaturated carbocyclic ring having 2 to 30 carbon atoms or an unsaturated heterocyclic ring having 2 to 30 ring atoms; and the ring B is selected from an unsaturated carbocyclic ring having 4 to 30 carbon atoms or an unsaturated heterocyclic ring having 4 to 30 ring atoms;
the ring B at least comprises one structure represented by Formula 2:

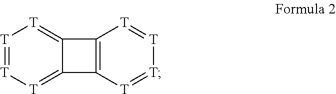

wherein T is, at each occurrence identically or differently, selected from C or N;
R_{A} and R_{B} represent, at each occurrence identically or differently, mono-substitution, multiple substitutions or non-substitution;

R_{A} and R_{B} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{A} and R_{B} can be optionally joined to form a ring;
L_{b} has a structure represented by Formula 3:

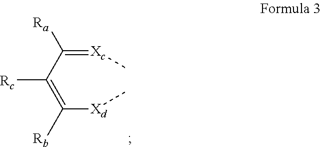

wherein X_{c} and X_{d} are, at each occurrence identically or differently, selected from the group consisting of: O, S, Se, and NR_{N2};
Rₐ, R_{b}, R_{c}, and R_{N2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted amino having 0 to 20 carbon atoms, an acyl group, a carbonyl group, a carboxylic acid group, an ester group, a cyano group, an isocyano group, a sulfanyl group, a sulfinyl group, a sulfonyl group, a phosphino group, and combinations thereof;
adjacent substituents Rₐ, R_{b}, R_{c}, and R_{N2} can be optionally joined to form a ring;
L_{c} is selected from a mono-anionic bidentate ligand.

According to another embodiment of the present disclosure, an electroluminescent device is further disclosed, which comprisies an anode, a cathode, and an organic layer disposed between the anode and the cathode, wherein the organic layer comprises a metal complex whose specific structure is as shown in the preceding embodiment.

According to another embodiment of the present disclosure, a compound composition is further disclosed, which comprises a metal complex whose specific structure is as shown in the preceding embodiment.

These metal complexes comprising a ligand having a structure of Formula 1 and a ligand having a structure of Formula 3 in the present disclosure can achieve deep red and near-infrared light emission and have strong hole trapping abilities. These metal complexes have excellent properties and potential application prospects of becoming excellent deep red emissive materials.

### BRIEF DESCRIPTION OF DRAWINGS

FIG. 1 is a schematic diagram of an organic light-emitting device that may contain a metal complex and a compound composition disclosed herein.

FIG. 2 is a schematic diagram of another organic light-emitting device that may contain a metal complex and a compound composition disclosed herein.

### DETAILED DESCRIPTION

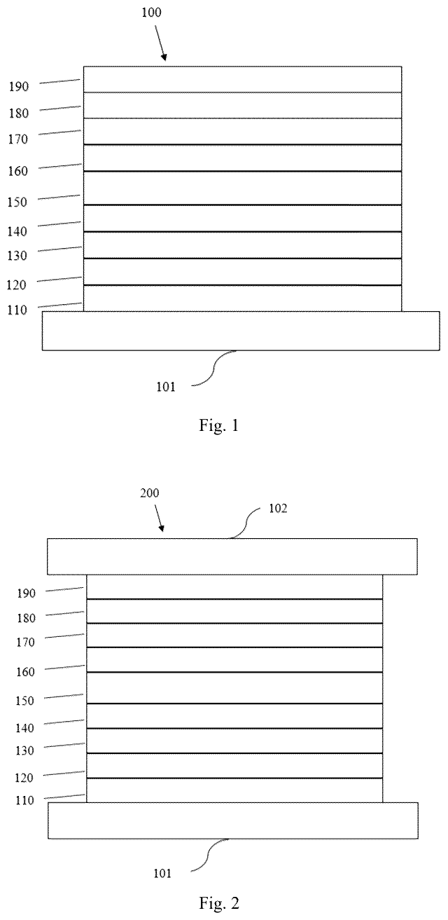

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AEs-T). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small AEs-T. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, an n-butyl group, an s-butyl group, an isobutyl group, a 1-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butyldimethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl, and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by—O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by—O-aryl or—O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl 1-butylsilyl. Additionally, the arylsilyl group may be optionally substituted.

Alkylgermanyl—as used herein contemplates a germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylisopropylgermanyl, diphenylmethylgermanyl, phenyldiisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more groups selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl group having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitutions refer to a range that includes di-substitutions, up to the maximum available substitutions. When substitution in the compounds mentioned in the present disclosure represents multiple substitutions (including di-, tri-, and tetra-substitutions etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

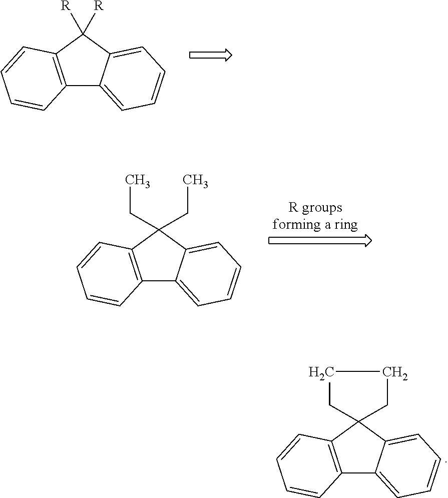

The expression that adjacent substituents can be optionally joined to form a ring is also intended to mean that two substituents bonded to carbon atoms which are directly bonded to each other are joined to each other via a chemical bond to form a ring, which can be exemplified by the following formula:

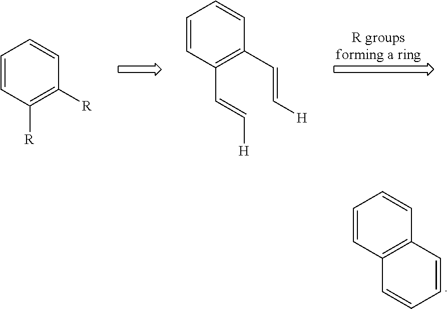

The expression that adjacent substituents can be optionally joined to form a ring is also intended to mean that two substituents bonded to further distant carbon atoms are joined to each other via a chemical bond to form a ring, which can be exemplified by the following formula:

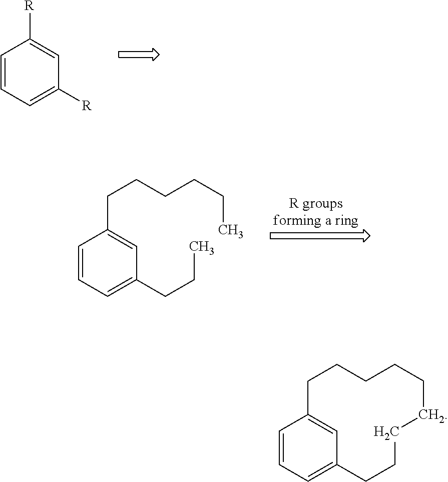

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

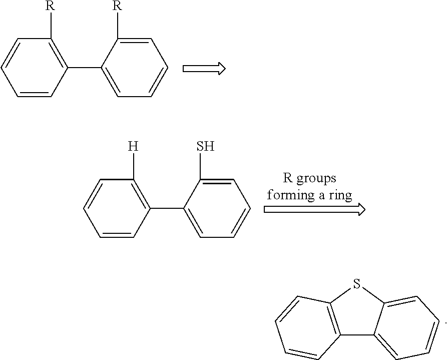

According to an embodiment of the present disclosure, a metal complex is disclosed, which has a general formula of M (Lₐ)ₘ (L_{b})ₙ (L_{c})_{q}; wherein the metal M is selected from a metal with a relative atomic mass greater than 40, and Lₐ, L_{b}, and L_{c} are a first ligand, a second ligand, and a third ligand coordinated to the metal M, respectively;
Lₐ, L_{b}, and L_{c} can be optionally joined to form a multidentate ligand;
m is selected from 1 or 2, n is selected from 1 or 2, q is selected from 0 or 1, and m+n+q equals the oxidation state of the metal M; when m is equal to 2, two Lₐ are the same or different; when n is equal to 2, two L_{b} are the same or different;
the first ligand Lₐ has a structure represented by Formula 1:

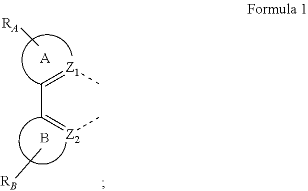

wherein Z₁ and Z₂ are each independently selected from C or N, and Z₁ is different from Z₂;
the ring A is selected from an unsaturated carbocyclic ring having 2 to 30 carbon atoms or an unsaturated heterocyclic ring having 2 to 30 ring atoms; and the ring B is selected from an unsaturated carbocyclic ring having 4 to 30 carbon atoms or an unsaturated heterocyclic ring having 4 to 30 ring atoms;
the ring B at least comprises one structure represented by Formula 2:

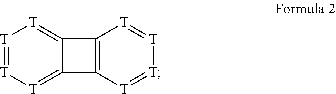

wherein T is, at each occurrence identically or differently, selected from C or N;
R_{A} and R_{B} represent, at each occurrence identically or differently, mono-substitution, multiple substitutions or non-substitution;
R_{A} and R_{B} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{A} and R_{B} can be optionally joined to form a ring;
L_{b} has a structure represented by Formula 3:

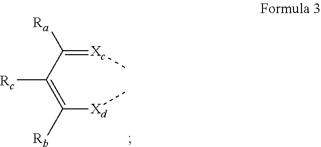

wherein X_{c} and X_{d} are, at each occurrence identically or differently, selected from the group consisting of: O, S, Se, and NR_{N2};
Rₐ, R_{b}, R_{c}, and R_{N2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted amino having 0 to 20 carbon atoms, an acyl group, a carbonyl group, a carboxylic acid group, an ester group, a cyano group, an isocyano group, a sulfanyl group, a sulfinyl group, a sulfonyl group, a phosphino group, and combinations thereof;
adjacent substituents Rₐ, R_{b}, R_{c}, and R_{N2} can be optionally joined to form a ring;
L_{c} is selected from a mono-anionic bidentate ligand.

According to an embodiment of the present disclosure, the ring B has a structure represented by Formula 2, and Lₐ has a structure represented by Formula 4, Formula 5 or Formula 6:

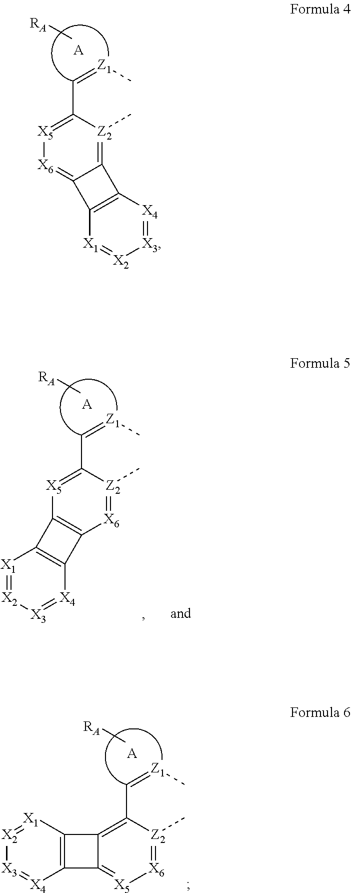

wherein Z₁ and Z₂ are each independently selected from C or N, and Z₁ is different from Z₂;
X₁ to X₆ are, at each occurrence identically or differently, selected from N or CR_{X};
R_{A} represents, at each occurrence identically or differently, mono-substitution, multiple substitutions or non-substitution;
R_{A} and R_{X} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; adjacent substituents R_{A} and R_{X} can be optionally joined to form a ring.

According to an embodiment of the present disclosure, R_{X} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted alkenyl having 2 to 20 carbon atoms, substituted or unsubstituted alkynyl having 2 to 20 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, and the combinations thereof; adjacent substituents R_{X} can be optionally joined to form a ring.

According to an embodiment of the present disclosure, the ring A is selected from the group consisting of the following structures:

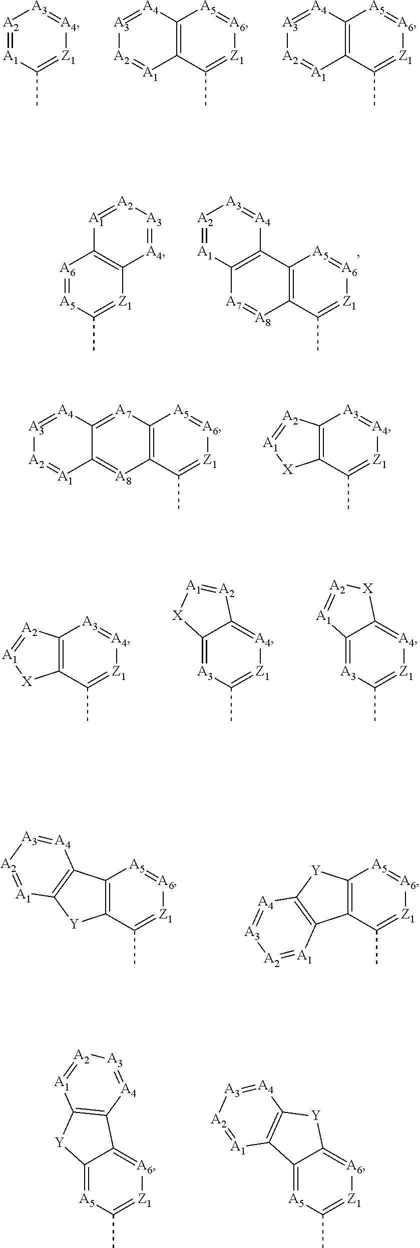

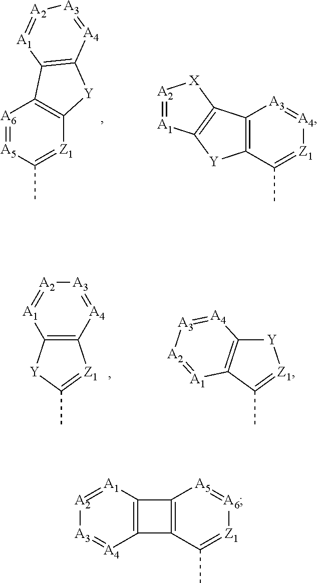

wherein A₁ to A₈ are, at each occurrence identically or differently, selected from N or CR_{A};
X is, at each occurrence identically or differently, selected from O, S, Se, NR_{X}, CR_{X}R_{X}, SiR_{X}R_{X} or PR_{X}; when a plurality of R_{X} are present at the same time, the plurality of R_{X} are the same or different;
Y is, at each occurrence identically or differently, selected from O, S, Se, NR_{Y}, CR_{Y}R_{Y}, SiR_{Y}R_{Y} or PR_{Y}; when a plurality of R_{Y} are present at the same time, the plurality of R_{Y} are the same or different;
R_{A}, R_{X}, and R_{Y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{A}, R_{X}, and R_{Y} can be optionally joined to form a ring.

According to an embodiment of the present disclosure, the first ligand Lₐ is selected from a structure represented by any one of Formula 7 to Formula 30:

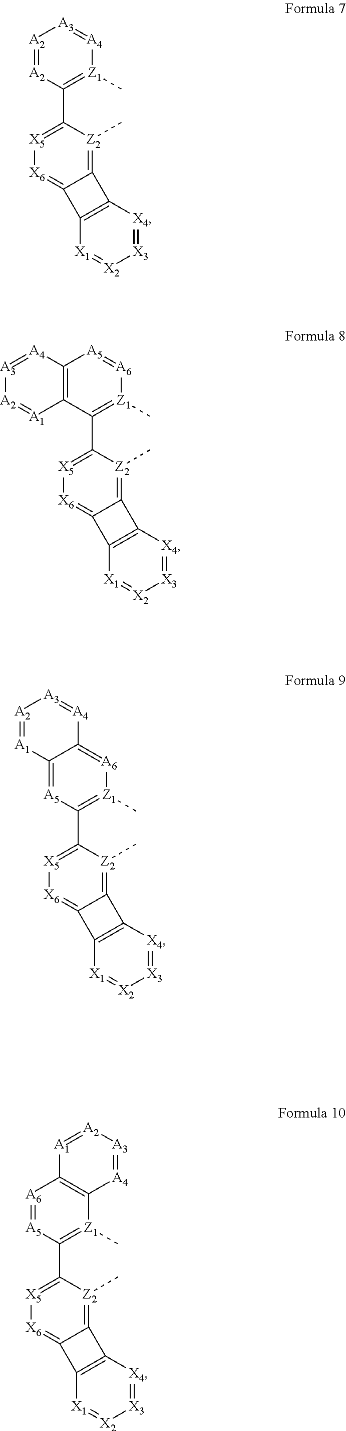

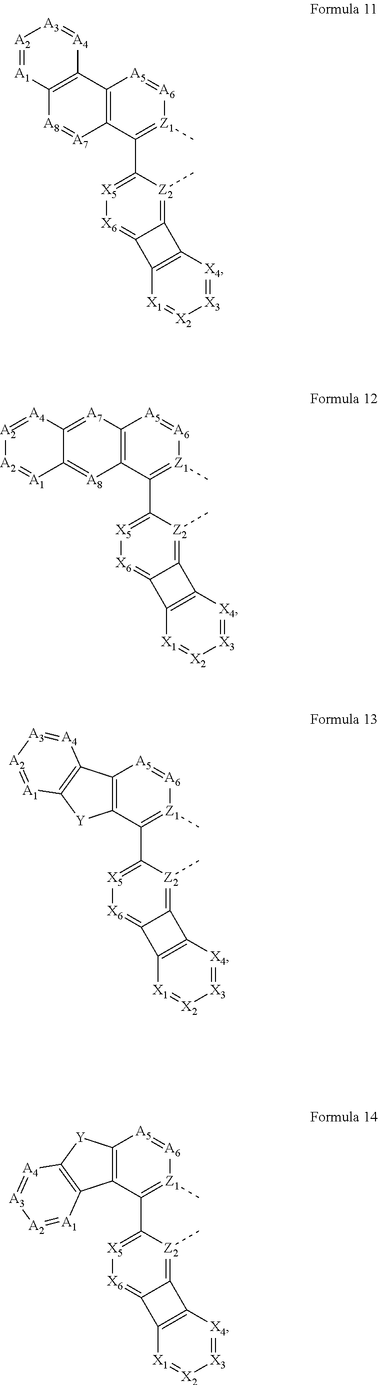

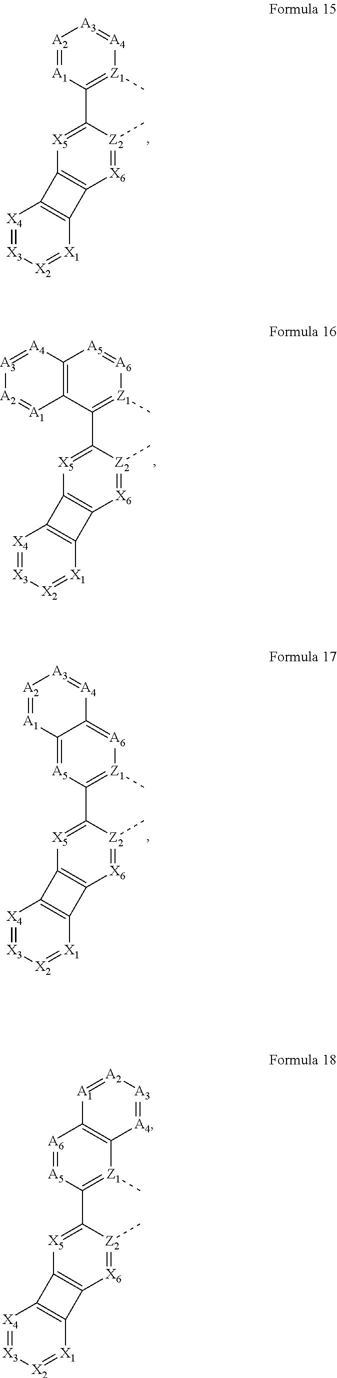

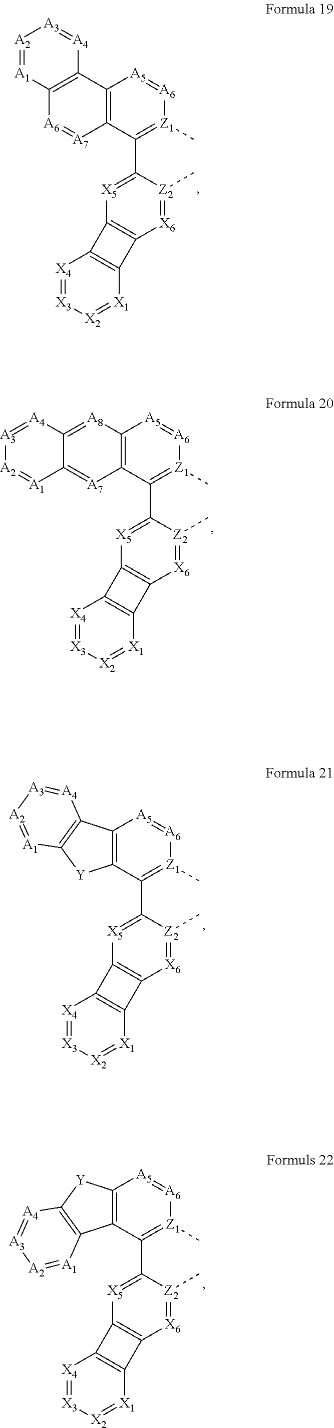

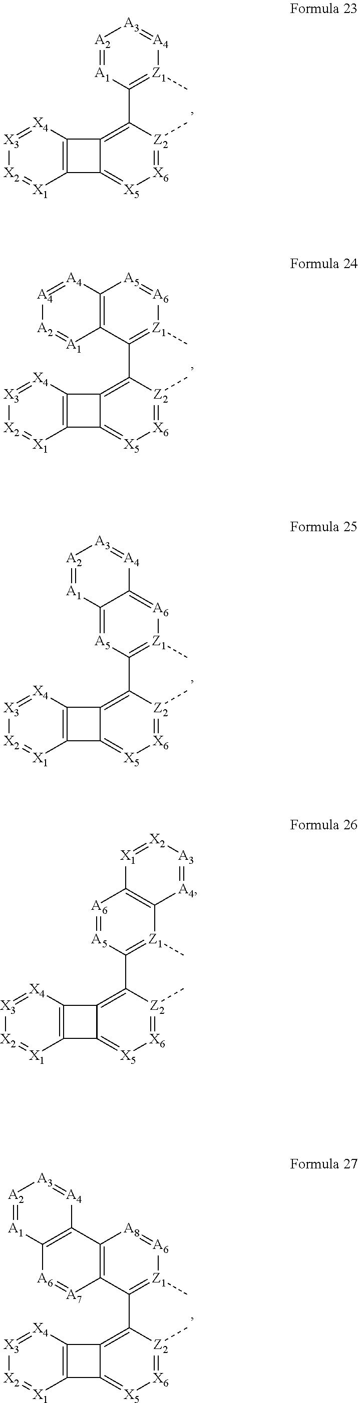

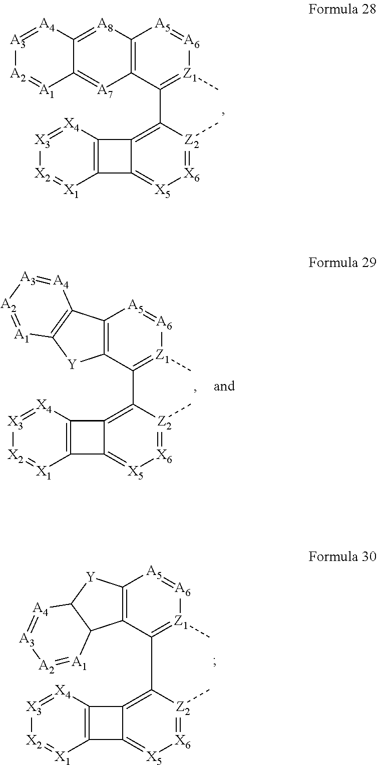

wherein
Z₁ and Z₂ are each independently selected from C or N, and Z₁ is different from Z₂;
Y is, at each occurrence identically or differently, selected from O, S, Se, NR_{Y}, CR_{Y}R_{Y}, SiR_{Y}R_{Y} or PR_{Y}; when a plurality of R_{Y} are present at the same time, the plurality of R_{Y} are the same or different;
A₁ to A₈ are, at each occurrence identically or differently, selected from N or CR_{A};
X₁ to X₄ are, at each occurrence identically or differently, selected from N or CR_{X}, and X₅ and X₆ are, at each occurrence identically or differently, selected from N or CR_{Xi};
R_{A}, R_{X}, R_{Xi}, and R_{Y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a sulfanyl group, a sulfinyl group, a sulfonyl group, a phosphino group, and combinations thereof;
adjacent substituents R_{A}, R_{X}, R_{Xi}, and R_{Y} can be optionally joined to form a ring.

According to an embodiment of the present disclosure, Z₁ is C, and Z₂ is N.

According to an embodiment of the present disclosure, Lₐ is selected from a structure represented by any one of Formula 7, Formula 8, Formula 10, Formula 15, Formula 16, Formula 18, Formula 19, Formula 21, Formula 23, Formula 24, Formula 26, Formula 27 or Formula 29.

According to an embodiment of the present disclosure, Lₐ is selected from a structure represented by any one of Formula 7, Formula 8, Formula 10, Formula 13, Formula 15, Formula 16, Formula 18, Formula 23, Formula 24 or Formula 26.

According to an embodiment of the present disclosure, in Formula 7 to Formula 30, at least one of A₁ to A_{N} and/or at least one of X₁ to X_{M} is selected from N.

According to an embodiment of the present disclosure, in Formula 7, Formula 15, and Formula 23, at least one of A₃ and A₄ and/or at least one of X₅ and X₆ is selected from N, and in Formula 8 to Formula 14, Formula 16 to Formula 22, and Formula 24 to Formula 30, at least one of A₅ and A₆ and/or at least one of X₅ and X₆ is selected from N.

According to an embodiment of the present disclosure, in Formula 7, Formula 15, and Formula 23, A₃ and/or X₅ is selected from N, and in Formula 8 to Formula 14, Formula 16 to Formula 22, and Formula 24 to Formula 30, A₅ and/or X₅ is selected from N.

According to an embodiment of the present disclosure, in Formula 7 to Formula 30, A₁ to Av are each independently selected from CR_{A}, and X₁ to X₄ are each independently selected from CR_{X}; X₅ to X₆ are each independently selected from CR_{Xi}, and adjacent substituents R_{A}, R_{X}, and R_{Xi} can be optionally joined to form a ring.

According to an embodiment of the present disclosure, the R_{A}, R_{X}, and R_{Xi} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, and combinations thereof.

According to an embodiment of the present disclosure, at least one or two of R_{A}, R_{X}, and R_{Xi} are, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, and combinations thereof.

According to an embodiment of the present disclosure, in Formula 7 to Formula 30, A₁ to Ag are each independently selected from CR_{A}, X₁ to X₄ are each independently selected from CR_{X}, and adjacent substituents R_{A} and R_{X} can be optionally joined to form a ring.

According to an embodiment of the present disclosure, R_{A} and R_{X} are identically or differently selected from hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, or a combination thereof.

According to an embodiment of the present disclosure, R_{A} and R_{X} are, at each occurrence identically or differently, selected from the group consisting of: hydrogen, deuterium, fluorine, methyl, ethyl, isopropyl, isobutyl, t-butyl, neopentyl, cyclopentyl, cyclopentylmethyl, cyclohexyl, norbornyl, adamantyl, trimethylsilyl, isopropyldimethylsilyl, phenyldimethylsilyl, trifluoromethyl, cyano, phenyl, and combinations thereof.

According to an embodiment of the present disclosure, at least one or two of A₁ to A₄ are selected from CR_{A} and/or at least one or two of X₁ to X₄ are selected from CR_{X}; R_{A} and R_{X} are, at each occurrence identically or differently, selected from the group consisting of: deuterium, fluorine, methyl, ethyl, isopropyl, isobutyl, t-butyl, neopentyl, cyclopentyl, cyclopentylmethyl, cyclohexyl, norbornyl, adamantyl, trimethylsilyl, isopropyldimethylsilyl, phenyldimethylsilyl, trifluoromethyl, cyano, phenyl, and combinations thereof.

According to an embodiment of the present disclosure, in Formula 7 to Formula 30, at least one of X₅ or X₆ is selected from CR_{Xi}, and the R_{Xi} is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, and combinations thereof.

According to an embodiment of the present disclosure, the R_{X} is, at each occurrence identically or differently, selected from the group consisting of: deuterium, fluorine, methyl, ethyl, isopropyl, isobutyl, t-butyl, neopentyl, cyclopentyl, cyclopentylmethyl, cyclohexyl, norbornyl, adamantyl, trimethylsilyl, isopropyldimethylsilyl, phenyldimethylsilyl, trifluoromethyl, cyano, phenyl, and combinations thereof.

According to an embodiment of the present disclosure, in Formula 7 to Formula 14, at least one of X₅ or X₆ is selected from CR_{Xi}, and the R_{Xi} is, at each occurrence identically or differently, selected from the group consisting of: deuterium, fluorine, methyl, ethyl, isopropyl, isobutyl, 1-butyl, neopentyl, cyclopentyl, cyclopentylmethyl, cyclohexyl, norbornyl, adamantyl, trimethylsilyl, isopropyldimethylsilyl, phenyldimethylsilyl, trifluoromethyl, cyano, phenyl, and combinations thereof; in Formula 15 to Formula 30, at least one of X₅ or X₆ is selected from CR_{Xi}, and the R^{Xi} is selected from the group consisting of: deuterium, fluorine, and methyl.

According to an embodiment of the present disclosure, in Formula 13, Formula 14, Formula 21, Formula 22, Formula 29, and Formula 30, Y is, at each occurrence identically or differently, selected from O, S, NR_{Y}, CR_{Y}R_{Y} or SiR_{Y}R_{Y}; and when a plurality of R_{Y} are present at the same time, the plurality of R_{Y} are the same or different:
the R_{Y} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present invention, Y is O or S.

According to an embodiment of the present disclosure, Lₐ is, at each occurrence identically or differently, selected from the group consisting of Lₐ₁ to Lₐ₇₁₅, wherein the specific structures of Lₐ₁ to Lₐ₇₁₅ are referred to claim 10.

According to an embodiment of the present disclosure, the metal M is selected from Ir, Rh, Re, Os, Pt, Au or Cu.

According to an embodiment of the present disclosure, the metal M is selected from Ir, Pt or Os.

According to an embodiment of the present disclosure, L_{b} is, at each occurrence identically or differently, selected from the following structure:

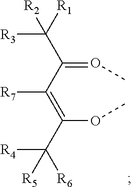

wherein R₁ to R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a sulfanyl group, a sulfinyl group, a sulfonyl group, a phosphino group, and combinations thereof; adjacent substituents R₁ to R₃ or R₄ to R₆ can be optionally joined to form a ring.

According to an embodiment of the present disclosure, at least one or two of R₁ to R₃ are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, or a combination thereof; and/or at least one or two of R₄ to R₆ are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, or a combination thereof.

According to an embodiment of the present disclosure, at least two of R₁ to R₃ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms, or a combination thereof; and/or at least two of R₄ to R₆ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms, or a combination thereof.

According to an embodiment of the present disclosure, L_{c} is selected from the group consisting of the following structures:

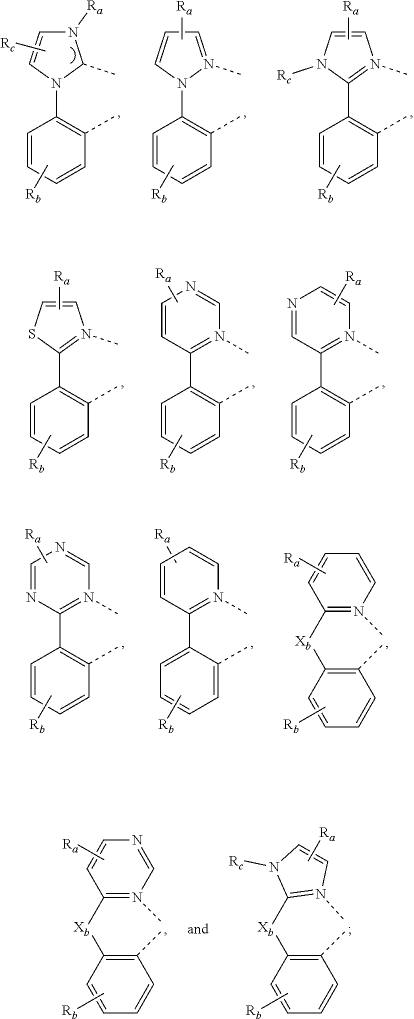

wherein Rₐ, R_{b}, and R_{c} represent, at each occurrence identically or differently, mono-substitution, multiple substitutions or non-substitution;
X_{b} is, at each occurrence identically or differently, selected from the group consisting of: O, S, Se, NR_{N1} and CR_{C1}R_{C2};
Rₐ, R_{b}, R_{c}, R_{N1}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a sulfanyl group, a sulfinyl group, a sulfonyl group, a phosphino group, and combinations thereof;
adjacent substituents Rₐ, R_{b}, R_{c}, R_{N1}, R_{C1}, and R_{C2} can be optionally joined to form a ring.

According to an embodiment of the present disclosure, L_{b} is, at each occurrence identically or differently, selected from the group consisting of L_{b1} to L_{b322}, and Le is, at each occurrence identically or differently, selected from the group consisting of L_{c1} to L_{c231}, wherein the specific structures of L_{b1} to L_{b322} and L_{c1} to L_{c231} are referred to claim 14.

According to an embodiment of the present disclosure, the metal complex has a structure of Ir(Lₐ)₂ (L_{b}) or Ir(Lₐ)(L_{b})(L_{c}); when the metal complex has the structure of Ir(Lₐ)₂(L_{b}), Lₐ is, at each occurrence identically or differently, selected from any one or two of the group consisting of Lₐ₁ to Lₐ₇₁₅, and L_{b} is selected from any one of the group consisting of L_{b1} to L_{b322}; when the metal complex has the structure of Ir(Lₐ)(L_{b})₂, Lₐ is selected from any one of the group consisting of Lₐ₁ to Lₐ₇₁₅, and L_{b} is, at each occurrence identically or differently, selected from any one or two of the group consisting of L_{b1} to L_{b332}; when the metal complex has the structure of Ir(Lₐ)(L_{b})(L_{c}), Lₐ is, at each occurrence identically or differently, selected from any one of the group consisting of Lₐ₁ to Lₐ₇₁₅, L_{b} is, at each occurrence identically or differently, selected from any one of the group consisting of L_{b1} to L_{b332}, and L_{c} is elected from any one of the group consisting of L_{c1} to L_{c231}.

According to an embodiment of the present disclosure, the metal complex is selected from the group consisting of Compound 1 to Compound 794, wherein the specific structures of Compound 1 to Compound 794 are referred to claim 15.

According to another embodiment of the present disclosure, an electroluminescent device is further disclosed, which comprises an anode, a cathode, and an organic layer disposed between the anode and the cathode, wherein the organic layer comprises a metal complex whose specific structure is as shown in the preceding embodiments.

According to an embodiment of the present disclosure, the organic layer is an emissive layer, and the metal complex is an emissive material.

According to an embodiment of the present disclosure, the electroluminescent device emits dark red light, infrared light or white light.

According to an embodiment of the present disclosure, the emissive layer further comprises at least one host material.

According to an embodiment of the present disclosure, at least one host material comprises at least one chemical group selected from the group consisting of: benzene, pyridine, pyrimidine, triazine, carbazole, azacarbazole, indolocarbazole, dibenzothiophene, azadibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

According to an embodiment of the present disclosure, in the electroluminescent device, the emissive layer further comprises a first host material and a second host material.

According to an embodiment of the present disclosure, the first host material has a structure represented by Formula 4-1, Formula 4-2 or Formula 4-3:

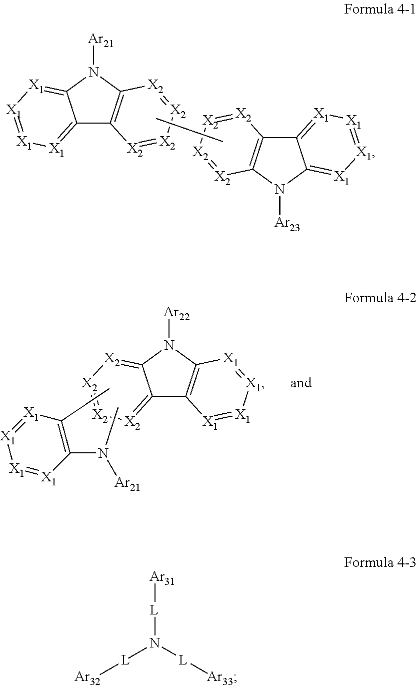

wherein X₁ is, at each occurrence identically or differently, selected from CRₓ or N;
X₂ is, at each occurrence identically or differently, selected from C, CRₓ or N;
L is, at each occurrence identically or differently, selected from a single bond, substituted or unsubstituted arylene having 6 to 30 carbon atoms, substituted or unsubstituted heteroarylene having 3 to 30 carbon atoms, or a combination thereof;
Ar₂₁, Ar₂₂, Ar₃₁, Ar₃₂, and Ar₃₃ are, at each occurrence identically or differently, selected from substituted or unsubstituted aryl having 6 to 30 carbon atoms or substituted or unsubstituted heteroaryl having 3 to 30 carbon atoms;
Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₓ can be optionally joined to form a ring.

Herein, the expression that adjacent substituents Rₓ can be optionally joined to form a ring is intended to mean that a group of adjacent substituents, such as adjacent substituents Rₓ, can be joined to form a ring. Obviously, it is also possible that none of these substituents are joined to form a ring.

According to an embodiment of the present disclosure, the first host material has a structure represented by Formula 4-1-1, Formula 4-2-1 or Formula 4-3-1:

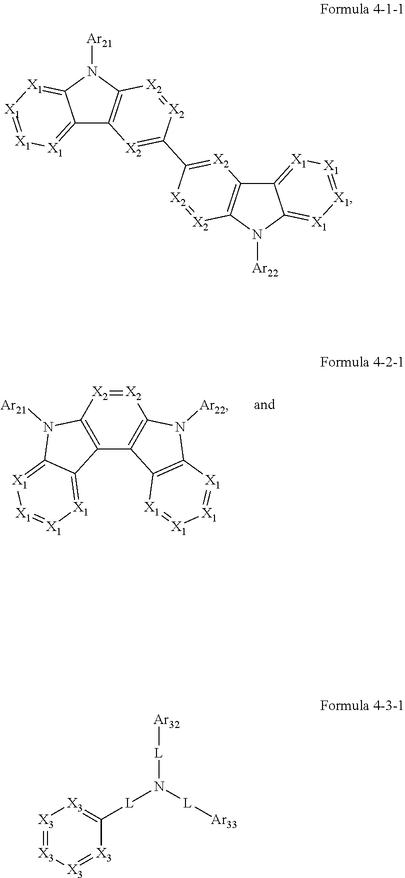

wherein X₁, X₂, and X₃ are, at each occurrence identically or differently, selected from CRₓ or N;
Ar₂₁, Ar₂₂, Ar₃₂, and Ar₃₃ are, at each occurrence identically or differently, selected from substituted or unsubstituted aryl having 6 to 30 carbon atoms or substituted or unsubstituted heteroaryl having 3 to 30 carbon atoms;
L is, at each occurrence identically or differently, selected from a single bond, substituted or unsubstituted arylene having 6 to 30 carbon atoms, substituted or unsubstituted heteroarylene having 3 to 30 carbon atoms, or a combination thereof;
Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₓ can be optionally joined to form a ring.

According to an embodiment of the present disclosure, the first host material is selected from the group consisting of Compound 1-1-1 to Compound 1-1-104, Compound 1-2-1 to Compound 1-2-100, and Compound 1-3-1 to Compound Jan. 3, 1962, wherein the specific structures of Compound 1-1-1 to Compound Jan. 3, 1962 are referred to claim 19.

According to an embodiment of the present disclosure, hydrogens in Compound 1-1-1 to Compound 1-1-104, Compound 1-2-1 to Compound 1-2-100, and Compound 1-3-1 to Compound Jan. 3, 1962 can be partially or fully substituted with deuterium.

According to an embodiment of the present disclosure, the second host material has a structure represented by Formula 5:

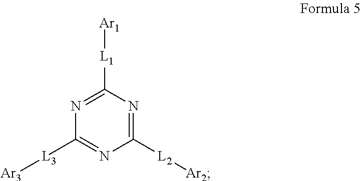

wherein L₁ to L₃ are, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, or a combination thereof;

Ar₁ to Ar₃ are, at each occurrence identically or differently, selected from substituted or unsubstituted aryl having 6 to 30 carbon atoms, substituted or unsubstituted heteroaryl having 3 to 30 carbon atoms, or a combination thereof.

According to an embodiment of the present disclosure, the second host material has a structure represented by Formula 5-1 or Formula 5-2:

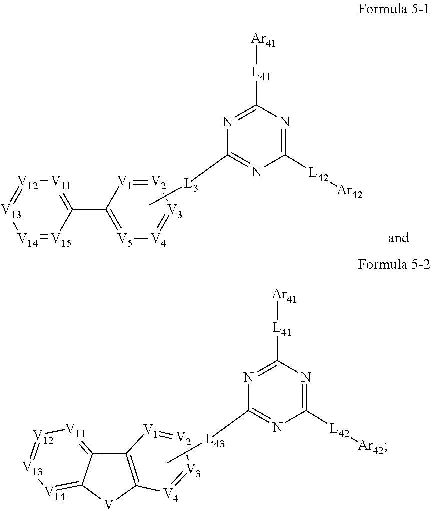

wherein in Formula 5-1, V₁ to V₅ are, at each occurrence identically or differently, selected from C, N or CRᵥ, V₁₁ to V₁₅ are, at each occurrence identically or differently, selected from N or CRᵥ₁, and one of V₁ to V₅ is C and is joined to L₄₃;
in Formula 5-2, V₁ to V₄ are, at each occurrence identically or differently, selected from C, N or CRᵥ, V₁₁ to V₁₄ are, at each occurrence identically or differently, selected from N or CRᵥ₁, and one of V₁ to V₄ is C and is joined to L₄₃;
V is selected from O, S or Se;
L₄₁ to L₄₃ are, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, or a combination thereof;
Ar₄₁ and Ar₄₂ are, at each occurrence identically or differently, selected from substituted or unsubstituted aryl having 6 to 30 carbon atoms, substituted or unsubstituted heteroaryl having 3 to 30 carbon atoms, or a combination thereof;
Rᵥ and Rᵥ₁ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; adjacent substituents Rᵥ and Rᵥ₁ can be optionally joined to form a ring.

Herein, the expression that adjacent substituents Rᵥ and Rᵥ₁ can be optionally joined to form a ring is intended to mean that any one or more of groups of adjacent substituents, such as adjacent substituents Rᵥ, adjacent substituents Rᵥ₁, and adjacent substituents Rᵥ and Rᵥ₁, can be joined to form a ring. Obviously, it is also possible that none of these substituents are joined to form a ring.

According to an embodiment of the present disclosure, at least one of Ar₄₁ or Ar₄₂ is a structure with two or three fused rings.

According to an embodiment of the present disclosure, the Ar₄₁ and Ar₄₂ are, at each occurrence identically or differently, selected from substituted or unsubstituted phenyl, substituted or unsubstituted biphenyl, substituted or unsubstituted terphenyl, substituted or unsubstituted naphthyl, substituted or unsubstituted phenanthryl, substituted or unsubstituted triphenylenyl, substituted or unsubstituted chrysenyl, substituted or unsubstituted fluorenyl, substituted or unsubstituted carbazolyl, substituted or unsubstituted dibenzofuryl, substituted or unsubstituted dibenzothienyl, substituted or unsubstituted pyridyl, substituted or unsubstituted pyrimidinyl, substituted or unsubstituted quinolyl, substituted or unsubstituted indolocarbazolyl, or a combination thereof.

According to an embodiment of the present disclosure, in the third compound, L₄₁ to L₄₃ are, at each occurrence identically or differently, selected from a single bond, substituted or unsubstituted phenylene, substituted or unsubstituted naphthylene, substituted or unsubstituted biphenylylene, or a combination thereof.

According to an embodiment of the present disclosure, the second host material is selected from the group consisting of Compound B-1 to Compound B-236, wherein the specific structures of Compound B-1 to Compound B-236 are referred to claim 19.

According to an embodiment of the present disclosure, hydrogens in Compound B-1 to Compound B-236 can be partially or fully substituted with deuterium.

According to an embodiment of the present disclosure, the at least one host material comprises at least one chemical group selected from the group consisting of: benzene, pyridine, pyrimidine, triazine, carbazole, azacarbazole, indolocarbazole, dibenzothiophene, azadibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

According to another embodiment of the present disclosure, a compound composition is further disclosed. The specific structure of the compound is as shown in any of the preceding embodiments.

Combination with Other Materials

The materials described in the present disclosure for a particular layer in an organic light emitting device can be used in combination with various other materials present in the device. The combinations of these materials are described in more detail in U.S. patent application No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, light-emitting dopants disclosed herein may be used in combination with a wide variety of hosts, transporting layers, blocking layers, injection layers, electrodes, and other layers that may be present. The combination of these materials is described in detail in paragraphs 0080-0101 of U.S. patent application No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (comprising, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (comprising, but not limited to, evaporator produced by ANGSTROM ENGINEERING, optical testing system produced by SUZHOU FSTAR, life testing system produced by SUZHOU FSTAR, and ellipsometer produced by BEIJING ELLITOP, etc.) by methods well known to the persons skilled in the art. As the persons skilled in the art are aware of the above-mentioned equipment use, test methods, and other related contents, the inherent data of the sample can be obtained with certainty and without influence, so the above related contents are not further described in this patent.

### Material Synthesis Example

The method for preparing the compound of the present disclosure is not limited herein. Those skilled in the art may select appropriate raw materials and process routes based on the synthesis target. For example, the metal complex of the present disclosure may be synthesized according to the following route.

First, the ligand compound Lₐ is prepared by referring to existing techniques, such as the method described in CN111269269A. After the ligand compound Lₐ is obtained, the target metal complex is prepared by employing a commonly used synthesis method in the existing art. For example, the ligand compound Lₐ reacts with iridium trichloride trihydrate to obtain an iridium dimer, and the iridium dimer then reacts with the ligand L_{b} to yield the target metal complex. The schematic synthetic route is as follows:

### Step1:

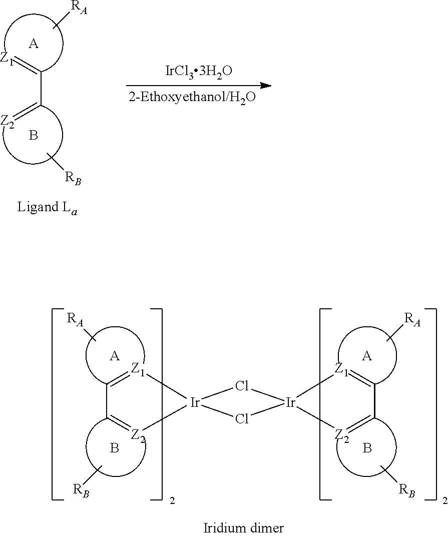

### Step2:

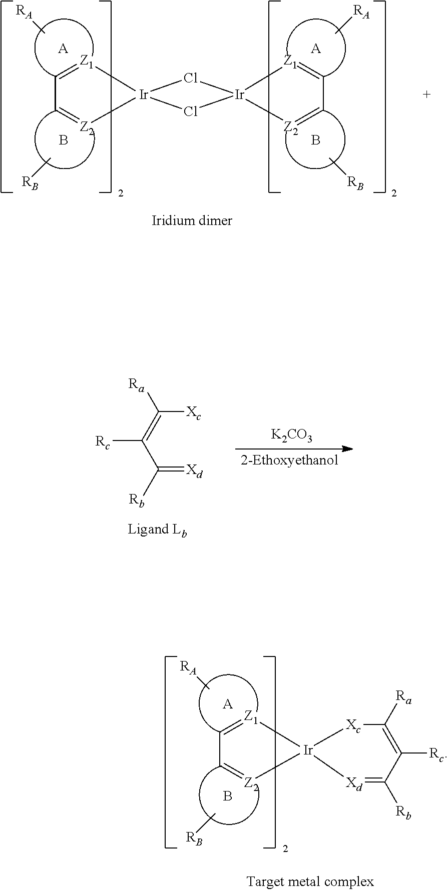

During the synthesis of the metal complex of the present disclosure, those skilled in the art may also refer to existing techniques or synthesis methods documented in prior applications such as US20190103574A₁, US20220109118A₁, and CN117534709A; or, those skilled in the art may design synthetic routes through retrosynthetic analysis to effectively synthesize the metal complex of the present disclosure.

Those skilled in the art will appreciate that the above preparation methods are merely exemplary. Those skilled in the art can obtain other compound structures of the present disclosure through the modifications of the preparation methods.

Since the compounds of the present disclosure can achieve deep red to near-infrared light emission due to their ligand design featuring a biphenylene structure, to further verify the luminescent effect, the energy levels of some representative compounds of the present disclosure were determined through discrete Fourier transformation (DFT) calculations.

The DFT calculations performed on the compounds of the present disclosure are as follows:

Using the B3LYP hybrid functional and the CEP-31G effective core potential basis set within the Gaussian software package and using the SMD solvation model to simulate the THF solvent environment, the DFT calculations were performed on some compounds disclosed in the present disclosure and the compounds RD-A, RD-B, and RD-C in Comparative Examples. Data such as triplet energy levels (T₁), HOMO energy levels, and LUMO energy levels of these compounds were obtained, and according to the conversion formula, λ (nm)=1240/T₁, the maximum emission wavelength λ (nm) of the compounds was derived. The data are recorded and are presented in Table 1.

TABLE 1
Calculated data

| Compound No. | T₁ (eV) | λ (nm) | HOMO (eV) | LUMO (eV) |
|---|---|---|---|---|
| Compound 65 | 1.7204 | 721 | −4.98 | −1.78 |
| Compound 69 | 1.6029 | 774 | −4.99 | −2.12 |
| Compound 73 | 1.6624 | 746 | −4.97 | −2.1 |
| Compound 83 | 1.7693 | 701 | −4.73 | −2.05 |
| Compound 239 | 1.6918 | 733 | −4.76 | −2.21 |
| Compound 241 | 1.6555 | 749 | −4.79 | −2.34 |
| Compound 249 | 1.7538 | 707 | −4.83 | −2.17 |
| Compound 289 | 1.5886 | 781 | −5.08 | −2.26 |
| Compound 293 | 1.5886 | 781 | −5.06 | −2.24 |
| Compound 295 | 1.5801 | 785 | −5.00 | −2.24 |
| Compound 301 | 1.7795 | 697 | −4.92 | −2.15 |
| Compound 313 | 1.6884 | 734 | −4.84 | −1.92 |
| Compound 327 | 1.7028 | 728 | −5.12 | −2.16 |
| Compound 329 | 1.6722 | 742 | −5.09 | −2.15 |
| Compound 779 | 1.6329 | 759 | −5.08 | −2.19 |
| Compound 780 | 1.7040 | 728 | −5.10 | −2.20 |
| Compound | 1.9840 | 625 | −4.99 | −2.07 |
| RD-A | | | | |

The structures of the compounds in Table I are as follows:

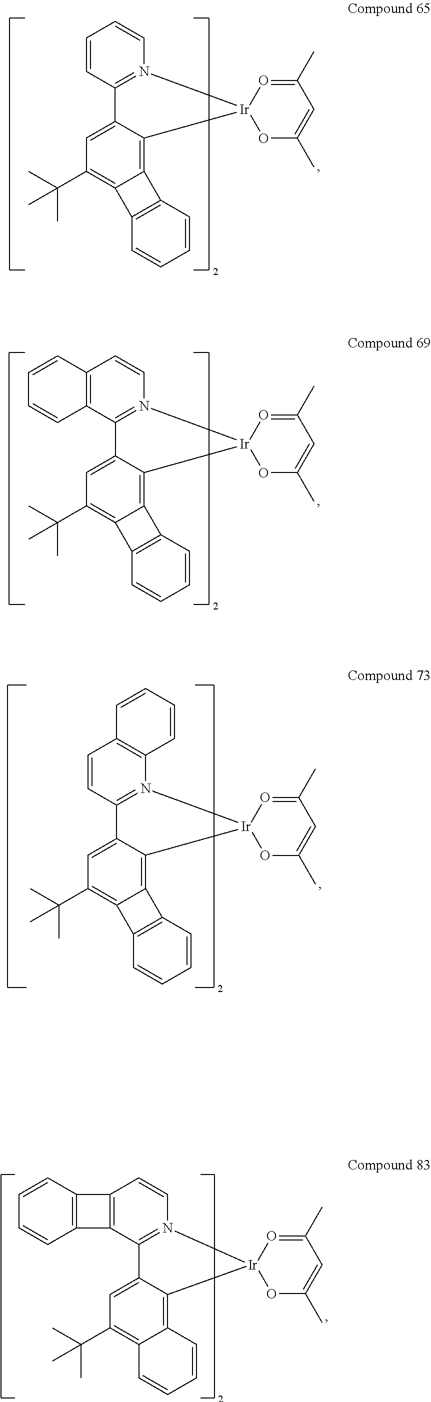

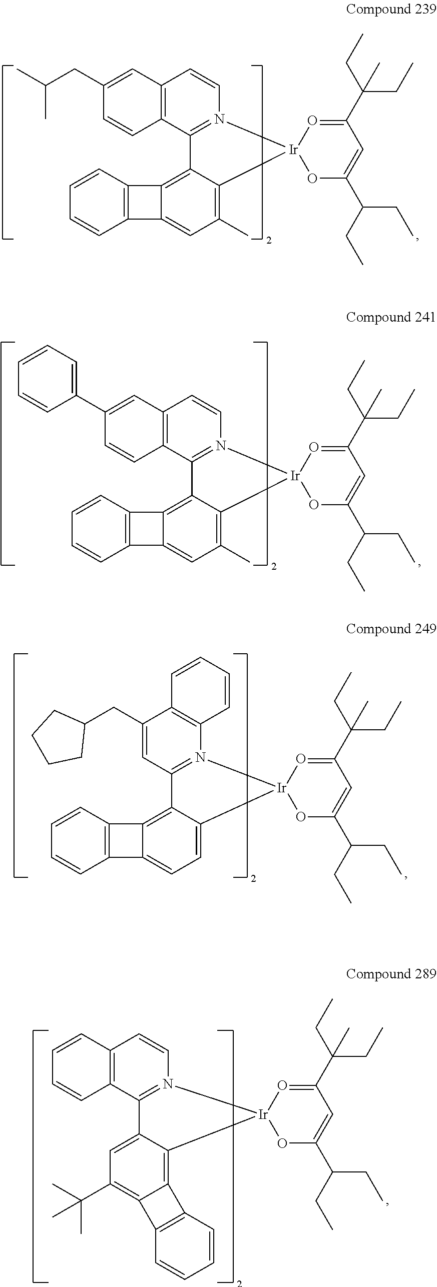

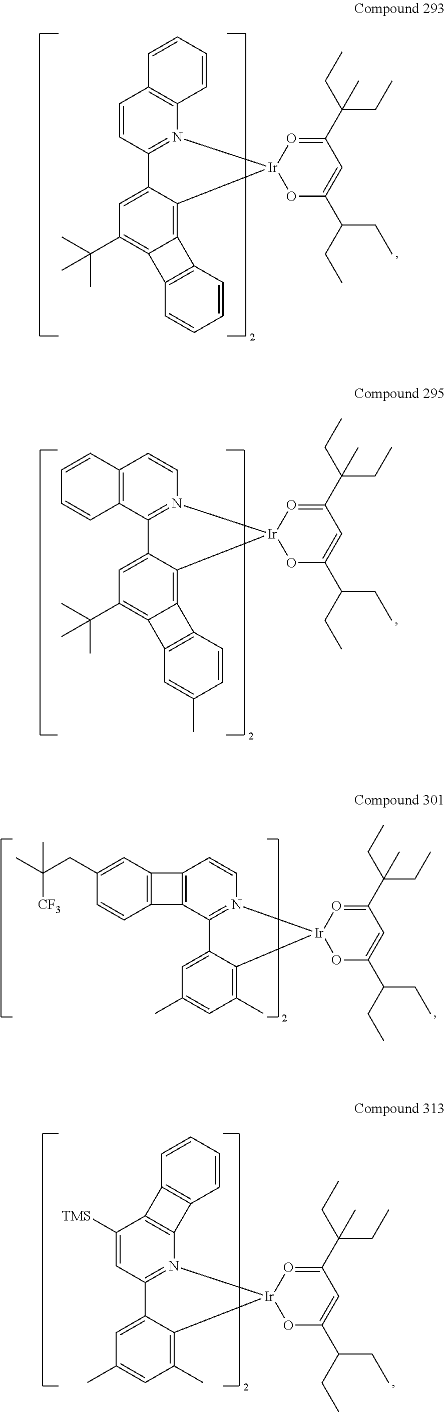

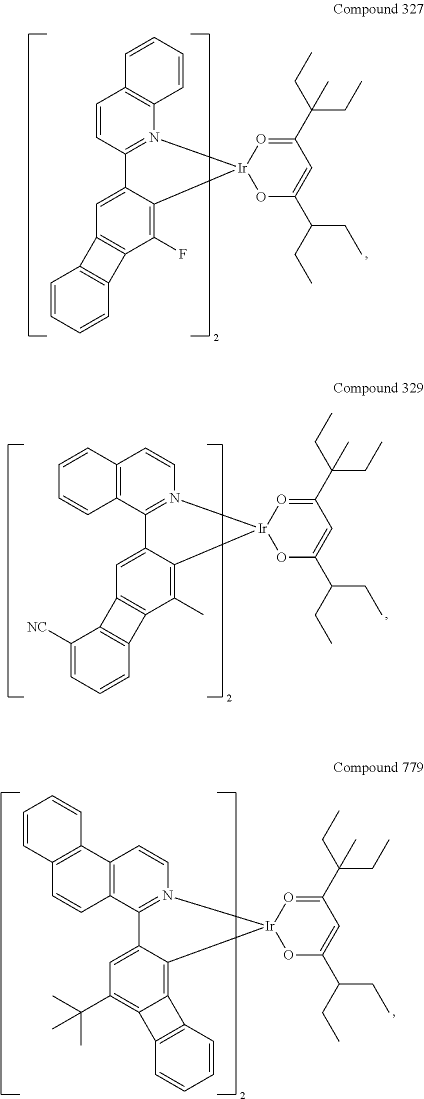

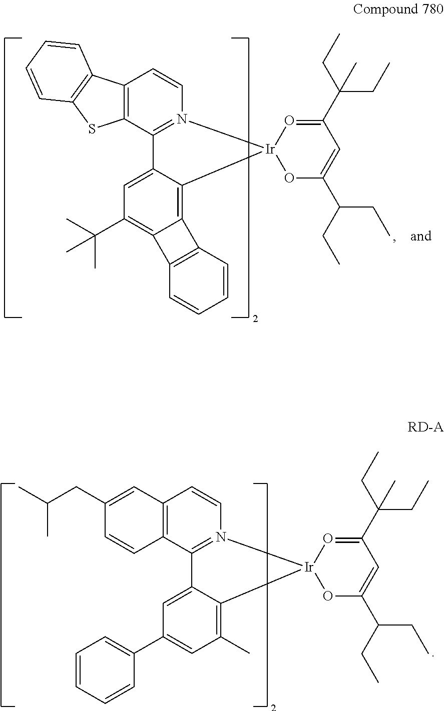

### DISCUSSION

As can be seen from the calculation results, the metal complexes of the present disclosure can achieve deep red to infrared triplet light emission due to their ligands having specific biphenylene structures. Compared with the comparative compound RD-A, Compound 239 of the present discourse is prepared by only replacing biphenyl with a biphenylene structure and further connecting the biphenylene structure to isoquinoline, and as a result, the emission wavelength of Compound 239 is significantly red-shifted from the original 625 nm to 733 nm. Furthermore, all the other compounds in the table comprising biphenylene structures can achieve deep red and near-infrared light emission. Compared with Compound RD-A, these compounds all exhibit noticeable red shifts in their wavelengths. Such a substantial red-shift effect is unexpected, further indicating that the compounds of the present disclosure, due to their specific biphenylene ligand design, can achieve deep red to near-infrared emission. In addition, the HOMO energy levels of the compounds of the present disclosure generally fall within the range of −5.12 eV to −4.73 eV, which are comparable to or shallower than those of the comparative compounds, indicating that the compounds of the present disclosure may possess hole trapping abilities comparable to or stronger than those of the comparative compounds. The strong hole trapping ability is beneficial for the metal complexes of the present disclosure to achieve excellent performance in devices, such as low voltage, high device efficiency, and long device lifetime, indicating that the metal complexes of the present disclosure have great application prospects of becoming excellent deep red and near-infrared emissive materials.

In conclusion, the metal complexes comprising a ligand having a structure of Formula 1 and a ligand having a structure of Formula 3 disclosed in the present disclosure can achieve deep red and near-infrared light emission and have strong hole trapping abilities, proving that the metal complexes comprising ligands having specific biphenylene structures disclosed in the present disclosure have excellent properties and potential application prospects of becoming excellent deep red emissive materials.

It should be understood that various embodiments described herein are merely embodiments and not intended to limit the scope of the present disclosure. Therefore, it is apparent to those skilled in the art that the present disclosure as claimed may include variations of specific embodiments and preferred embodiments described herein. Many of the materials and structures described herein may be replaced with other materials and structures without departing from the spirit of the present disclosure. It should be understood that various theories as to why the present disclosure works are not intended to be limitative.

What is claimed is:

1. A metal complex having a general formula of M (Lₐ)ₘ (L_{b})ₙ (L_{c})_{q}; wherein the metal M is selected from a metal with a relative atomic mass greater than 40, and Lₐ, L_{b}, and L_{c} are a first ligand, a second ligand, and a third ligand coordinated to the metal M, respectively;
Lₐ, L_{b}, and L_{c} can be optionally joined to form a multidentate ligand;
m is selected from 1 or 2, n is selected from 1 or 2, q is selected from 0 or 1, and m+n+q equals the oxidation state of the metal M; when m is equal to 2, two Lₐ are the same or different; when n is equal to 2, two L_{b} are the same or different;
the first ligand Lₐ has a structure represented by Formula 1: 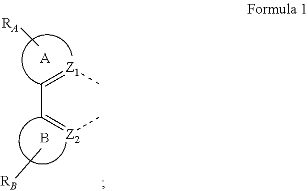
wherein Z₁ and Z₂ are each independently selected from C or N, and Z₁ is different from Z₂;
the ring A is selected from an unsaturated carbocyclic ring having 2 to 30 carbon atoms or an unsaturated heterocyclic ring having 2 to 30 ring atoms; and the ring B is selected from an unsaturated carbocyclic ring having 4 to 30 carbon atoms or an unsaturated heterocyclic ring having 4 to 30 ring atoms;
the ring B at least comprises one structure represented by Formula 2: 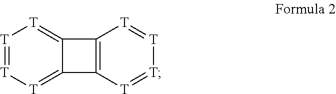
wherein T is, at each occurrence identically or differently, selected from C or N;
R_{A} and R_{B} represent, at each occurrence identically or differently, mono-substitution, multiple substitutions or non-substitution;
R_{A} and R_{B} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{A} and R_{B} can be optionally joined to form a ring;
L_{b} has a structure represented by Formula 3: 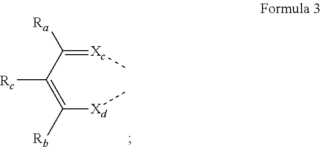
wherein X_{c} and X_{d} are, at each occurrence identically or differently, selected from the group consisting of: O, S, Se, and NR_{N2};
Rₐ, R_{b}, R_{c}, and R_{N2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted amino having 0 to 20 carbon atoms, an acyl group, a carbonyl group, a carboxylic acid group, an ester group, a cyano group, an isocyano group, a sulfanyl group, a sulfinyl group, a sulfonyl group, a phosphino group, and combinations thereof;
adjacent substituents Rₐ, R_{b}, R_{c}, and R_{N2} can be optionally joined to form a ring;
L_{c} is selected from a mono-anionic bidentate ligand.

2. The metal complex of claim 1, wherein the ring B has a structure represented by Formula 2, and the Lₐ has a structure represented by Formula 4, Formula 5 or Formula 6: 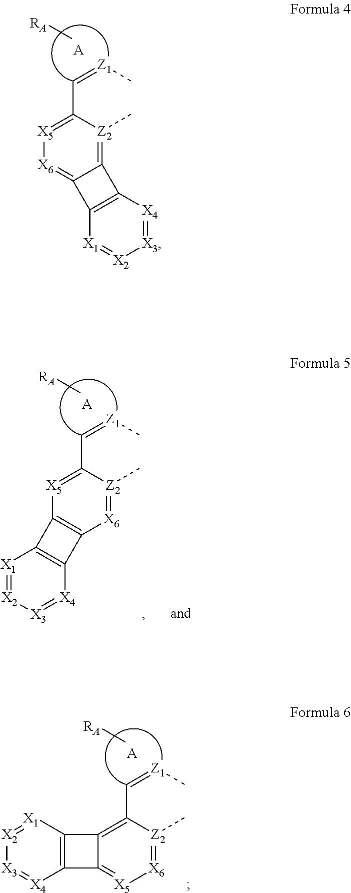
wherein Z₁ and Z₂ are each independently selected from C or N, and Z₁ is different from Z₂;
X₁ to X₆ are, at each occurrence identically or differently, selected from N or CR_{X};
R_{A} represents, at each occurrence identically or differently, mono-substitution, multiple substitutions or non-substitution;
R_{A} and R_{X} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{A} and R_{X} can be optionally joined to form a ring;
preferably, the R_{X} is, at each occurrence identically or differently, selected from hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted alkenyl having 2 to 20 carbon atoms, substituted or unsubstituted alkynyl having 2 to 20 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, or a combination thereof.

3. The metal complex of claim 1, wherein the ring A is selected from the group consisting of the following structures: 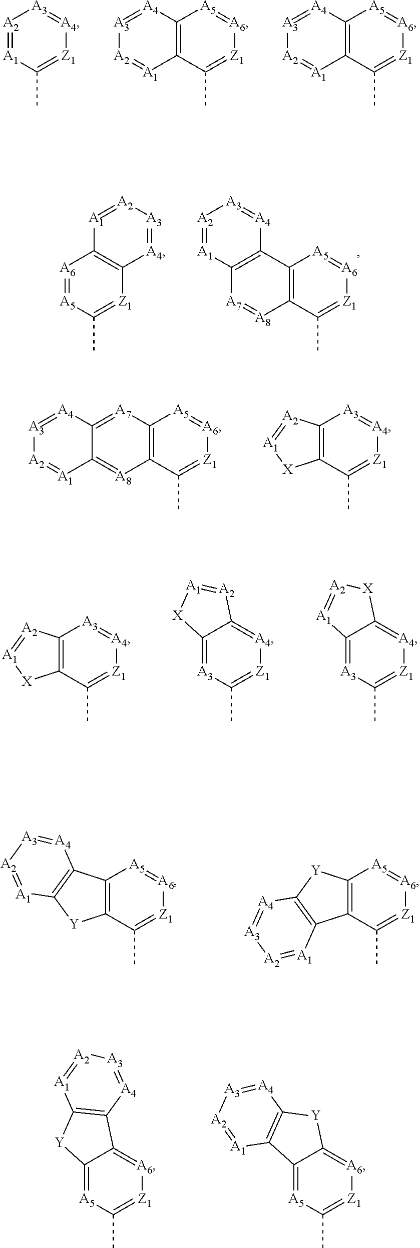 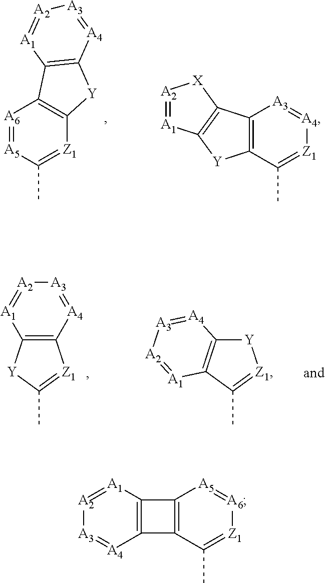
wherein A₁ to A₈ are, at each occurrence identically or differently, selected from N or CR_{A};
X is, at each occurrence identically or differently, selected from O, S, Se, NRₓ, CR_{X}R_{X}, SiR_{X}R_{X} or PR_{X}; when a plurality of R_{Y} are present at the same time, the plurality of R_{X} are the same or different;
Y is, at each occurrence identically or differently, selected from O, S, Se, NR_{Y}, CR_{Y}R_{Y}, SiR_{Y}R_{Y} or PR_{Y}; when a plurality of R_{Y} are present at the same time, the plurality of R_{Y} are the same or different;
R_{A}, R_{X}, and R_{Y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{A}, R_{X}, and R_{Y} can be optionally joined to form a ring.

4. The metal complex of claim 1, wherein the first ligand Lₐ is selected from a structure represented by any one of Formula 7 to Formula 30: 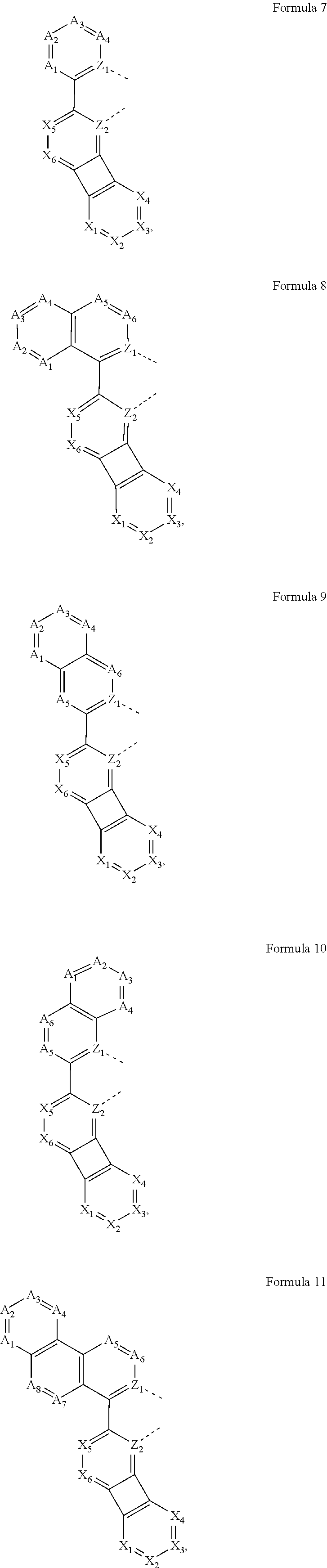 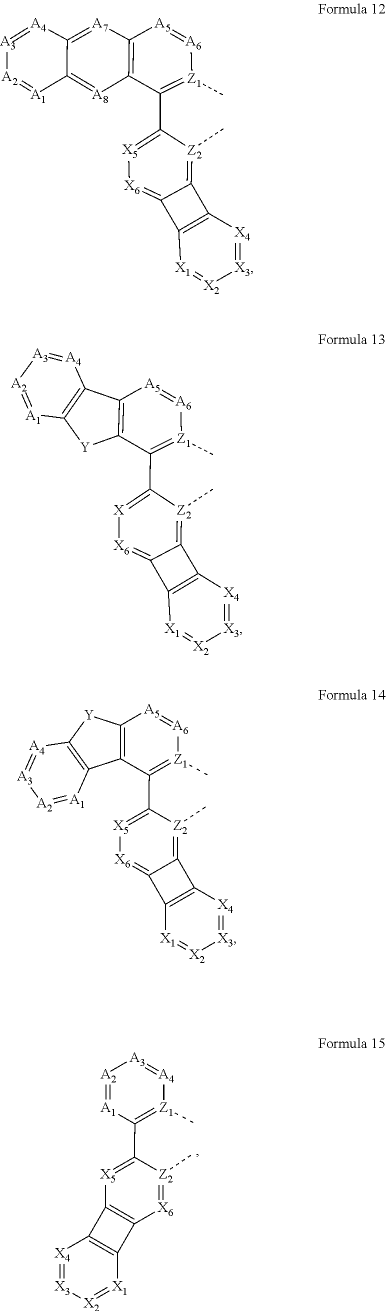 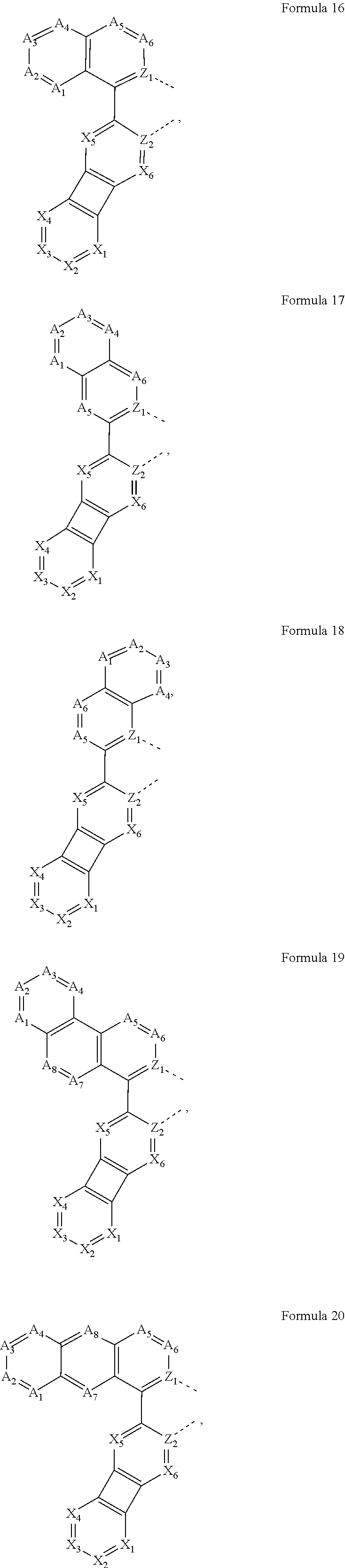 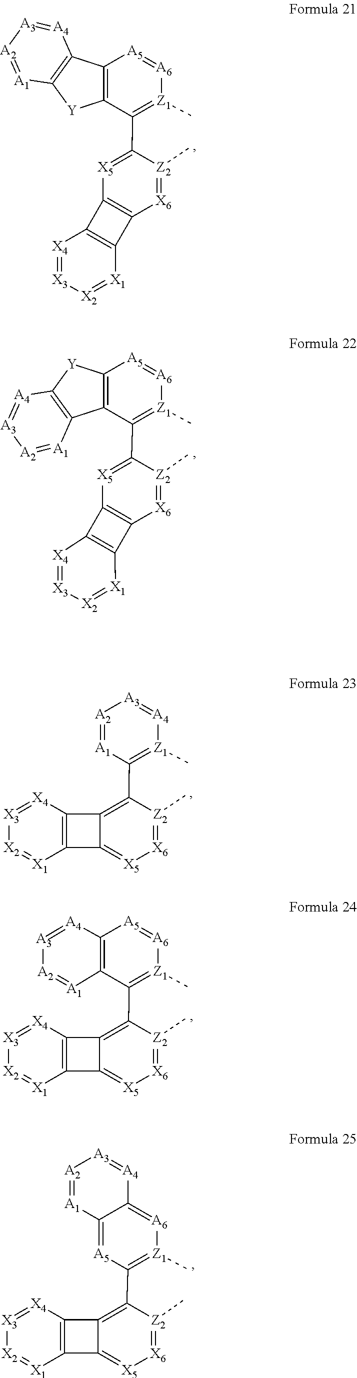 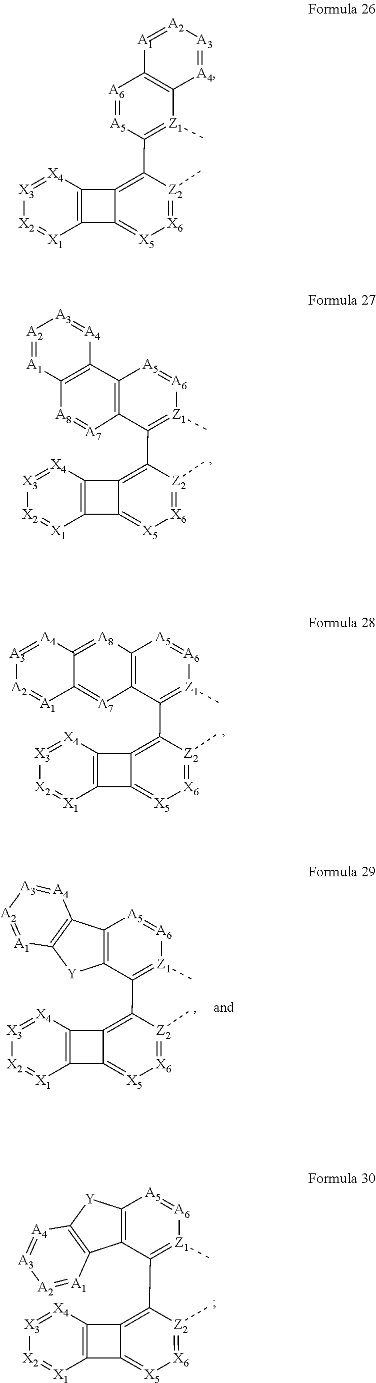
wherein
Z₁ and Z₂ are each independently selected from C or N, and Z₁ is different from Z₂;
preferably, Z₁ is C, and Z₂ is N;
Y is, at each occurrence identically or differently, selected from O, S, Se, NR_{Y}, CR_{Y}R_{Y}, SiR_{Y}R_{Y} or PR_{Y}; when a plurality of R_{Y} are present at the same time, the plurality of R_{Y} are the same or different;
A₁ to A₈ are, at each occurrence identically or differently, selected from N or CR_{A};
X₁ to X₄ are, at each occurrence identically or differently, selected from N or CR_{X}, and X₅ and X₆ are, at each occurrence identically or differently, selected from N or CR_{Xi};
R_{A}, R_{X}, R_{Xi}, and R_{Y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a sulfanyl group, a sulfinyl group, a sulfonyl group, a phosphino group, and combinations thereof;
adjacent substituents R_{A}, R_{X}, R_{Xi}, and R_{Y} can be optionally joined to form a ring;
preferably, Lₐ is selected from a structure represented by any one of Formula 7, Formula 8, Formula 10, Formula 15, Formula 16, Formula 18, Formula 19, Formula 21, Formula 23, Formula 24, Formula 26, Formula 27 or Formula 29;
more preferably, Lₐ is selected from a structure represented by any one of Formula 7, Formula 8, Formula 10, Formula 13, Formula 15, Formula 16, Formula 18, Formula 23, Formula 24 or Formula 26.

5. The metal complex of claim 4, wherein in Formula 7 to Formula 30, at least one of A₁ to A_{N} and/or at least one of X₁ to X_{M} is selected from N;
preferably, in Formula 7, Formula 15, and Formula 23, at least one of A₃ and A₄ and/or at least one of X₅ and X₆ is selected from N, and in Formula 8 to Formula 14, Formula 16 to Formula 22, and Formula 24 to Formula 30, at least one of A₅ and A₆ and/or at least one of X₅ and X₆ is selected from N;
more preferably, in Formula 7, Formula 15, and Formula 23, A₃ and/or X₅ is selected from N, and in Formula 8 to Formula 14, Formula 16 to Formula 22, and Formula 24 to Formula 30, A₅ and/or X₅ is selected from N.

6. The metal complex of claim 4, wherein in Formula 7 to Formula 30, A₁ to A_{N} are each independently selected from CR_{A}, and X₁ to X₄ are each independently selected from CR_{X}; X₁ to X₄ are each independently selected from CR_{Xi}, and adjacent substituents R_{A}, R_{X}, and R_{Xi} can be optionally joined to form a ring;
preferably, the R_{A}, R_{X}, and R_{Xi} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, and combinations thereof;
more preferably, at least one or two of the R_{A}, R_{X}, and R_{Xi} are, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, and combinations thereof.

7. The metal complex of claim 4, wherein in Formula 7 to Formula 30, A₁ to A₈ are each independently selected from CR_{A}, X₁ to X₄ are each independently selected from CR_{X}, and adjacent substituents R_{A} and R_{X} can be optionally joined to form a ring;
preferably, the R_{A} and R_{X} are identically or differently selected from hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, or a combination thereof;
more preferably, the R_{A} and R_{X} are, at each occurrence identically or differently, selected from the group consisting of: hydrogen, deuterium, fluorine, methyl, ethyl, isopropyl, isobutyl, t-butyl, neopentyl, cyclopentyl, cyclopentylmethyl, cyclohexyl, norbornyl, adamantyl, trimethylsilyl, isopropyldimethylsilyl, phenyldimethylsilyl, trifluoromethyl, cyano, phenyl, and combinations thereof;
most preferably, at least one or two of A₁ to A₄ are selected from CR_{A} and/or at least one or two of X₁ to X₄ are selected from CR_{X}; the R_{A} and R_{X} are, at each occurrence identically or differently, selected from the group consisting of: deuterium, fluorine, methyl, ethyl, isopropyl, isobutyl, t-butyl, neopentyl, cyclopentyl, cyclopentylmethyl, cyclohexyl, norbornyl, adamantyl, trimethylsilyl, isopropyldimethylsilyl, phenyldimethylsilyl, trifluoromethyl, cyano, phenyl, and combinations thereof.

8. The metal complex of claim 4, wherein in Formula 7 to Formula 30, at least one of X₅ or X₆ is selected from CR_{Xi}, and the R_{Xi} is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, and combinations thereof;
preferably, the R_{Xi} is, at each occurrence identically or differently, selected from the group consisting of: deuterium, fluorine, methyl, ethyl, isopropyl, isobutyl, 1-butyl, neopentyl, cyclopentyl, cyclopentylmethyl, cyclohexyl, norbornyl, adamantyl, trimethylsilyl, isopropyldimethylsilyl, phenyldimethylsilyl, trifluoromethyl, cyano, phenyl, and combinations thereof;
most preferably, in Formula 7 to Formula 14, at least one of X₅ or X₆ is selected from CR_{Xi}, and the R_{Xi} is, at each occurrence identically or differently, selected from the group consisting of: deuterium, fluorine, methyl, ethyl, isopropyl, isobutyl, t-butyl, neopentyl, cyclopentyl, cyclopentylmethyl, cyclohexyl, norbornyl, adamantyl, trimethylsilyl, isopropyldimethylsilyl, phenyldimethylsilyl, trifluoromethyl, cyano, phenyl, and combinations thereof; in Formula 15 to Formula 30, at least one of X₅ or X₆ is selected from CR_{Xi}, and R_{Xi} is selected from the group consisting of: deuterium, fluorine, and methyl.

9. The metal complex of claim 4, wherein in Formula 13, Formula 14, Formula 21, Formula 22, Formula 29, and Formula 30, Y is, at each occurrence identically or differently, selected from O, S, NR_{Y}, CR_{Y}R_{Y} or SiR_{Y}R_{Y}; and when a plurality of R_{Y} are present at the same time, the plurality of R_{Y} are the same or different;
R_{Y} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
preferably, Y is O or S.

10. The metal complex of claim 1, wherein Lₐ is, at each occurrence identically or differently, selected from the group consisting of the following structures:

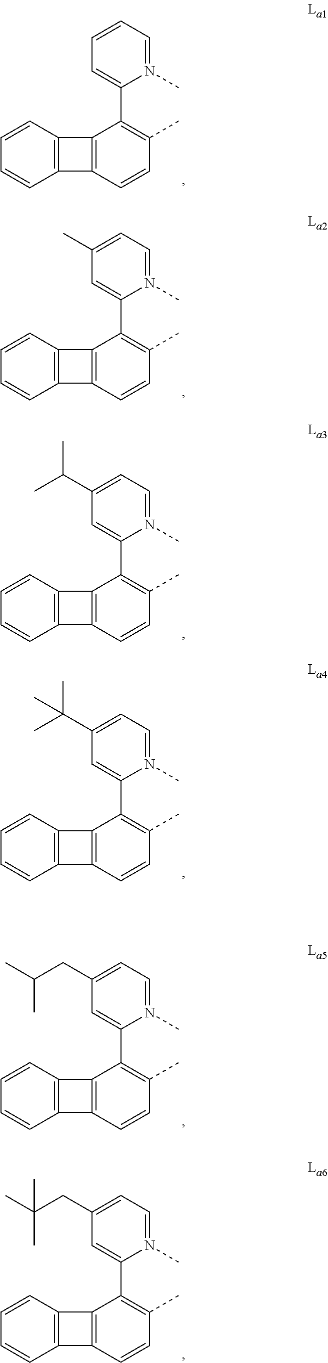

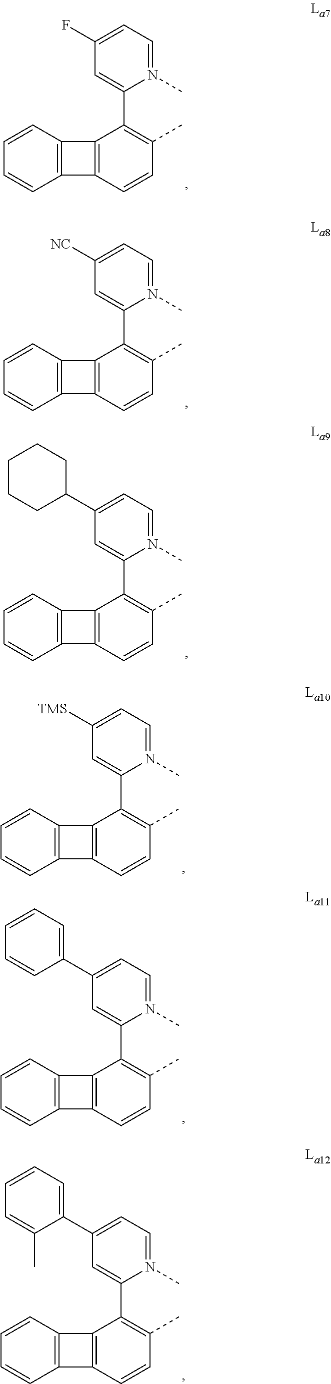

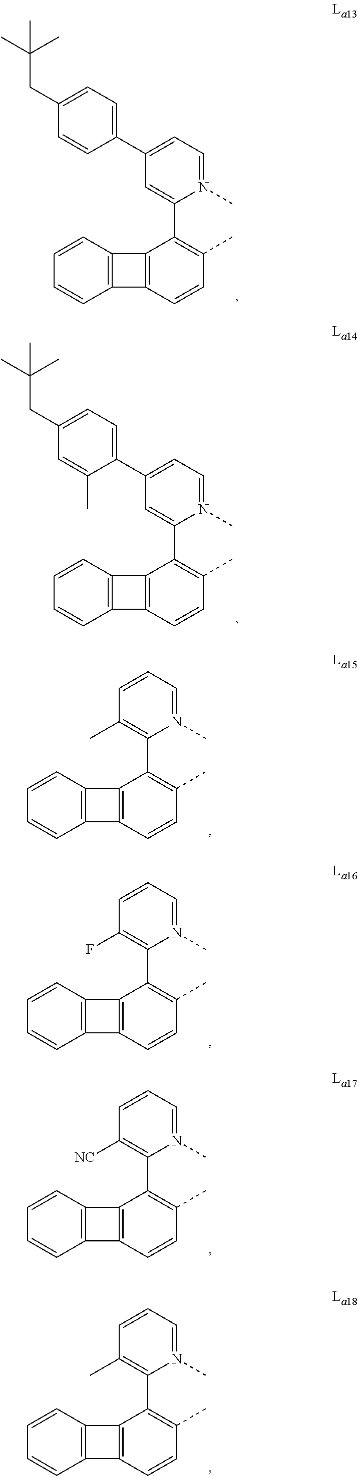

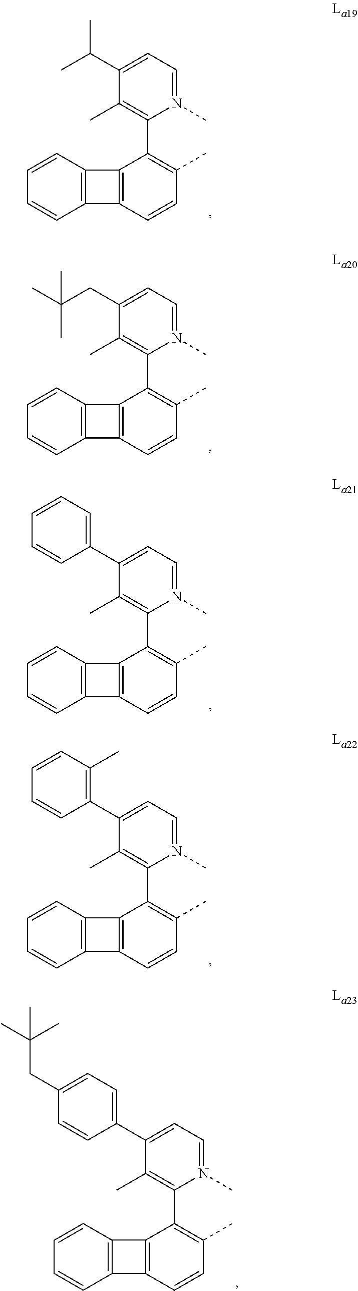

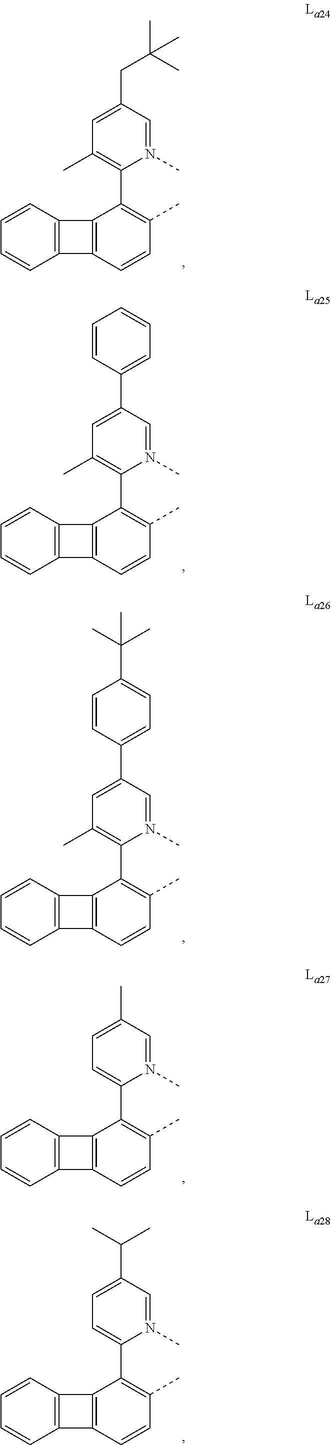

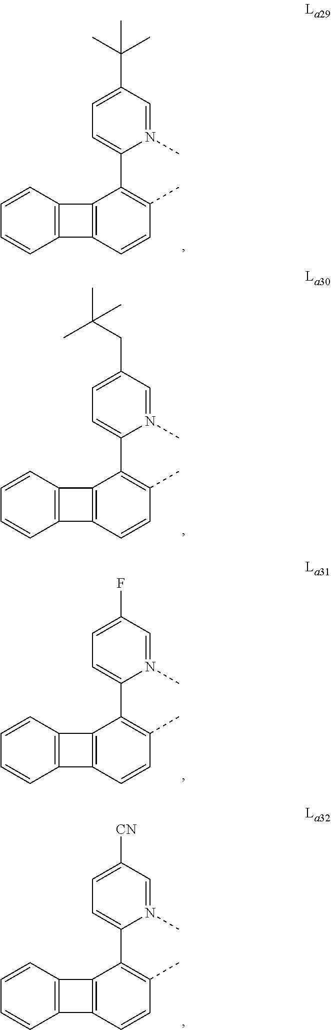

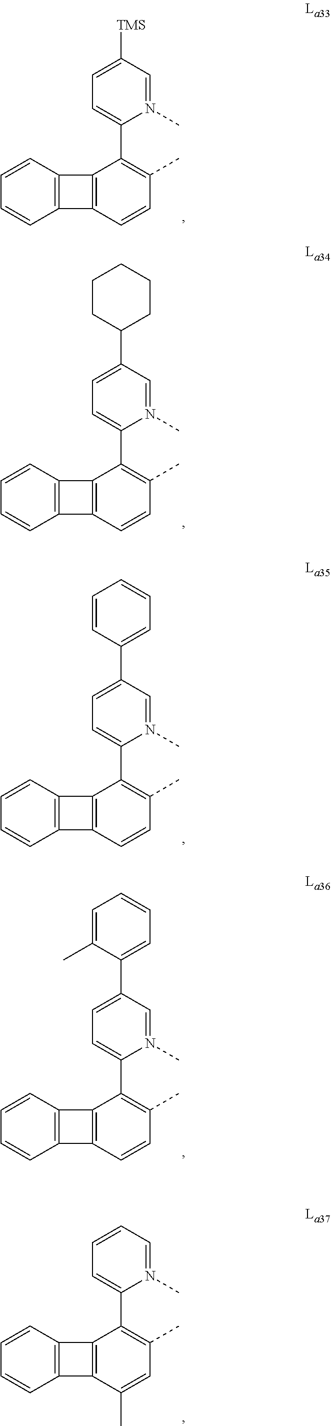

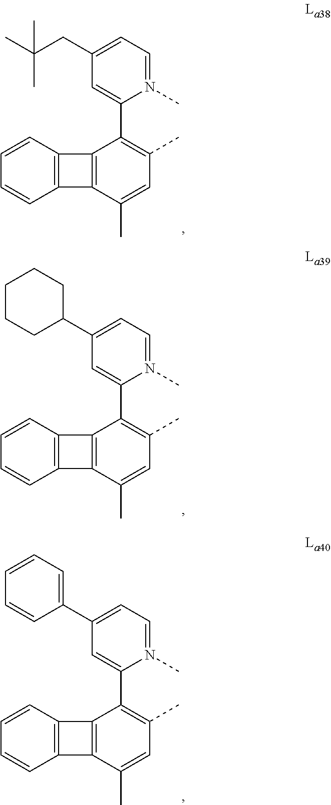

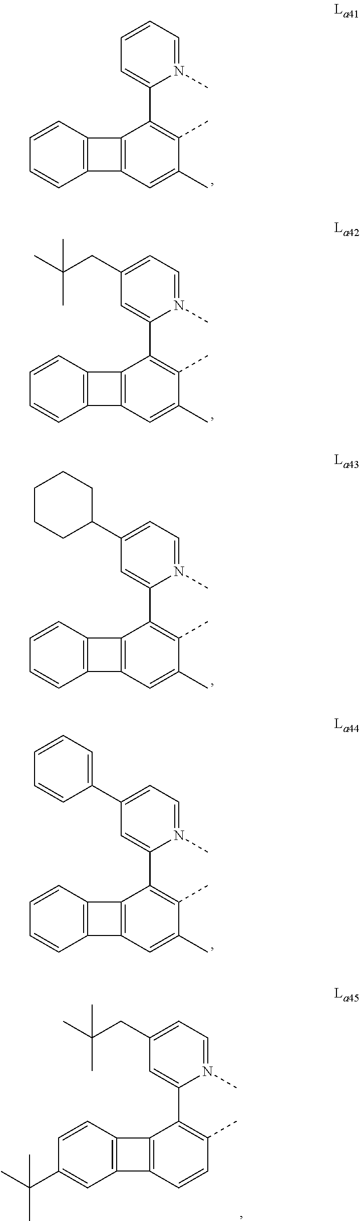

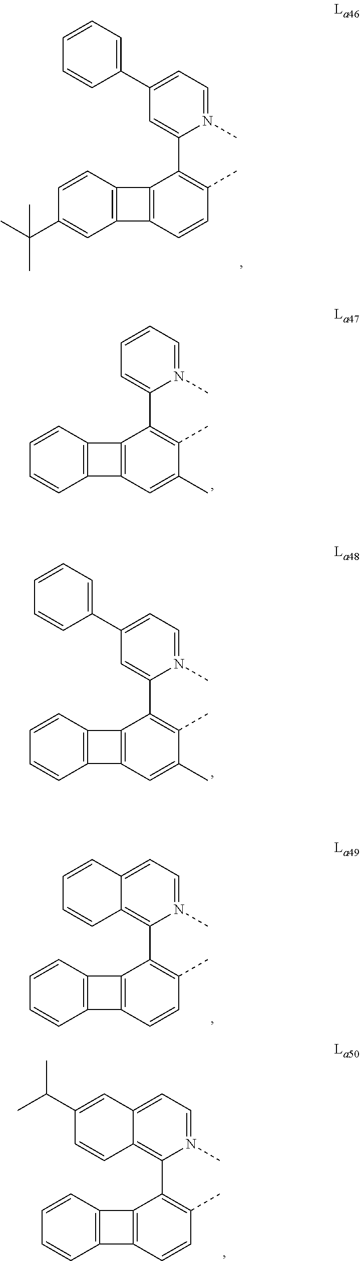

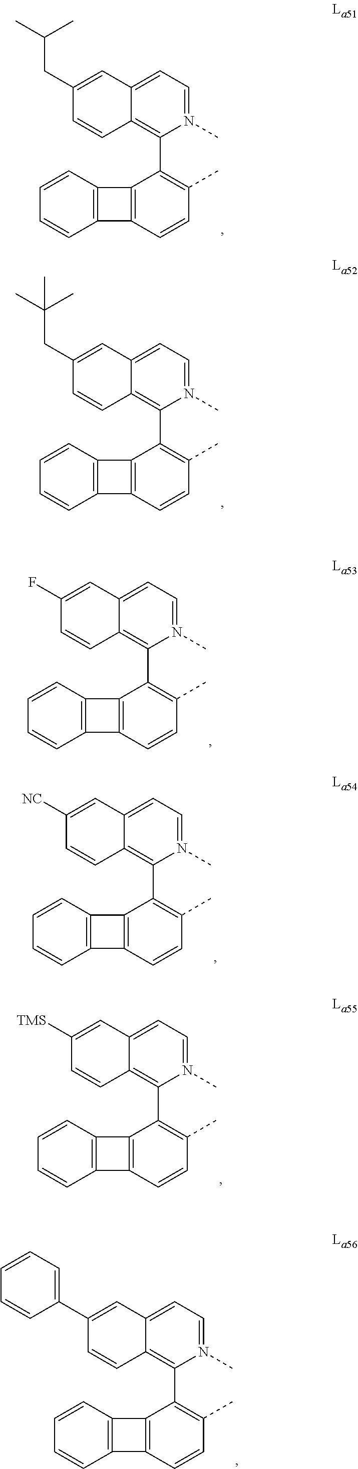

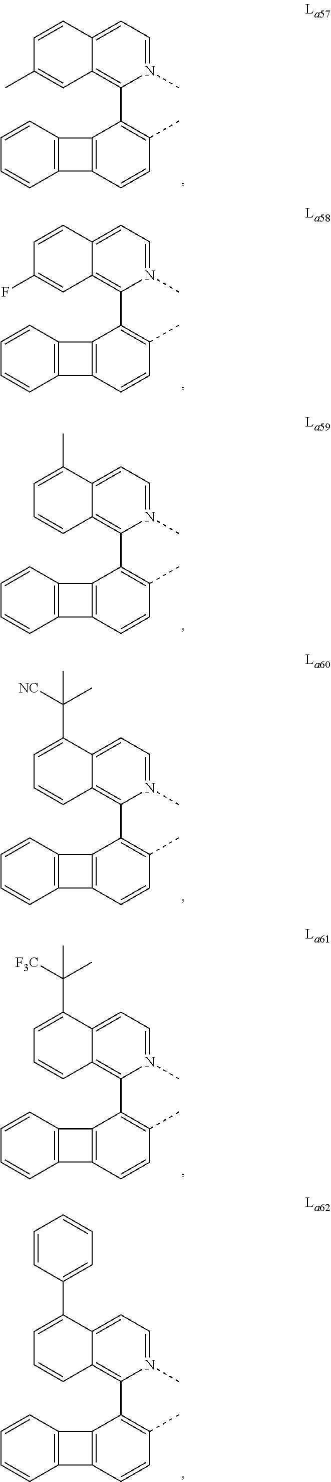

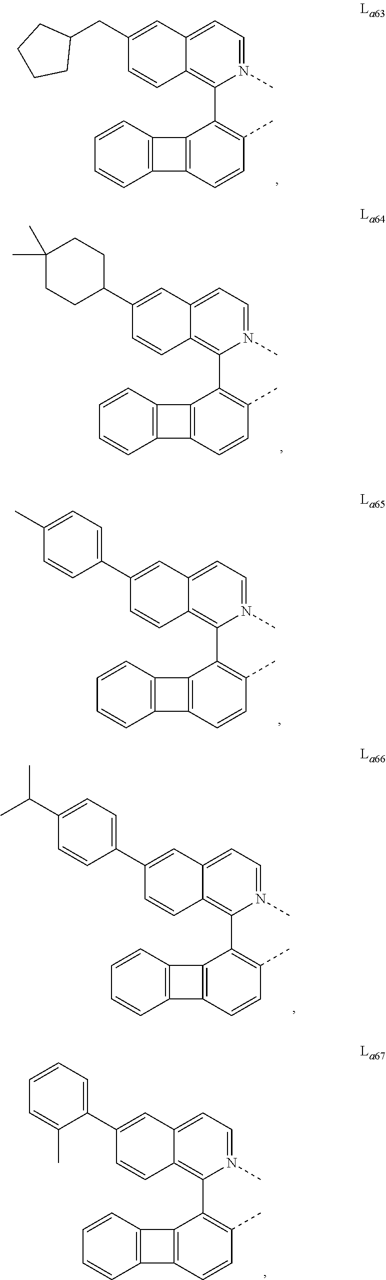

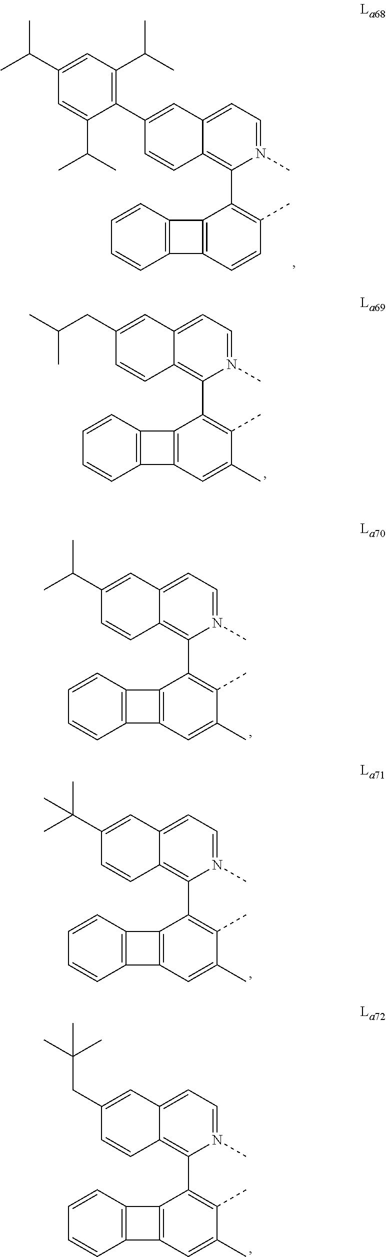

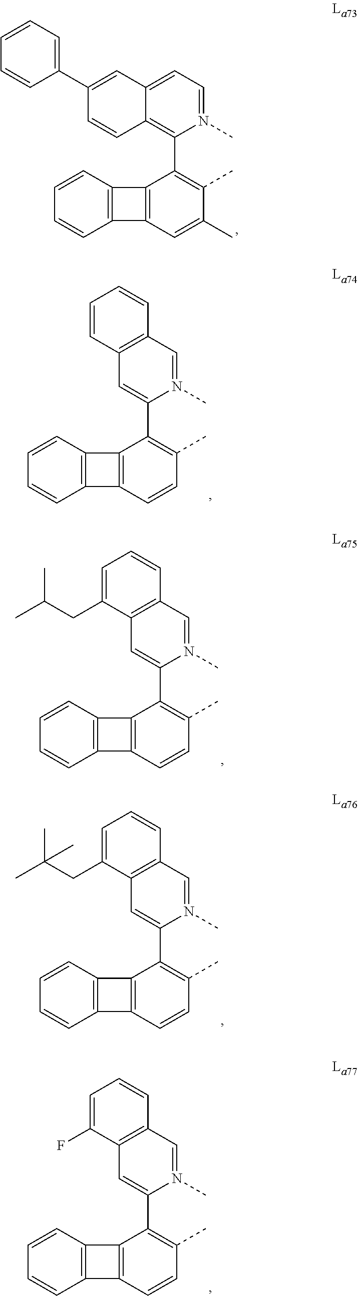

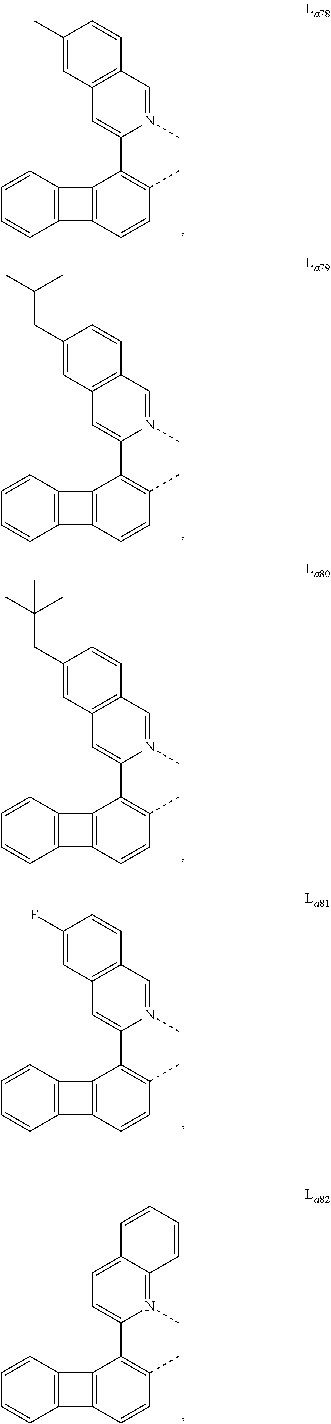

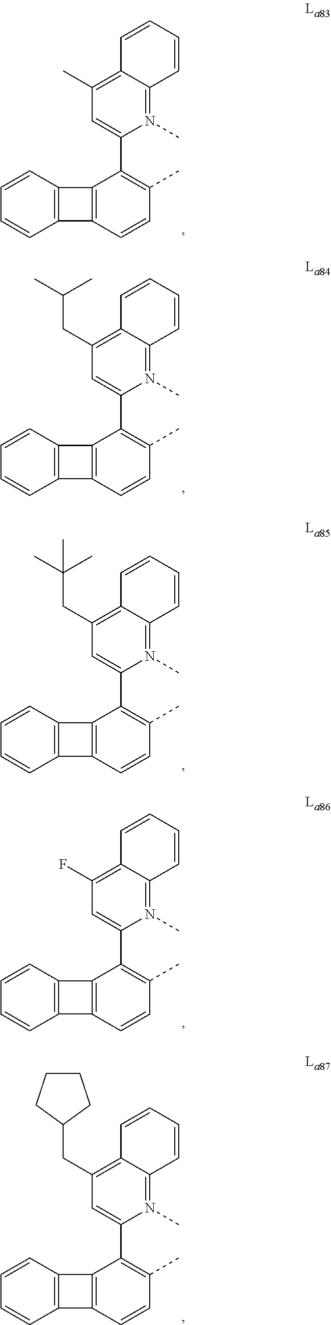

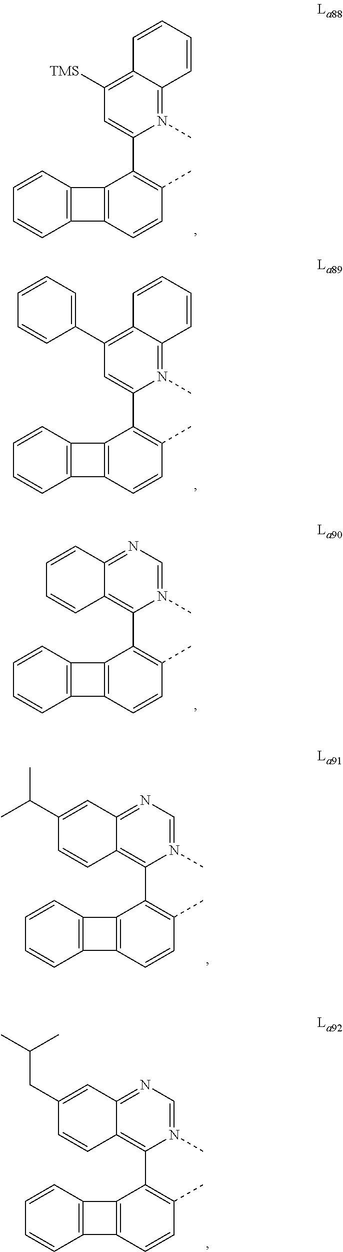

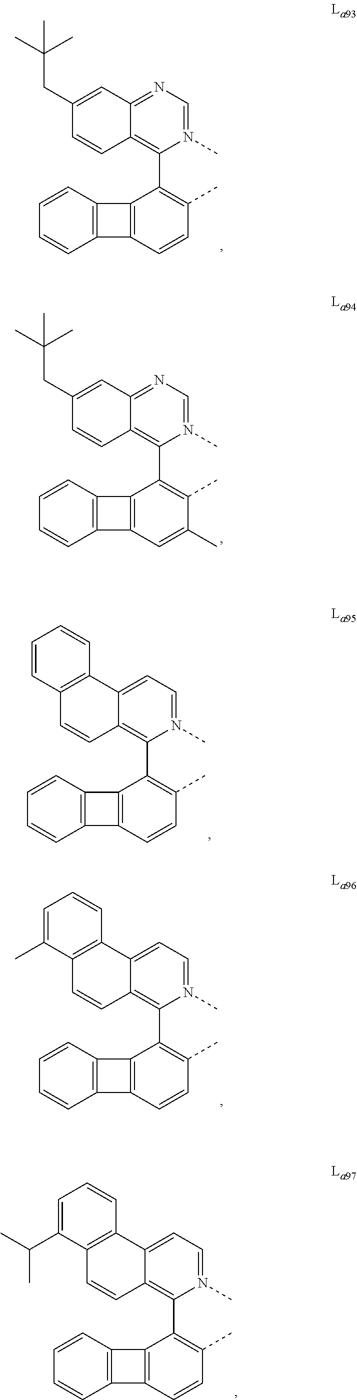

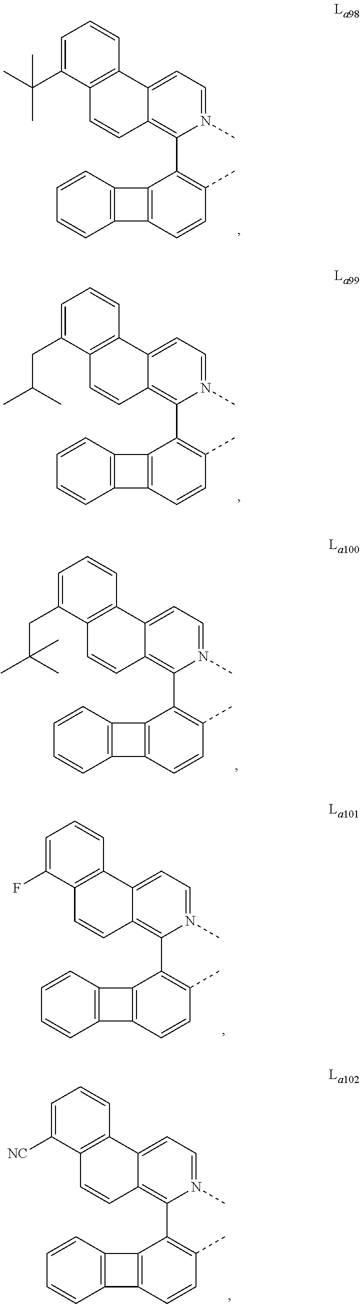

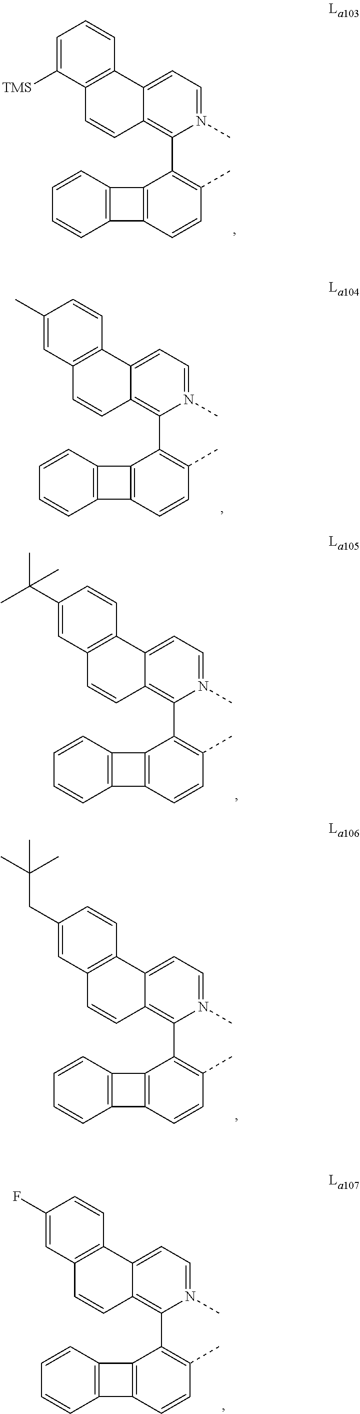

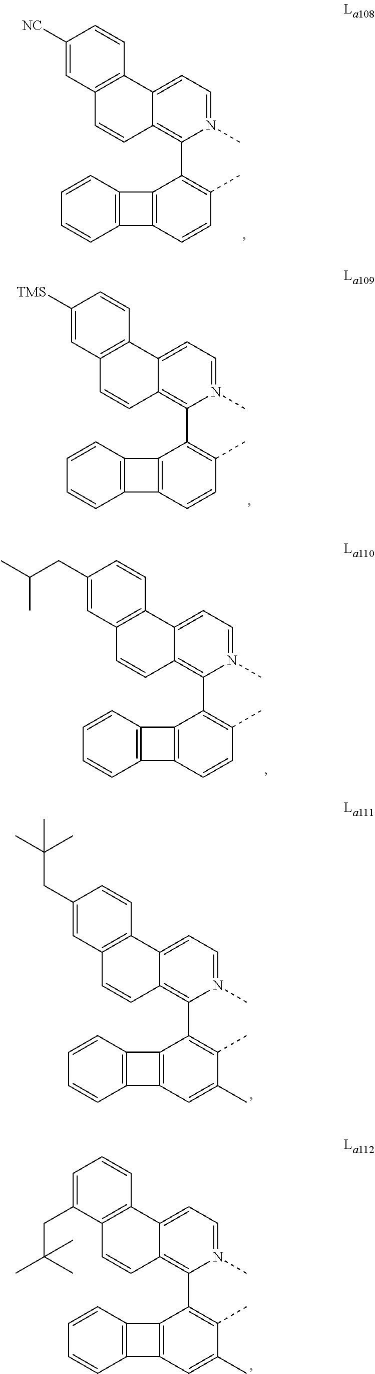

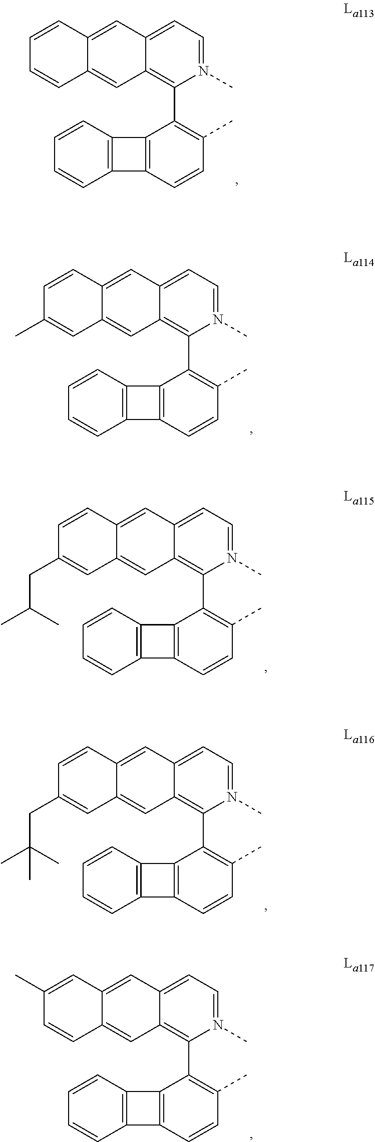

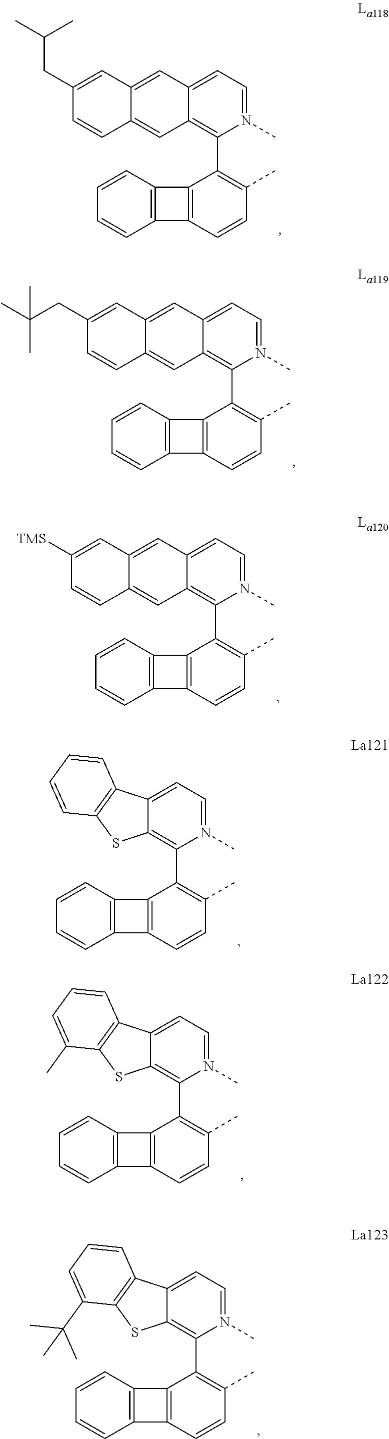

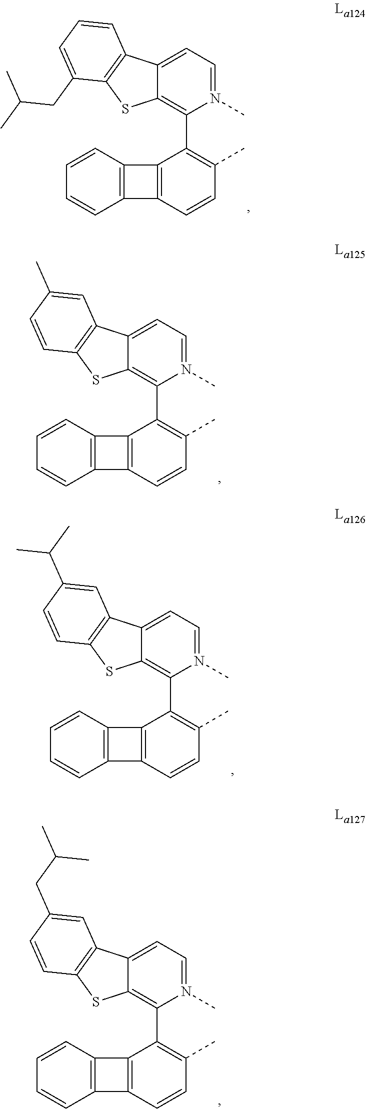

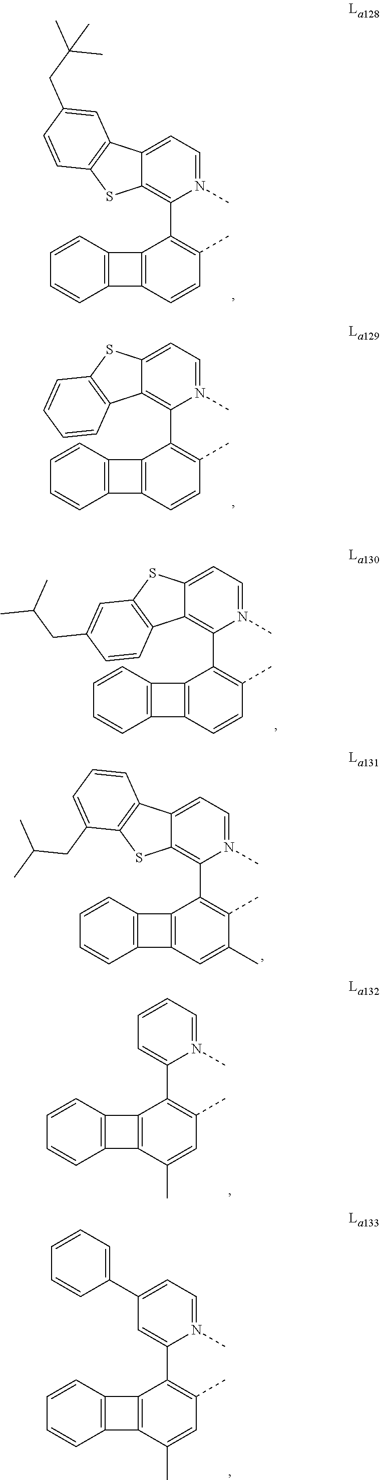

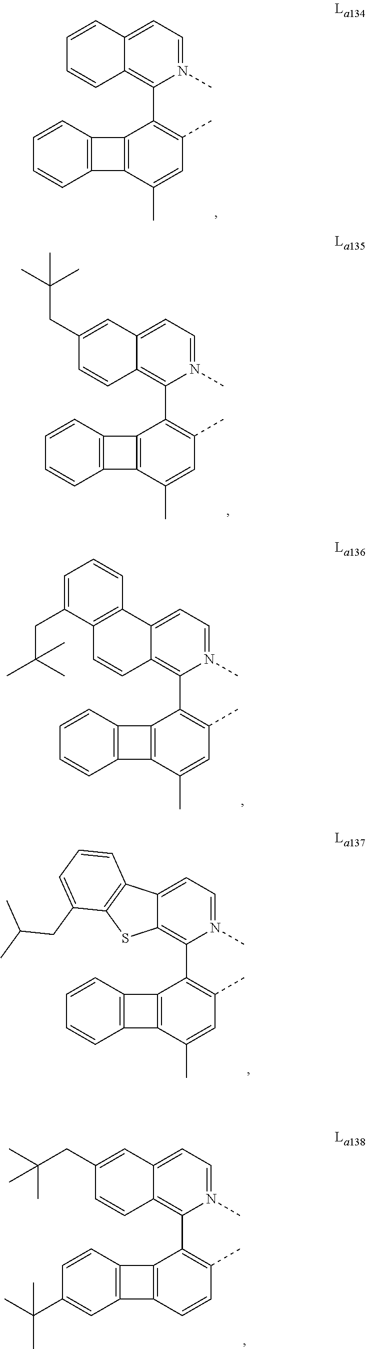

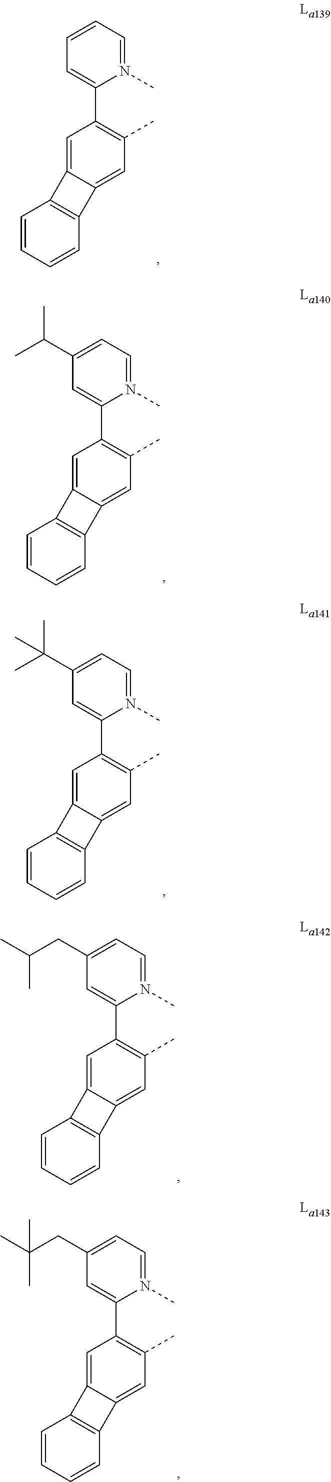

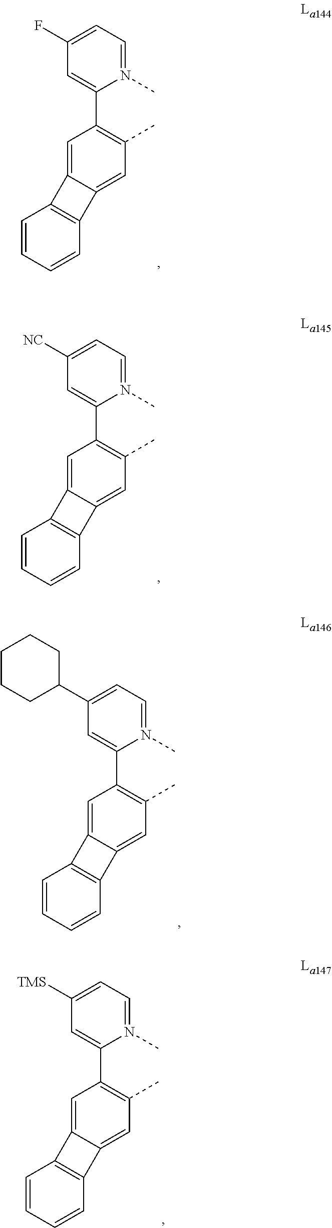

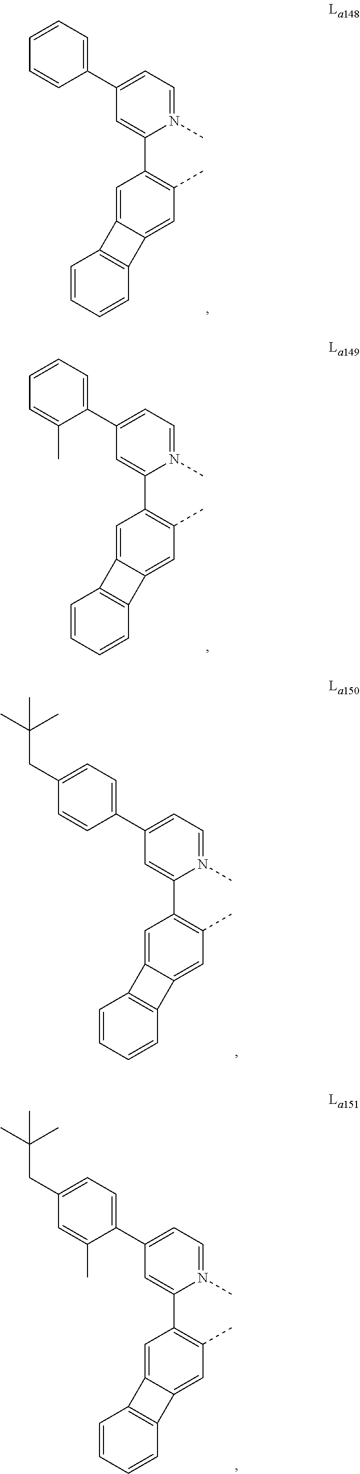

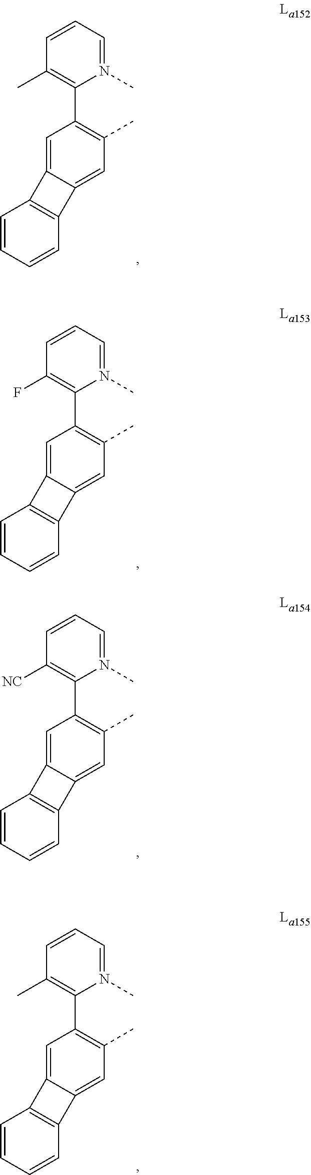

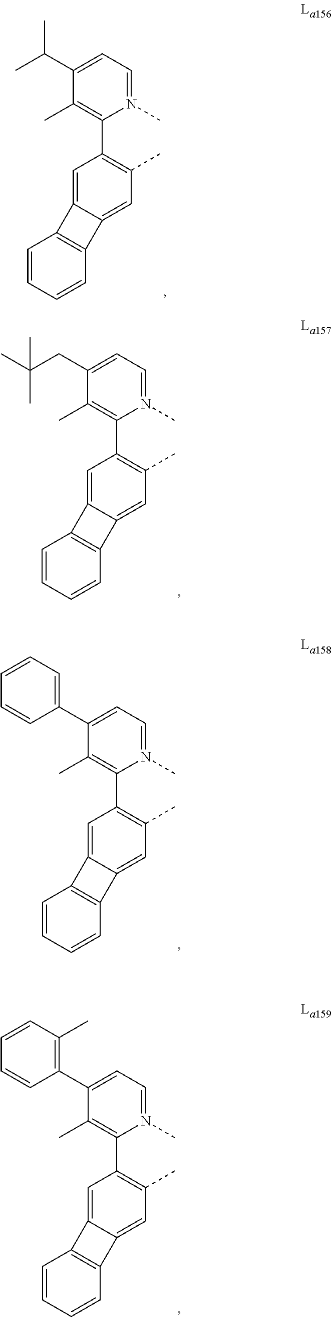

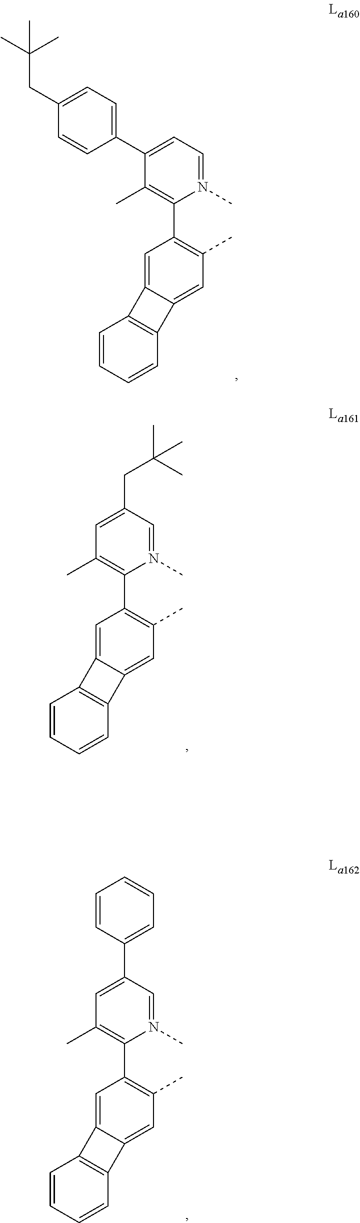

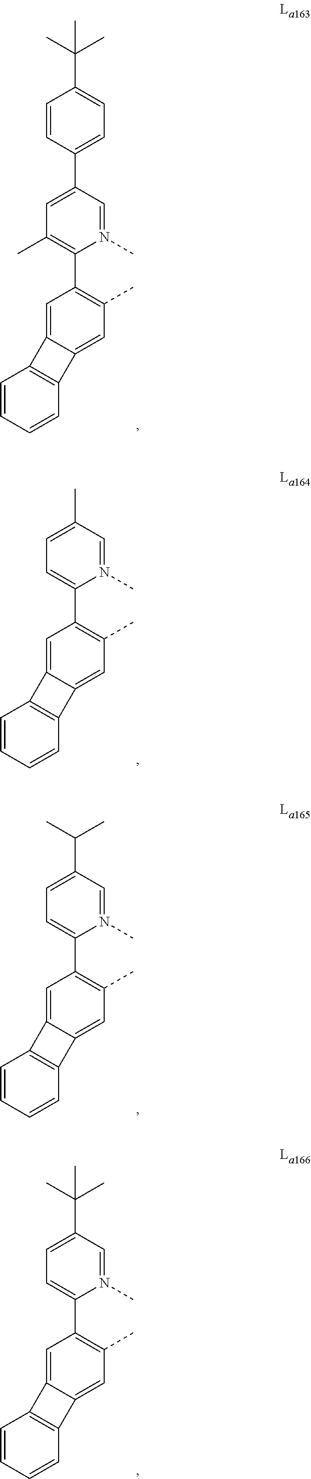

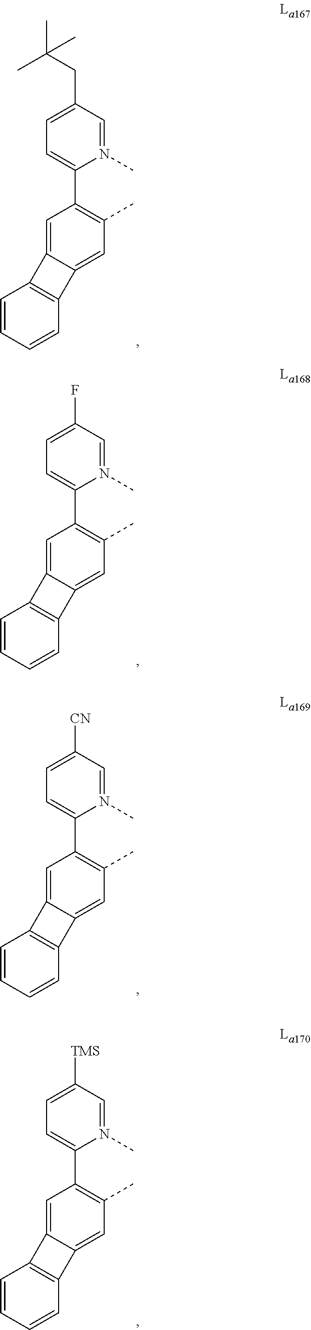

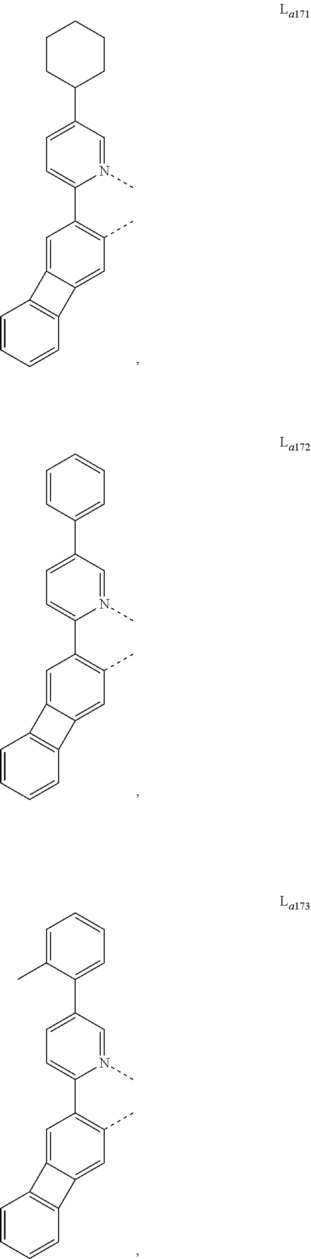

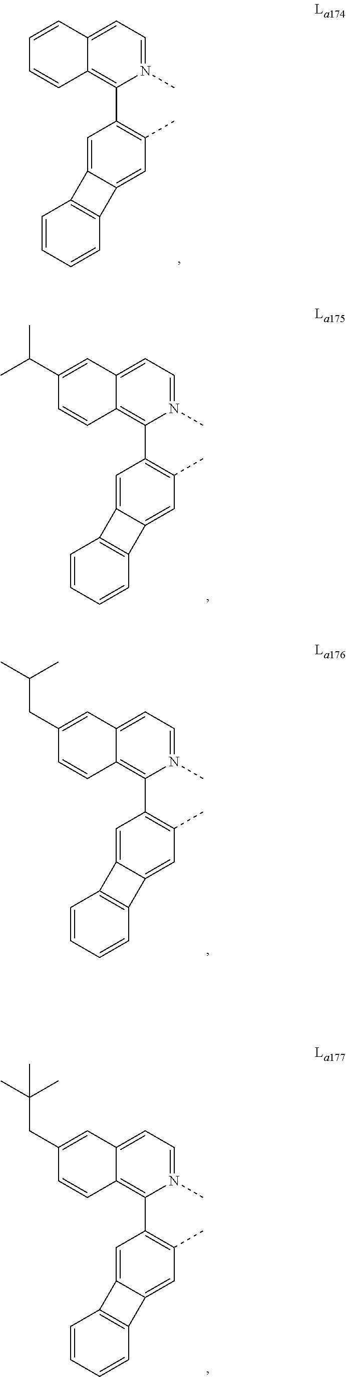

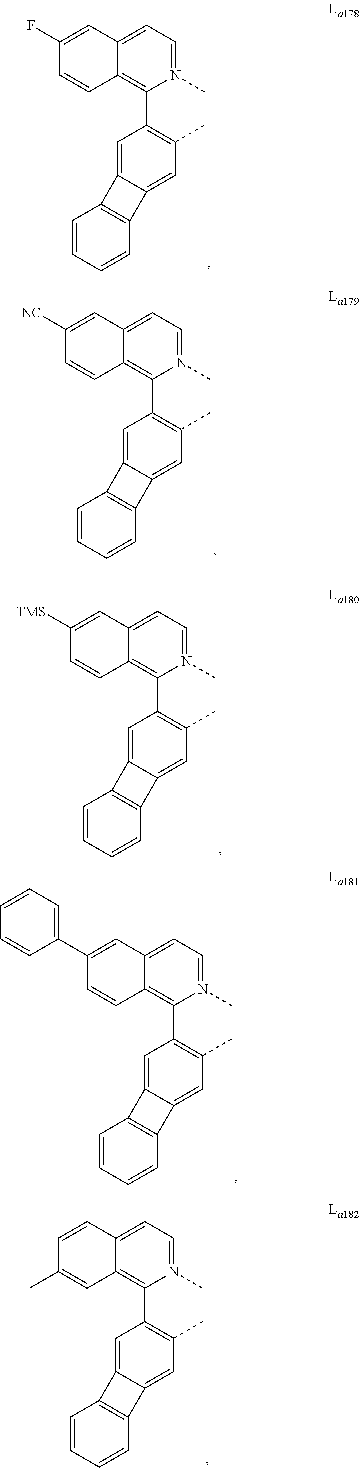

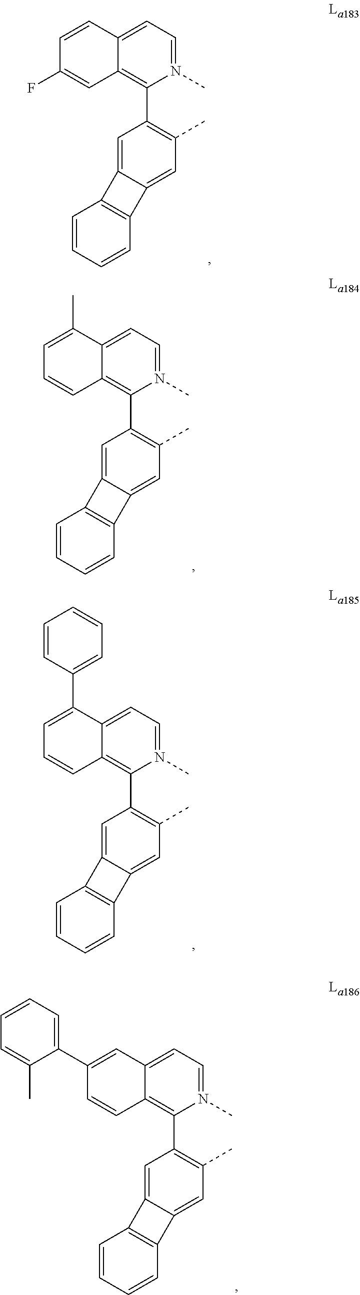

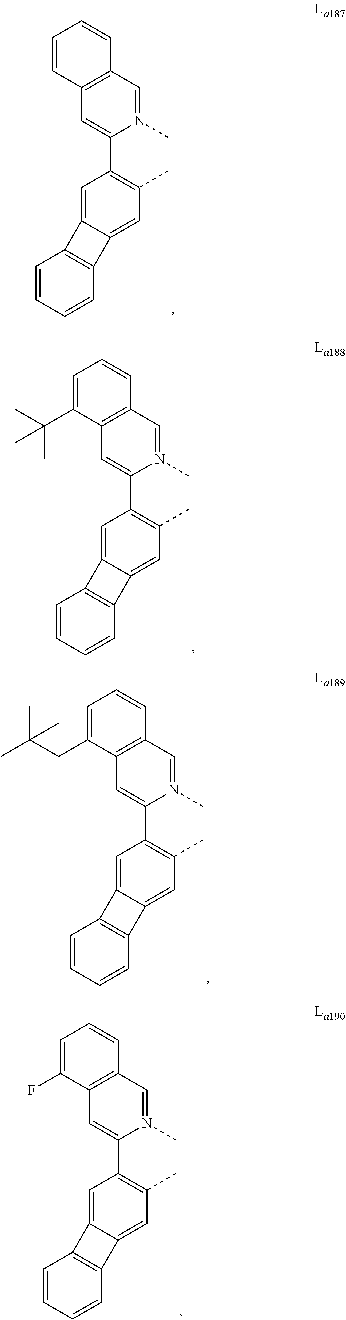

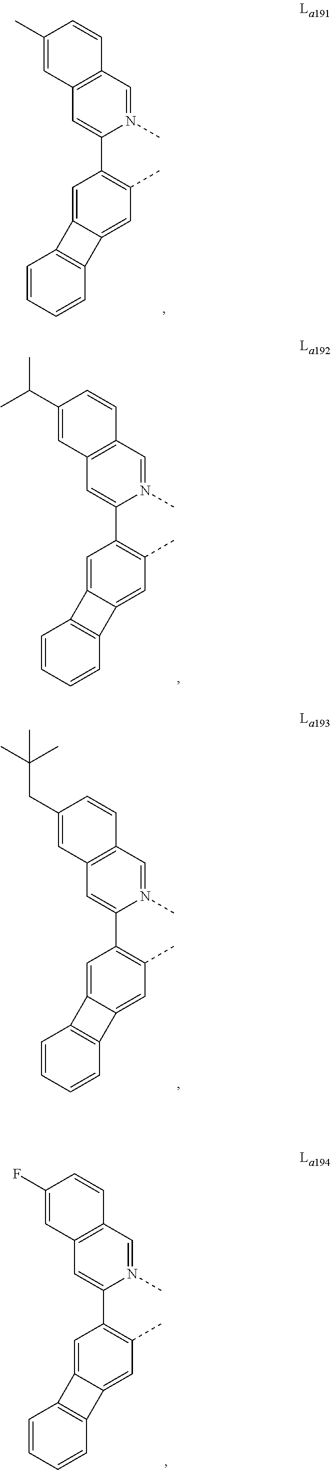

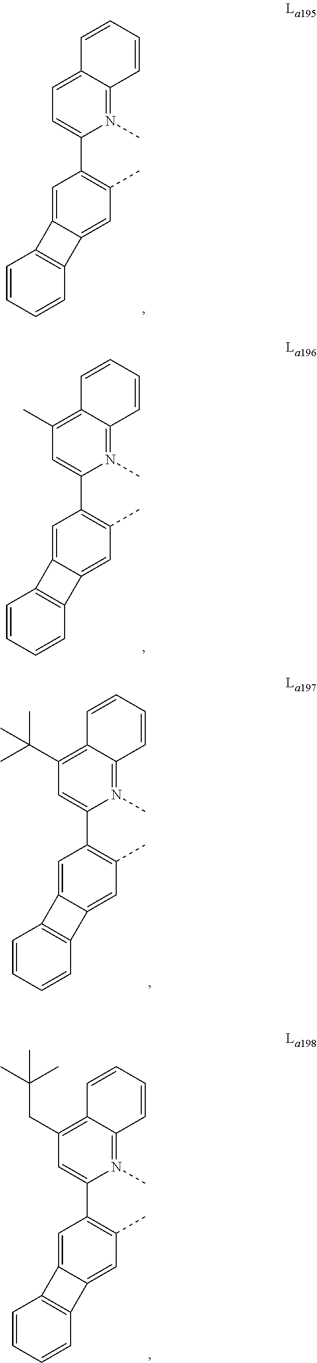

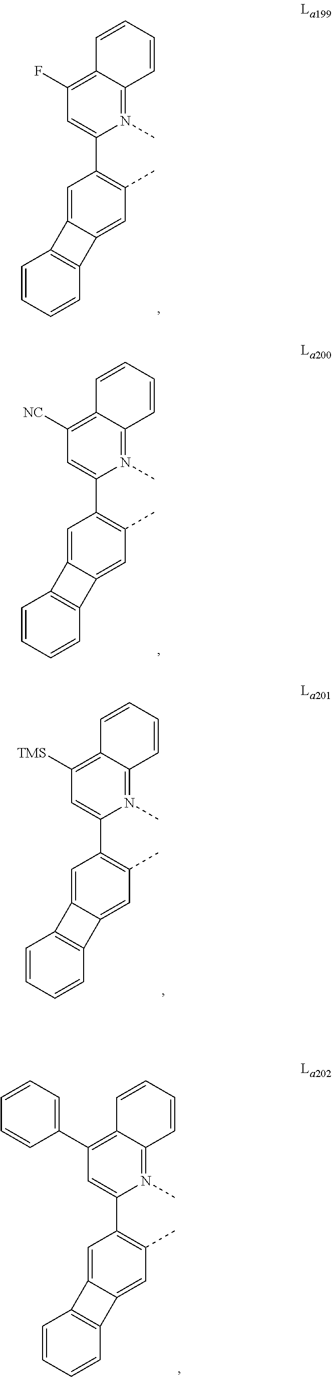

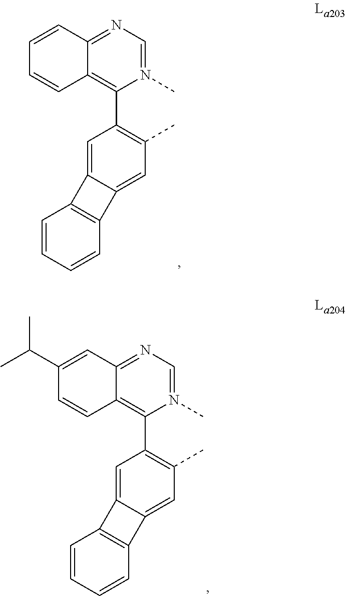

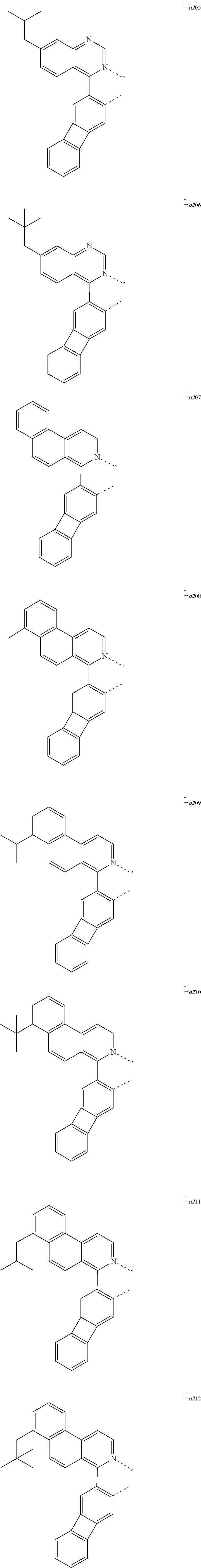

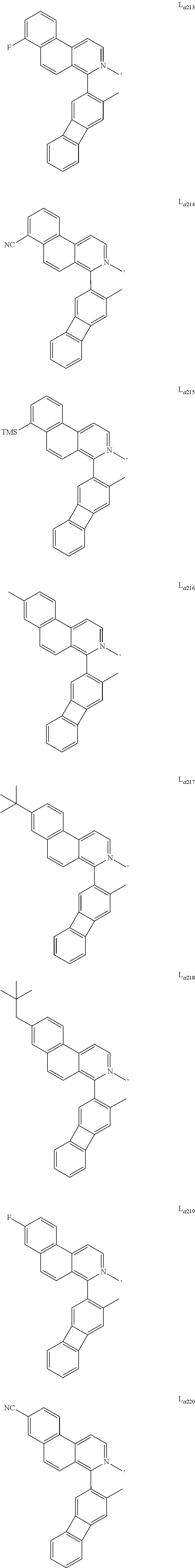

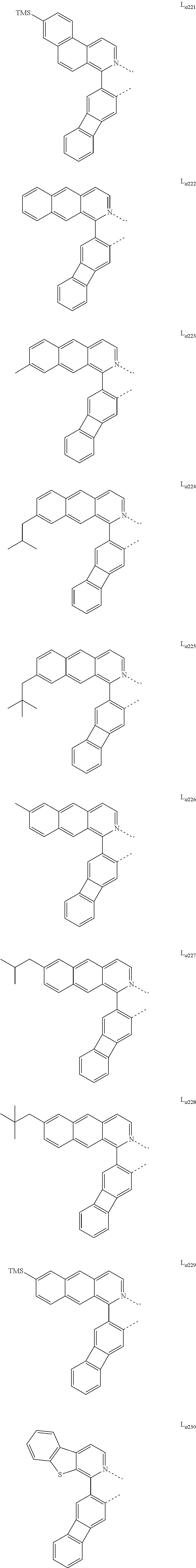

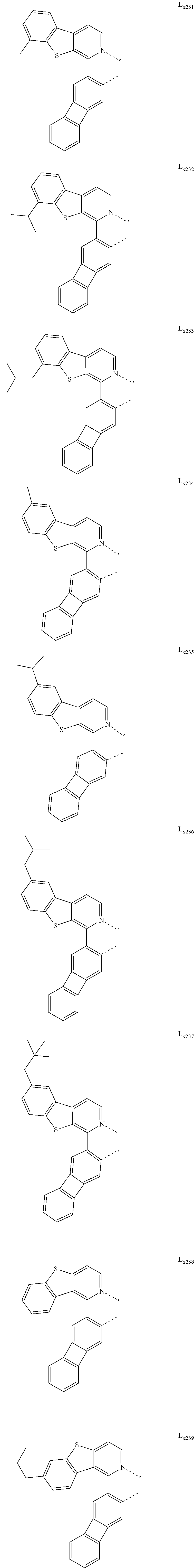

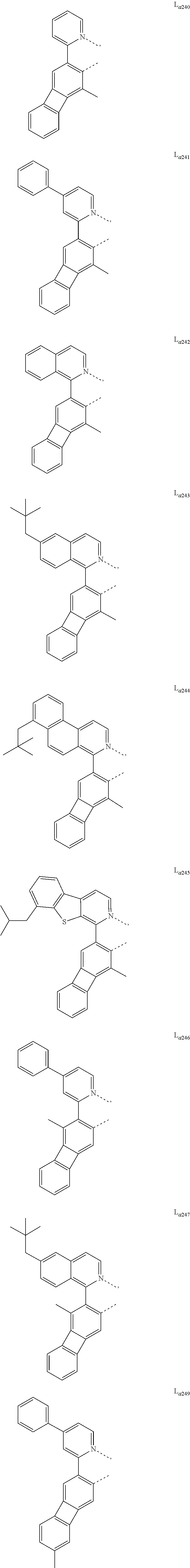

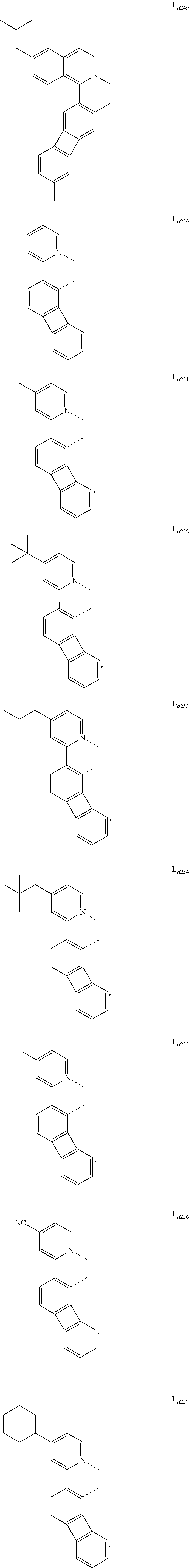

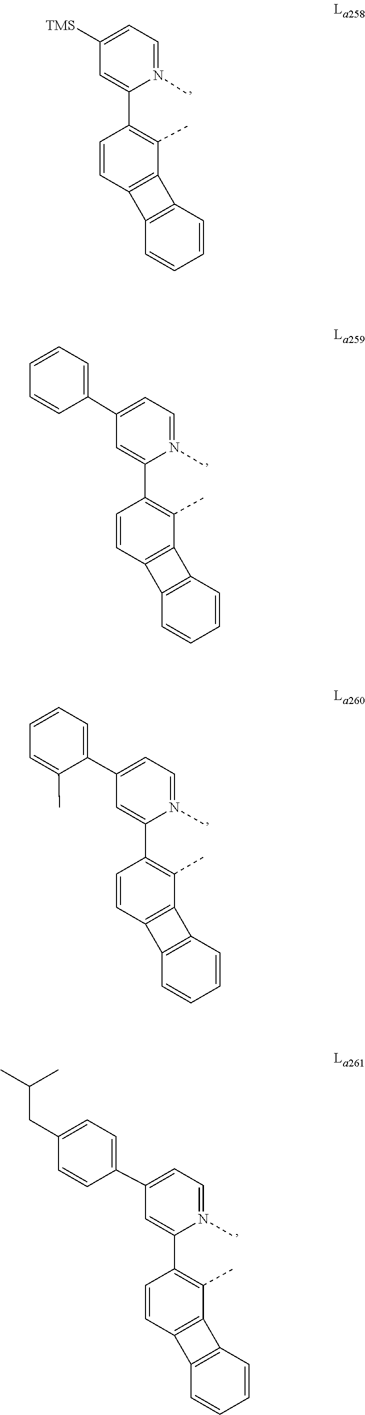

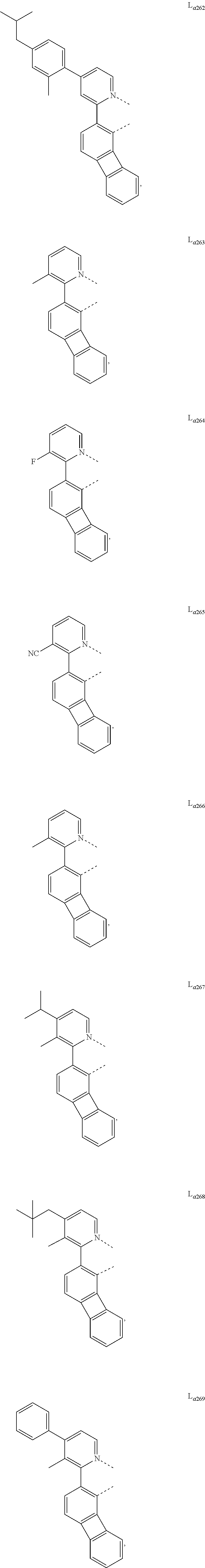

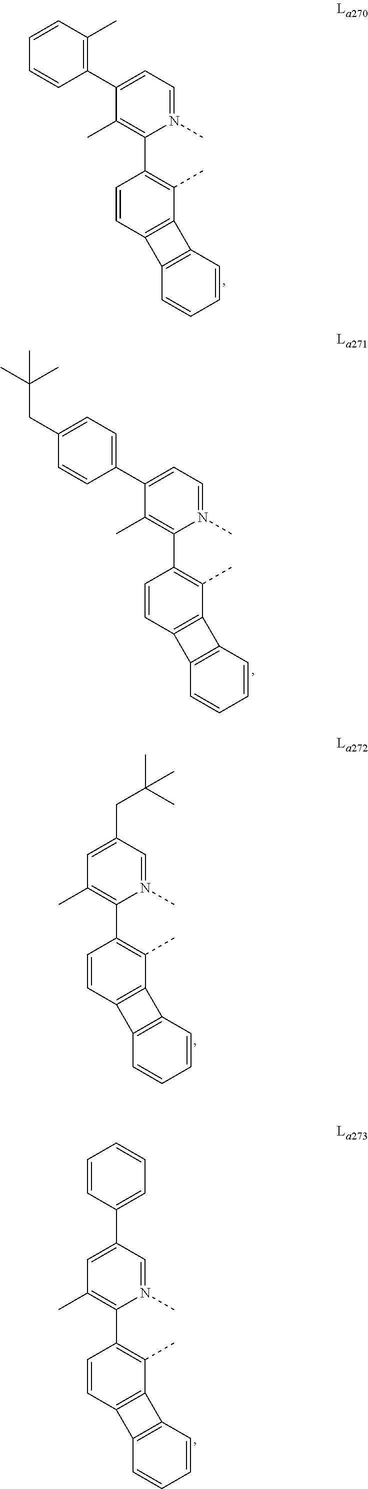

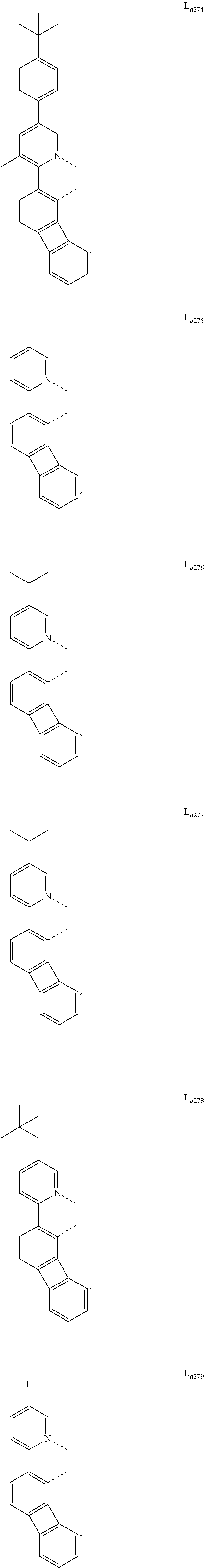

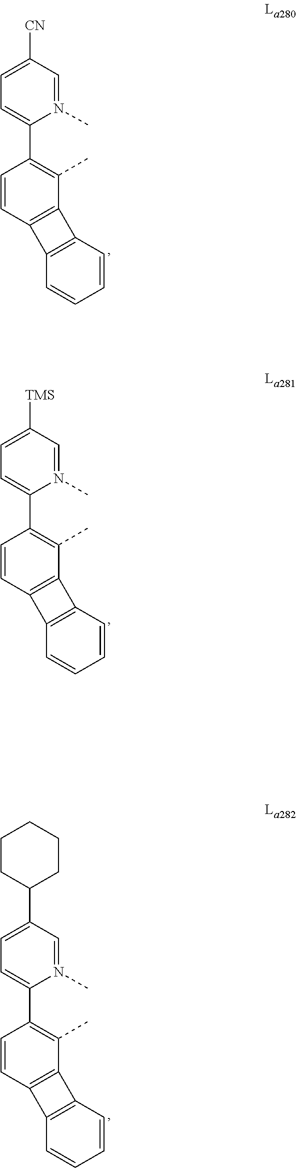

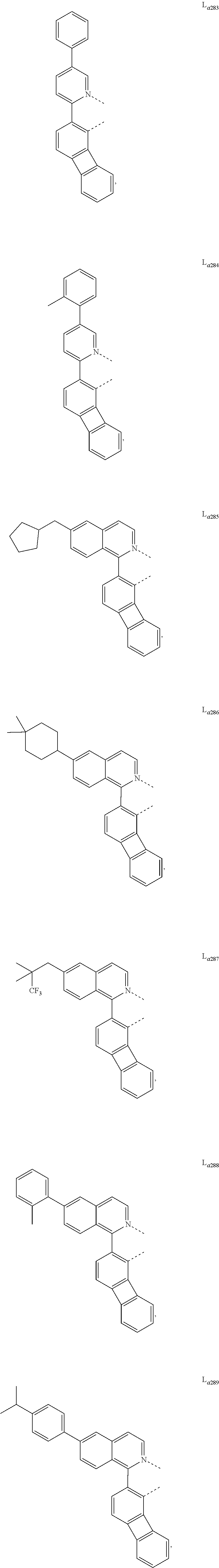

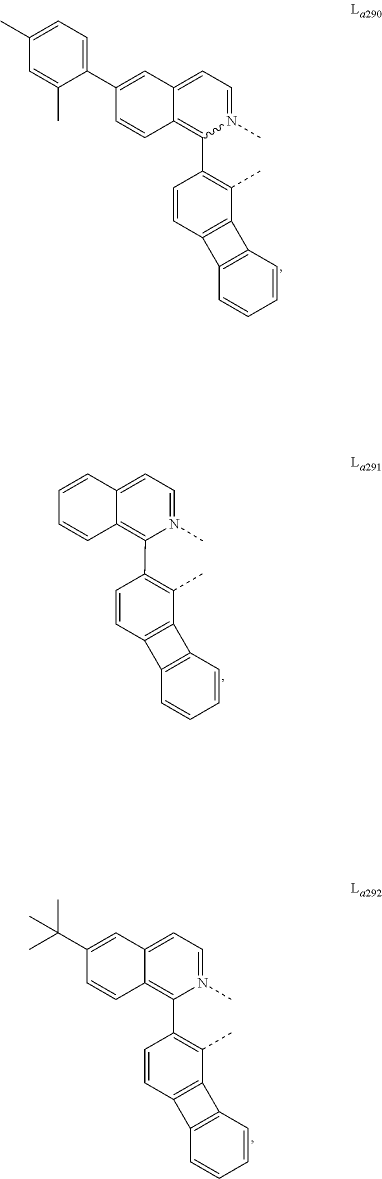

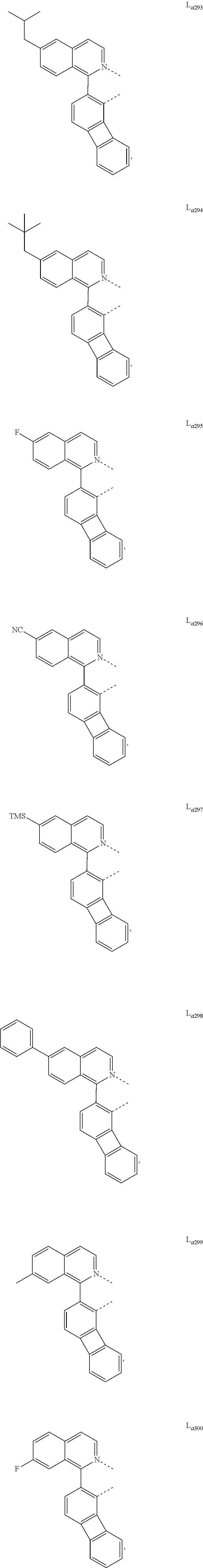

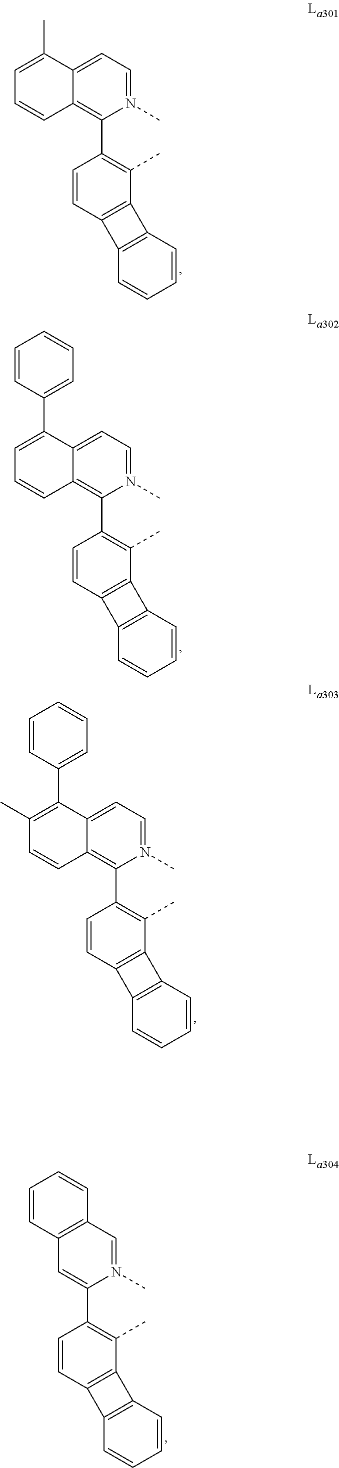

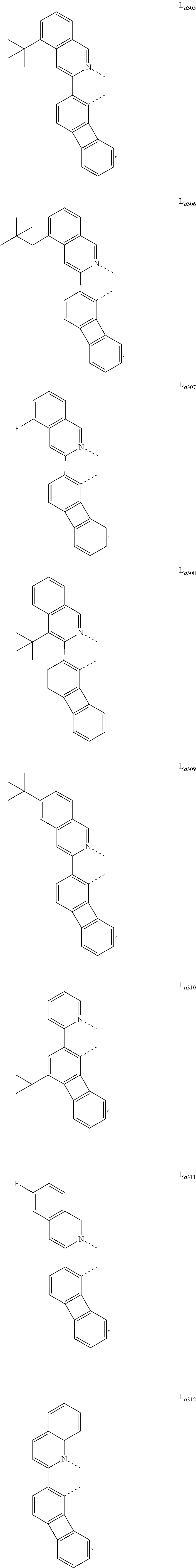

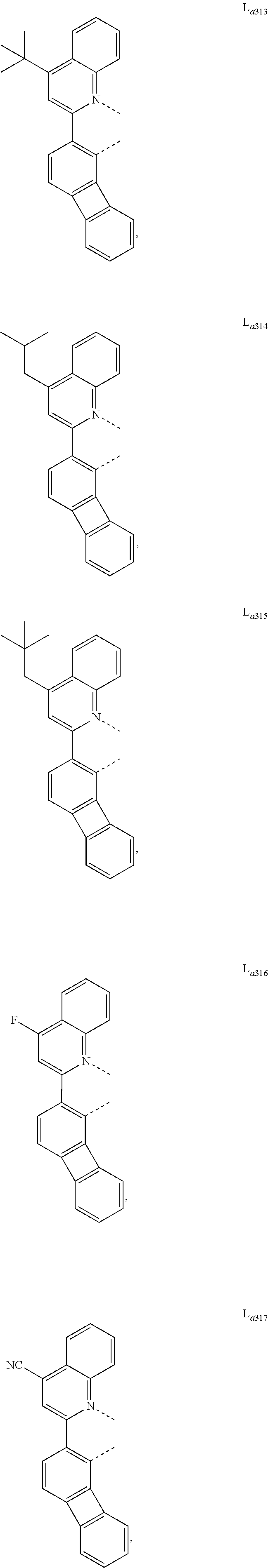

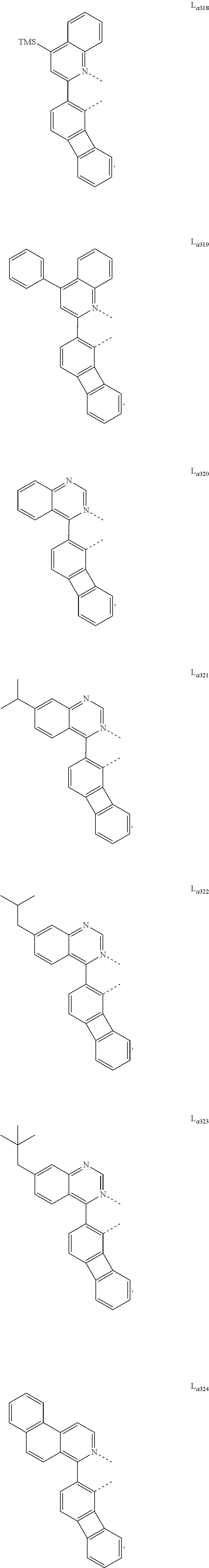

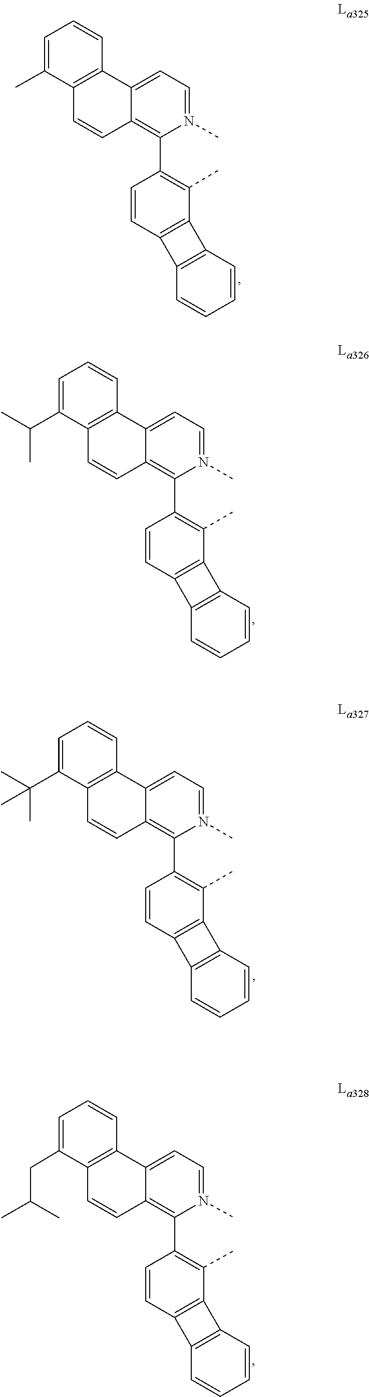

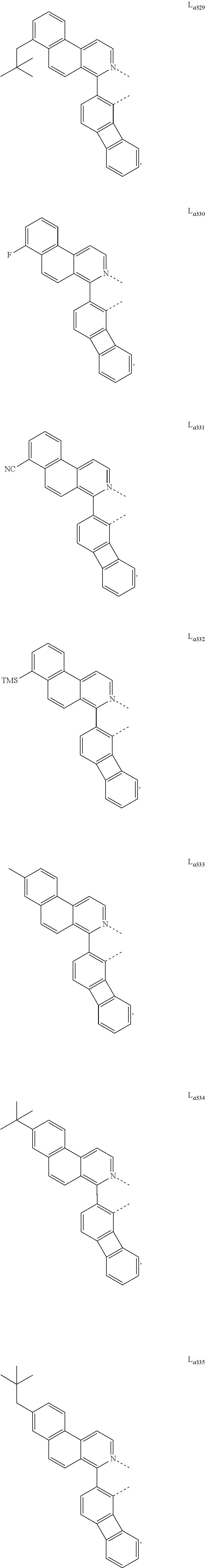

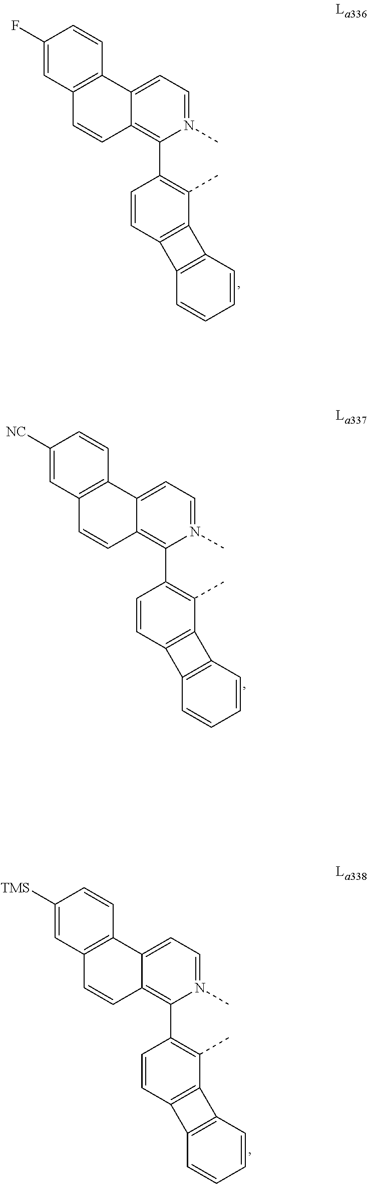

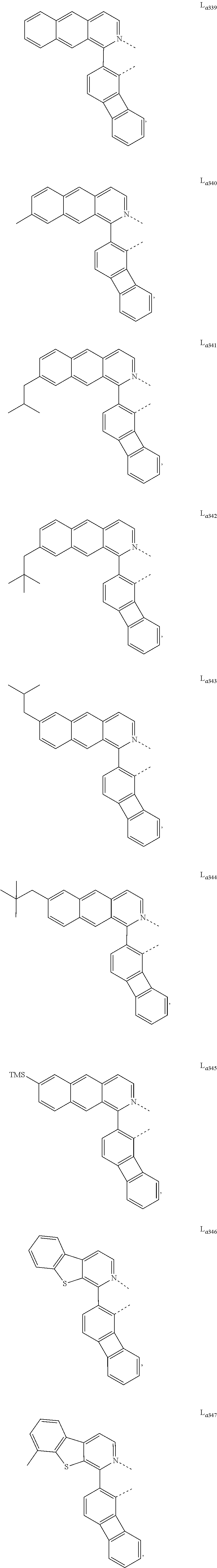

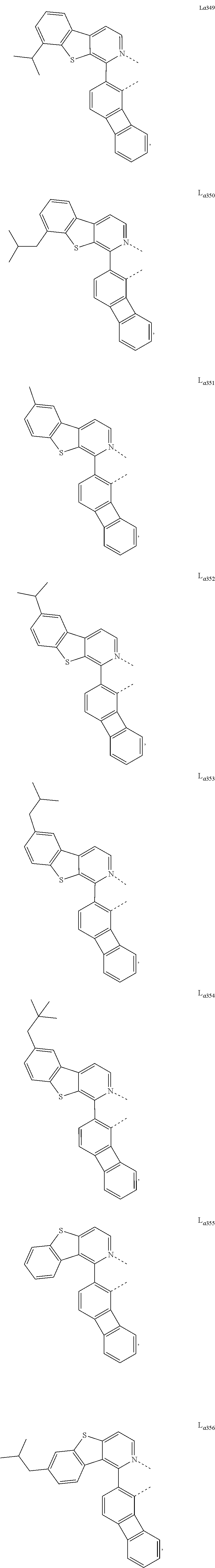

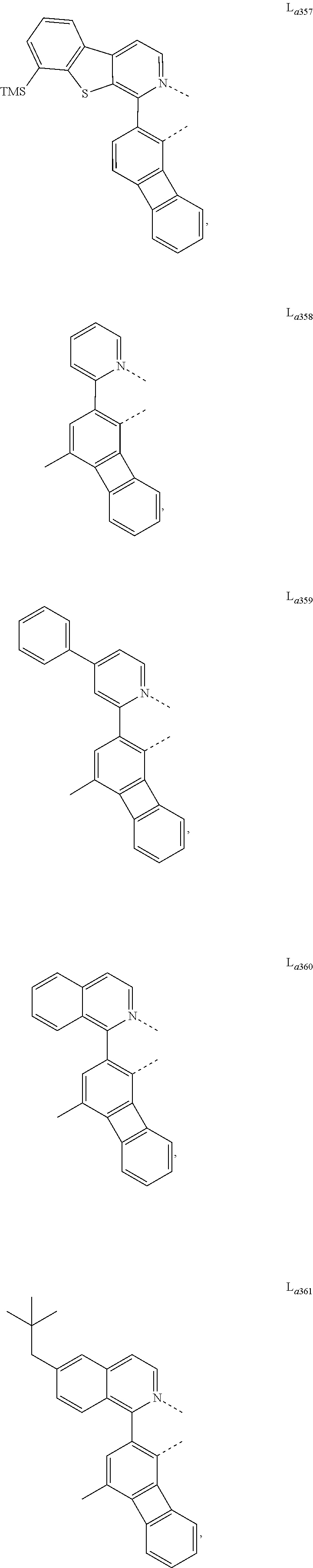

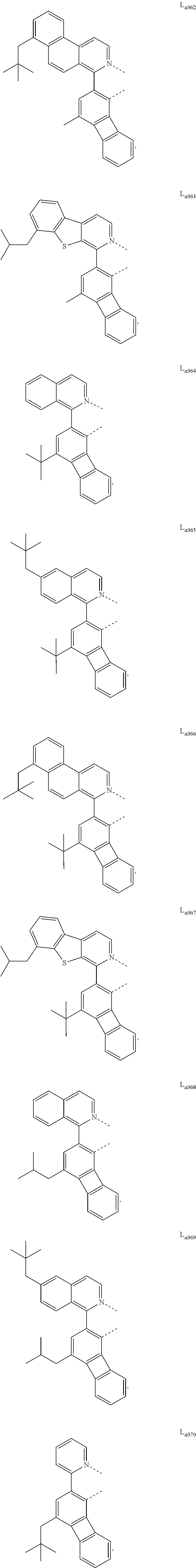

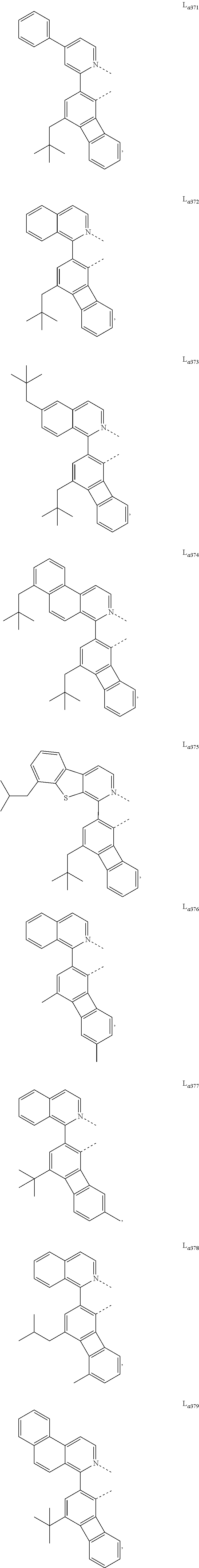

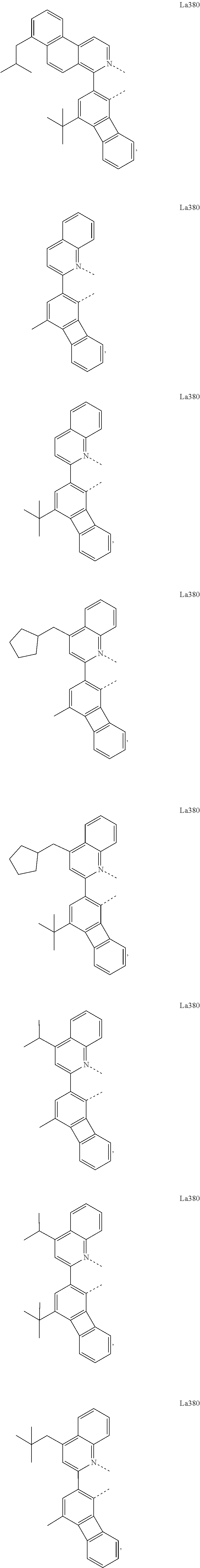

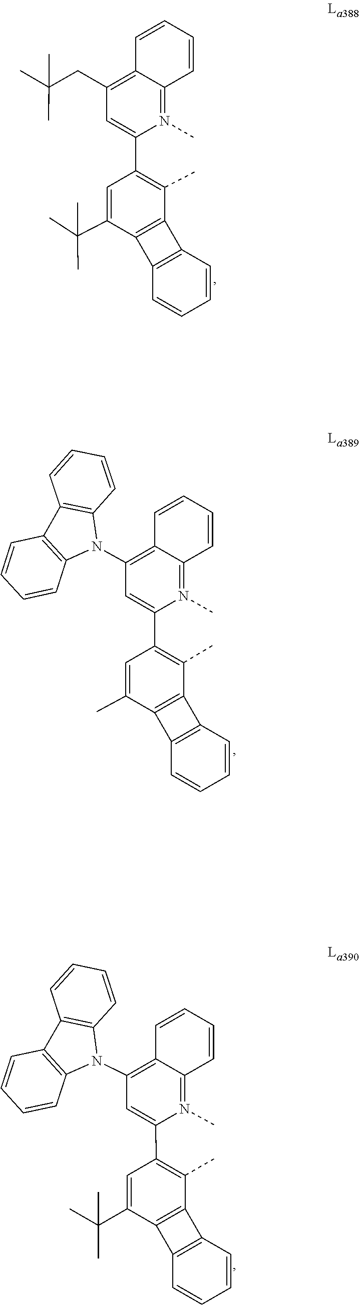

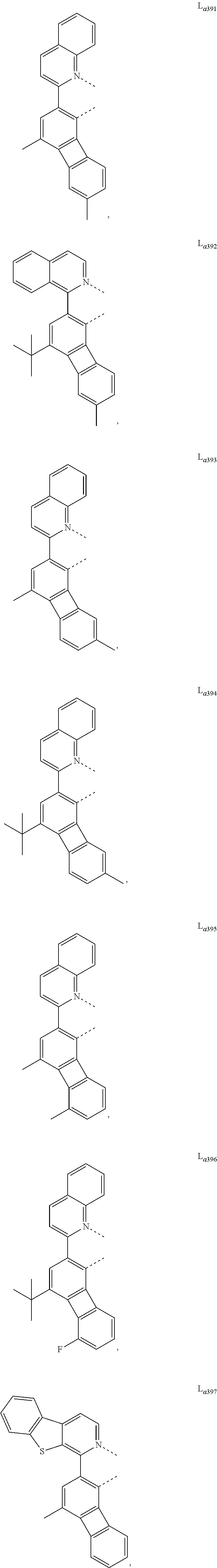

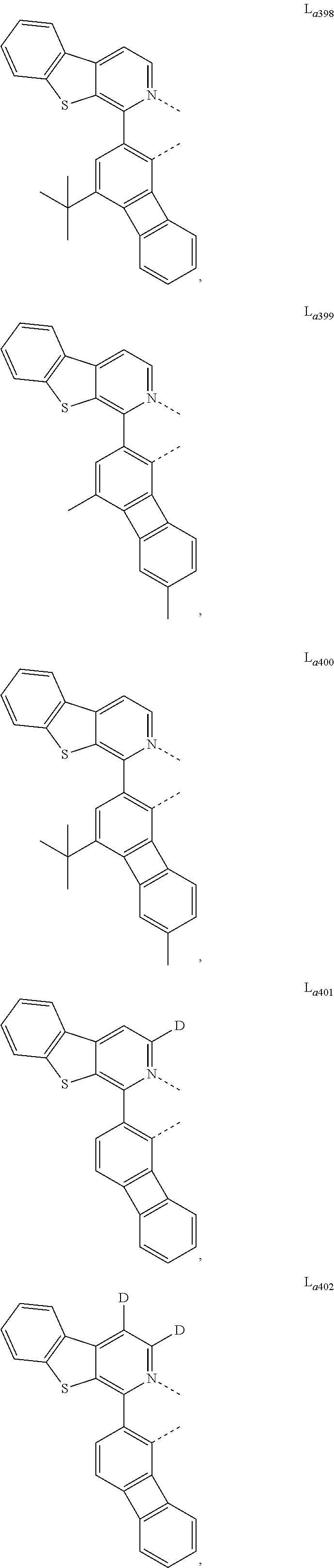

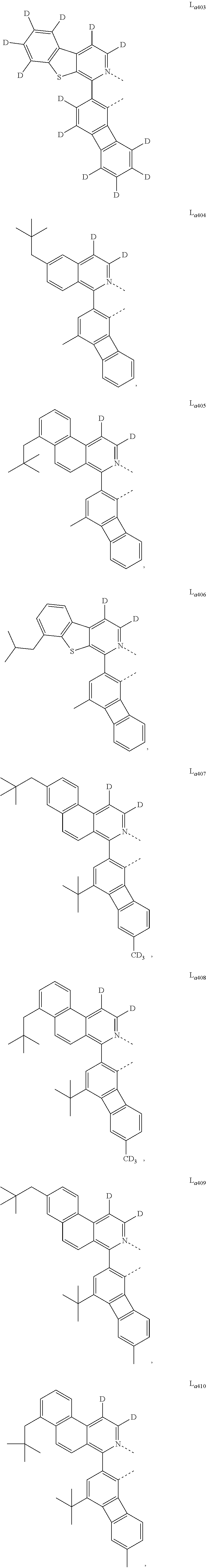

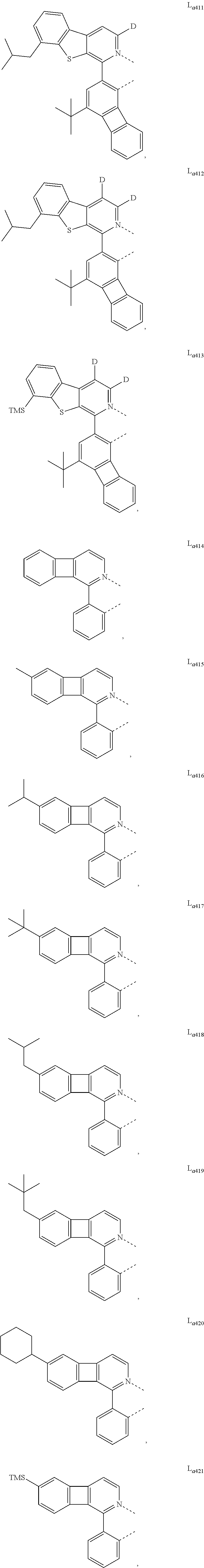

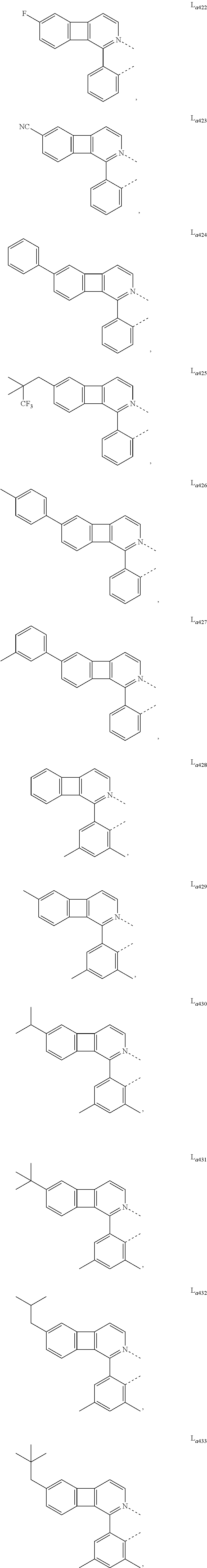

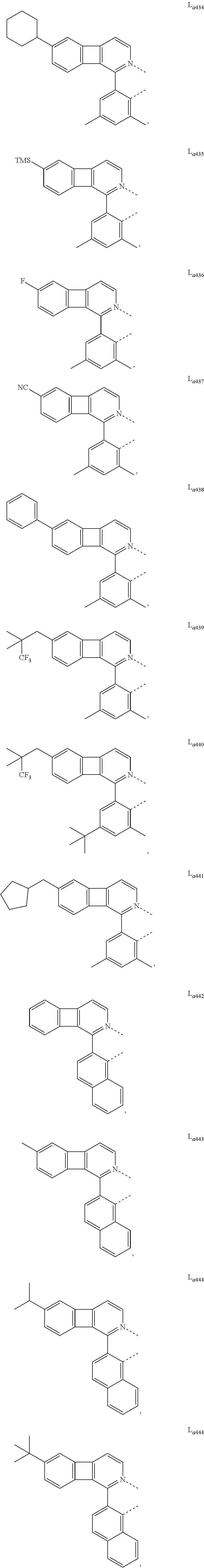

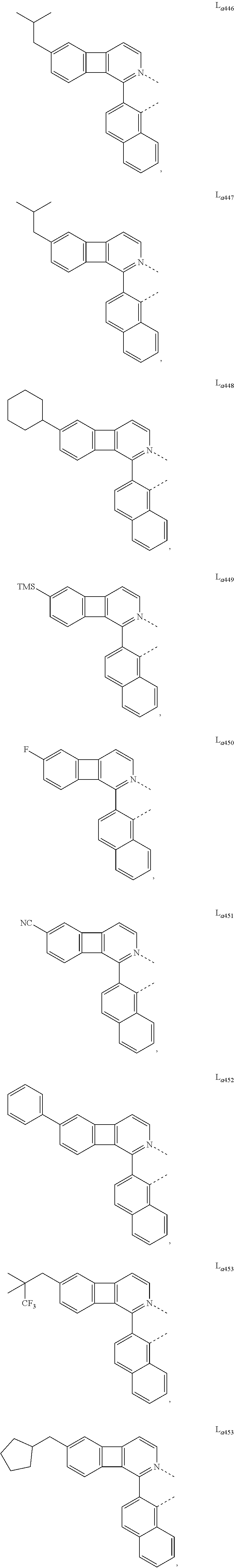

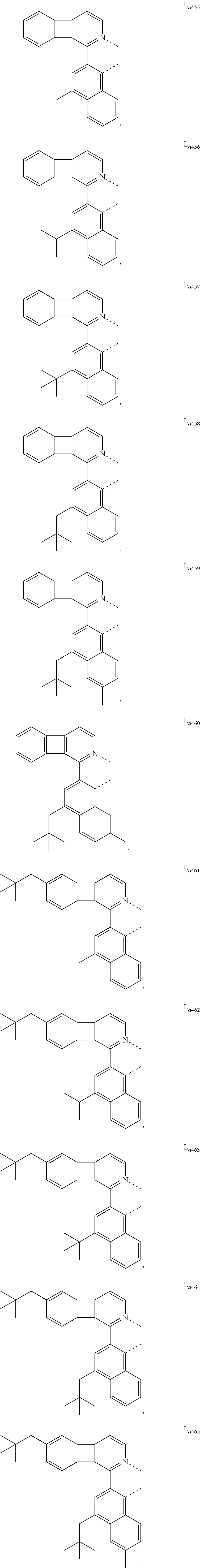

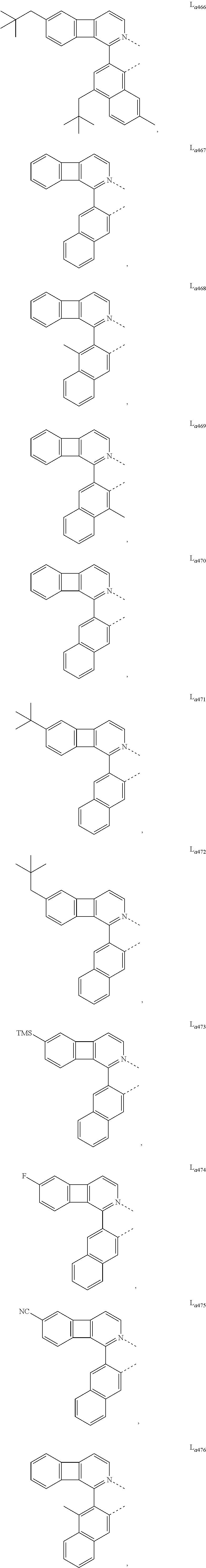

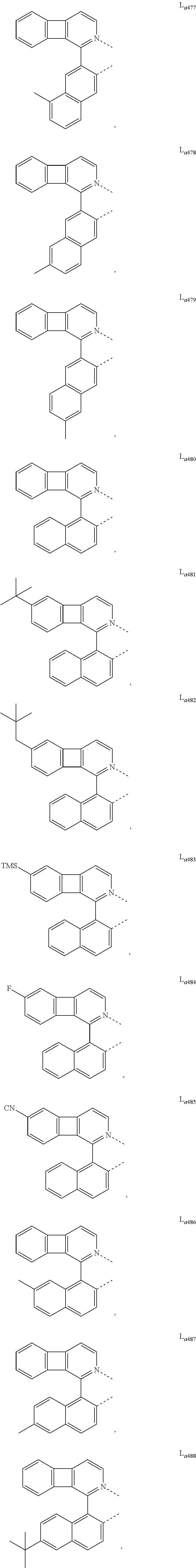

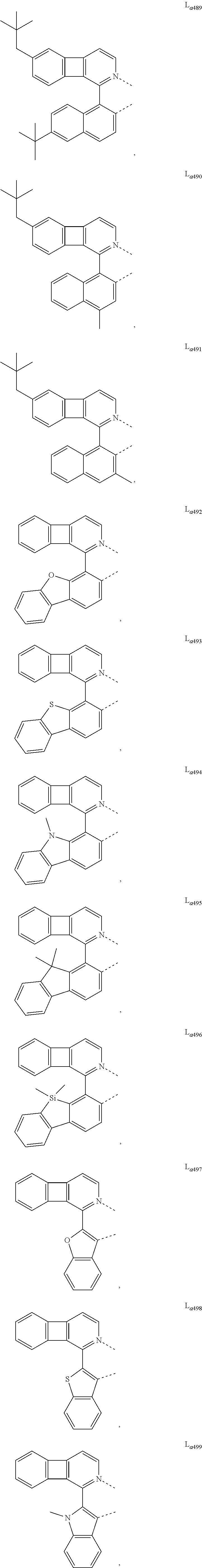

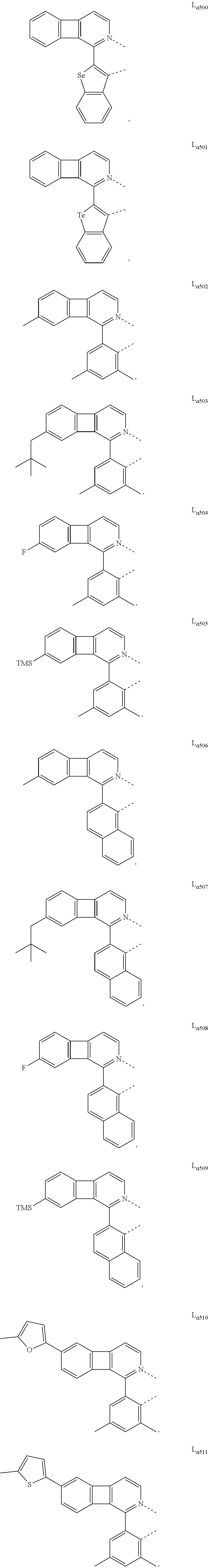

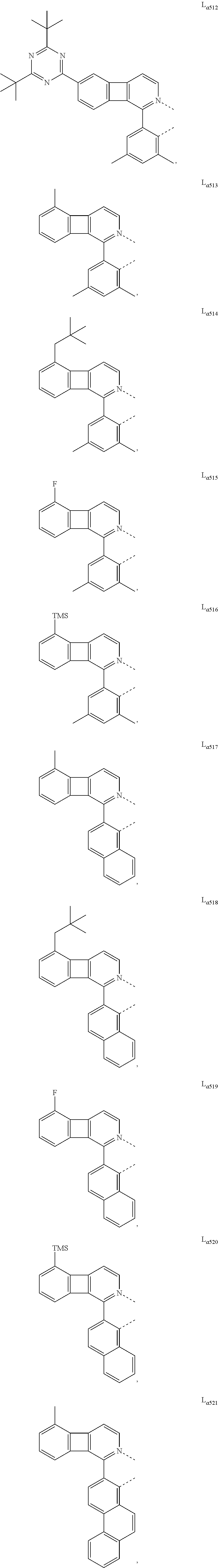

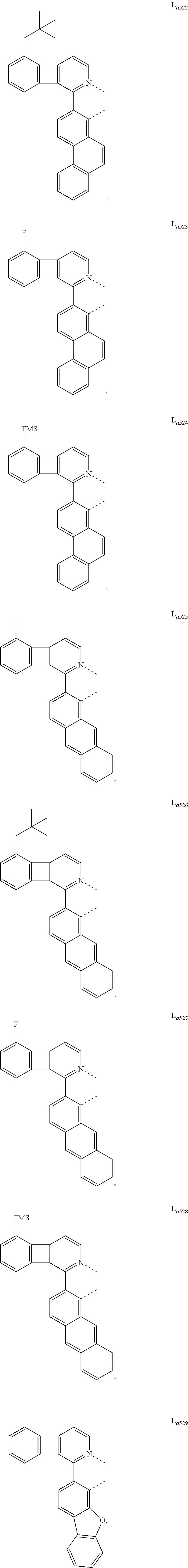

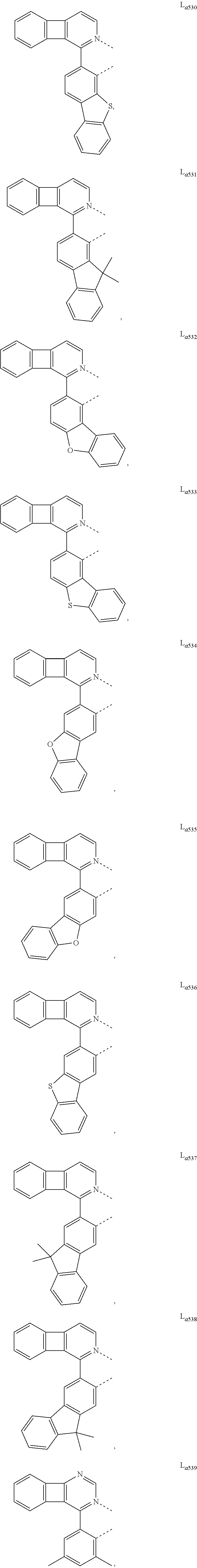

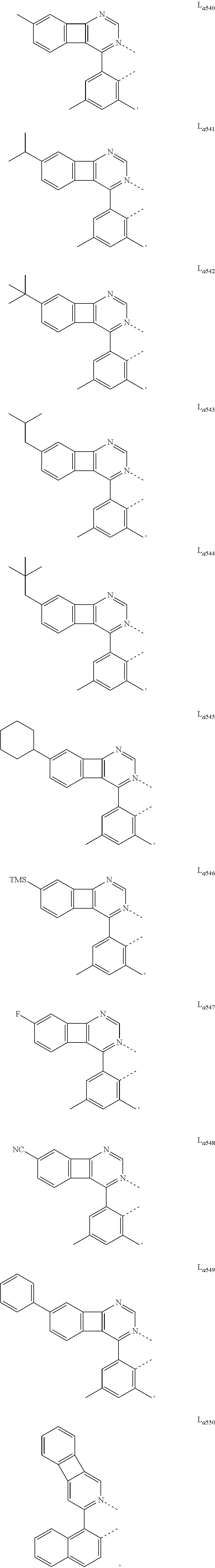

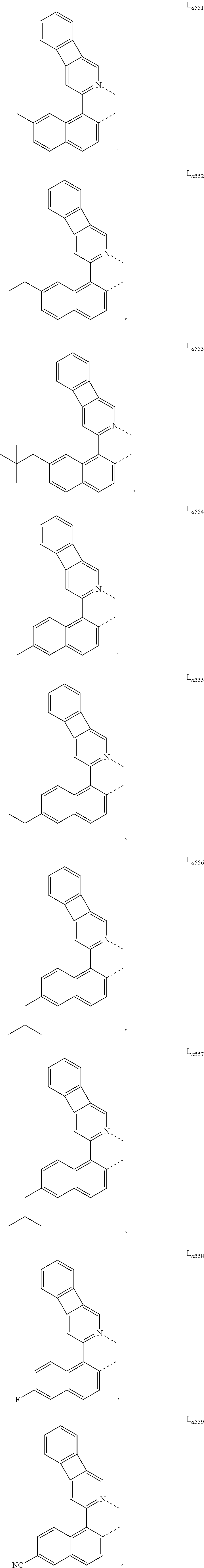

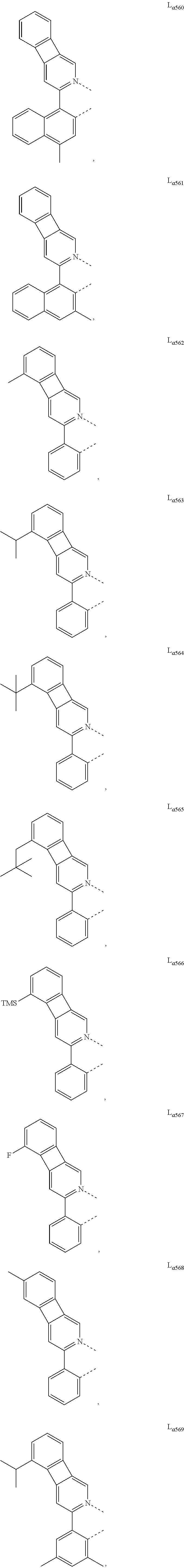

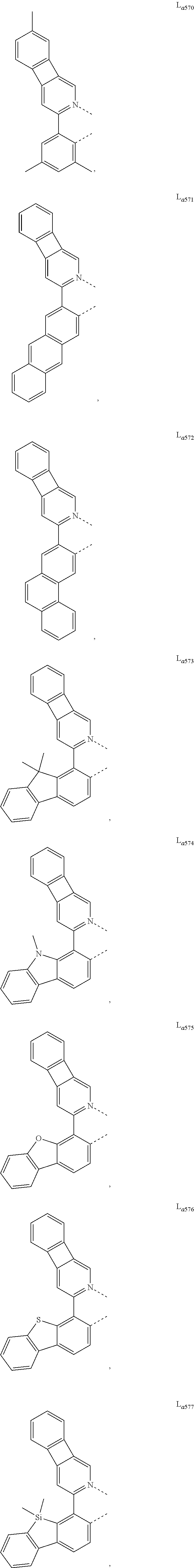

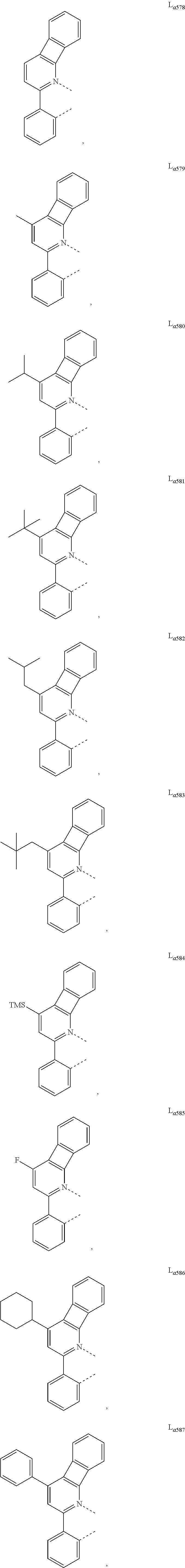

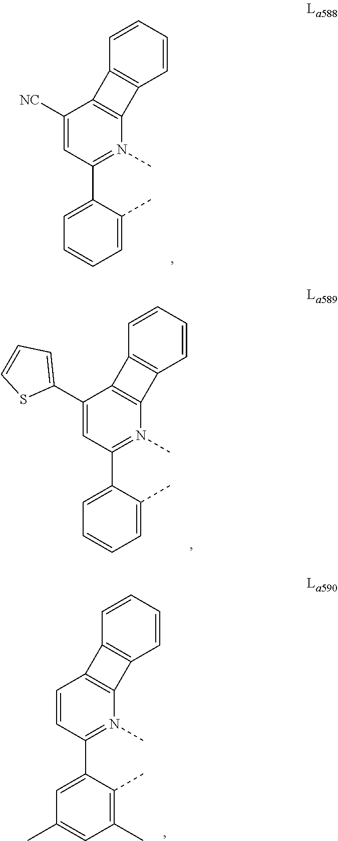

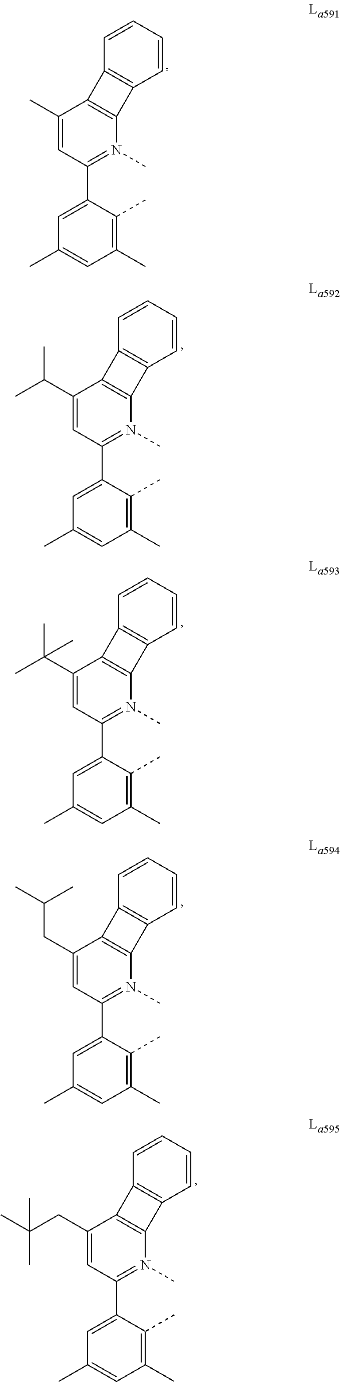

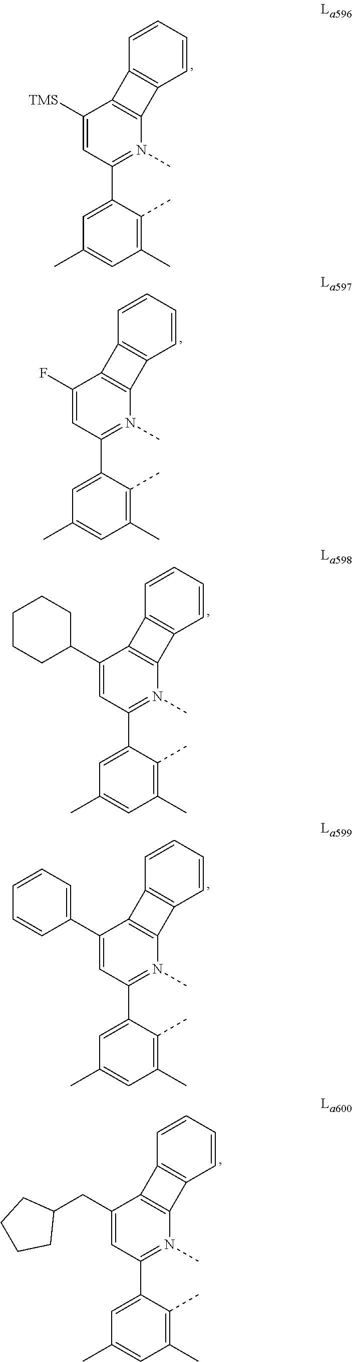

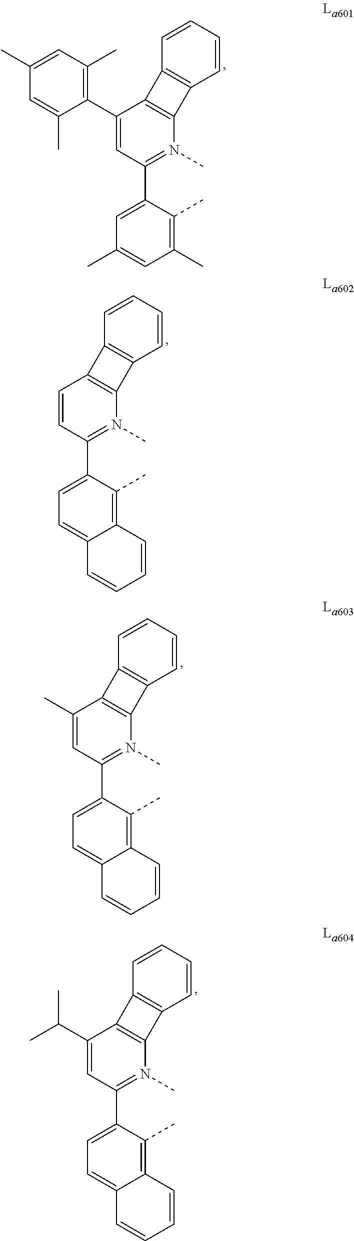

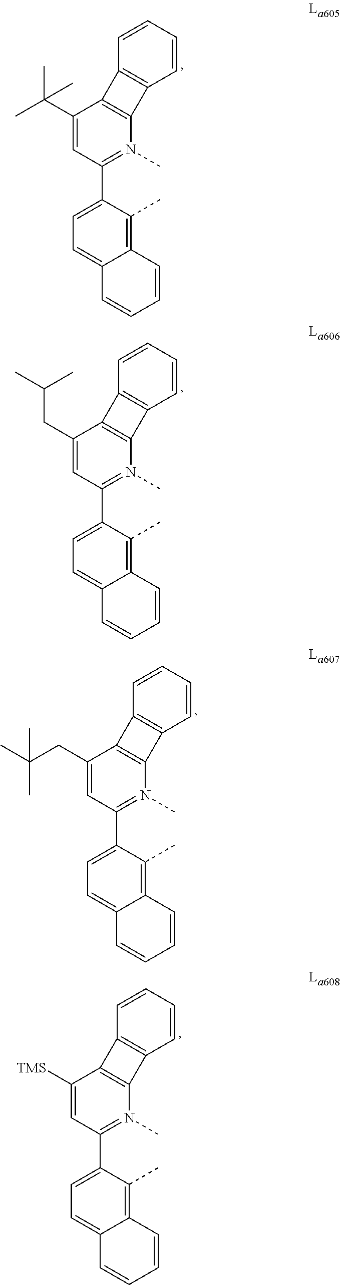

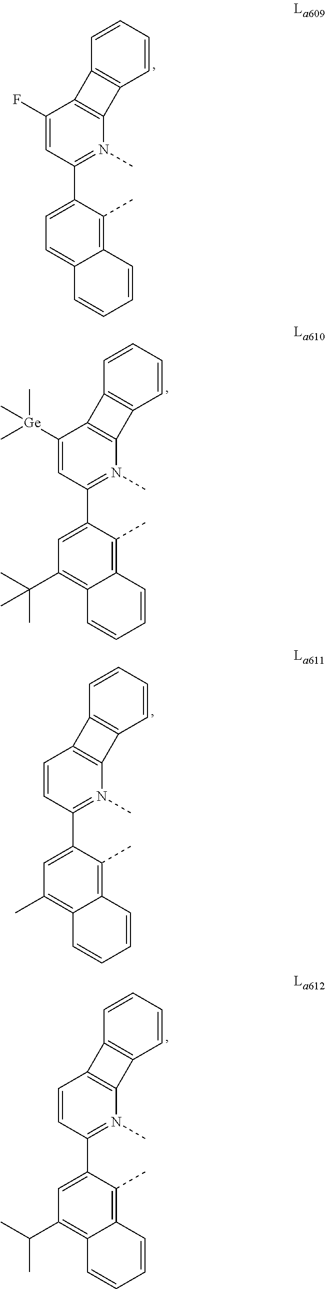

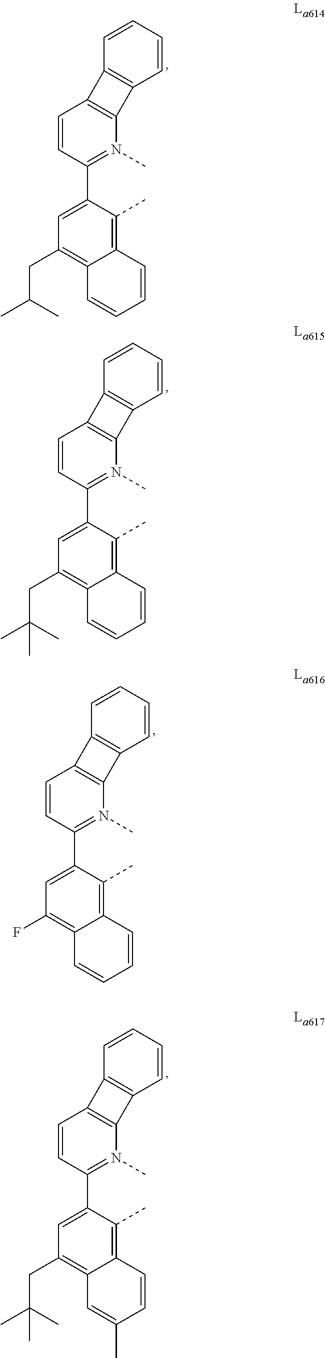

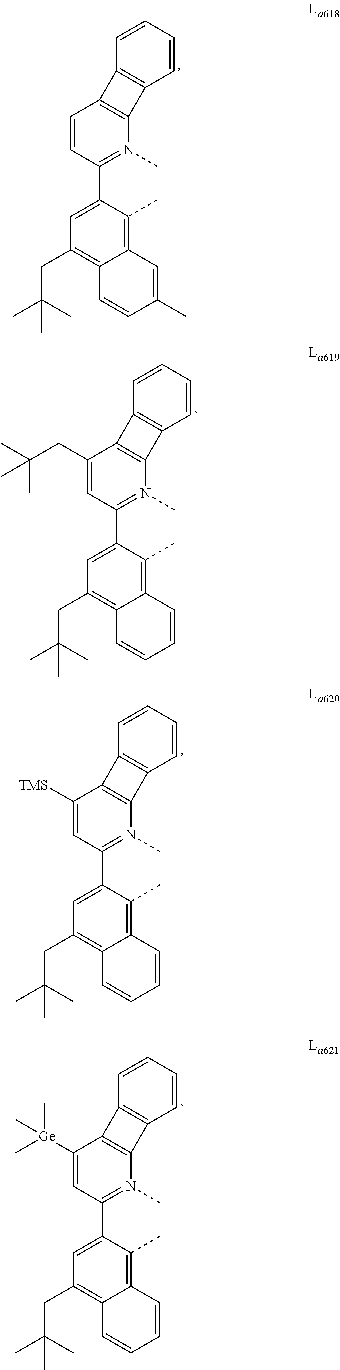

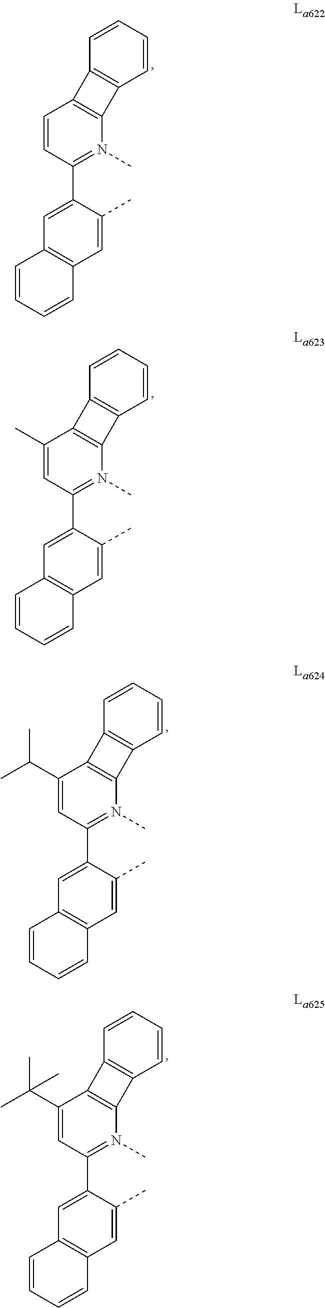

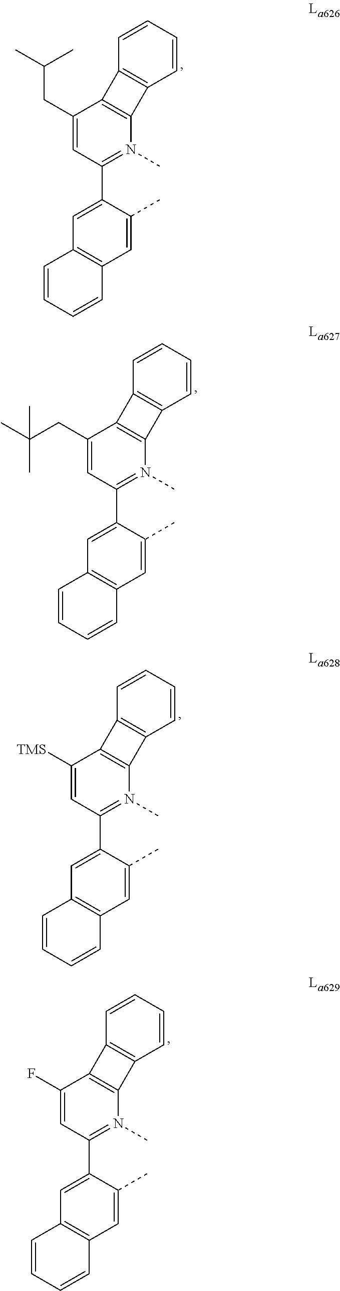

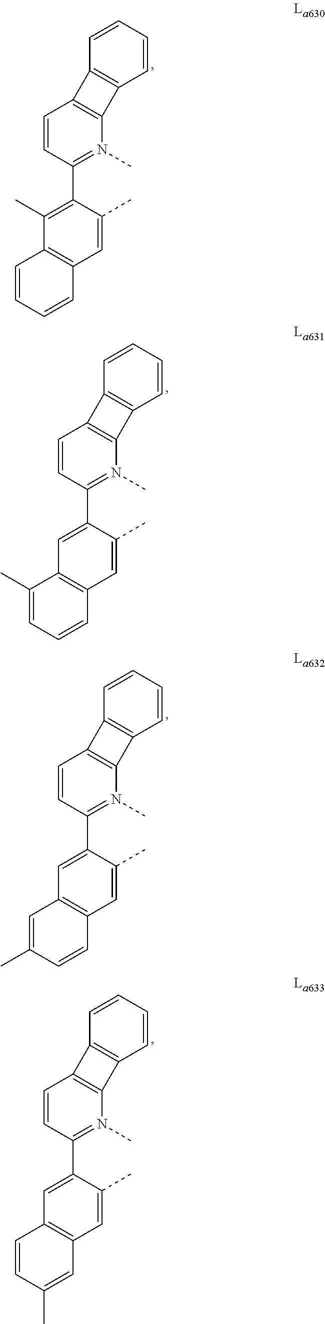

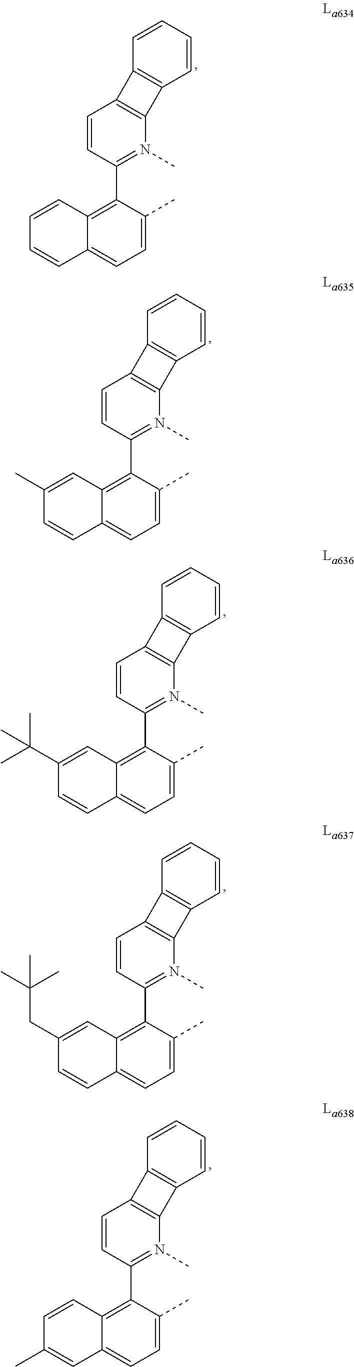

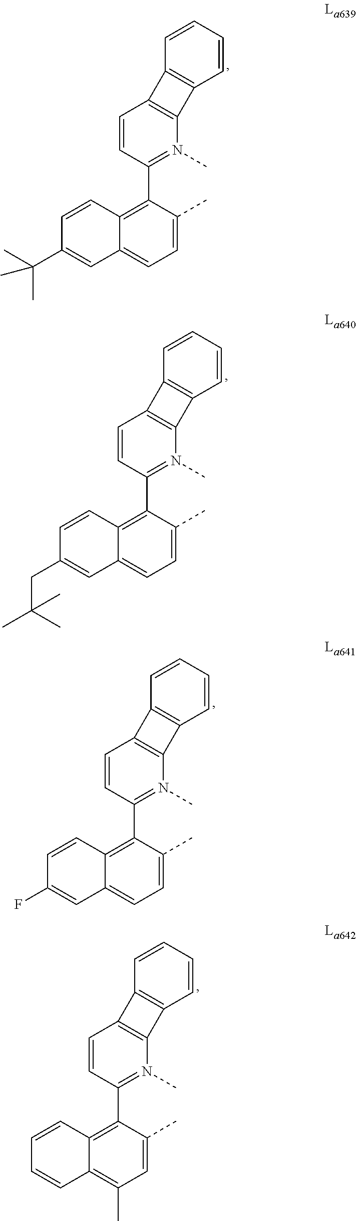

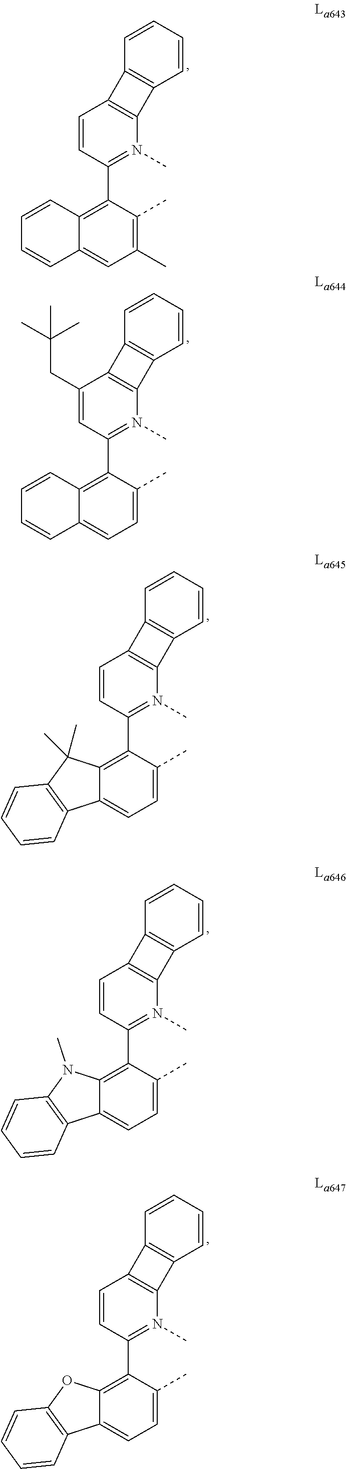

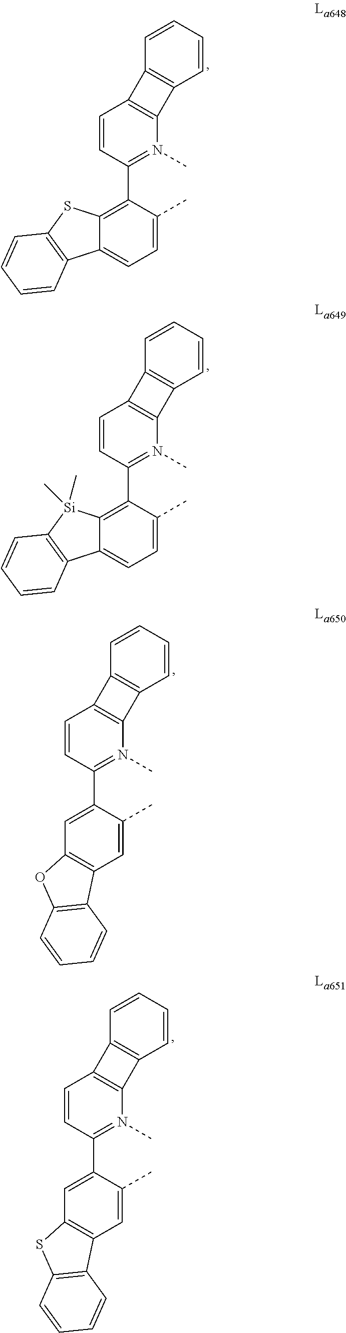

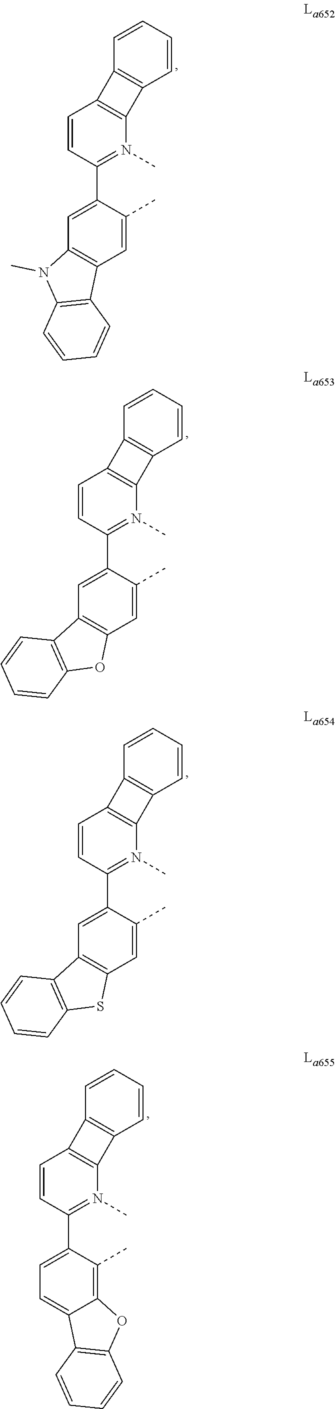

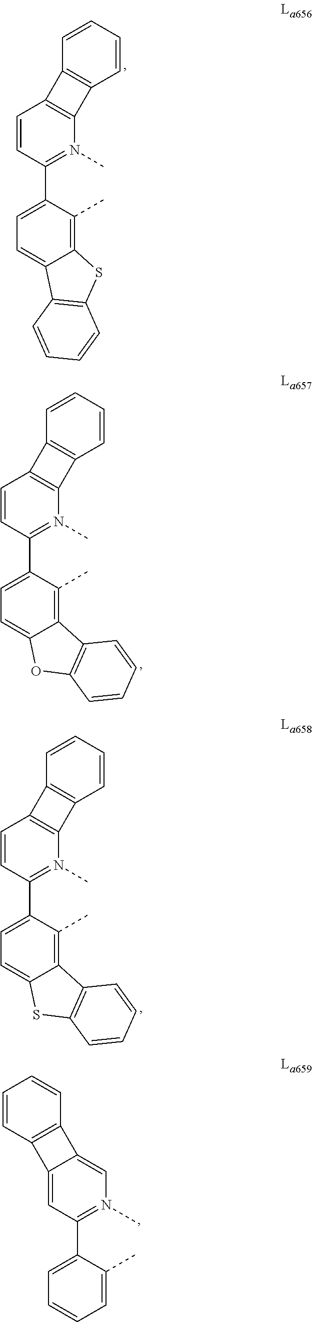

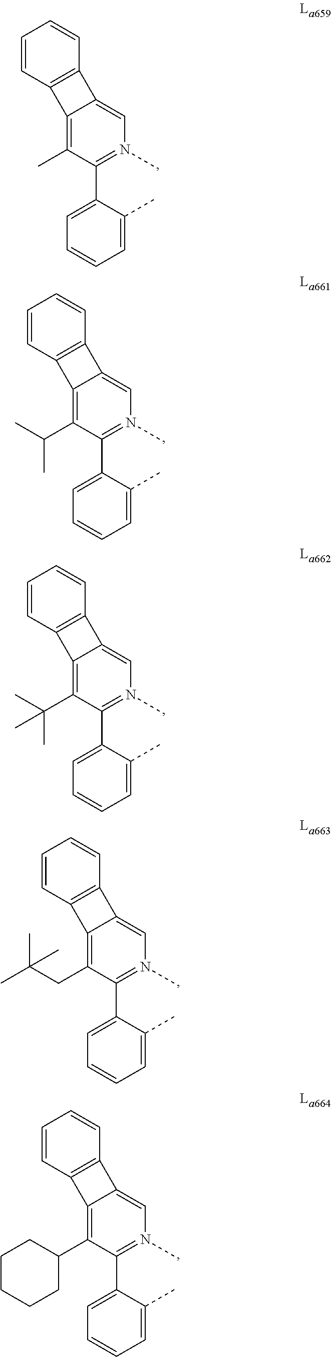

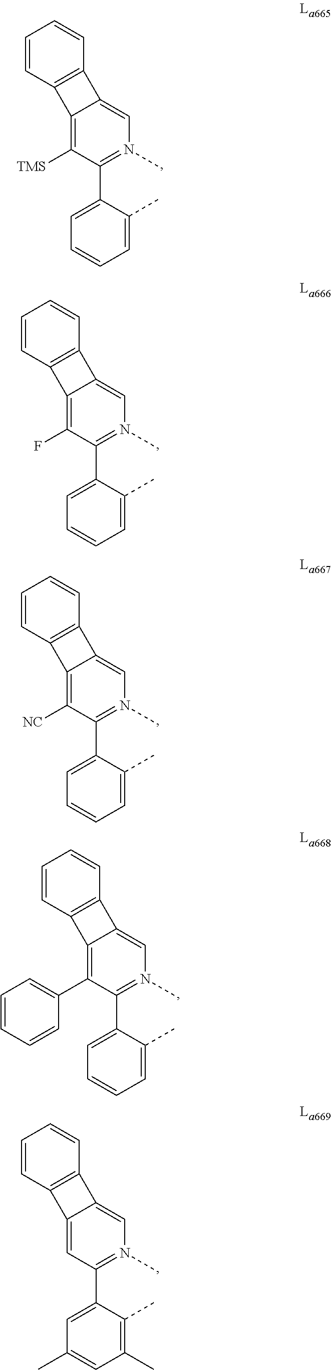

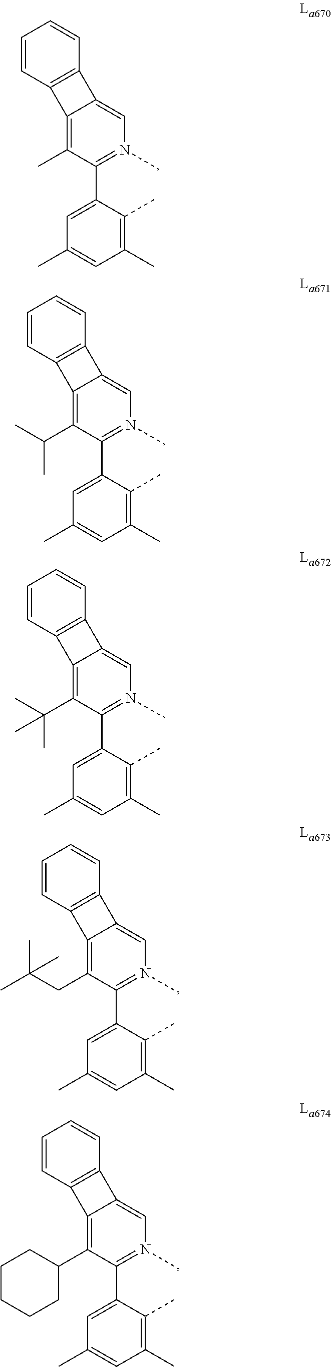

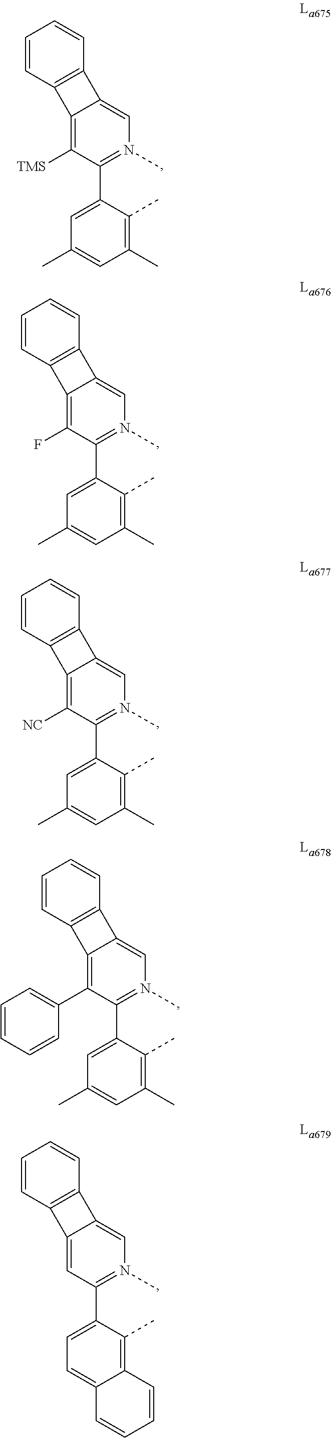

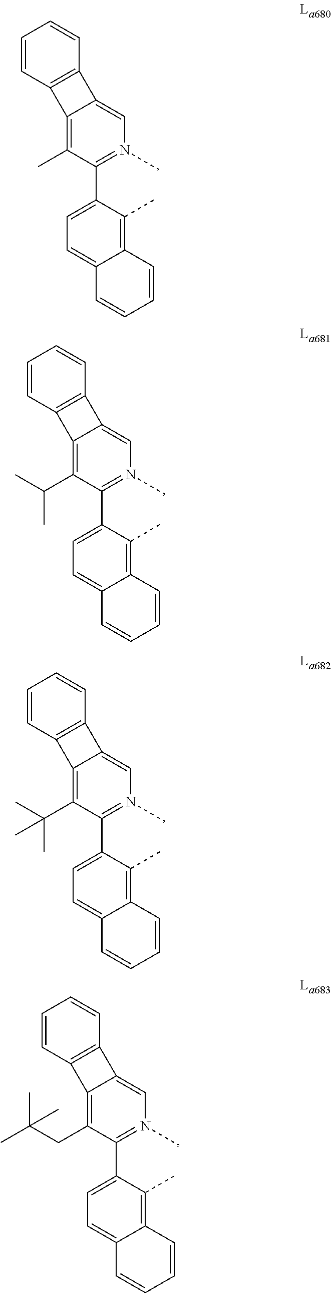

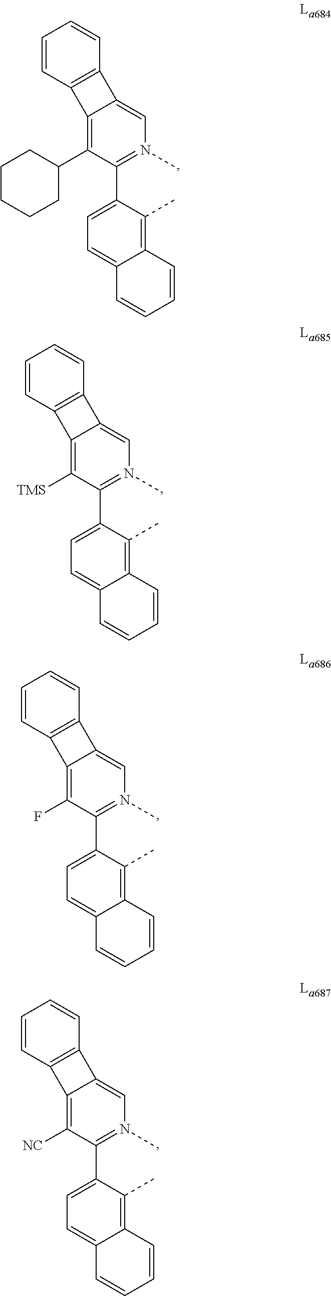

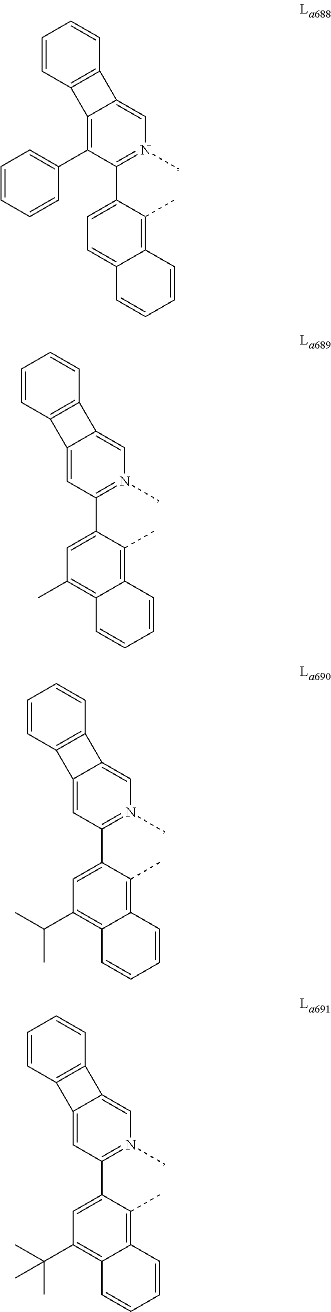

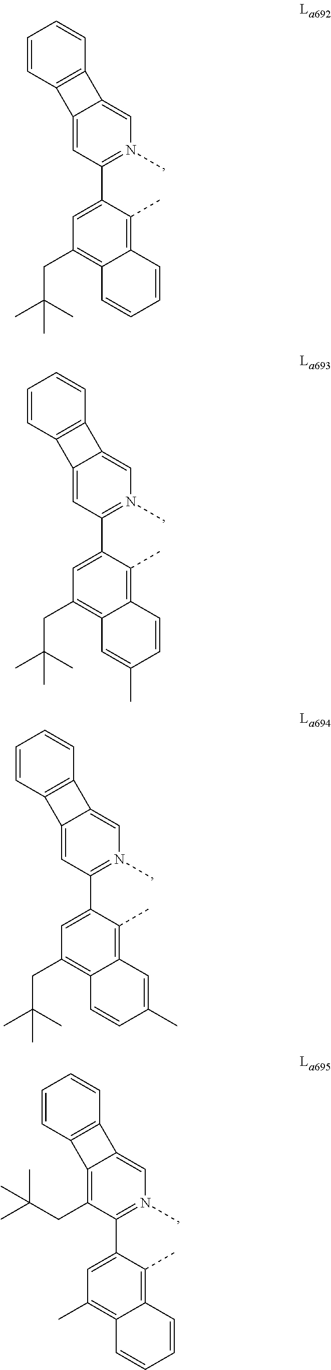

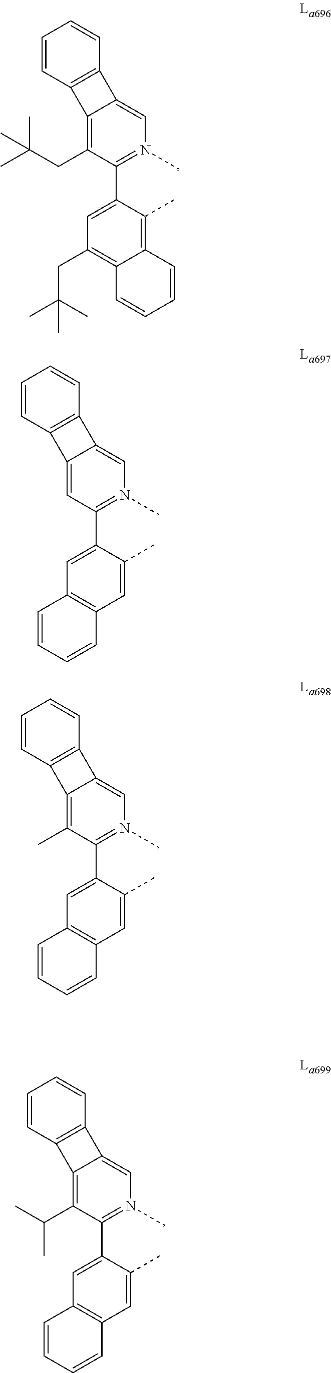

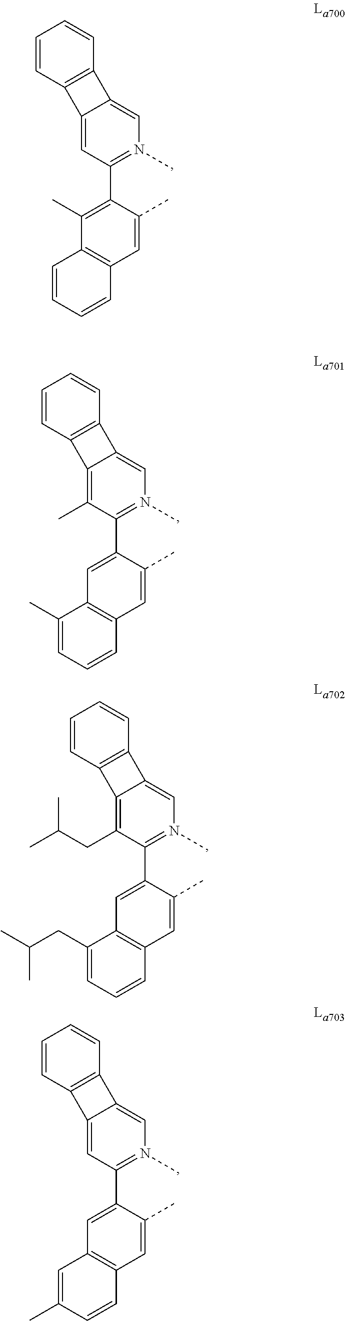

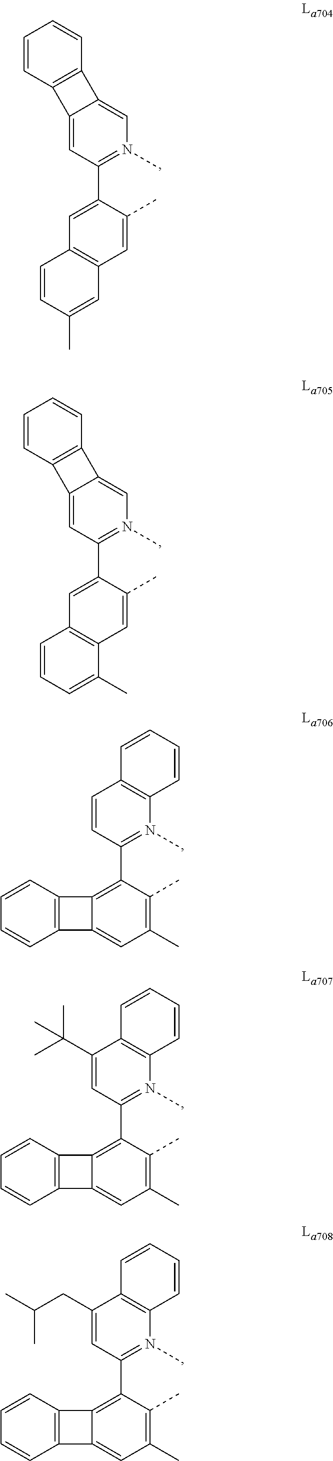

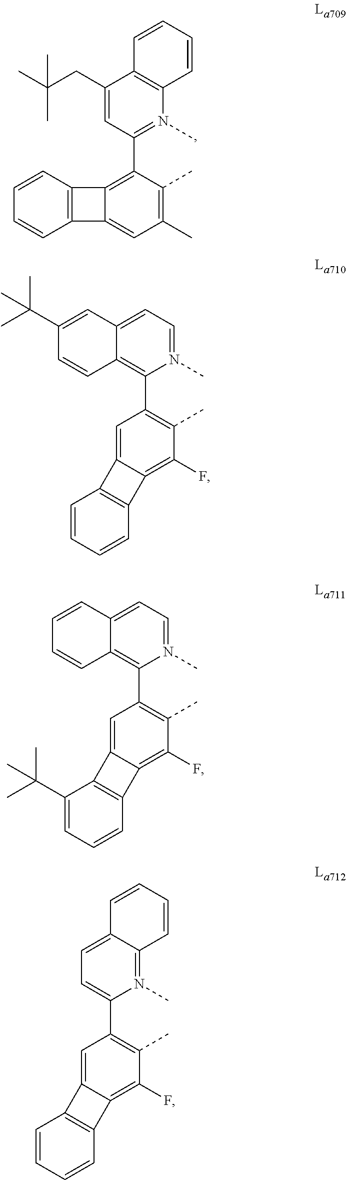

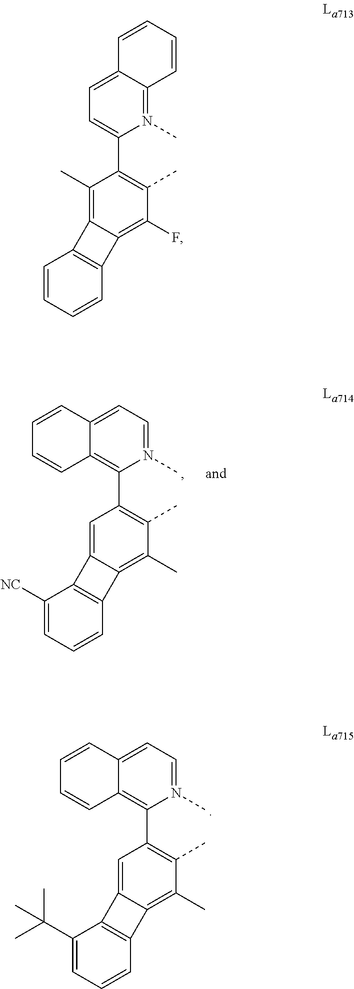

11. The metal complex of claim 1, wherein the metal M is selected from Ir, Rh, Re, Os, Pt, Au or Cu; preferably, the metal M is selected from Ir, Pt or Os; more preferably, the metal M is Ir.

12. The metal complex of claim 1, wherein L_{b} is, at each occurrence identically or differently, selected from the following structure: 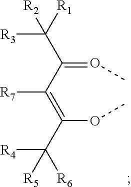
wherein R₁ to R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a sulfanyl group, a sulfinyl group, a sulfonyl group, a phosphino group, and combinations thereof;
adjacent substituents R₁ to R₃ or R₄ to R₆ can be optionally joined to form a ring;
preferably, at least one or two of R₁ to R₃ are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, or a combination thereof; and/or at least one or two of R₄ to R₆ are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, or a combination thereof;
more preferably, at least two of R₁ to R₃ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms, or a combination thereof; and/or at least two of R₄ to R₆ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms, or a combination thereof.

13. The metal complex of claim 1, wherein L_{c} is selected from the group consisting of the following structures 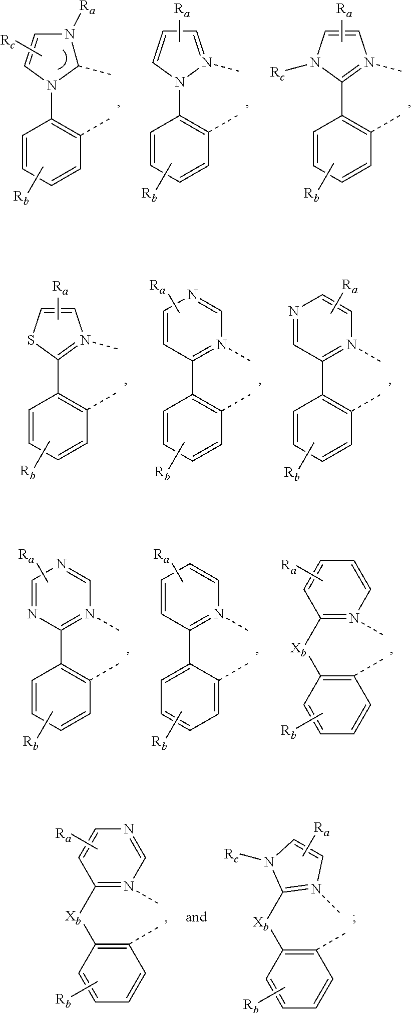
wherein Rₐ, R_{b}, and R_{c} represent, at each occurrence identically or differently, mono-substitution, multiple substitutions or non-substitution;
X_{b} is, at each occurrence identically or differently, selected from the group consisting of: O, S, Se, NR_{N1} and CR_{C1}R_{C2};
Rₐ, R_{b}, R_{c}, R_{N1}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a sulfanyl group, a sulfinyl group, a sulfonyl group, a phosphino group, and combinations thereof;
adjacent substituents Rₐ, R_{b}, R_{c}, R_{N1}, R_{C1}, and R_{C2} can be optionally joined to form a ring.

14. The metal complex of claim 10, wherein L_{b} is, at each occurrence identically or differently, selected from the group consisting of the following structures: 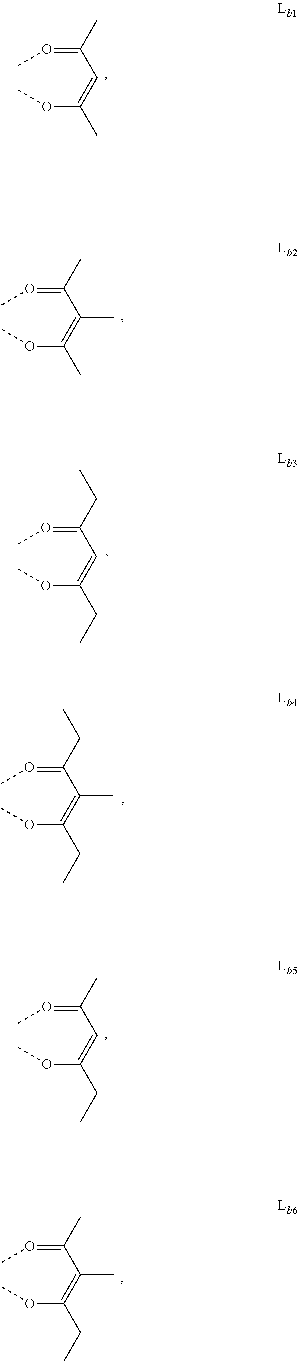 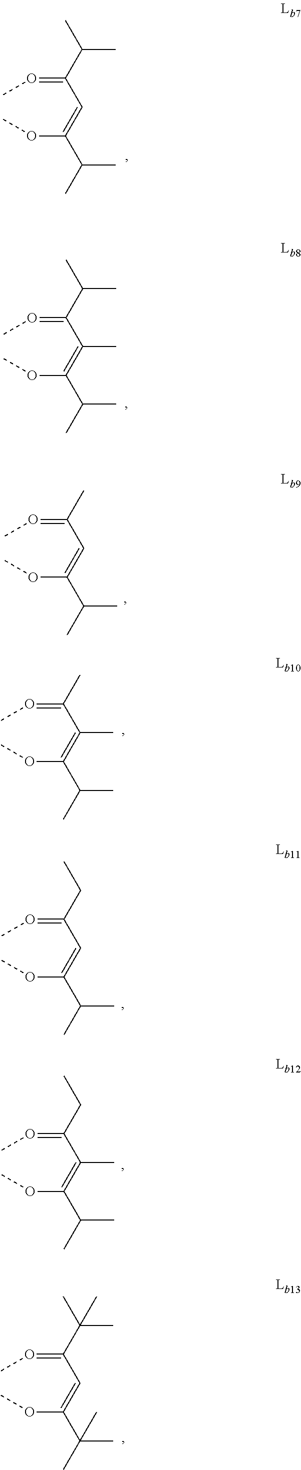 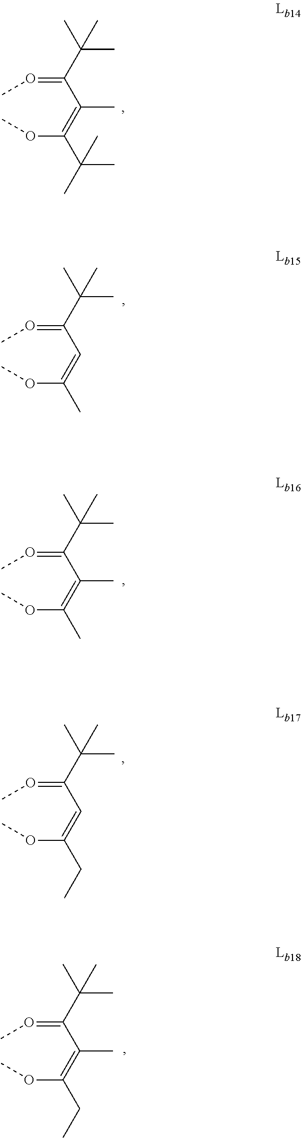 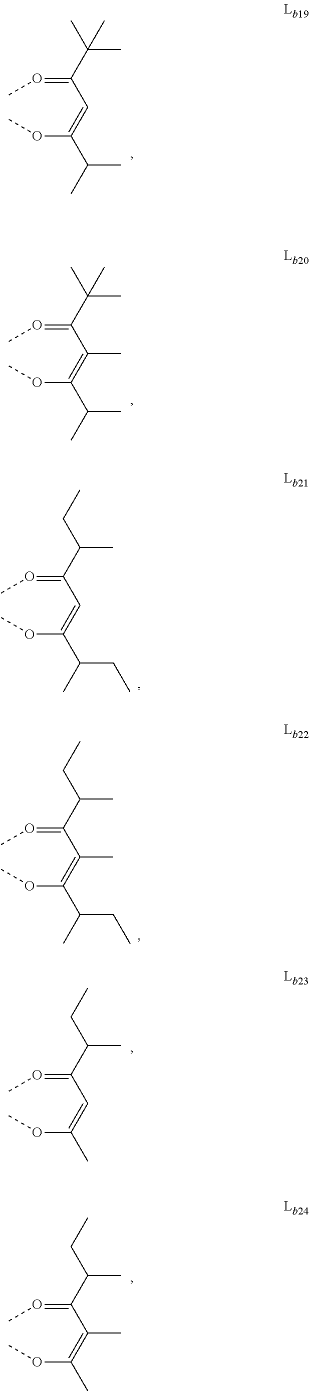 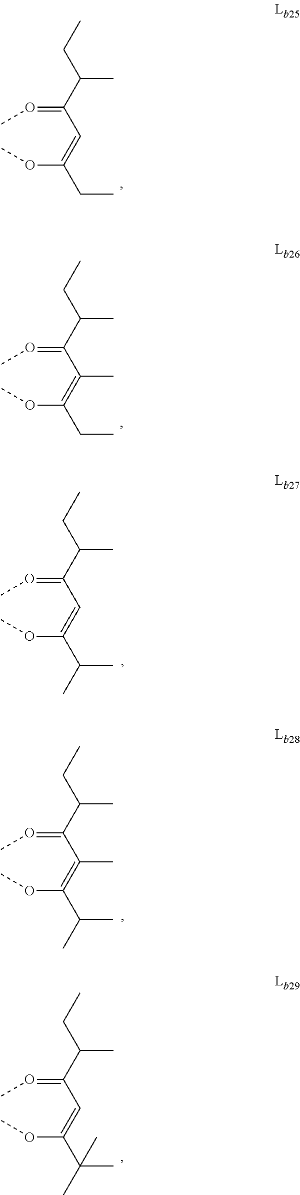 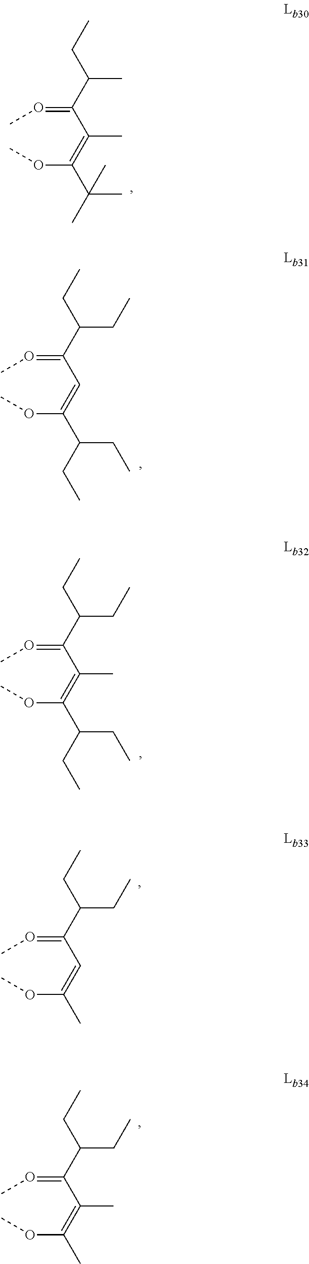 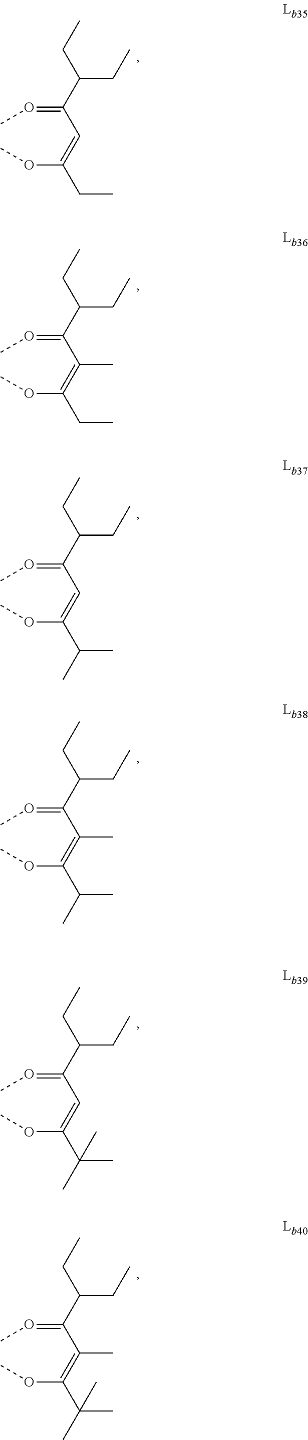 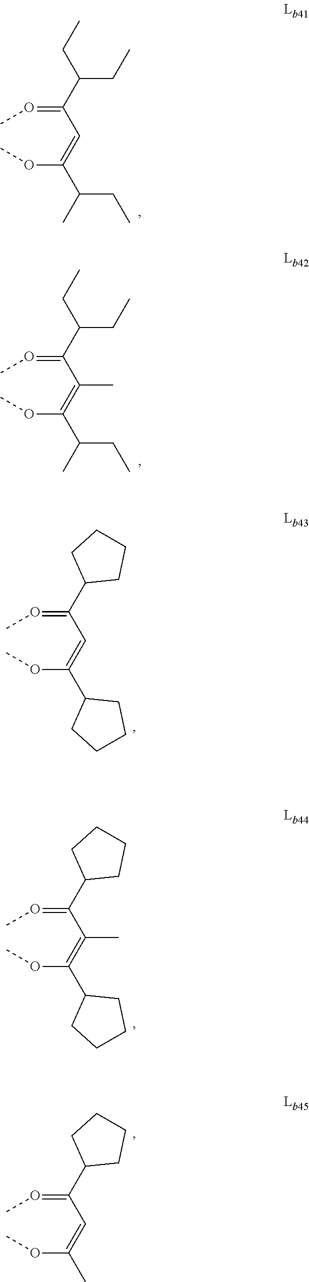 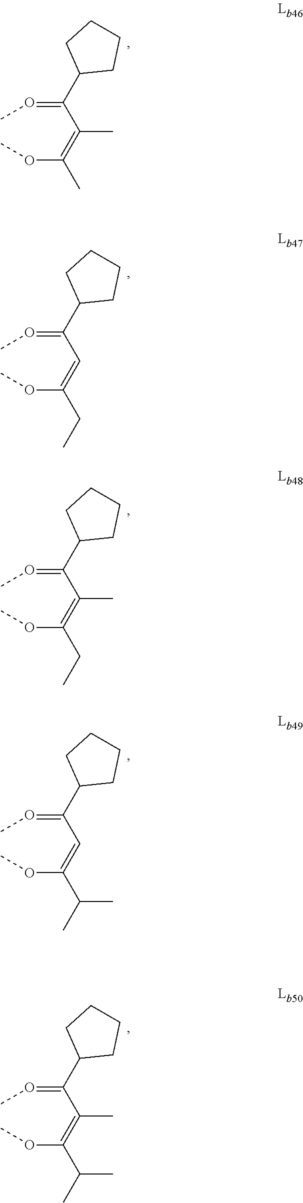 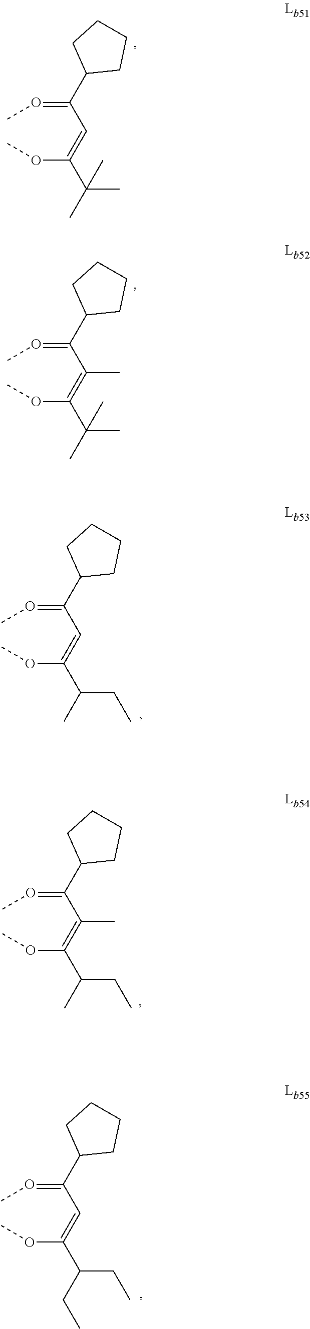 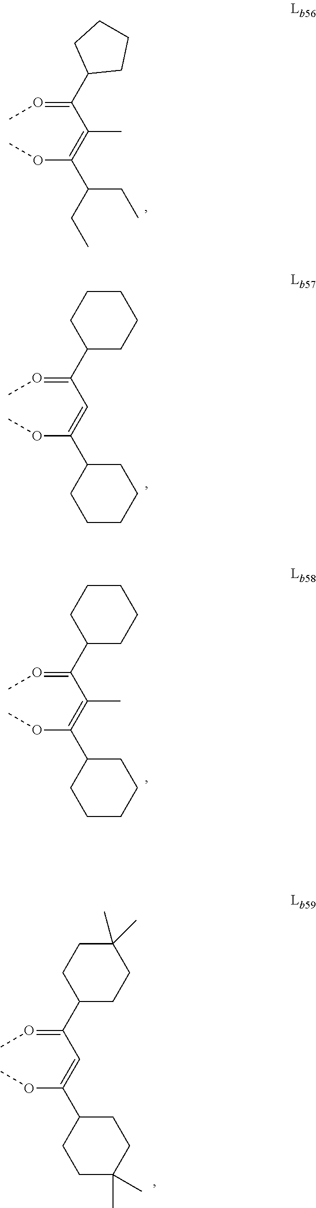 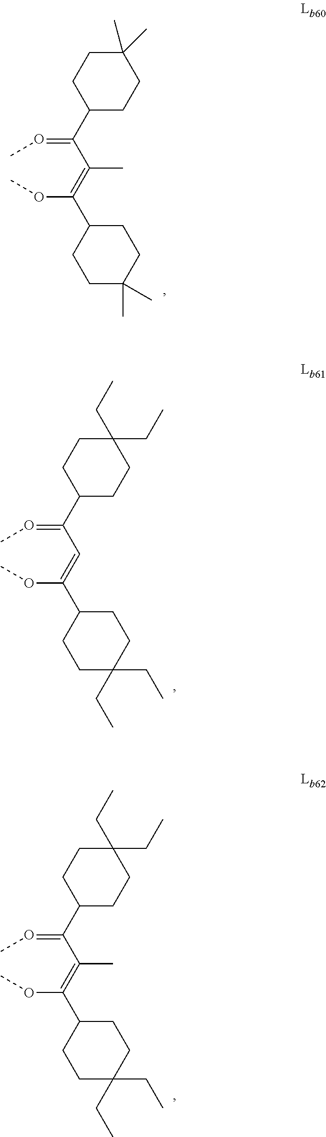 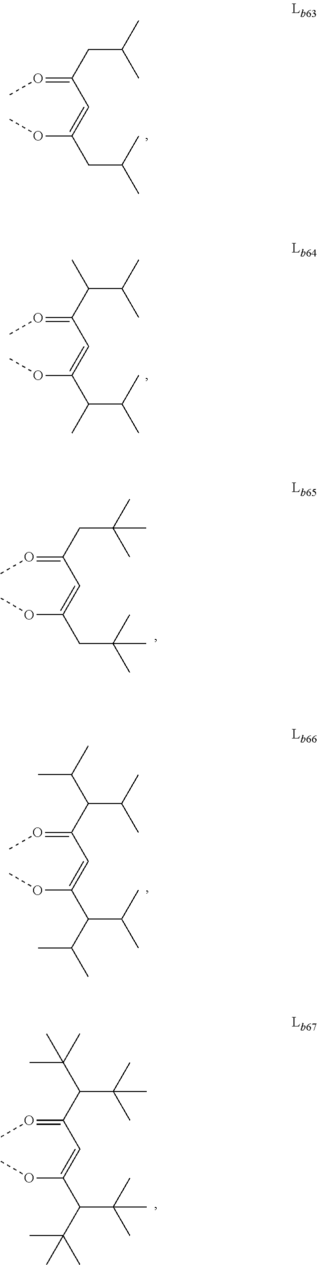 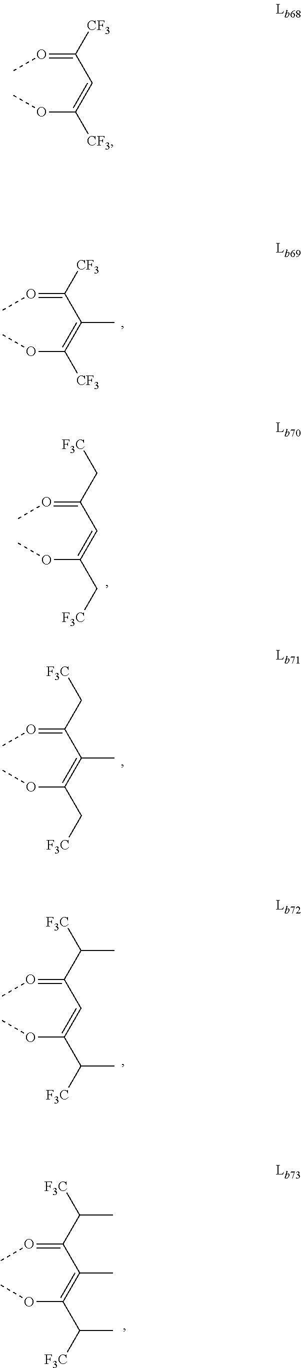 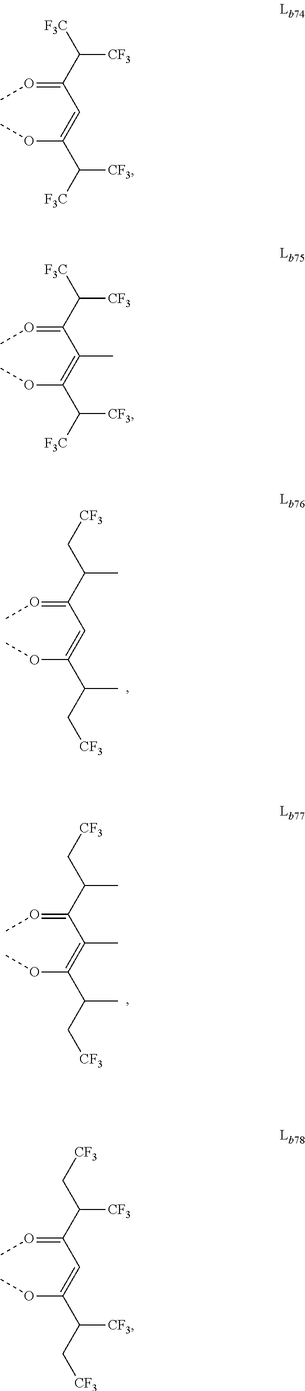 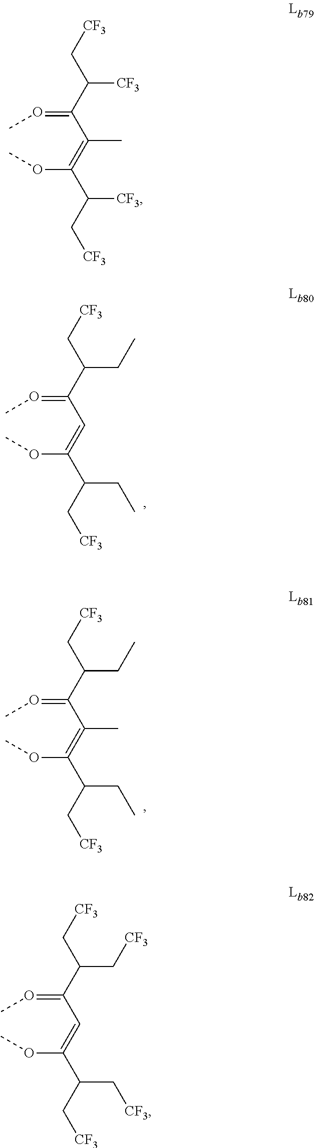 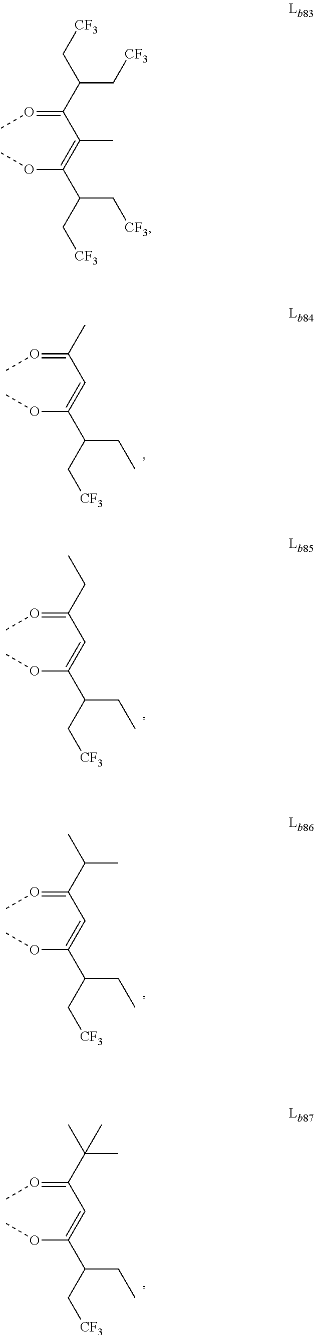 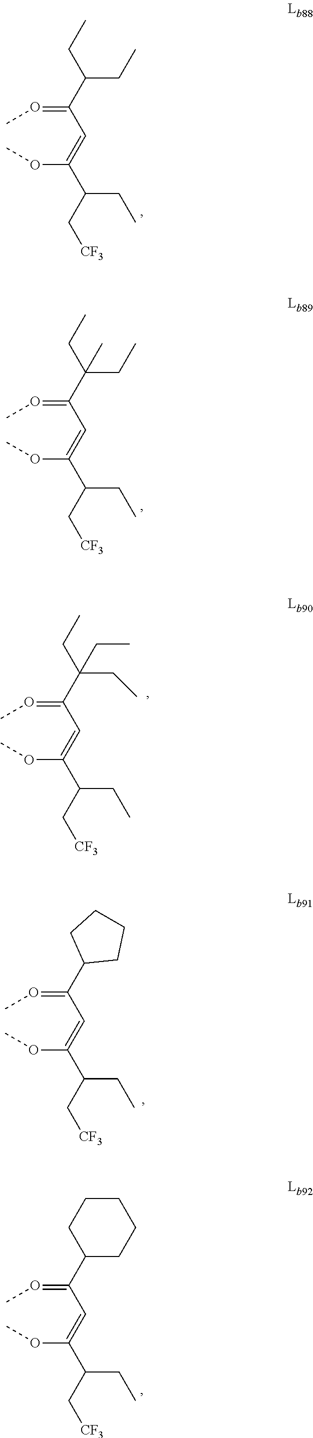 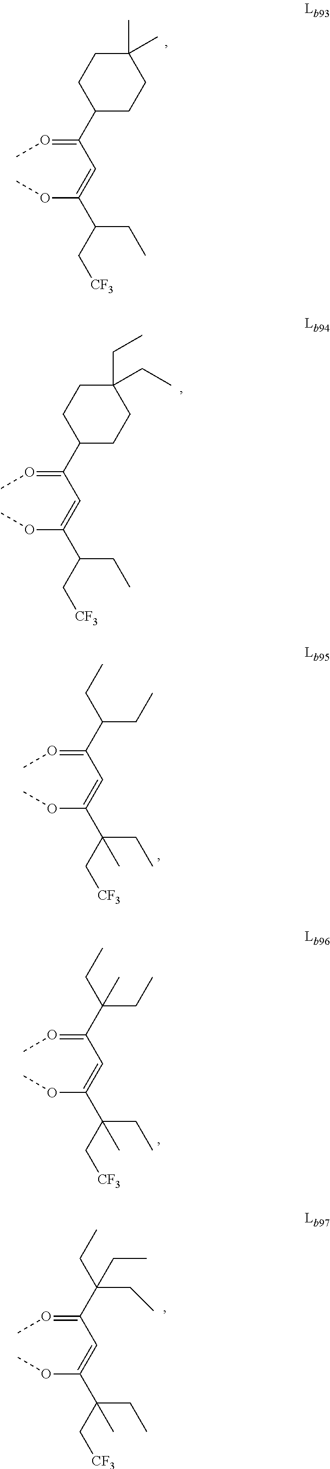 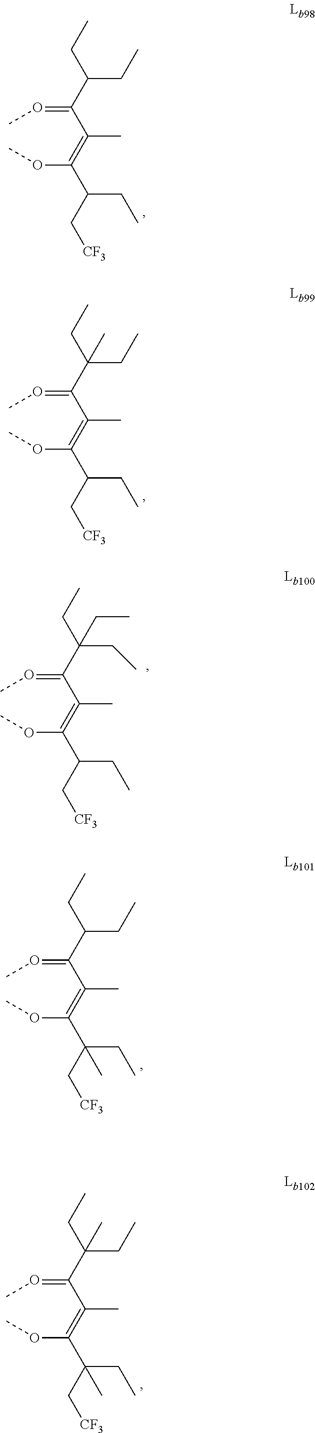 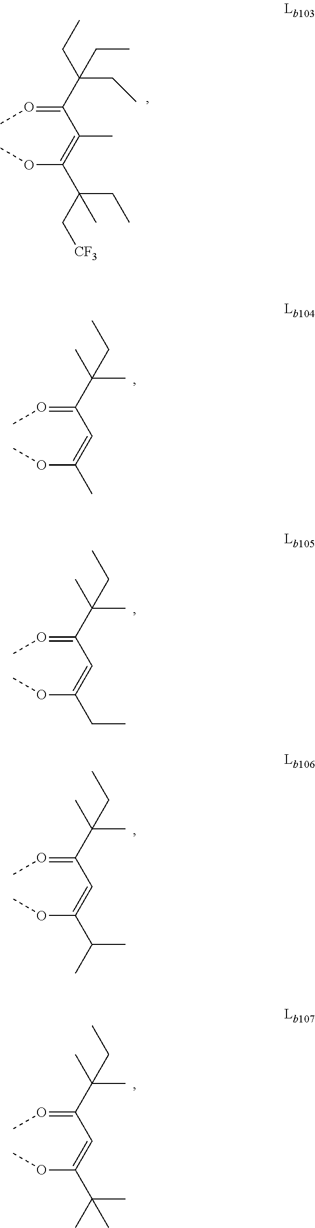 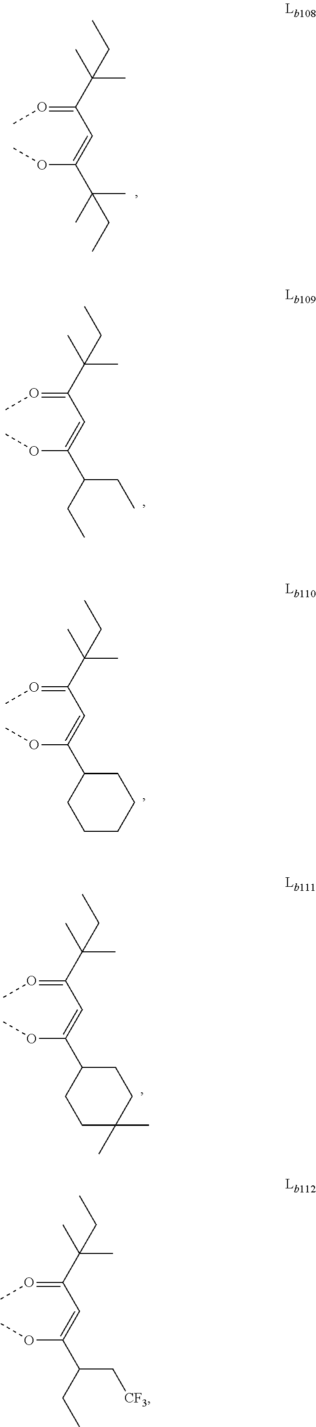 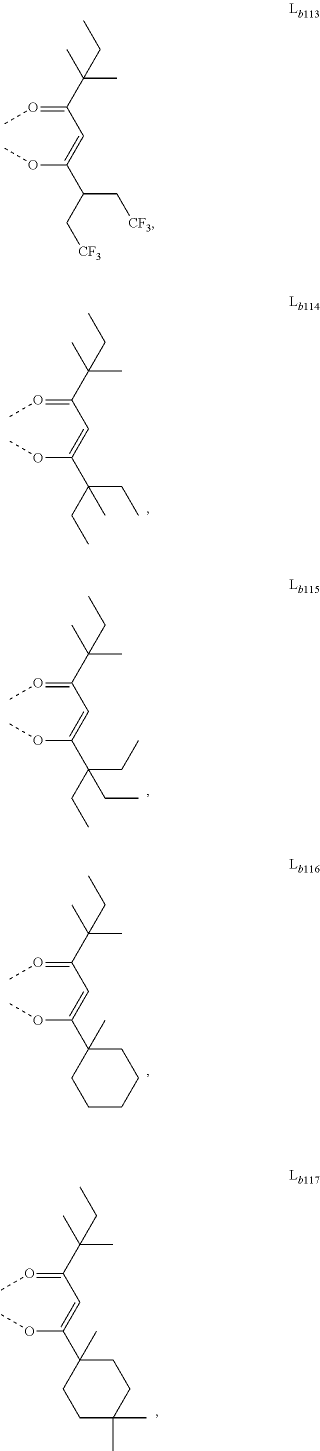 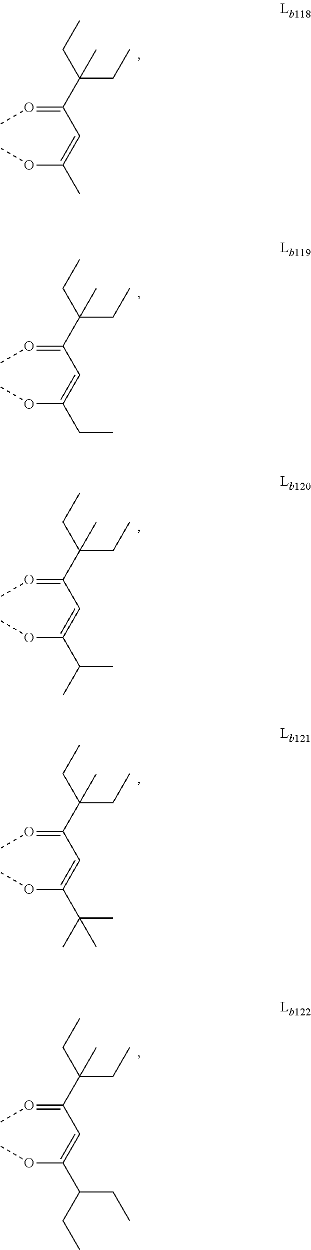 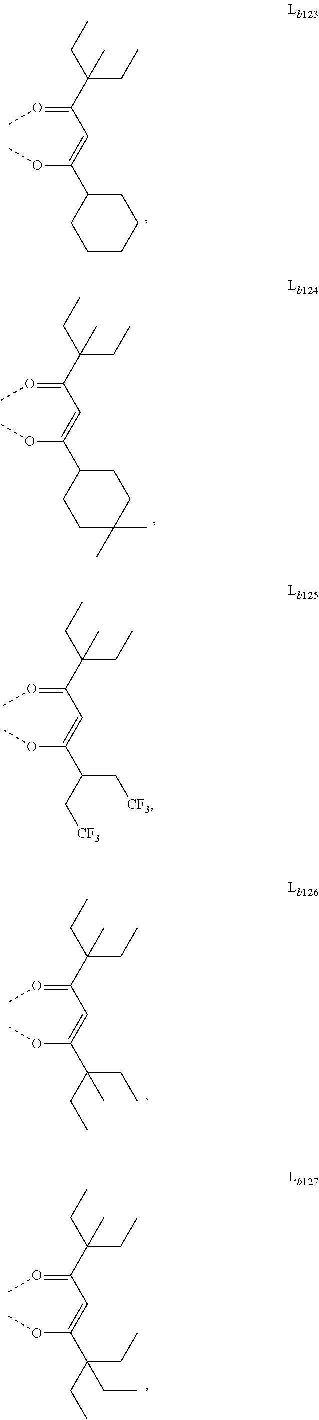 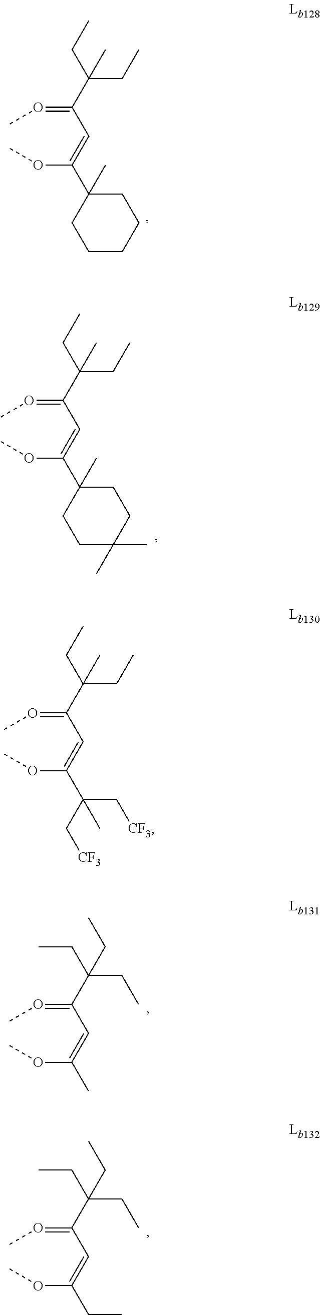 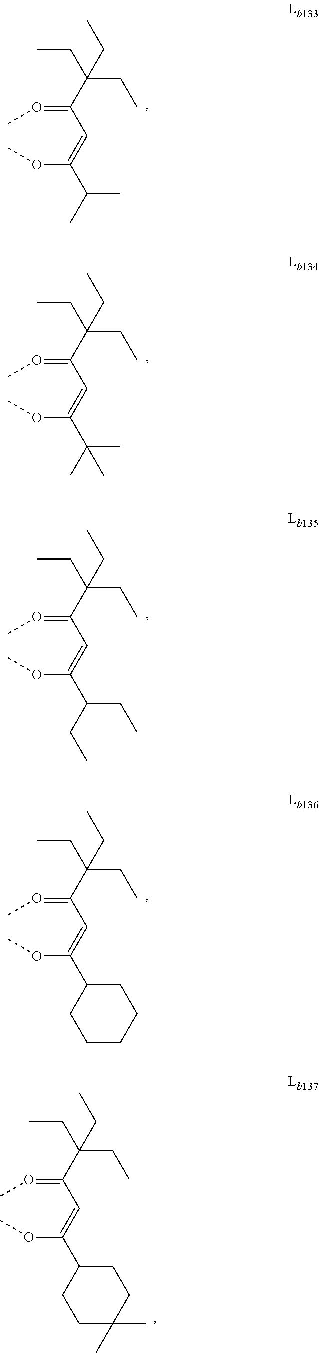 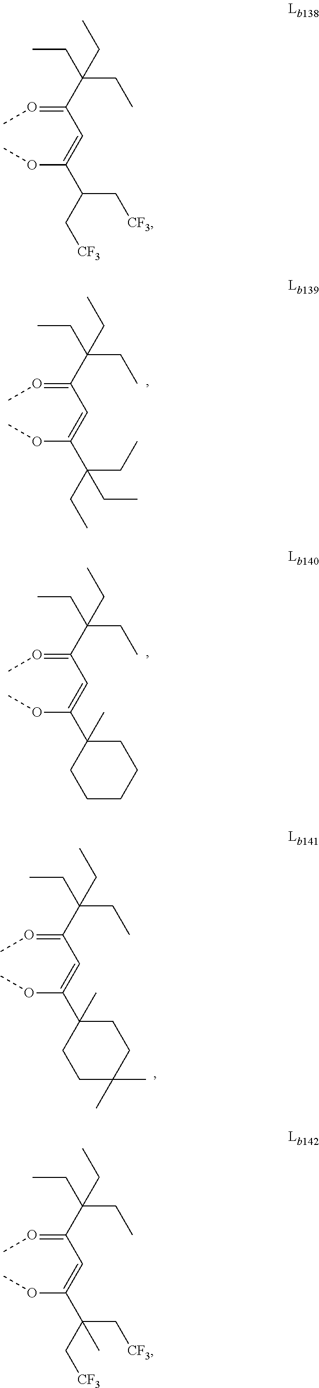 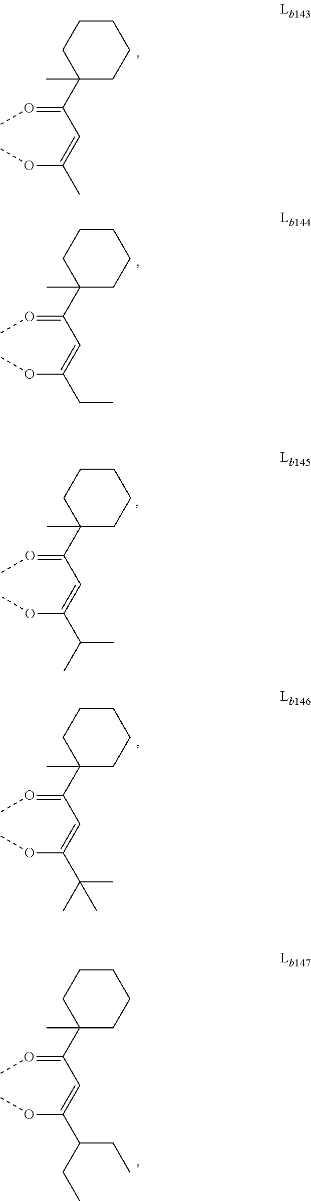 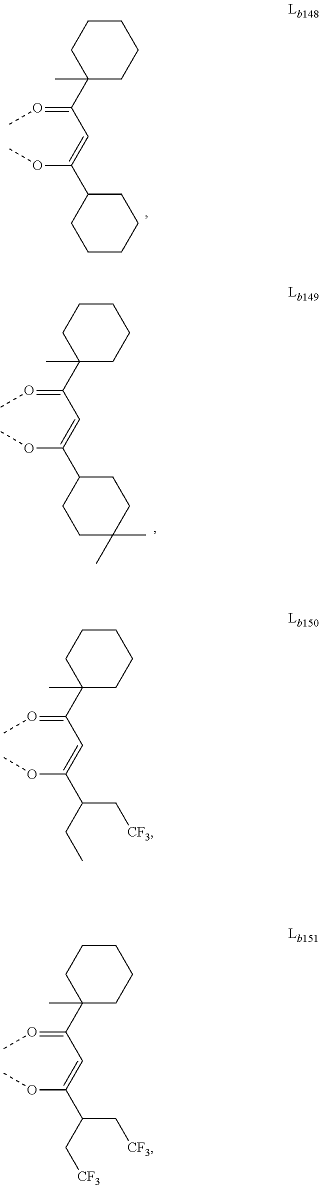 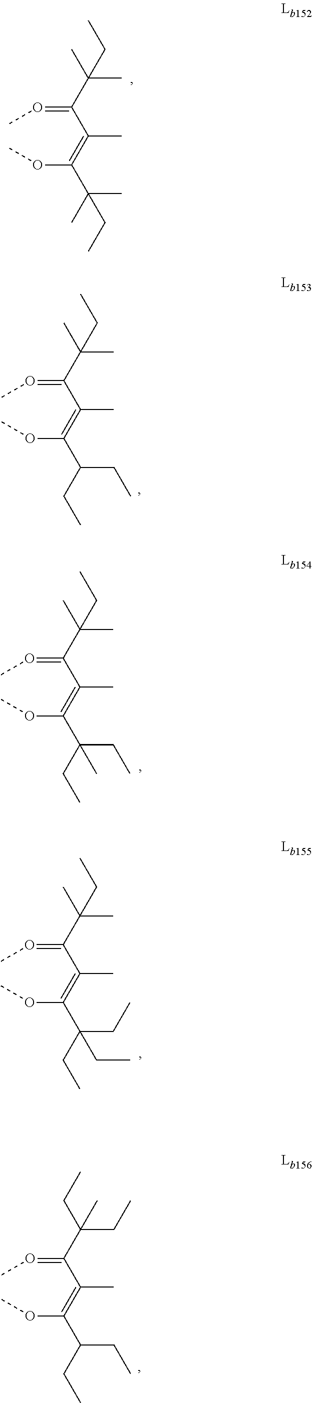 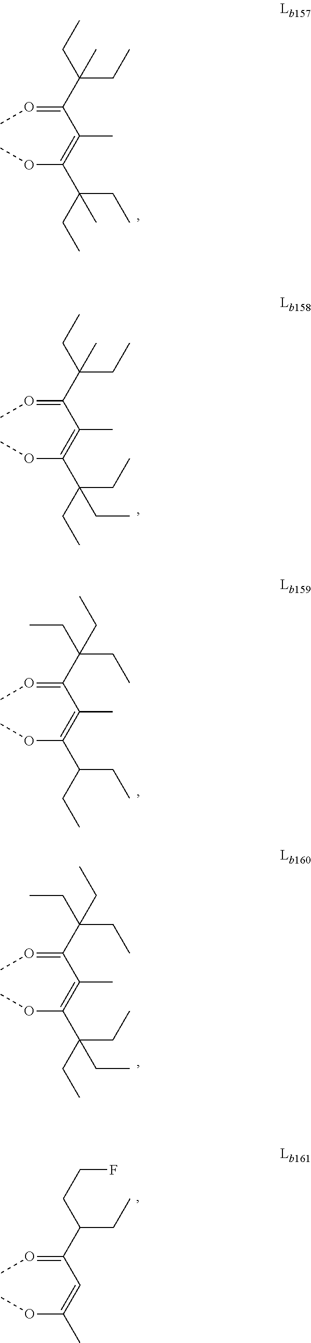 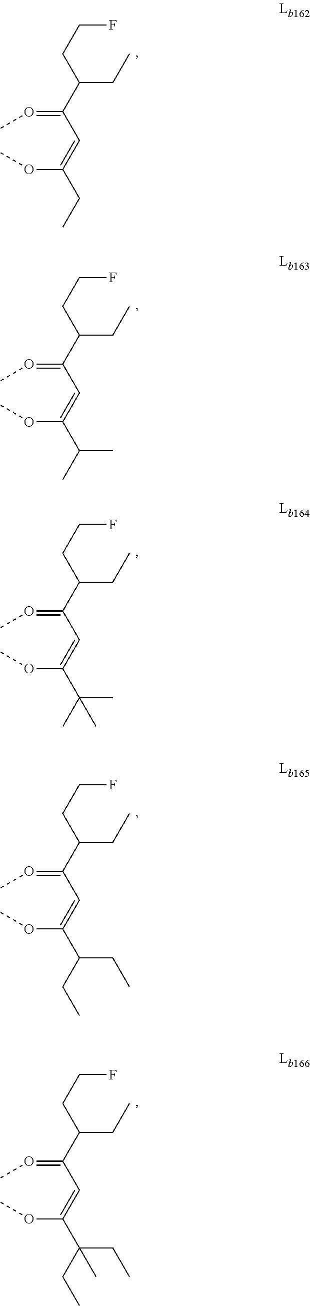 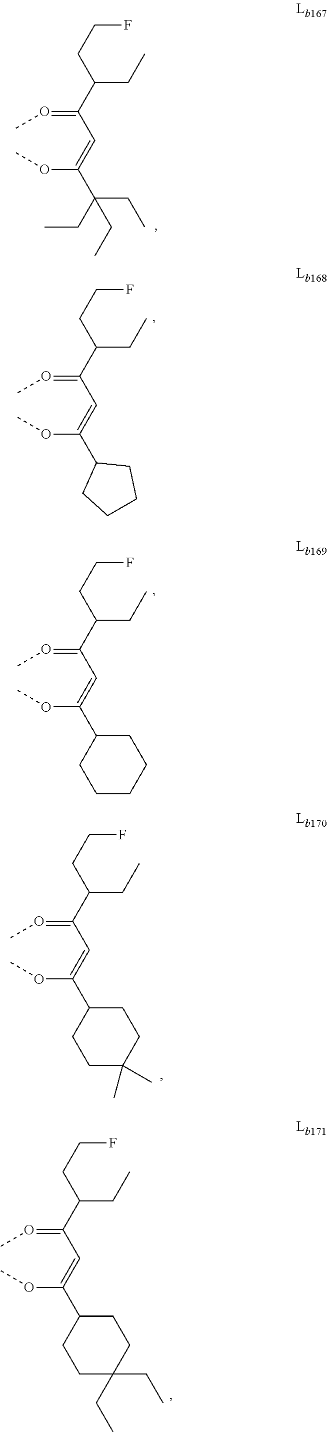 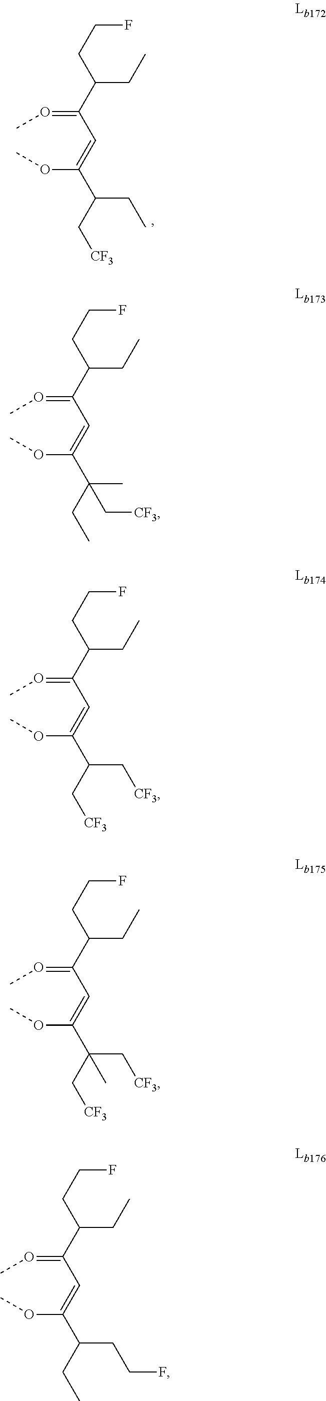 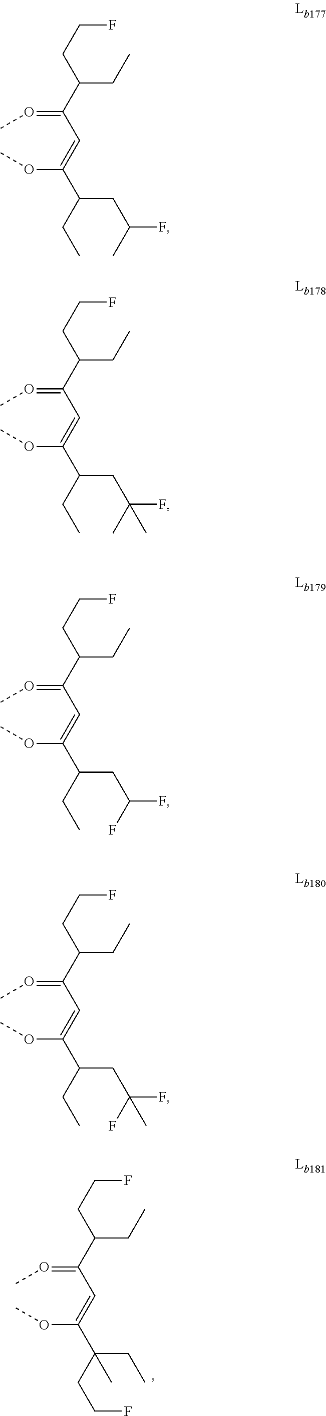 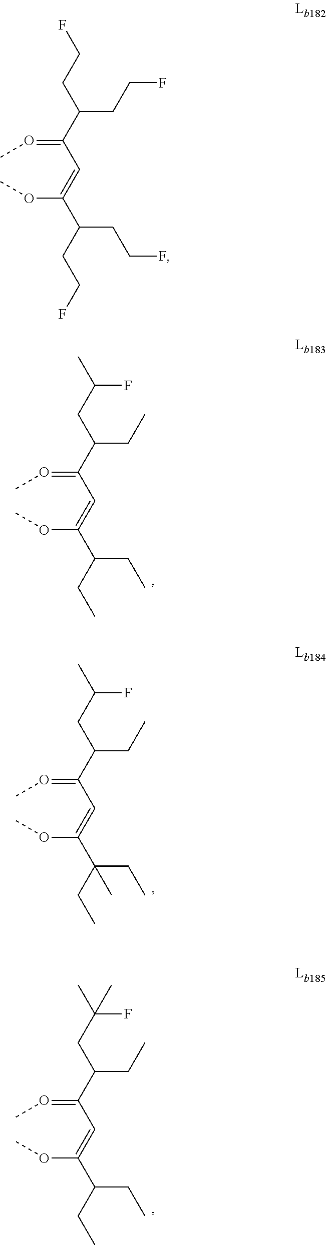 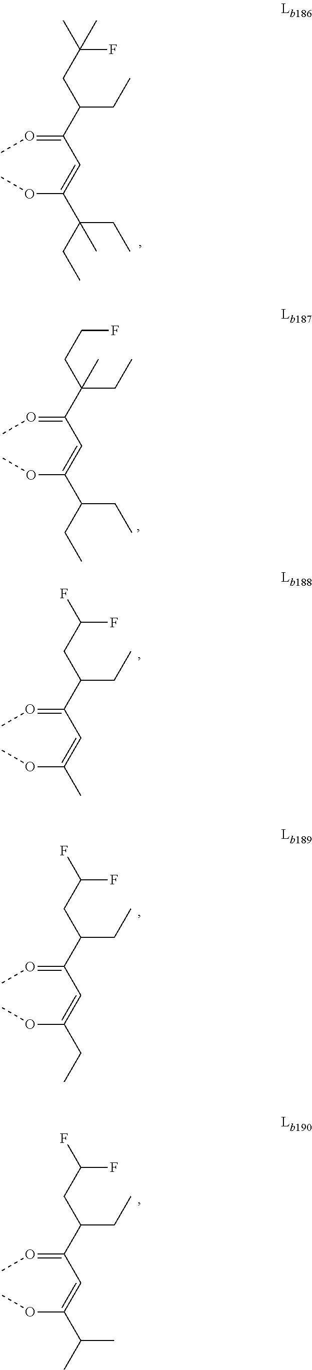 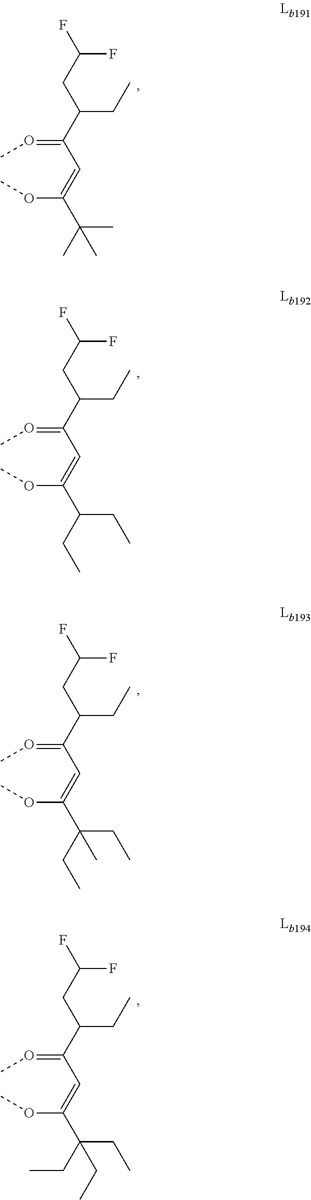 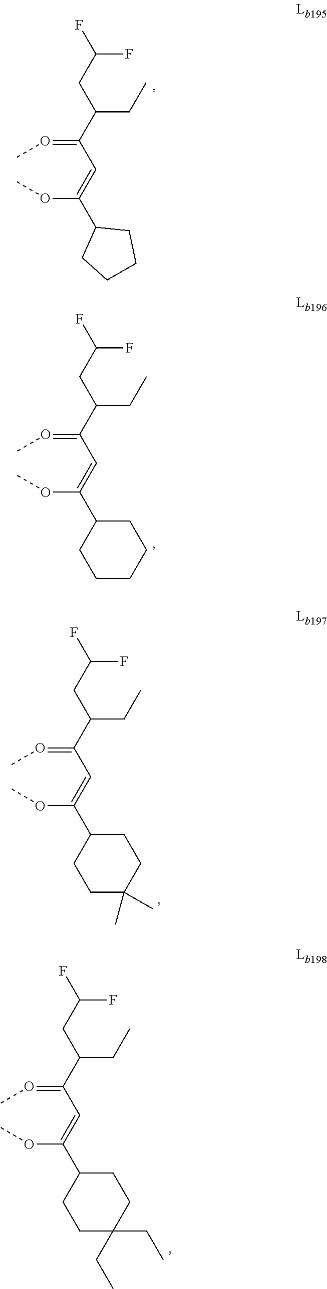 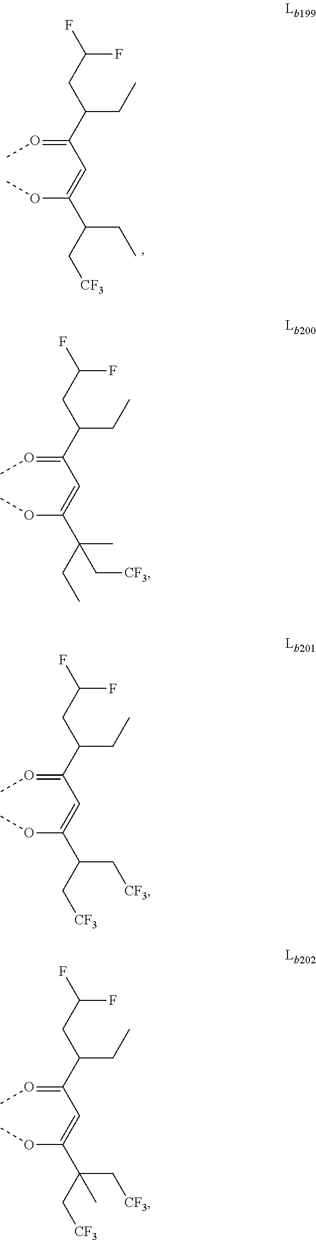 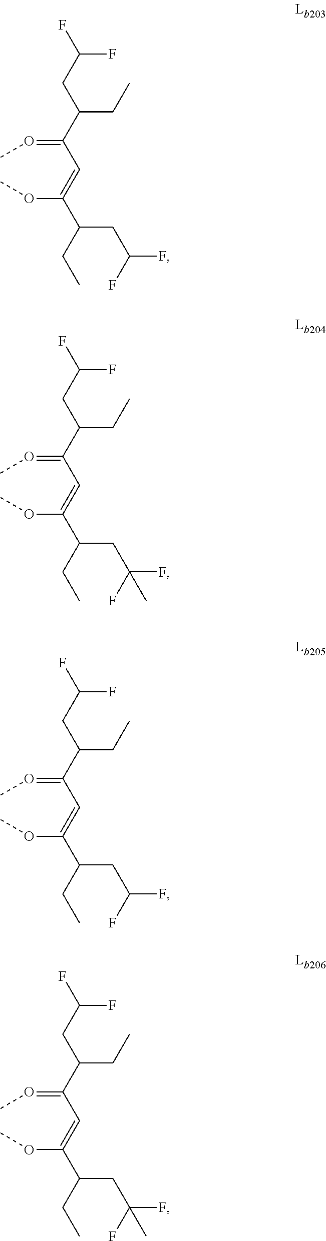 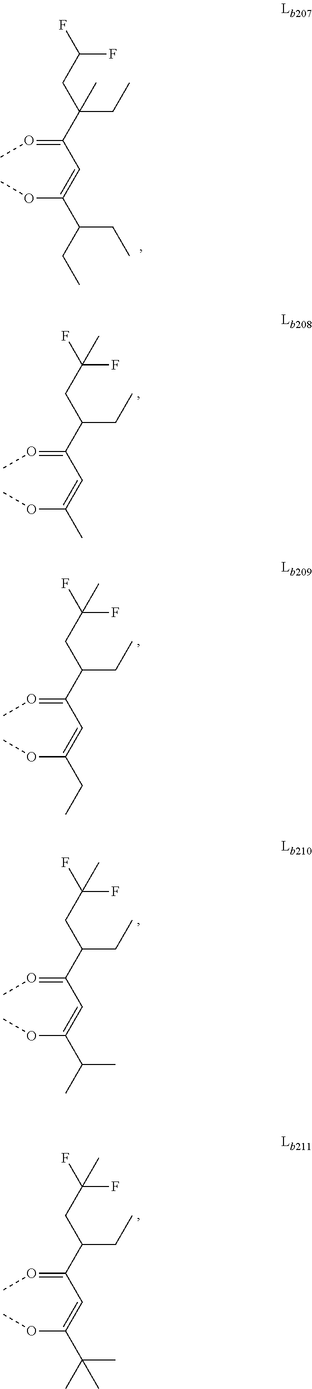 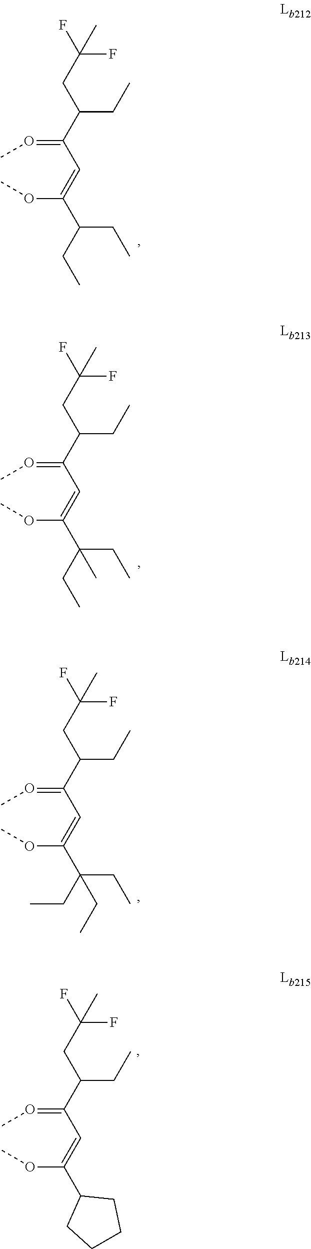 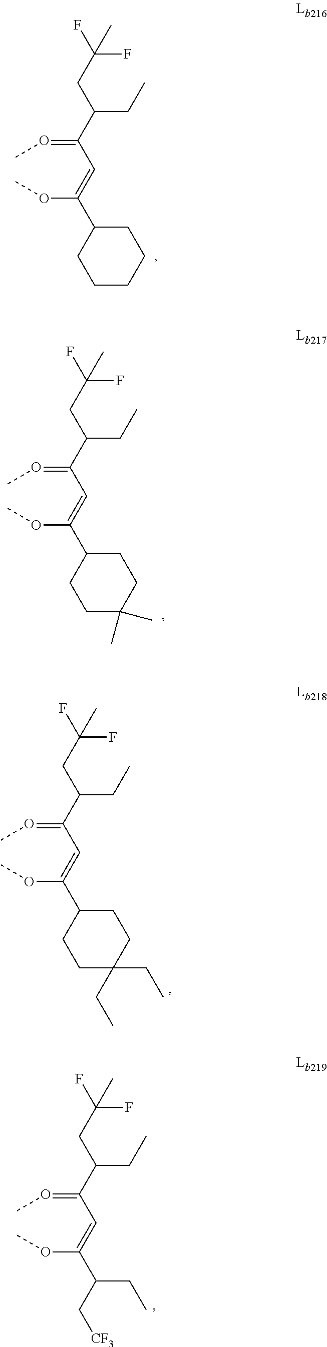 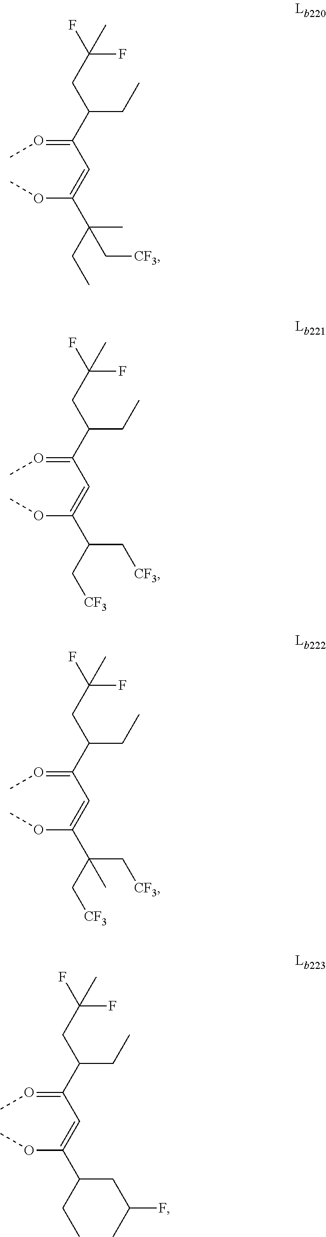 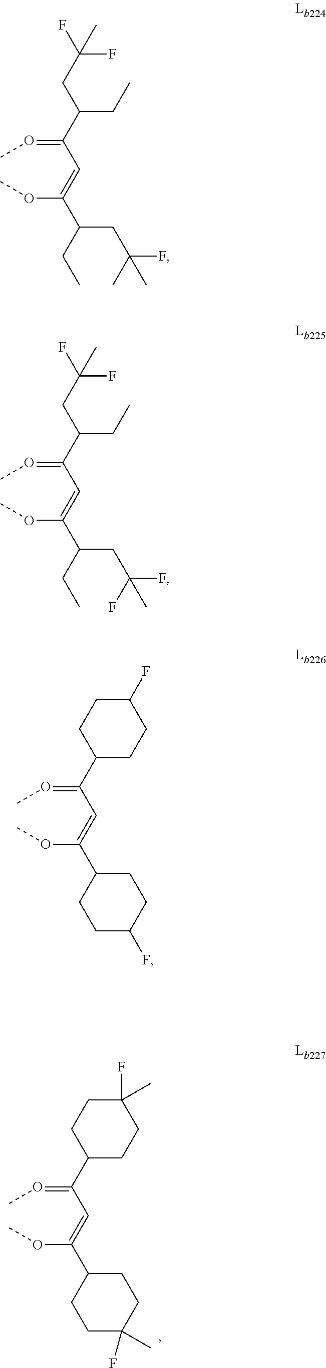 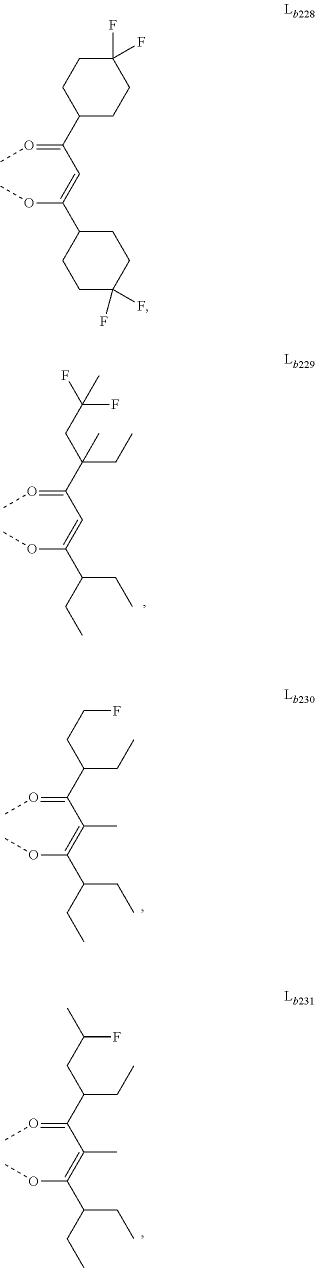 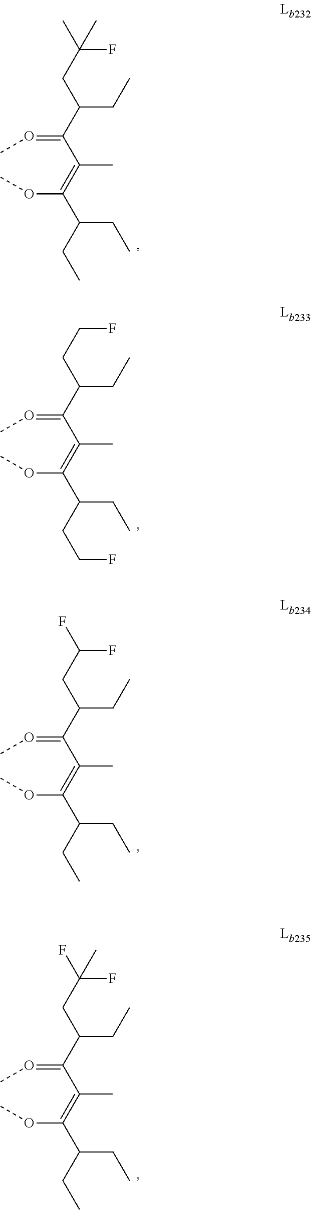 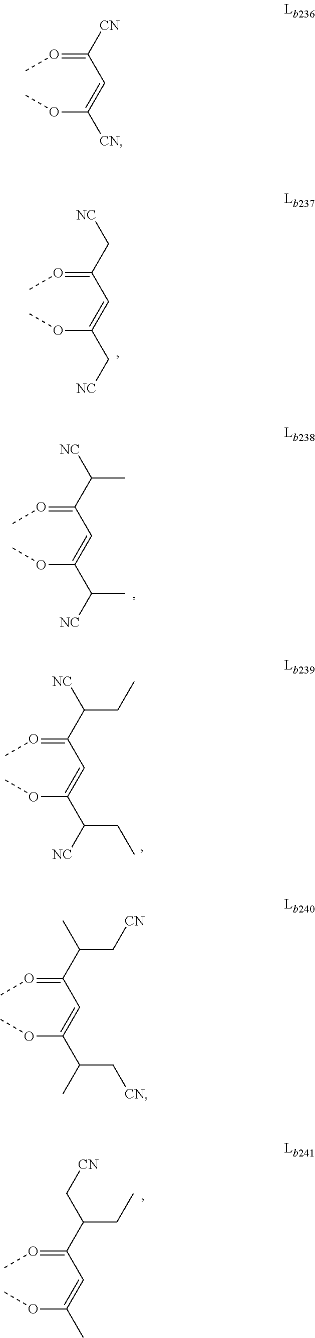 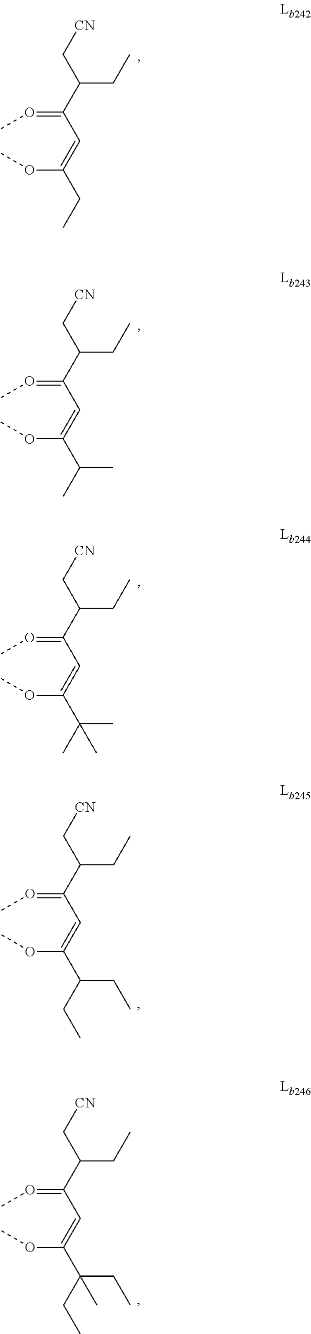 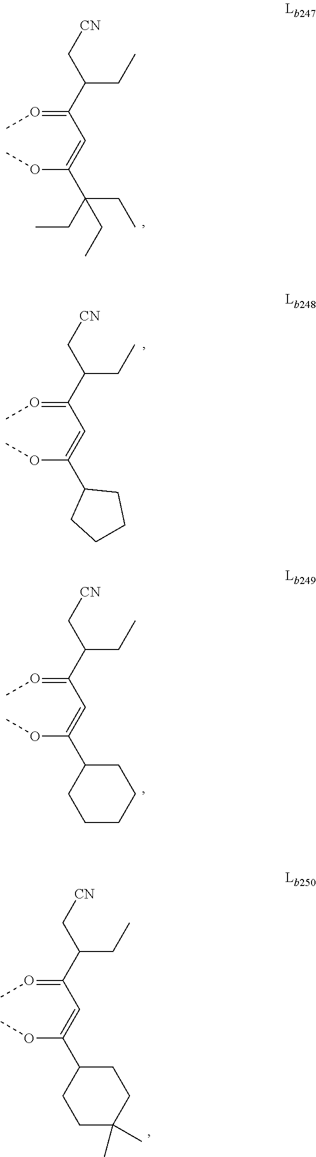 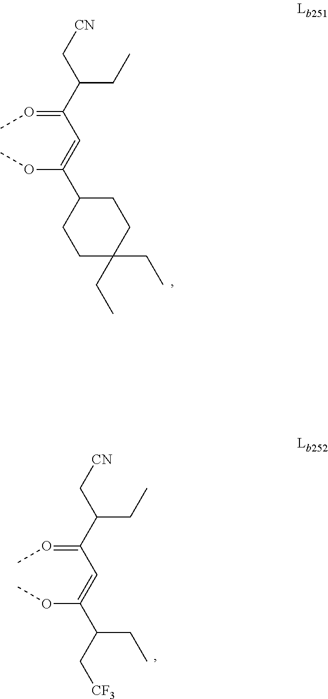 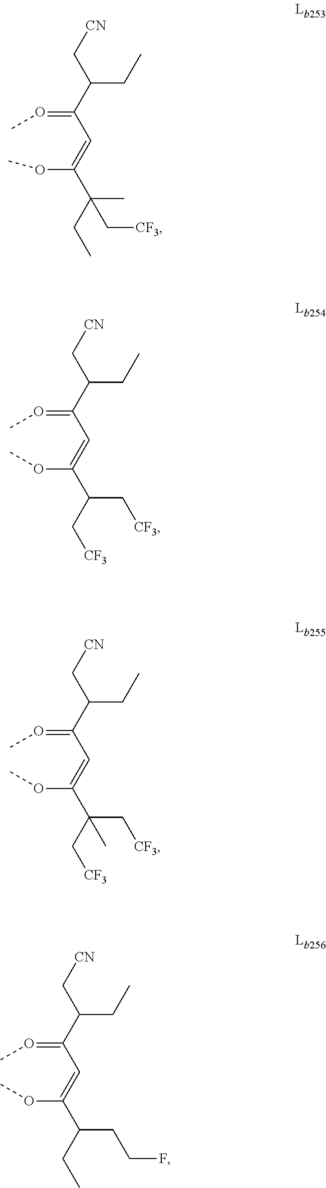 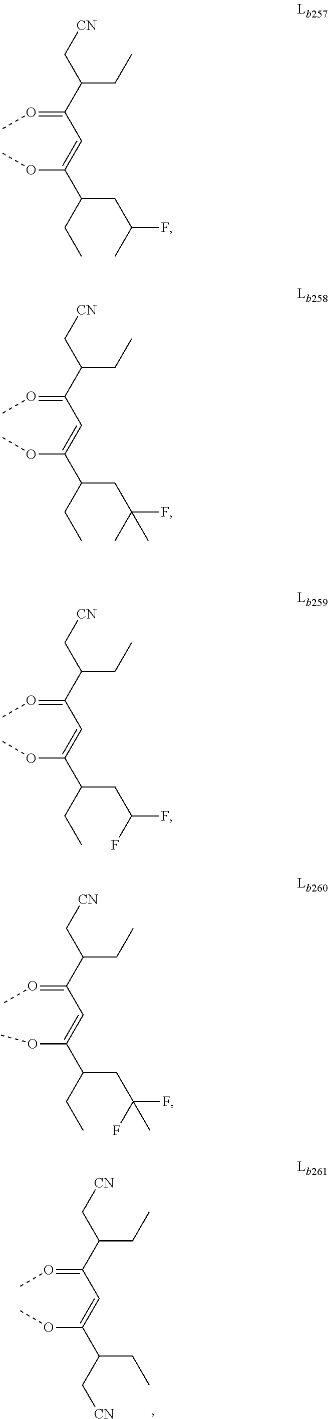 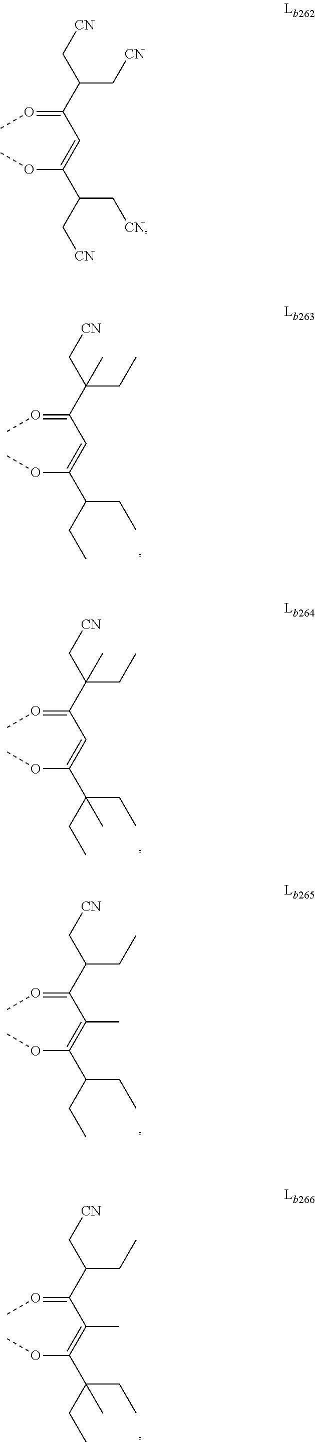 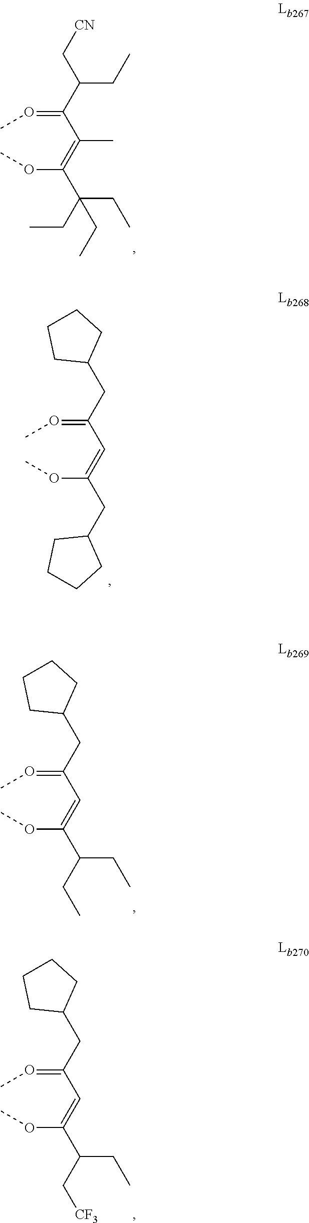 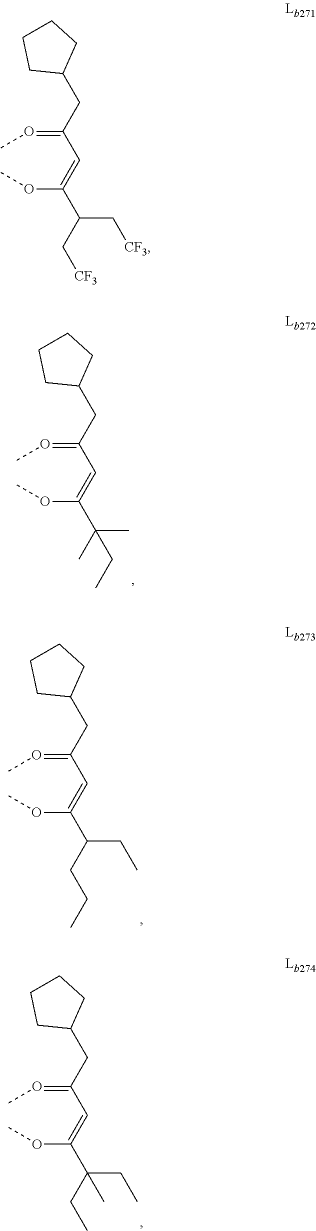 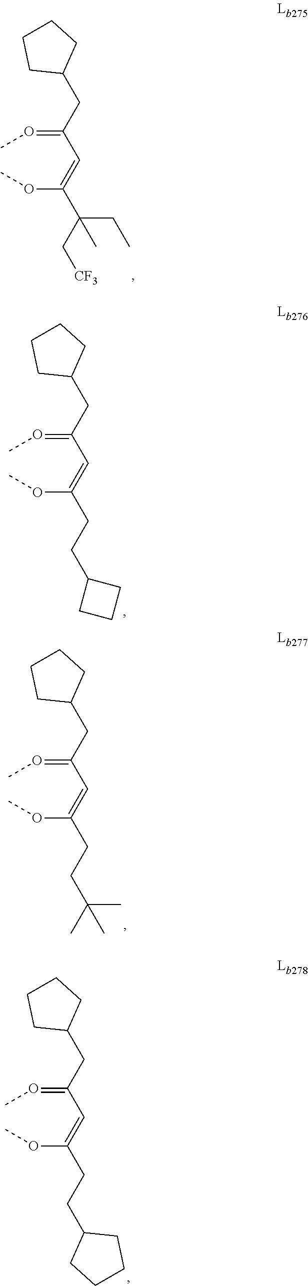 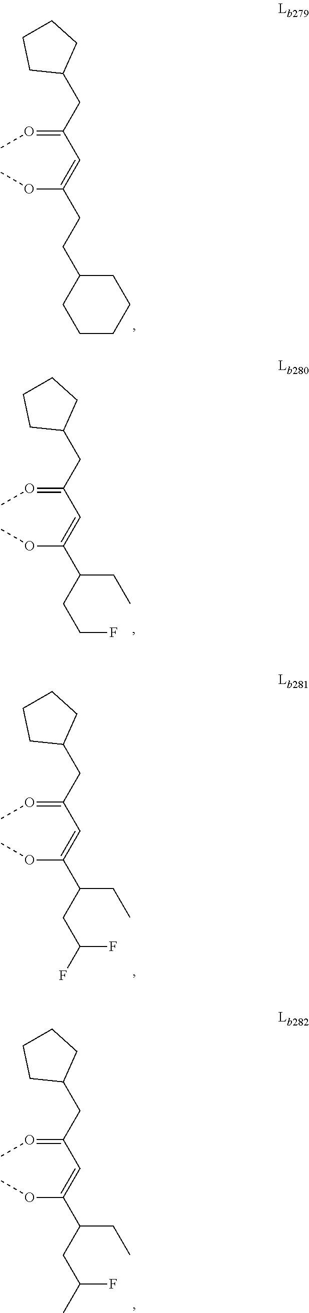 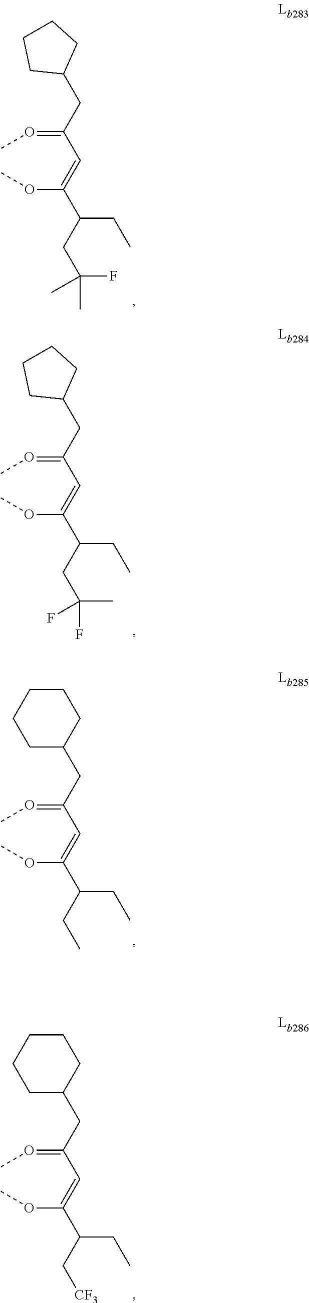 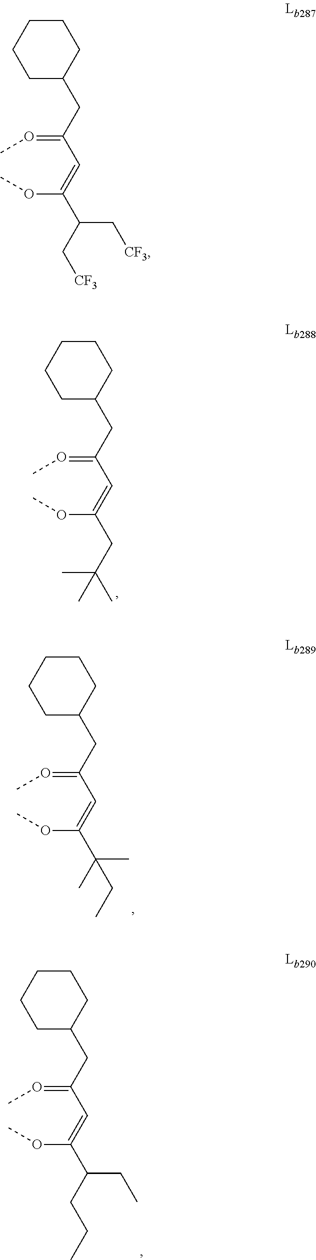 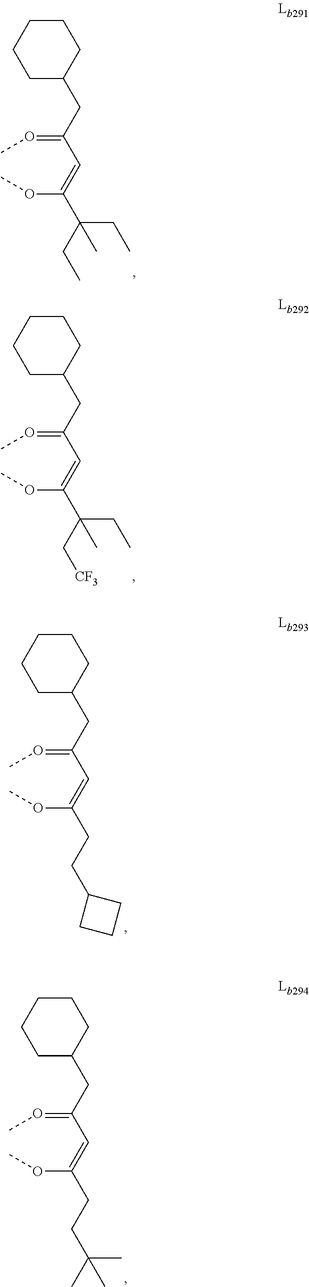 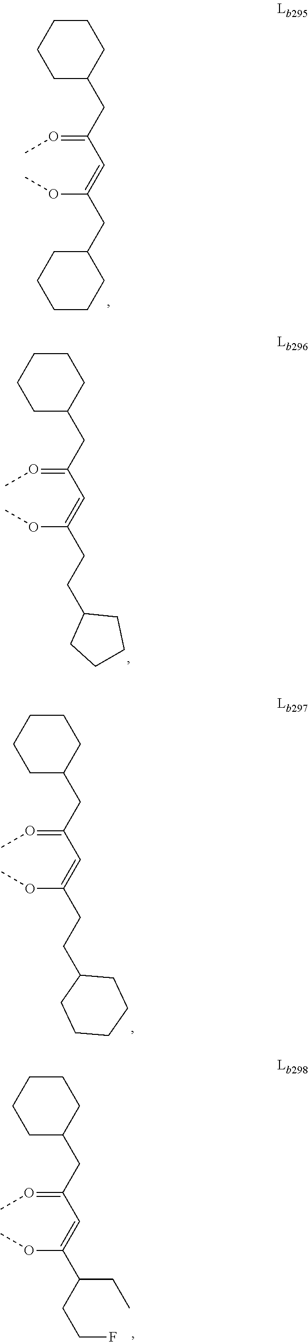 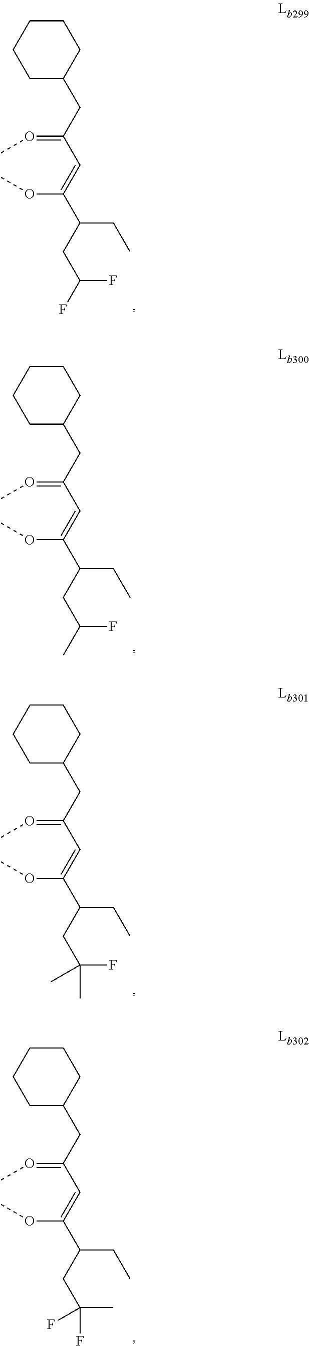 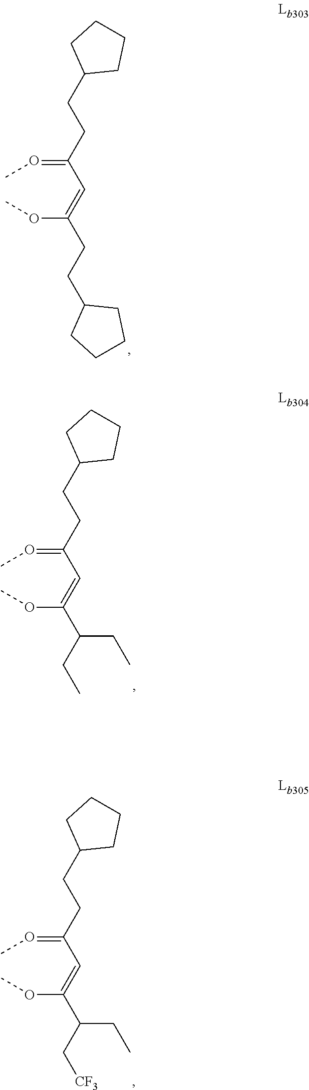 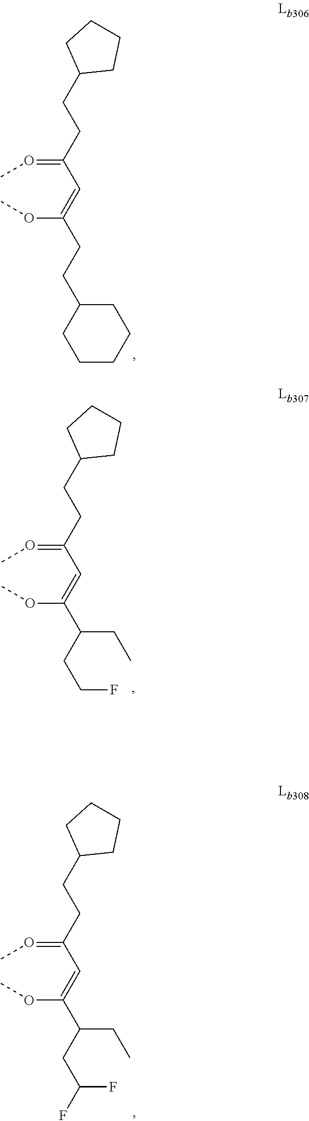 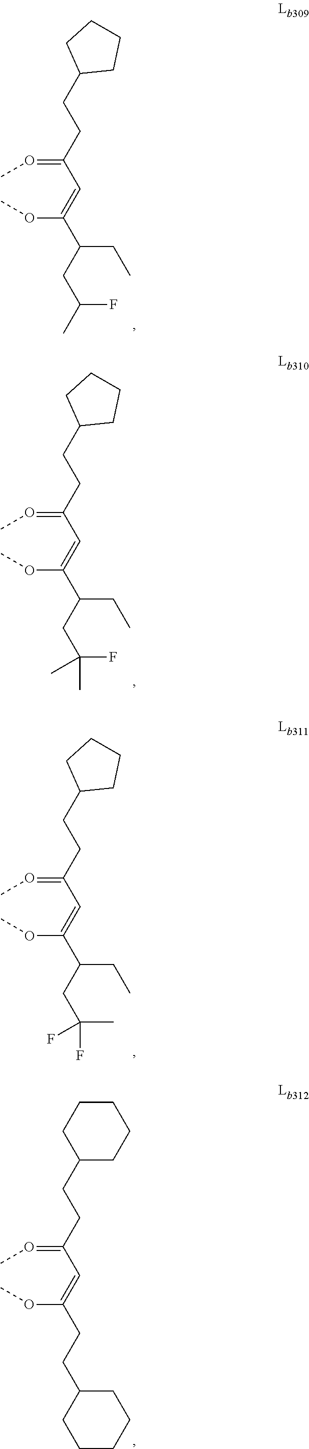 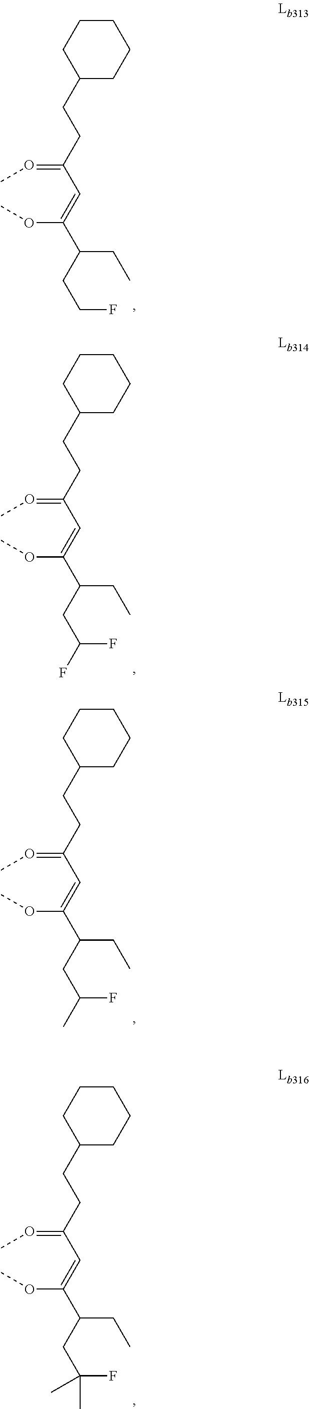 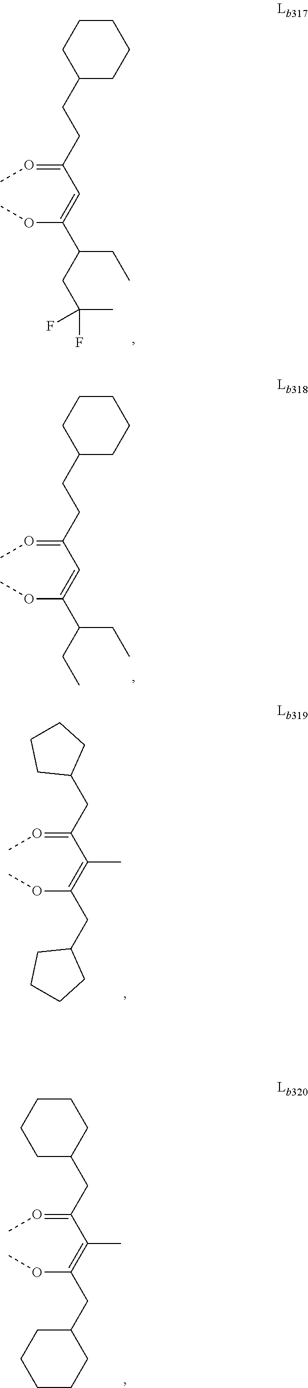 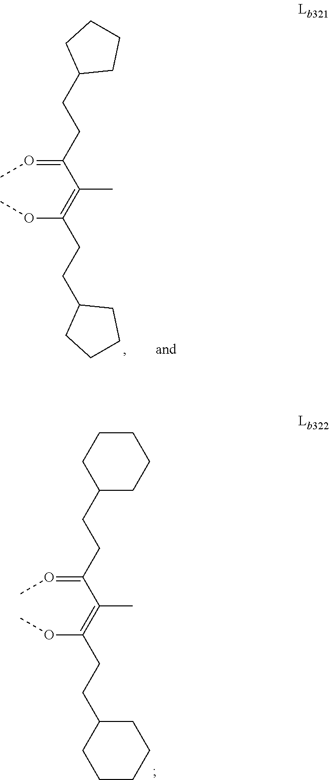
L_{c} is, at each occurrence identically or differently, selected from the group consisting of the following structures:

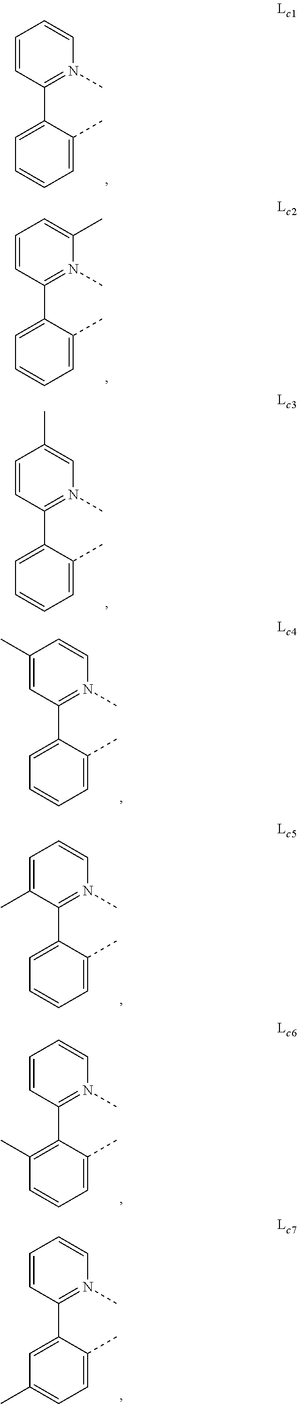

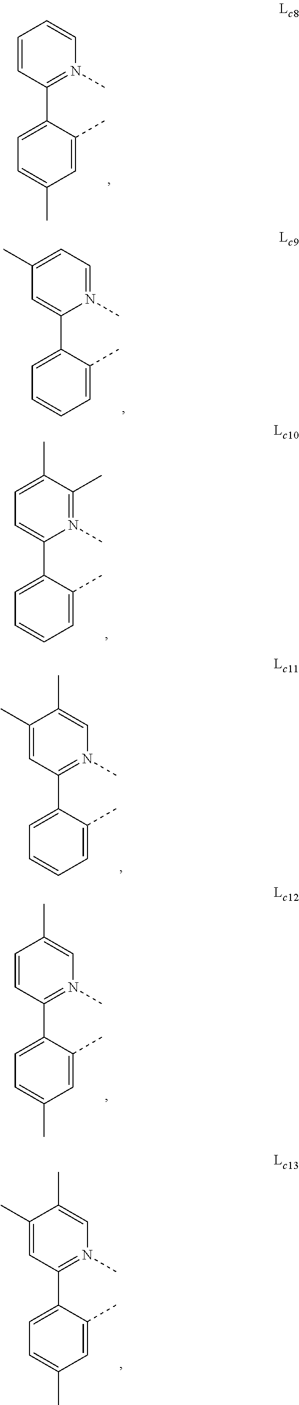

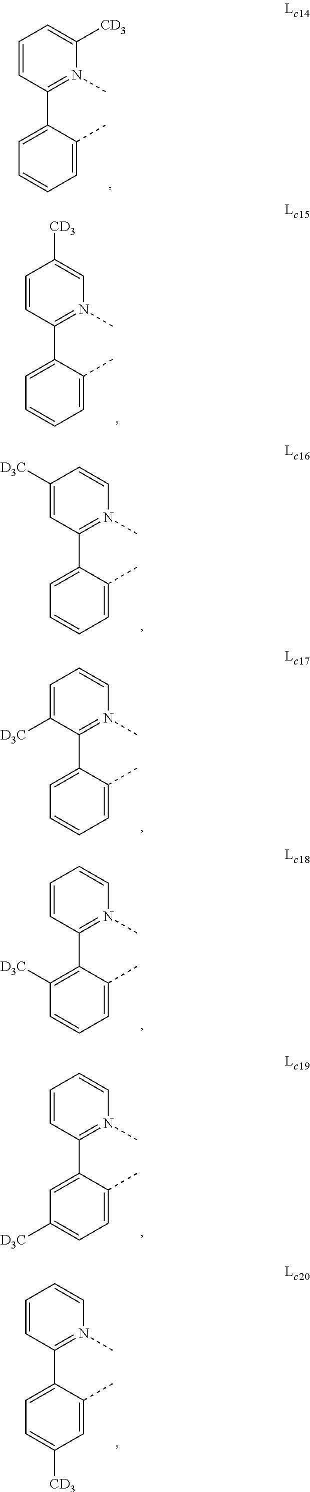

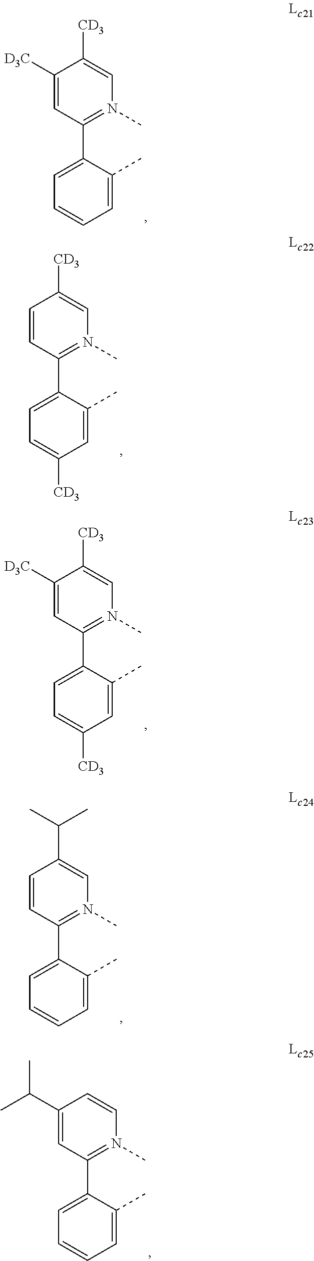

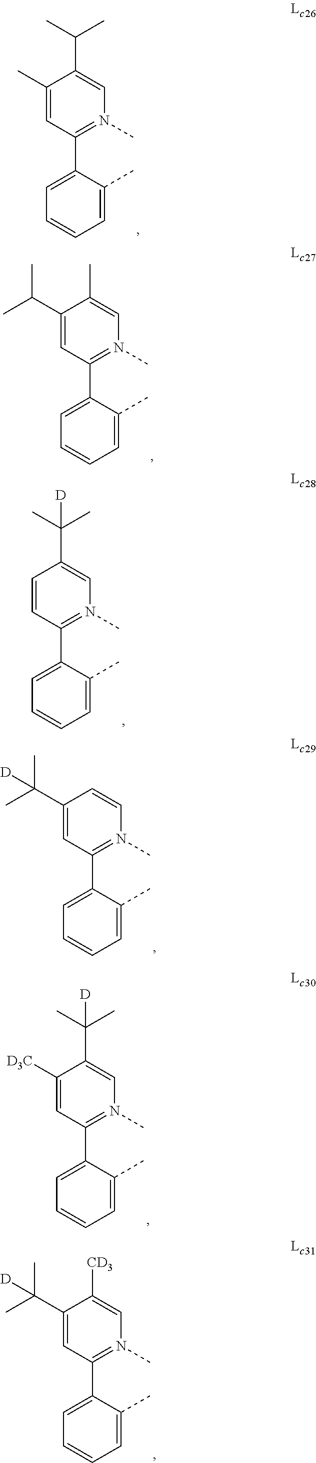

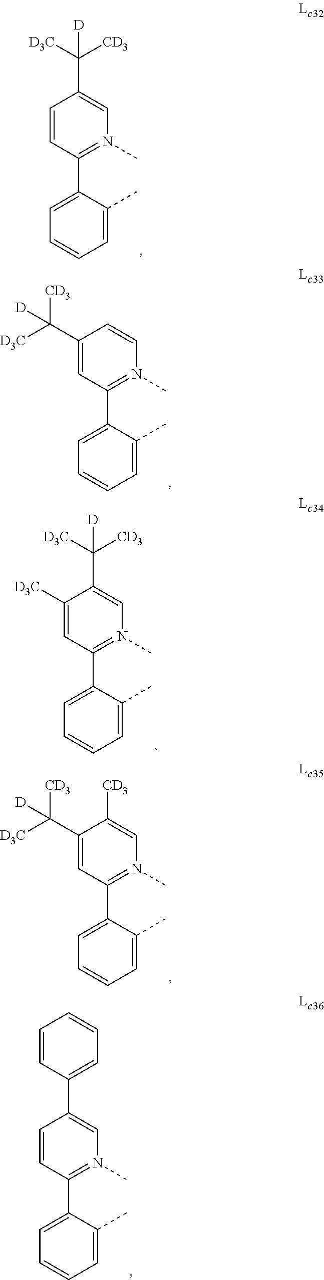

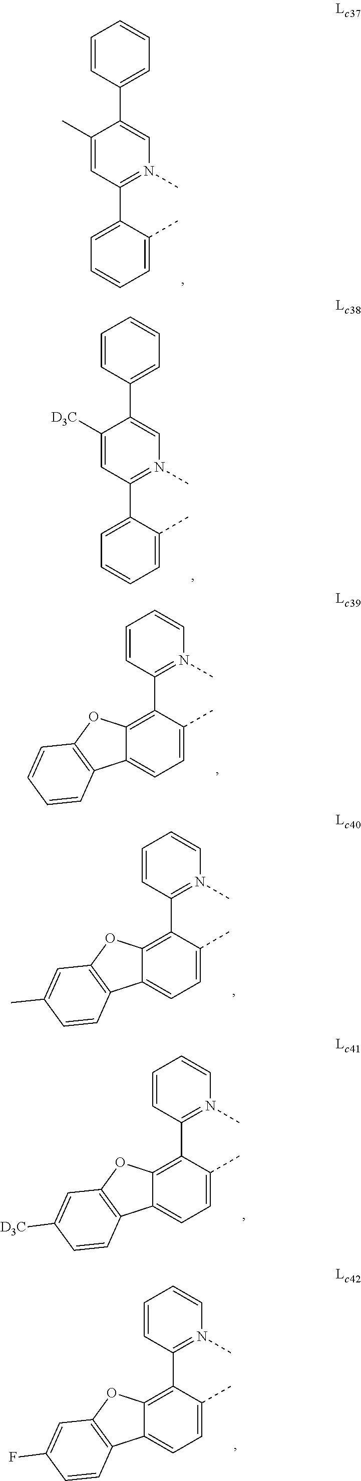

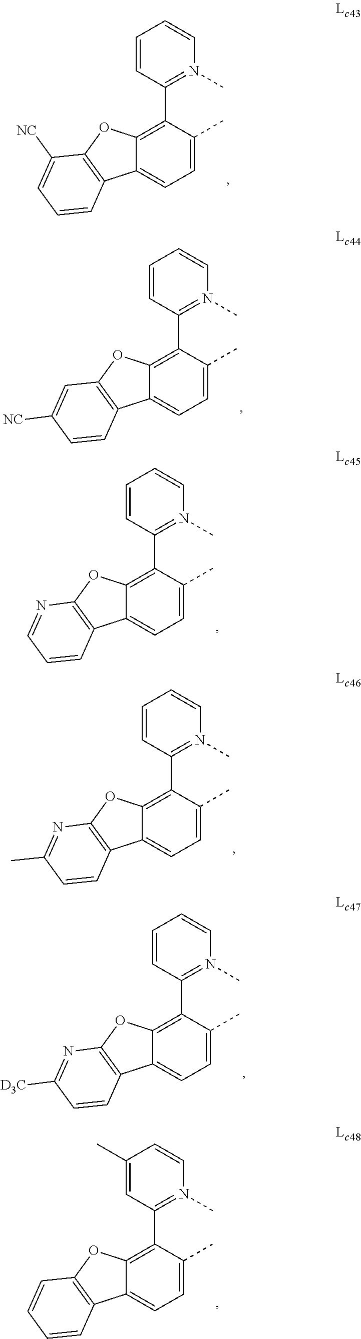

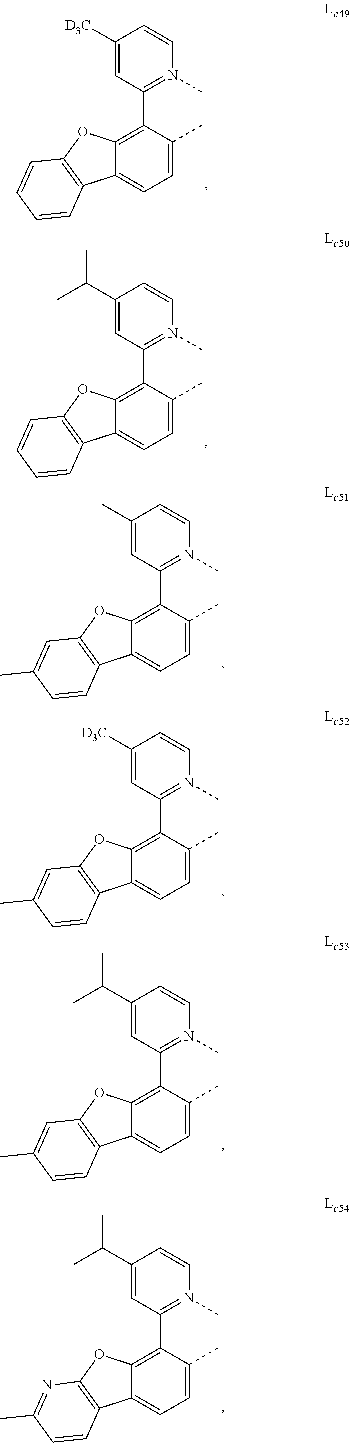

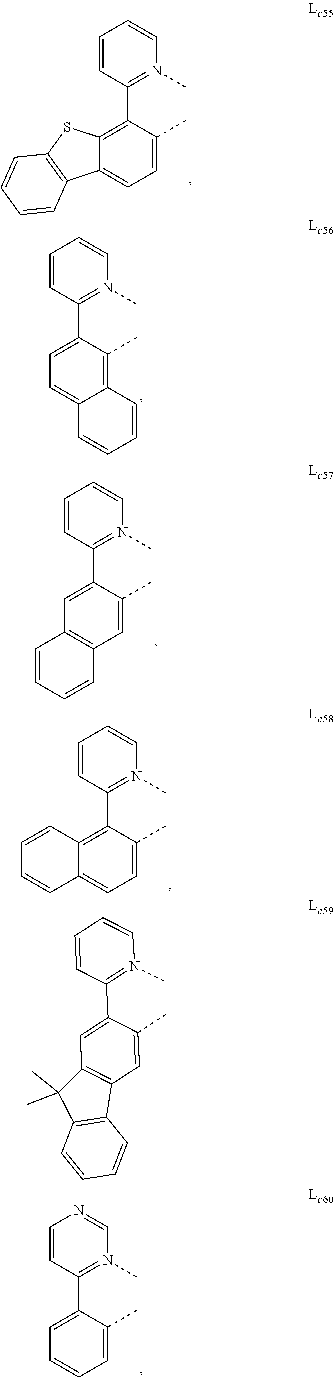

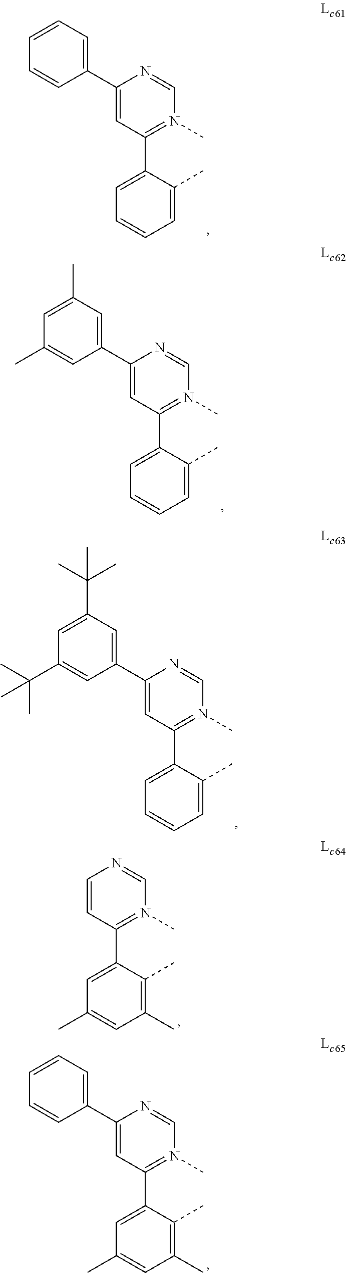

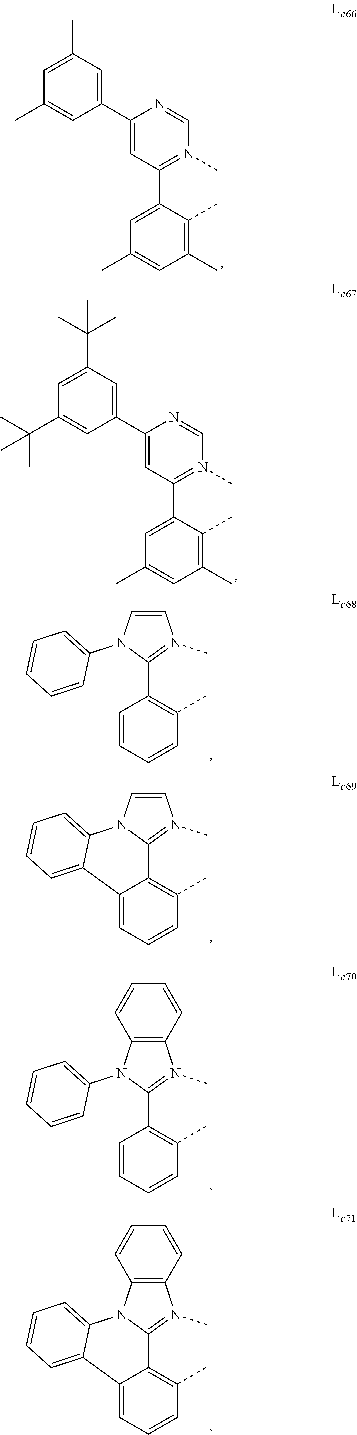

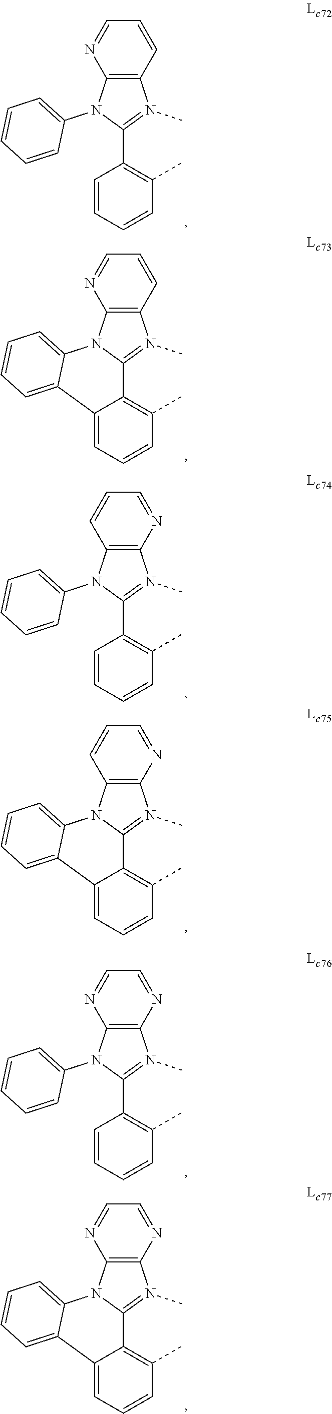

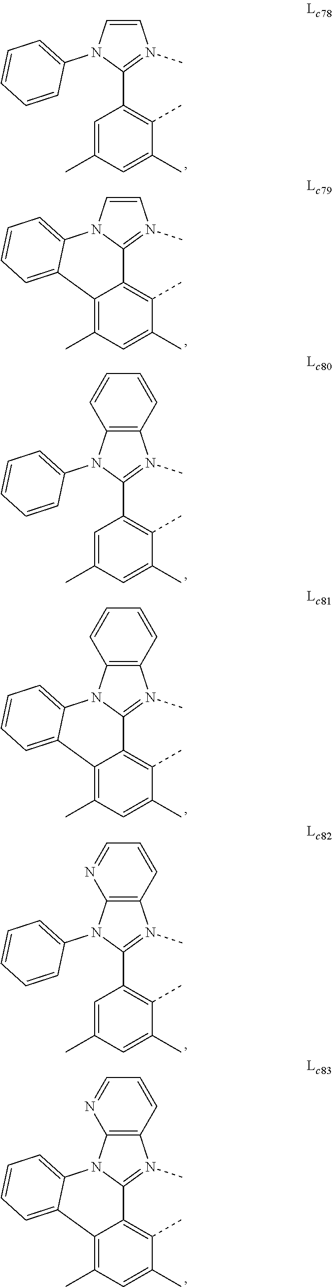

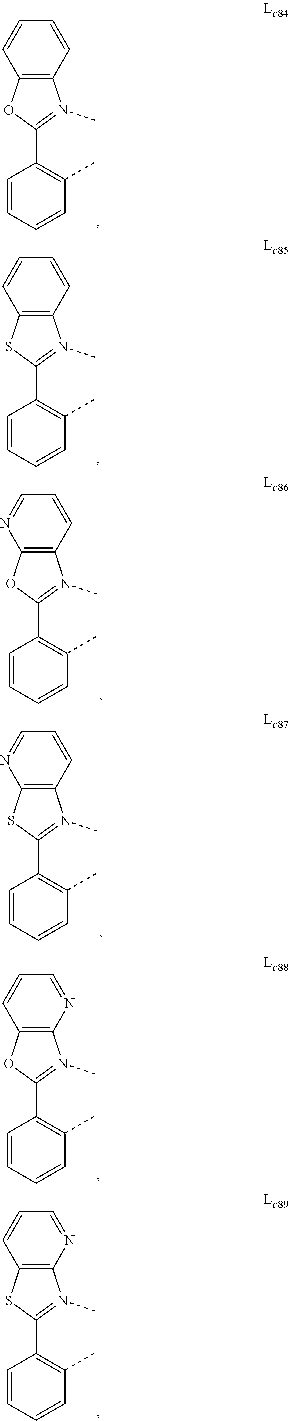

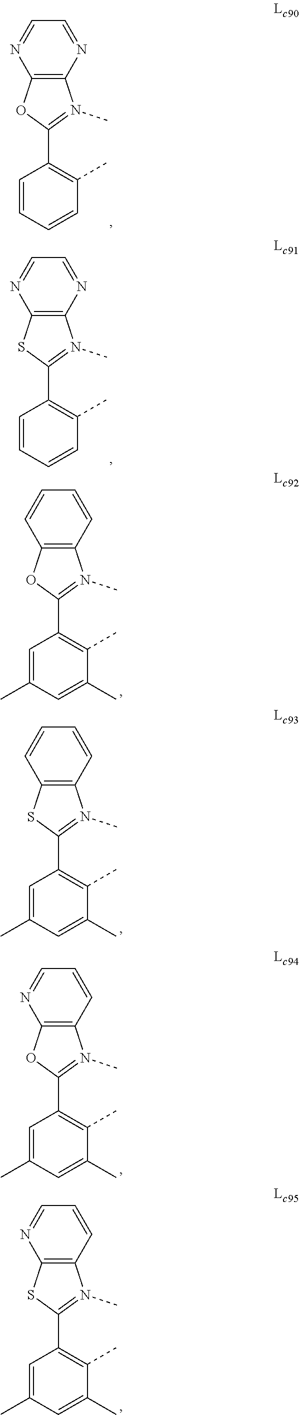

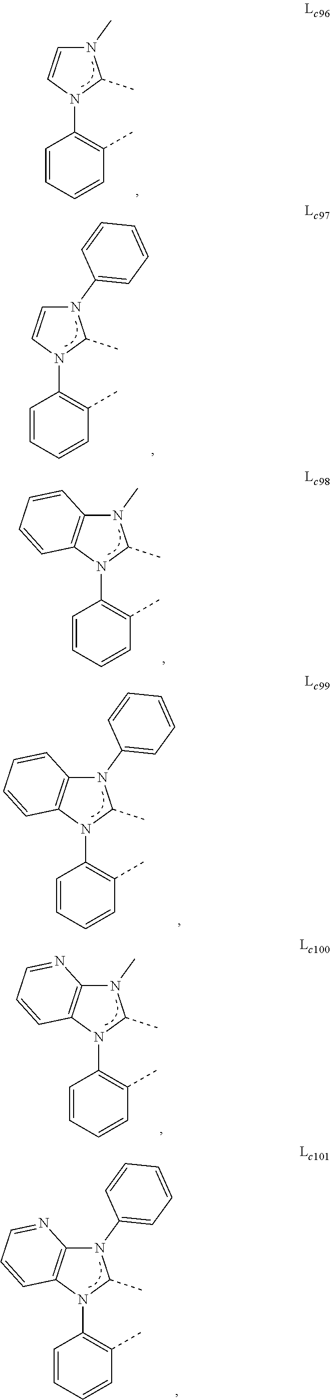

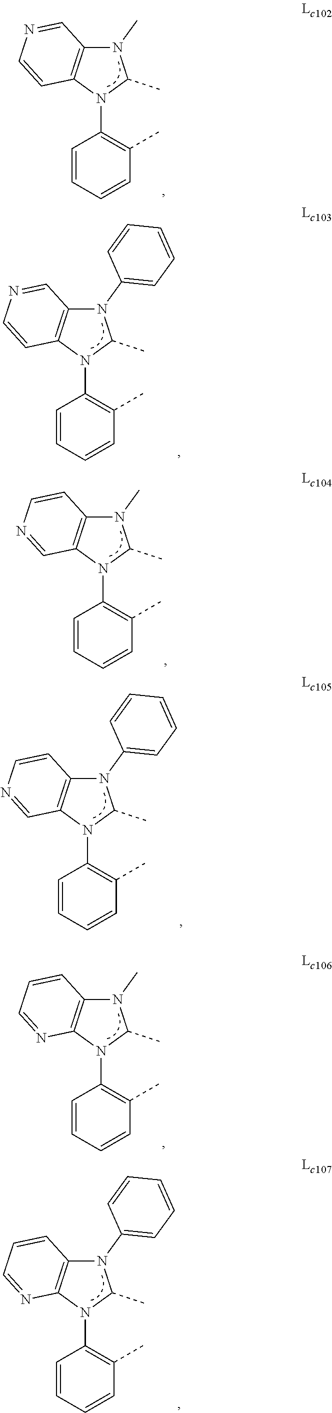

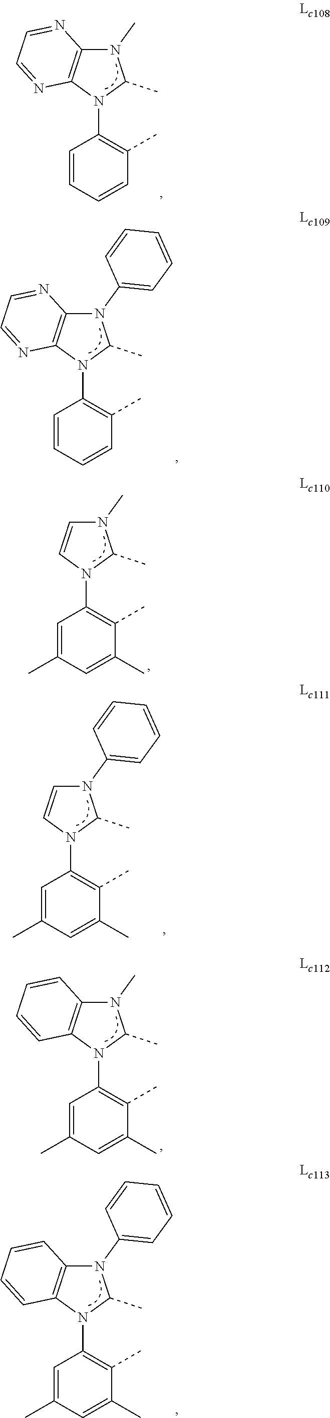

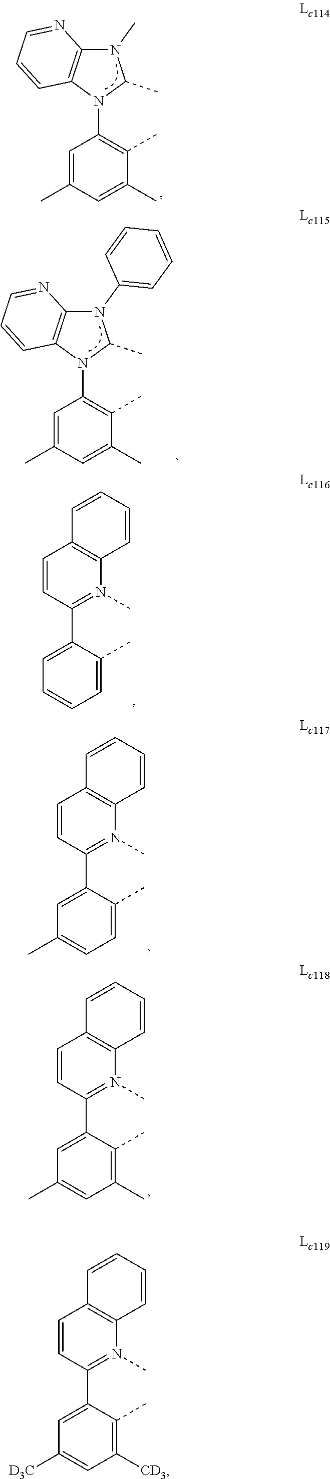

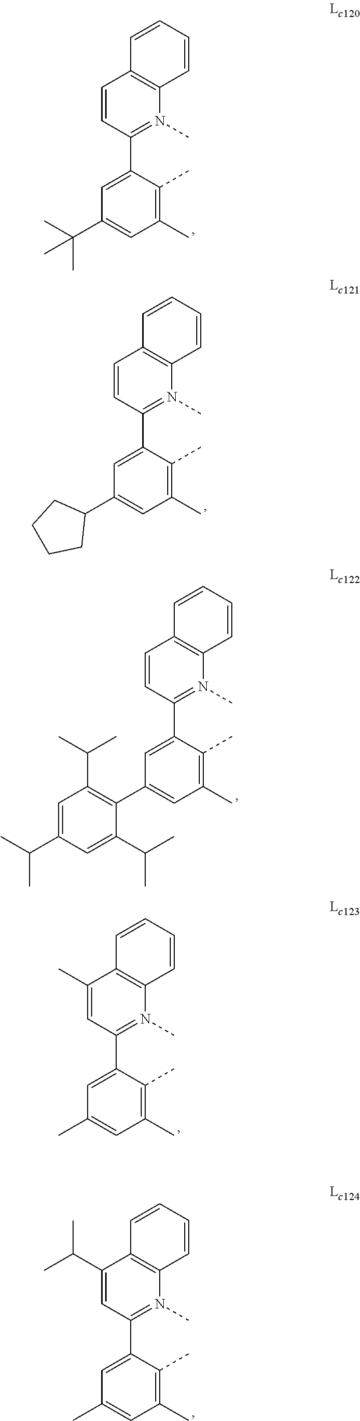

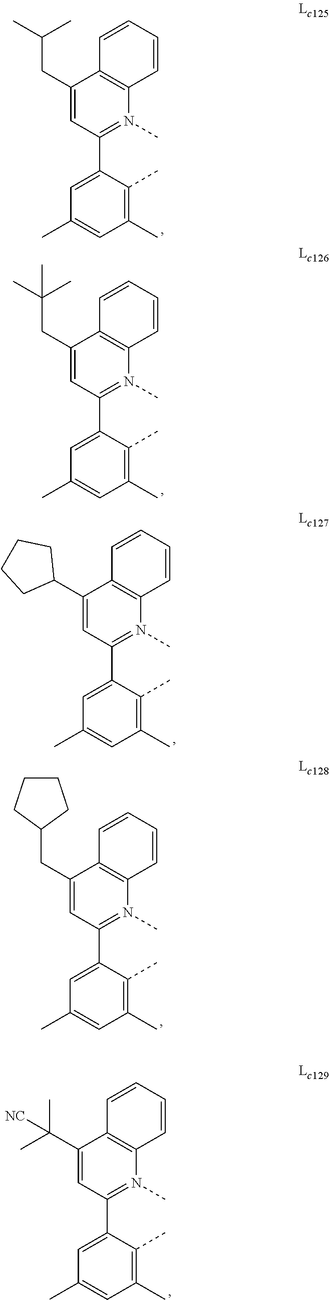

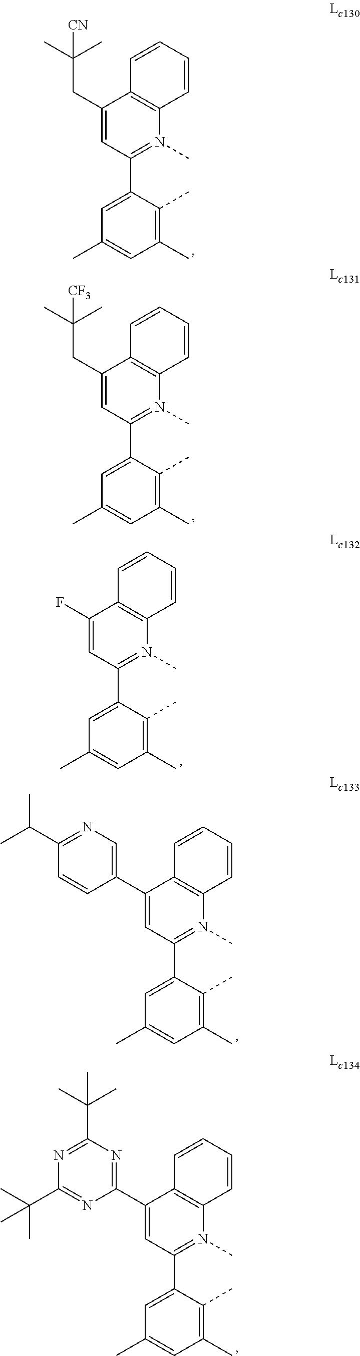

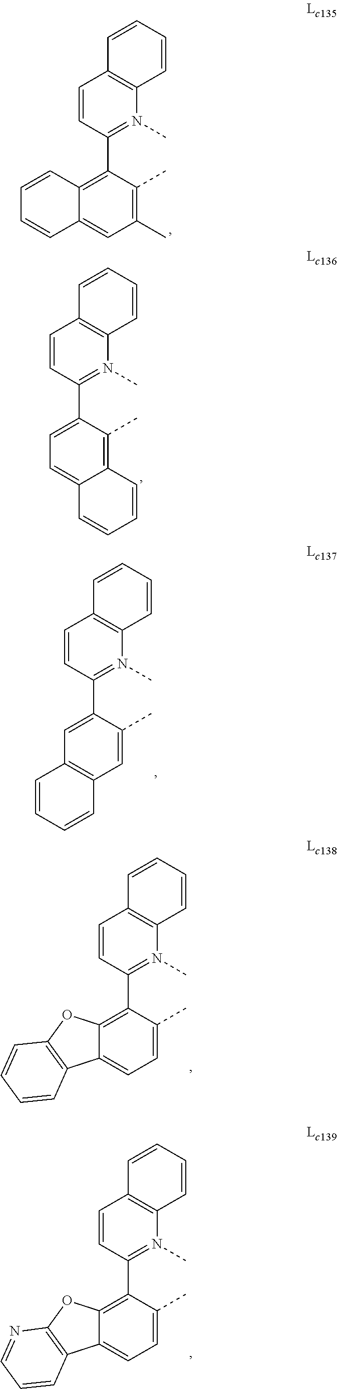

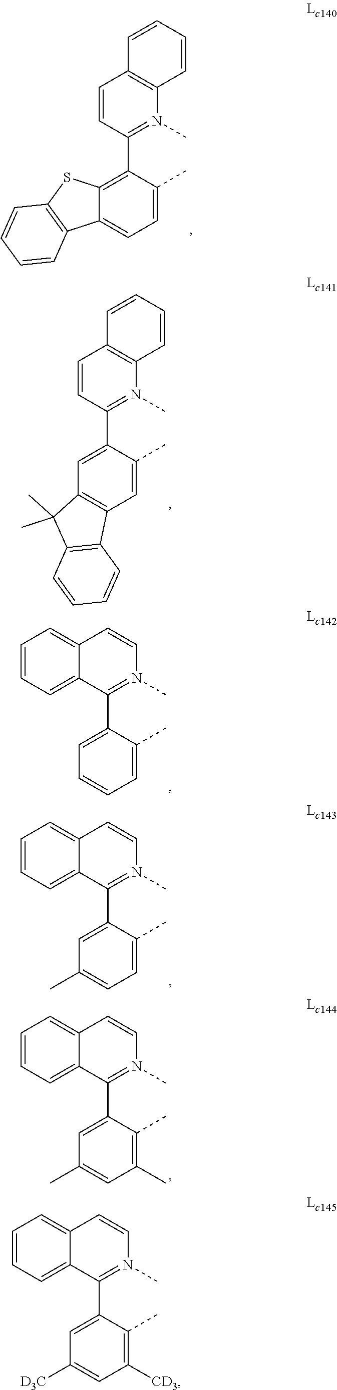

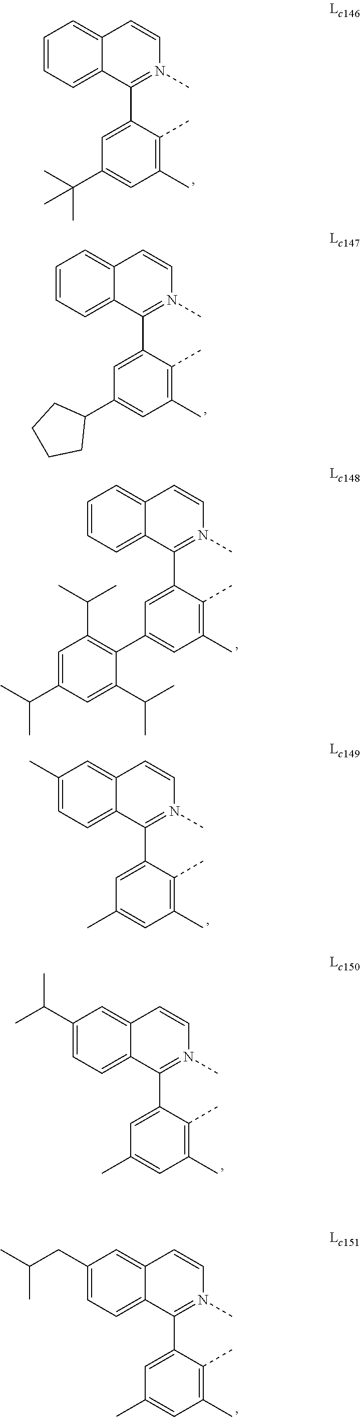

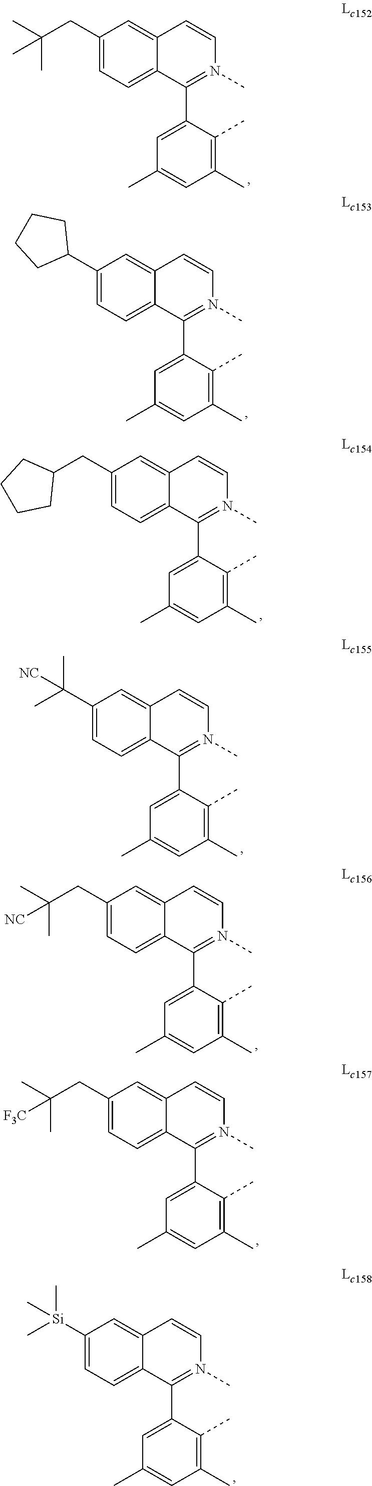

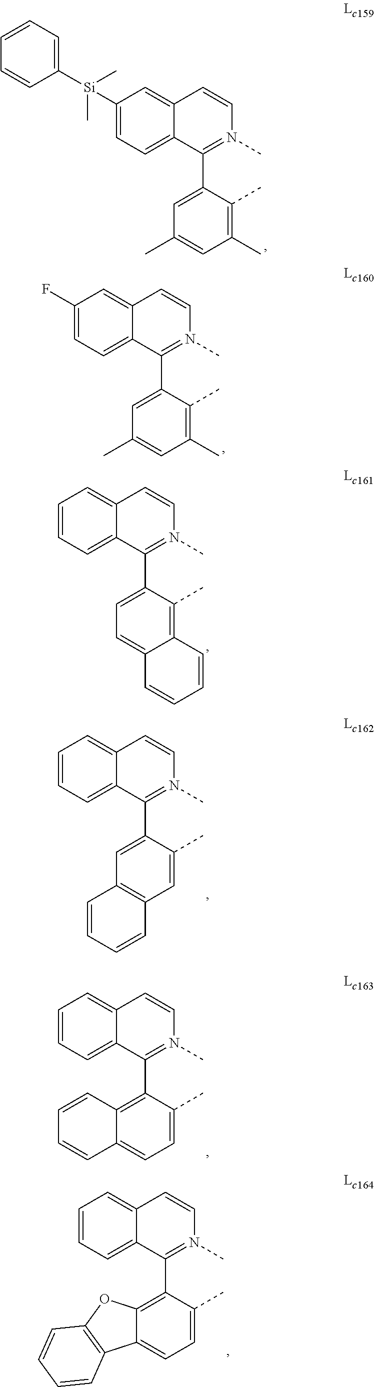

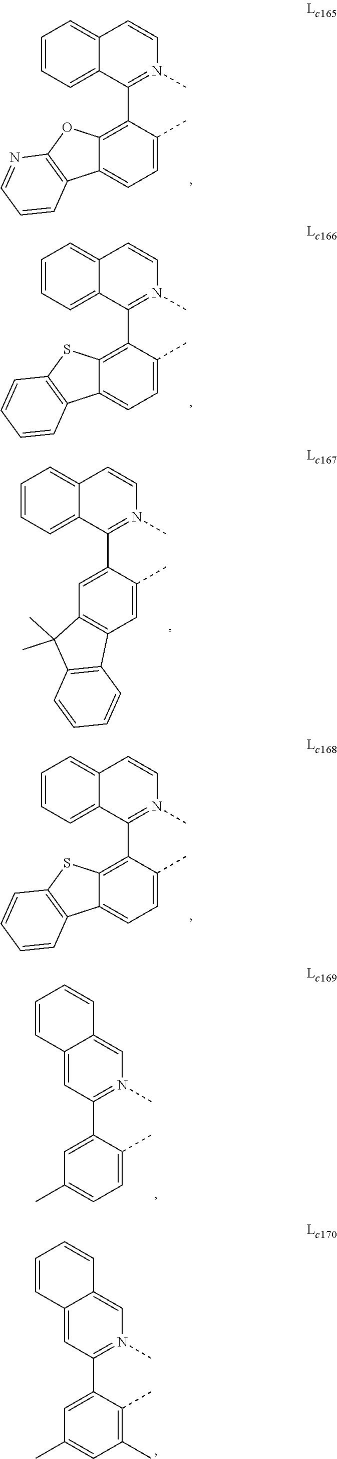

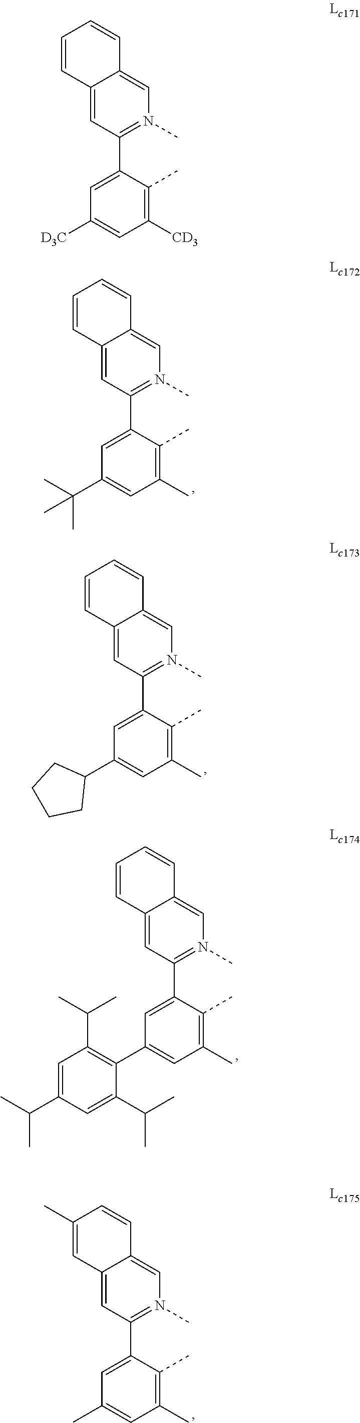

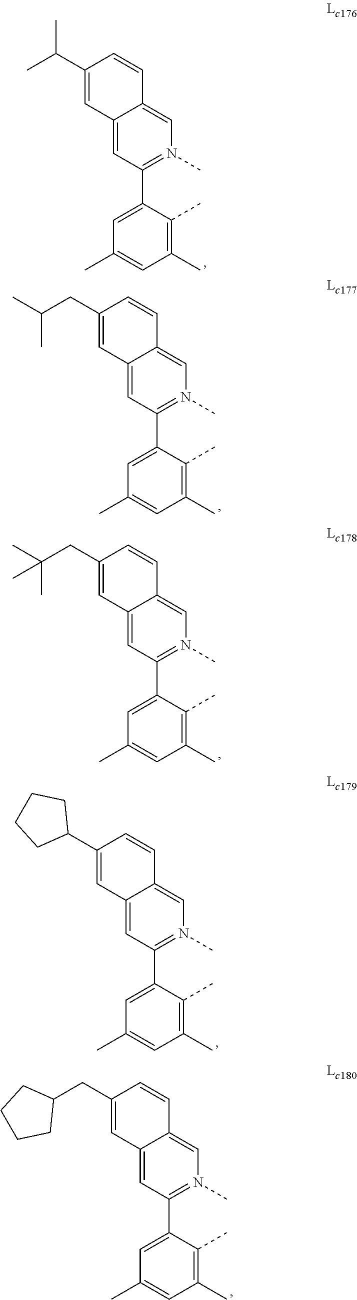

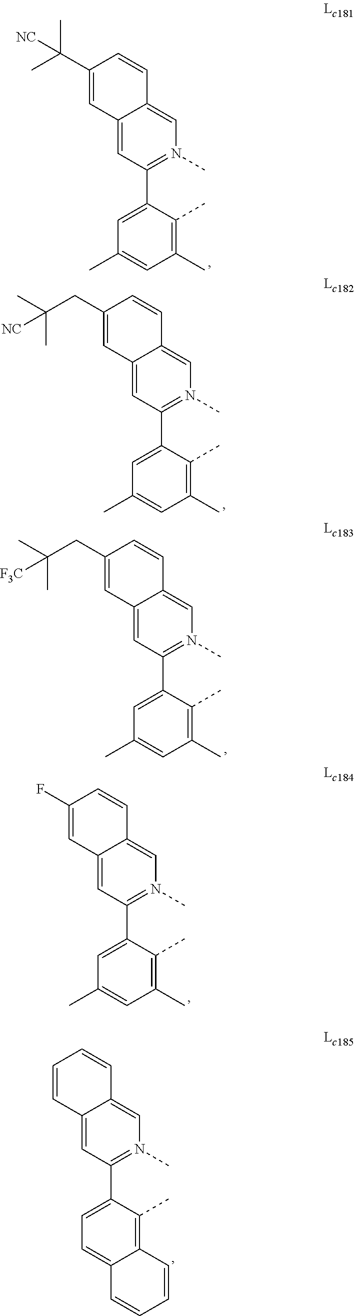

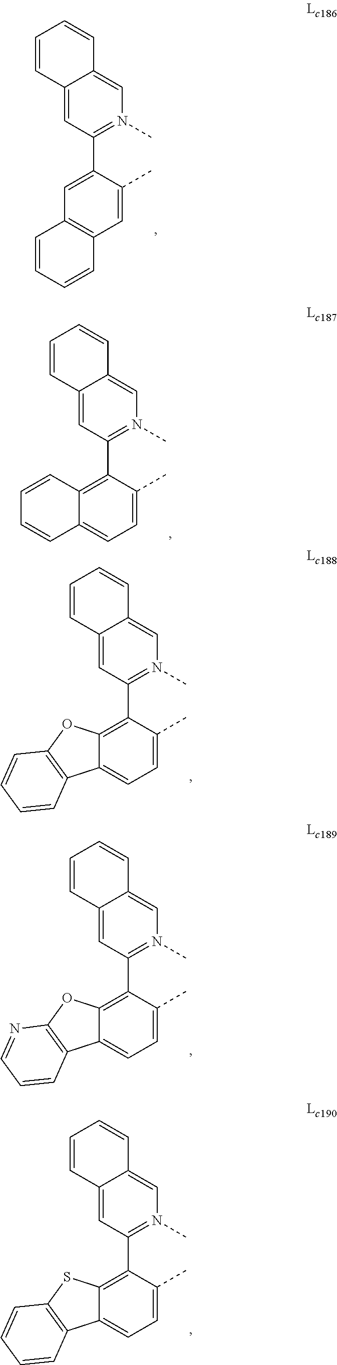

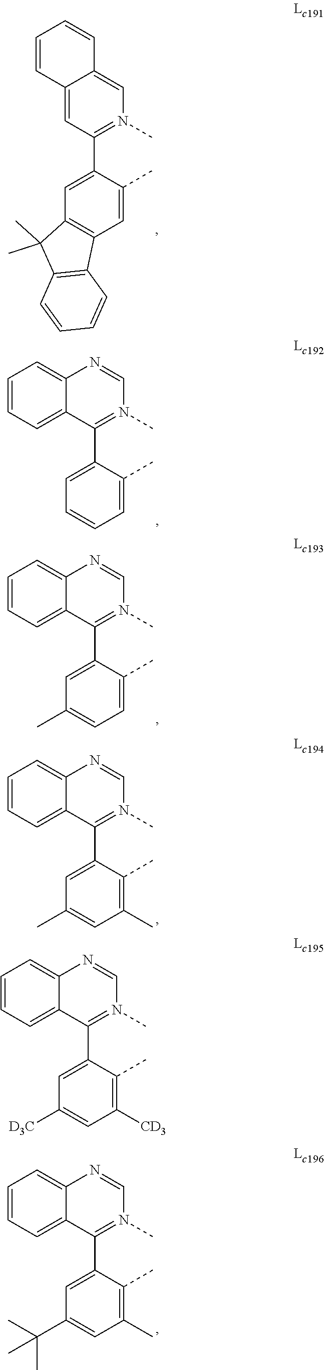

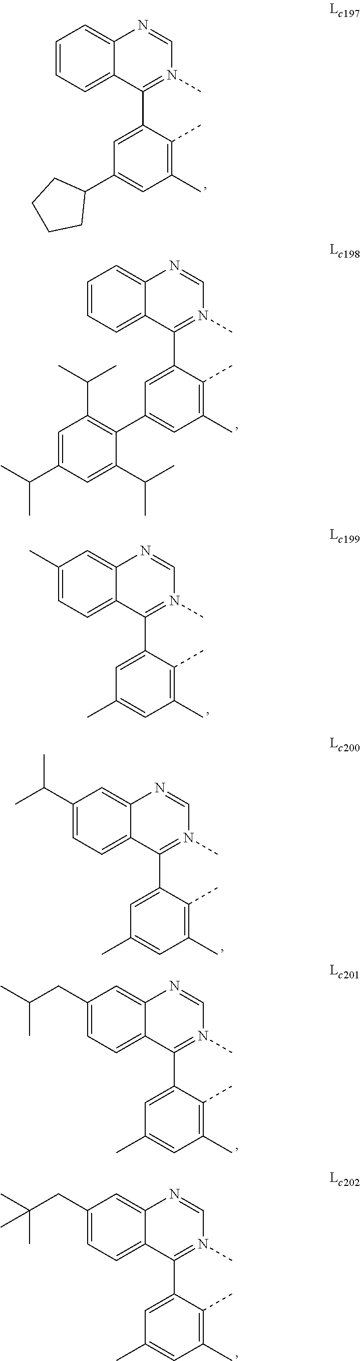

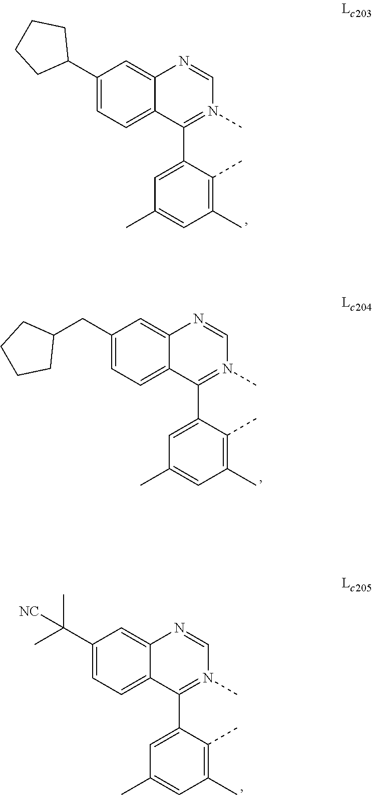

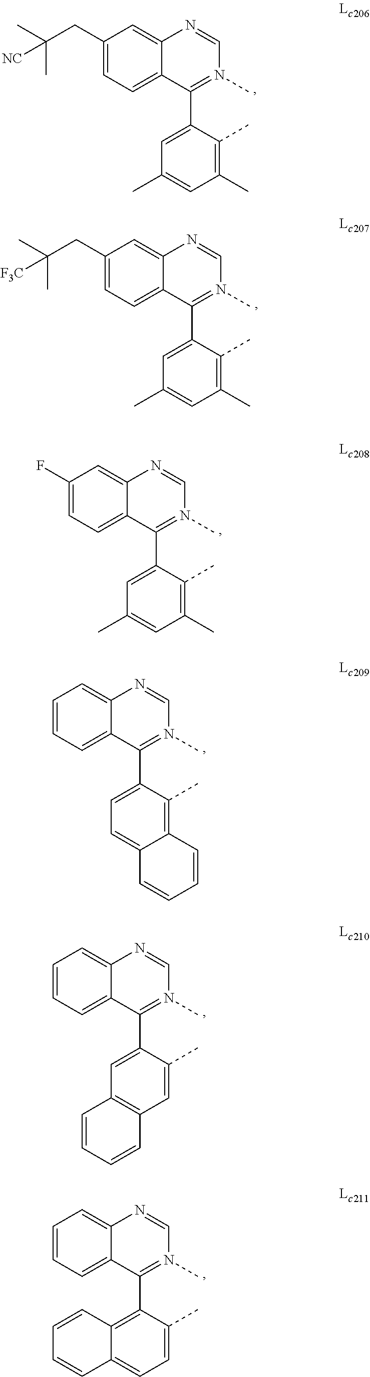

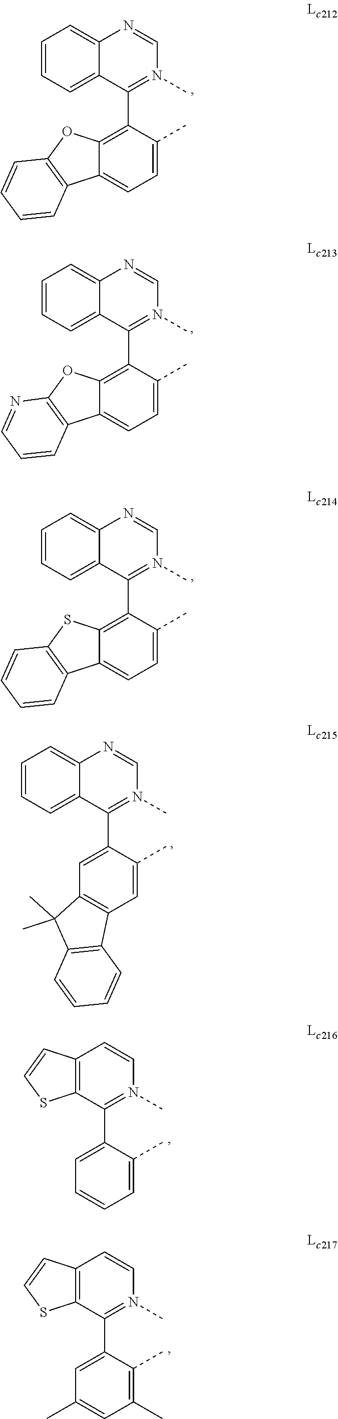

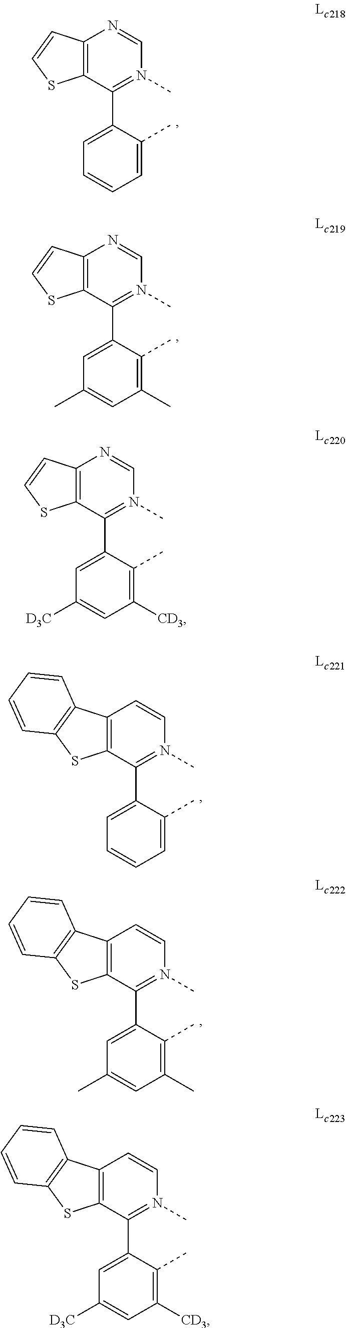

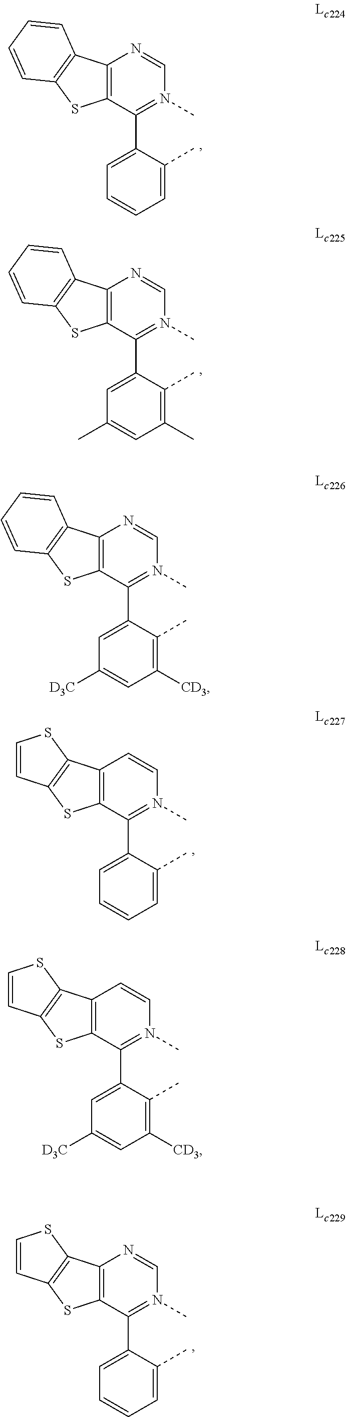

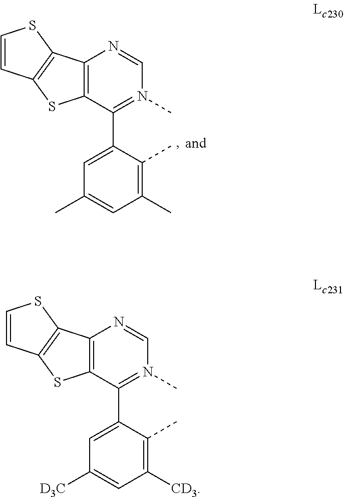

15. The metal complex of claim 1, wherein the metal complex has a structure of Ir(Lₐ)₂(L_{b}) or Ir(Lₐ)(L_{b})(L_{c});
wherein when the metal complex has the structure of Ir(Lₐ)₂(L_{b}), Lₐ is, at each occurrence identically or differently, selected from any one or two of the group consisting of Lₐ₁ to Lₐ₇₁₅, and L_{b} is selected from any one of the group consisting of L_{b1} to L_{b322}; when the metal complex has the structure of Ir(Lₐ)(L_{b})(L_{c}), Lₐ is selected from any one of the group consisting of Lₐ₁ to Lₐ₇₁₅, L_{b} is selected from any one of the group consisting of L_{b1} to L_{b322}, and L_{c} is selected from any one of the group consisting of L_{c1} to L_{c231};
preferably, the metal complex is selected from the group consisting of Compound 1 to Compound 794;
wherein Compound I to Compound 794 have the structure of Ir(Lₐ)₂(L_{b}), wherein two Lₐ are the same, and Lₐ and L_{b} are selected from the structures listed in the following table, respectively:

| Compound | | | Compound | | |
|---|---|---|---|---|---|
| No. | Lₐ | L_{b} | No. | Lₐ | L_{b} |
| 1 | Lₐ₄ | L_{b1} | 2 | Lₐ₄ | L_{b31} |
| 3 | Lₐ₁₁ | L_{b1} | 4 | Lₐ₁₁ | L_{b31} |
| 5 | Lₐ₄₇ | L_{b1} | 6 | Lₐ₄₇ | L_{b31} |
| 7 | Lₐ₅₁ | L_{b1} | 8 | Lₐ₅₁ | L_{b31} |
| 9 | Lₐ₅₃ | L_{b1} | 10 | Lₐ₅₃ | L_{b31} |
| 11 | Lₐ₅₅ | L_{b1} | 12 | Lₐ₅₅ | L_{b31} |
| 13 | Lₐ₅₆ | L_{b1} | 14 | Lₐ₅₆ | L_{b31} |
| 15 | Lₐ₆₁ | L_{b1} | 16 | Lₐ₆₁ | L_{b31} |
| 17 | Lₐ₆₃ | L_{b1} | 18 | Lₐ₆₃ | L_{b31} |
| 19 | Lₐ₆₉ | L_{b1} | 20 | Lₐ₆₉ | L_{b31} |
| 21 | Lₐ₇₃ | L_{b1} | 22 | Lₐ₇₃ | L_{b31} |
| 23 | Lₐ₇₅ | L_{b1} | 24 | Lₐ₇₅ | L_{b31} |
| 25 | Lₐ₈₄ | L_{b1} | 26 | Lₐ₈₄ | L_{b31} |
| 27 | Lₐ₈₆ | L_{b1} | 28 | Lₐ₈₆ | L_{b31} |
| 29 | Lₐ₈₇ | L_{b1} | 30 | Lₐ₈₇ | L_{b31} |
| 31 | Lₐ₈₈ | L_{b1} | 32 | Lₐ₈₈ | L_{b31} |
| 33 | Lₐ₈₉ | L_{b1} | 34 | Lₐ₈₉ | L_{b31} |
| 35 | Lₐ₉₄ | L_{b1} | 36 | Lₐ₉₄ | L_{b31} |
| 37 | Lₐ₁₀₀ | L_{b1} | 38 | Lₐ₁₀₀ | L_{b31} |
| 39 | Lₐ₁₄₁ | L_{b1} | 40 | Lₐ₁₄₁ | L_{b31} |
| 41 | Lₐ₁₄₈ | L_{b1} | 42 | Lₐ₁₄₈ | L_{b31} |
| 43 | Lₐ₁₇₆ | L_{b1} | 44 | Lₐ₁₇₆ | L_{b31} |
| 45 | Lₐ₁₈₀ | L_{b1} | 46 | Lₐ₁₈₀ | L_{b31} |
| 47 | Lₐ₁₈₈ | L_{b1} | 48 | Lₐ₁₈₈ | L_{b31} |
| 49 | Lₐ₁₉₇ | L_{b1} | 50 | Lₐ₁₉₇ | L_{b31} |
| 51 | Lₐ₂₀₁ | L_{b1} | 52 | Lₐ₂₀₁ | L_{b31} |
| 53 | Lₐ₂₀₆ | L_{b1} | 54 | Lₐ₂₀₆ | L_{b31} |
| 55 | Lₐ₂₄₃ | L_{b1} | 56 | Lₐ₂₄₃ | L_{b31} |
| 57 | Lₐ₂₄₉ | L_{b1} | 58 | Lₐ₂₄₉ | L_{b31} |
| 59 | Lₐ₂₅₂ | L_{b1} | 60 | Lₐ₂₅₂ | L_{b31} |
| 61 | Lₐ₂₅₉ | L_{b1} | 62 | Lₐ₂₅₉ | L_{b31} |
| 63 | Lₐ₂₉₃ | L_{b1} | 64 | Lₐ₂₉₃ | L_{b31} |
| 65 | Lₐ₃₁₀ | L_{b1} | 66 | Lₐ₃₁₀ | L_{b31} |
| 67 | Lₐ₃₁₃ | L_{b1} | 68 | Lₐ₃₁₃ | L_{b31} |
| 69 | Lₐ₃₆₄ | L_{b1} | 70 | Lₐ₃₆₄ | L_{b31} |
| 71 | Lₐ₃₆₇ | L_{b1} | 72 | Lₐ₃₆₇ | L_{b31} |
| 73 | Lₐ₃₈₂ | L_{b1} | 74 | Lₐ₃₈₂ | L_{b31} |
| 75 | Lₐ₃₉₂ | L_{b1} | 76 | Lₐ₃₉₂ | L_{b31} |
| 77 | Lₐ₄₂₈ | L_{b1} | 78 | Lₐ₄₂₈ | L_{b31} |
| 79 | Lₐ₄₃₂ | L_{b1} | 80 | Lₐ₄₃₂ | L_{b31} |
| 81 | Lₐ₄₃₉ | L_{b1} | 82 | Lₐ₄₃₉ | L_{b31} |
| 83 | Lₐ₄₅₇ | L_{b1} | 84 | Lₐ₄₅₇ | L_{b31} |
| 85 | Lₐ₄₈₂ | L_{b1} | 86 | Lₐ₄₈₂ | L_{b31} |
| 87 | Lₐ₅₄₂ | L_{b1} | 88 | Lₐ₅₄₂ | L_{b31} |
| 89 | Lₐ₅₆₉ | L_{b1} | 90 | Lₐ₅₆₉ | L_{b31} |
| 91 | Lₐ₅₉₃ | L_{b1} | 92 | Lₐ₅₉₃ | L_{b31} |
| 93 | Lₐ₅₉₆ | L_{b1} | 94 | Lₐ₅₉₆ | L_{b31} |
| 95 | Lₐ₆₁₃ | L_{b1} | 96 | Lₐ₆₁₃ | L_{b31} |
| 97 | Lₐ₆₃₆ | L_{b1} | 98 | Lₐ₆₃₆ | L_{b31} |
| 99 | Lₐ₆₄₃ | L_{b1} | 100 | Lₐ₆₄₃ | L_{b31} |
| 101 | Lₐ₆₇₂ | L_{b1} | 102 | Lₐ₆₇₂ | L_{b31} |
| 103 | Lₐ₆₇₈ | L_{b1} | 104 | Lₐ₆₇₈ | L_{b31} |
| 105 | Lₐ₇₀₈ | L_{b1} | 106 | Lₐ₇₀₈ | L_{b31} |
| 107 | Lₐ₇₁₂ | L_{b1} | 108 | Lₐ₇₁₂ | L_{b31} |
| 109 | Lₐ₇₁₄ | L_{b1} | 110 | Lₐ₇₁₄ | L_{b31} |
| 111 | Lₐ₄ | L_{b57} | 112 | Lₐ₄ | L_{b88} |
| 113 | Lₐ₁₁ | L_{b57} | 114 | Lₐ₁₁ | L_{b88} |
| 115 | Lₐ₄₇ | L_{b57} | 116 | Lₐ₄₇ | L_{b88} |
| 117 | Lₐ₅₁ | L_{b57} | 118 | Lₐ₅₁ | L_{b88} |
| 119 | Lₐ₅₃ | L_{b57} | 120 | Lₐ₅₃ | L_{b88} |
| 121 | Lₐ₅₅ | L_{b57} | 122 | Lₐ₅₅ | L_{b88} |
| 123 | Lₐ₅₆ | L_{b57} | 124 | Lₐ₅₆ | L_{b88} |
| 125 | Lₐ₆₁ | L_{b57} | 126 | Lₐ₆₁ | L_{b88} |
| 127 | Lₐ₆₃ | L_{b57} | 128 | Lₐ₆₃ | L_{b88} |
| 129 | Lₐ₆₉ | L_{b57} | 130 | Lₐ₆₉ | L_{b88} |
| 131 | Lₐ₇₃ | L_{b57} | 132 | Lₐ₇₃ | L_{b88} |
| 133 | Lₐ₇₅ | L_{b57} | 134 | Lₐ₇₅ | L_{b88} |
| 135 | Lₐ₈₄ | L_{b57} | 136 | Lₐ₈₄ | L_{b88} |
| 137 | Lₐ₈₆ | L_{b57} | 138 | Lₐ₈₆ | L_{b88} |
| 139 | Lₐ₈₇ | L_{b57} | 140 | Lₐ₈₇ | L_{b88} |
| 141 | Lₐ₈₈ | L_{b57} | 142 | Lₐ₈₈ | L_{b88} |
| 143 | Lₐ₈₉ | L_{b57} | 144 | Lₐ₈₉ | L_{b88} |
| 145 | Lₐ₉₄ | L_{b57} | 146 | Lₐ₉₄ | L_{b88} |
| 147 | Lₐ₁₀₀ | L_{b57} | 148 | Lₐ₁₀₀ | L_{b88} |
| 149 | Lₐ₁₄₁ | L_{b57} | 150 | Lₐ₁₄₁ | L_{b88} |
| 151 | Lₐ₁₄₈ | L_{b57} | 152 | Lₐ₁₄₈ | L_{b88} |
| 153 | Lₐ₁₇₆ | L_{b57} | 154 | Lₐ₁₇₆ | L_{b88} |
| 155 | Lₐ₁₈₀ | L_{b57} | 156 | Lₐ₁₈₀ | L_{b88} |
| 157 | Lₐ₁₈₈ | L_{b57} | 158 | Lₐ₁₈₈ | L_{b88} |
| 159 | Lₐ₁₉₇ | L_{b57} | 160 | Lₐ₁₉₇ | L_{b88} |
| 161 | Lₐ₂₀₁ | L_{b57} | 162 | Lₐ₂₀₁ | L_{b88} |
| 163 | Lₐ₂₀₆ | L_{b57} | 164 | Lₐ₂₀₆ | L_{b88} |
| 165 | Lₐ₂₄₃ | L_{b57} | 166 | Lₐ₂₄₃ | L_{b88} |
| 167 | Lₐ₂₄₉ | L_{b57} | 168 | Lₐ₂₄₉ | L_{b88} |
| 169 | Lₐ₂₅₂ | L_{b57} | 170 | Lₐ₂₅₂ | L_{b88} |
| 171 | Lₐ₂₅₉ | L_{b57} | 172 | Lₐ₂₅₉ | L_{b88} |
| 173 | Lₐ₂₉₃ | L_{b57} | 174 | Lₐ₂₉₃ | L_{b88} |
| 175 | Lₐ₃₁₀ | L_{b57} | 176 | Lₐ₃₁₀ | L_{b88} |
| 177 | Lₐ₃₁₃ | L_{b57} | 178 | Lₐ₃₁₃ | L_{b88} |
| 179 | Lₐ₃₆₄ | L_{b57} | 180 | Lₐ₃₆₄ | L_{b88} |
| 181 | Lₐ₃₆₇ | L_{b57} | 182 | Lₐ₃₆₇ | L_{b88} |
| 183 | Lₐ₃₈₂ | L_{b57} | 184 | Lₐ₃₈₂ | L_{b88} |
| 185 | Lₐ₃₉₂ | L_{b57} | 186 | Lₐ₃₉₂ | L_{b88} |
| 187 | Lₐ₄₂₈ | L_{b57} | 188 | Lₐ₄₂₈ | L_{b88} |
| 189 | Lₐ₄₃₂ | L_{b57} | 190 | Lₐ₄₃₂ | L_{b88} |
| 191 | Lₐ₄₃₉ | L_{b57} | 192 | Lₐ₄₃₉ | L_{b88} |
| 193 | Lₐ₄₅₇ | L_{b57} | 194 | Lₐ₄₅₇ | L_{b88} |
| 195 | Lₐ₄₈₂ | L_{b57} | 196 | Lₐ₄₈₂ | L_{b88} |
| 197 | Lₐ₅₄₂ | L_{b57} | 198 | Lₐ₅₄₂ | L_{b88} |
| 199 | Lₐ₅₆₉ | L_{b57} | 200 | Lₐ₅₆₉ | L_{b88} |
| 201 | Lₐ₅₉₃ | L_{b57} | 202 | Lₐ₅₉₃ | L_{b88} |
| 203 | Lₐ₅₉₆ | L_{b57} | 204 | Lₐ₅₉₆ | L_{b88} |
| 205 | Lₐ₆₁₃ | L_{b57} | 206 | Lₐ₆₁₃ | L_{b88} |
| 207 | Lₐ₆₃₆ | L_{b57} | 208 | Lₐ₆₃₆ | L_{b88} |
| 209 | Lₐ₆₄₃ | L_{b57} | 210 | Lₐ₆₄₃ | L_{b88} |
| 211 | Lₐ₆₇₂ | L_{b57} | 212 | Lₐ₆₇₂ | L_{b88} |
| 213 | Lₐ₆₇₈ | L_{b57} | 214 | Lₐ₆₇₈ | L_{b88} |
| 215 | Lₐ₇₀₈ | L_{b57} | 216 | Lₐ₇₀₈ | L_{b88} |
| 217 | Lₐ₇₁₂ | L_{b57} | 218 | Lₐ₇₁₂ | L_{b88} |
| 219 | Lₐ₇₁₄ | L_{b57} | 220 | Lₐ₇₁₄ | L_{b88} |
| 221 | Lₐ₄ | L_{b122} | 222 | Lₐ₄ | L_{b126} |
| 223 | Lₐ₁₁ | L_{b122} | 224 | Lₐ₁₁ | L_{b126} |
| 225 | Lₐ₄₇ | L_{b122} | 226 | Lₐ₄₇ | L_{b126} |
| 227 | Lₐ₅₁ | L_{b122} | 228 | Lₐ₅₁ | L_{b126} |
| 229 | Lₐ₅₃ | L_{b122} | 230 | Lₐ₅₃ | L_{b126} |
| 231 | Lₐ₅₅ | L_{b122} | 232 | Lₐ₅₅ | L_{b126} |
| 233 | Lₐ₅₆ | L_{b122} | 234 | Lₐ₅₆ | L_{b126} |
| 235 | Lₐ₆₁ | L_{b122} | 236 | Lₐ₆₁ | L_{b126} |
| 237 | Lₐ₆₃ | L_{b122} | 238 | Lₐ₆₃ | L_{b126} |
| 239 | Lₐ₆₉ | L_{b122} | 240 | Lₐ₆₉ | L_{b126} |
| 241 | Lₐ₇₃ | L_{b122} | 242 | Lₐ₇₃ | L_{b126} |
| 243 | Lₐ₇₅ | L_{b122} | 244 | Lₐ₇₅ | L_{b126} |
| 245 | Lₐ₈₄ | L_{b122} | 246 | Lₐ₈₄ | L_{b126} |
| 247 | Lₐ₈₆ | L_{b122} | 248 | Lₐ₈₆ | L_{b126} |
| 249 | Lₐ₈₇ | L_{b122} | 250 | Lₐ₈₇ | L_{b126} |
| 251 | Lₐ₈₈ | L_{b122} | 252 | Lₐ₈₈ | L_{b126} |
| 253 | Lₐ₈₉ | L_{b122} | 254 | Lₐ₈₉ | L_{b126} |
| 255 | Lₐ₉₄ | L_{b122} | 256 | Lₐ₉₄ | L_{b126} |
| 257 | Lₐ₁₀₀ | L_{b122} | 258 | Lₐ₁₀₀ | L_{b126} |
| 259 | Lₐ₁₄₁ | L_{b122} | 260 | Lₐ₁₄₁ | L_{b126} |
| 261 | Lₐ₁₄₈ | L_{b122} | 262 | Lₐ₁₄₈ | L_{b126} |
| 263 | Lₐ₁₇₆ | L_{b122} | 264 | Lₐ₁₇₆ | L_{b126} |
| 265 | Lₐ₁₈₀ | L_{b122} | 266 | Lₐ₁₈₀ | L_{b126} |
| 267 | Lₐ₁₈₈ | L_{b122} | 268 | Lₐ₁₈₈ | L_{b126} |
| 269 | Lₐ₁₉₇ | L_{b122} | 270 | Lₐ₁₉₇ | L_{b126} |
| 271 | Lₐ₂₀₁ | L_{b122} | 272 | Lₐ₂₀₁ | L_{b126} |
| 273 | Lₐ₂₀₆ | L_{b122} | 274 | Lₐ₂₀₆ | L_{b126} |
| 275 | Lₐ₂₄₃ | L_{b122} | 276 | Lₐ₂₄₃ | L_{b126} |
| 277 | Lₐ₂₄₉ | L_{b122} | 278 | Lₐ₂₄₉ | L_{b126} |
| 279 | Lₐ₂₅₂ | L_{b122} | 280 | Lₐ₂₅₂ | L_{b126} |
| 281 | Lₐ₂₅₉ | L_{b122} | 282 | Lₐ₂₅₉ | L_{b126} |
| 283 | Lₐ₂₉₃ | L_{b122} | 284 | Lₐ₂₉₃ | L_{b126} |
| 285 | Lₐ₃₁₀ | L_{b122} | 286 | Lₐ₃₁₀ | L_{b126} |
| 287 | Lₐ₃₁₃ | L_{b122} | 288 | Lₐ₃₁₃ | L_{b126} |
| 289 | Lₐ₃₆₄ | L_{b122} | 290 | Lₐ₃₆₄ | L_{b126} |
| 291 | Lₐ₃₆₇ | L_{b122} | 292 | Lₐ₃₆₇ | L_{b126} |
| 293 | Lₐ₃₈₂ | L_{b122} | 294 | Lₐ₃₈₂ | L_{b126} |
| 295 | Lₐ₃₉₂ | L_{b122} | 296 | Lₐ₃₉₂ | L_{b126} |
| 297 | Lₐ₄₂₈ | L_{b122} | 298 | Lₐ₄₂₈ | L_{b126} |
| 299 | Lₐ₄₃₂ | L_{b122} | 300 | Lₐ₄₃₂ | L_{b126} |
| 301 | Lₐ₄₃₉ | L_{b122} | 302 | Lₐ₄₃₉ | L_{b126} |
| 303 | Lₐ₄₅₇ | L_{b122} | 304 | Lₐ₄₅₇ | L_{b126} |
| 305 | Lₐ₄₈₂ | L_{b122} | 306 | Lₐ₄₈₂ | L_{b126} |
| 307 | Lₐ₅₄₂ | L_{b122} | 308 | Lₐ₅₄₂ | L_{b126} |
| 309 | Lₐ₅₆₉ | L_{b122} | 310 | Lₐ₅₆₉ | L_{b126} |
| 311 | Lₐ₅₉₃ | L_{b122} | 312 | Lₐ₅₉₃ | L_{b126} |
| 313 | Lₐ₅₉₆ | L_{b122} | 314 | Lₐ₅₉₆ | L_{b126} |
| 315 | Lₐ₆₁₃ | L_{b122} | 316 | Lₐ₆₁₃ | L_{b126} |
| 317 | Lₐ₆₃₆ | L_{b122} | 318 | Lₐ₆₃₆ | L_{b126} |
| 319 | Lₐ₆₄₃ | L_{b122} | 320 | Lₐ₆₄₃ | L_{b126} |
| 321 | Lₐ₆₇₂ | L_{b122} | 322 | Lₐ₆₇₂ | L_{b126} |
| 323 | Lₐ₆₇₈ | L_{b122} | 324 | Lₐ₆₇₈ | L_{b126} |
| 325 | Lₐ₇₀₈ | L_{b122} | 326 | Lₐ₇₀₈ | L_{b126} |
| 327 | Lₐ₇₁₂ | L_{b122} | 328 | Lₐ₇₁₂ | L_{b126} |
| 329 | Lₐ₇₁₄ | L_{b122} | 330 | Lₐ₇₁₄ | L_{b126} |
| 331 | Lₐ₄ | L_{b135} | 332 | Lₐ₄ | L_{b165} |
| 333 | Lₐ₁₁ | L_{b135} | 334 | Lₐ₁₁ | L_{b165} |
| 335 | Lₐ₄₇ | L_{b135} | 336 | Lₐ₄₇ | L_{b165} |
| 337 | Lₐ₅₁ | L_{b135} | 338 | Lₐ₅₁ | L_{b165} |
| 339 | Lₐ₅₃ | L_{b135} | 340 | Lₐ₅₃ | L_{b165} |
| 341 | Lₐ₅₅ | L_{b135} | 342 | Lₐ₅₅ | L_{b165} |
| 343 | Lₐ₅₆ | L_{b135} | 344 | Lₐ₅₆ | L_{b165} |
| 345 | Lₐ₆₁ | L_{b135} | 346 | Lₐ₆₁ | L_{b165} |
| 347 | Lₐ₆₃ | L_{b135} | 348 | Lₐ₆₃ | L_{b165} |
| 349 | Lₐ₆₉ | L_{b135} | 350 | Lₐ₆₉ | L_{b165} |
| 351 | Lₐ₇₃ | L_{b135} | 352 | Lₐ₇₃ | L_{b165} |
| 353 | Lₐ₇₅ | L_{b135} | 354 | Lₐ₇₅ | L_{b165} |
| 355 | Lₐ₈₄ | L_{b135} | 356 | Lₐ₈₄ | L_{b165} |
| 357 | Lₐ₈₆ | L_{b135} | 358 | Lₐ₈₆ | L_{b165} |
| 359 | Lₐ₈₇ | L_{b135} | 360 | Lₐ₈₇ | L_{b165} |
| 361 | Lₐ₈₈ | L_{b135} | 362 | Lₐ₈₈ | L_{b165} |
| 363 | Lₐ₈₉ | L_{b135} | 364 | Lₐ₈₉ | L_{b165} |
| 365 | Lₐ₉₄ | L_{b135} | 366 | Lₐ₉₄ | L_{b165} |
| 367 | Lₐ₁₀₀ | L_{b135} | 368 | Lₐ₁₀₀ | L_{b165} |
| 369 | Lₐ₁₄₁ | L_{b135} | 370 | Lₐ₁₄₁ | L_{b165} |
| 371 | Lₐ₁₄₈ | L_{b135} | 372 | Lₐ₁₄₈ | L_{b165} |
| 373 | Lₐ₁₇₆ | L_{b135} | 374 | Lₐ₁₇₆ | L_{b165} |
| 375 | Lₐ₁₈₀ | L_{b135} | 376 | Lₐ₁₈₀ | L_{b165} |
| 377 | Lₐ₁₈₈ | L_{b135} | 378 | Lₐ₁₈₈ | L_{b165} |
| 379 | Lₐ₁₉₇ | L_{b135} | 380 | Lₐ₁₉₇ | L_{b165} |
| 381 | Lₐ₂₀₁ | L_{b135} | 382 | Lₐ₂₀₁ | L_{b165} |
| 383 | Lₐ₂₀₆ | L_{b135} | 384 | Lₐ₂₀₆ | L_{b165} |
| 385 | Lₐ₂₄₃ | L_{b135} | 386 | Lₐ₂₄₃ | L_{b165} |
| 387 | Lₐ₂₄₉ | L_{b135} | 388 | Lₐ₂₄₉ | L_{b165} |
| 389 | Lₐ₂₅₂ | L_{b135} | 390 | Lₐ₂₅₂ | L_{b165} |
| 391 | Lₐ₂₅₉ | L_{b135} | 392 | Lₐ₂₅₉ | L_{b165} |
| 393 | Lₐ₂₉₃ | L_{b135} | 394 | Lₐ₂₉₃ | L_{b165} |
| 395 | Lₐ₃₁₀ | L_{b135} | 396 | Lₐ₃₁₀ | L_{b165} |
| 397 | Lₐ₃₁₃ | L_{b135} | 398 | Lₐ₃₁₃ | L_{b165} |
| 399 | Lₐ₃₆₄ | L_{b135} | 400 | Lₐ₃₆₄ | L_{b165} |
| 401 | Lₐ₃₆₇ | L_{b135} | 402 | Lₐ₃₆₇ | L_{b165} |
| 403 | Lₐ₃₈₂ | L_{b135} | 404 | Lₐ₃₈₂ | L_{b165} |
| 405 | Lₐ₃₉₂ | L_{b135} | 406 | Lₐ₃₉₂ | L_{b165} |
| 407 | Lₐ₄₂₈ | L_{b135} | 408 | Lₐ₄₂₈ | L_{b165} |
| 409 | Lₐ₄₃₂ | L_{b135} | 410 | Lₐ₄₃₂ | L_{b165} |
| 411 | Lₐ₄₃₉ | L_{b135} | 412 | Lₐ₄₃₉ | L_{b165} |
| 413 | Lₐ₄₅₇ | L_{b135} | 414 | Lₐ₄₅₇ | L_{b165} |
| 415 | Lₐ₄₈₂ | L_{b135} | 416 | Lₐ₄₈₂ | L_{b165} |
| 417 | Lₐ₅₄₂ | L_{b135} | 418 | Lₐ₅₄₂ | L_{b165} |
| 419 | Lₐ₅₆₉ | L_{b135} | 420 | Lₐ₅₆₉ | L_{b165} |
| 421 | Lₐ₅₉₃ | L_{b135} | 422 | Lₐ₅₉₃ | L_{b165} |
| 423 | Lₐ₅₉₆ | L_{b135} | 424 | Lₐ₅₉₆ | L_{b165} |
| 425 | Lₐ₆₁₃ | L_{b135} | 426 | Lₐ₆₁₃ | L_{b165} |
| 427 | Lₐ₆₃₆ | L_{b135} | 428 | Lₐ₆₃₆ | L_{b165} |
| 429 | Lₐ₆₄₃ | L_{b135} | 430 | Lₐ₆₄₃ | L_{b165} |
| 431 | Lₐ₆₇₂ | L_{b135} | 432 | Lₐ₆₇₂ | L_{b165} |
| 433 | Lₐ₆₇₈ | L_{b135} | 434 | Lₐ₆₇₈ | L_{b165} |
| 435 | Lₐ₇₀₈ | L_{b135} | 436 | Lₐ₇₀₈ | L_{b165} |
| 437 | Lₐ₇₁₂ | L_{b135} | 438 | Lₐ₇₁₂ | L_{b165} |
| 439 | Lₐ₇₁₄ | L_{b135} | 440 | Lₐ₇₁₄ | L_{b165} |
| 441 | Lₐ₄ | L_{b212} | 442 | Lₐ₄ | L_{b245} |
| 443 | Lₐ₁₁ | L_{b212} | 444 | Lₐ₁₁ | L_{b245} |
| 445 | Lₐ₄₇ | L_{b212} | 446 | Lₐ₄₇ | L_{b245} |
| 447 | Lₐ₅₁ | L_{b212} | 448 | Lₐ₅₁ | L_{b245} |
| 449 | Lₐ₅₃ | L_{b212} | 450 | Lₐ₅₃ | L_{b245} |
| 451 | Lₐ₅₅ | L_{b212} | 452 | Lₐ₅₅ | L_{b245} |
| 453 | Lₐ₅₆ | L_{b212} | 454 | Lₐ₅₆ | L_{b245} |
| 455 | Lₐ₆₁ | L_{b212} | 456 | Lₐ₆₁ | L_{b245} |
| 457 | Lₐ₆₃ | L_{b212} | 458 | Lₐ₆₃ | L_{b245} |
| 459 | Lₐ₆₉ | L_{b212} | 460 | Lₐ₆₉ | L_{b245} |
| 461 | Lₐ₇₃ | L_{b212} | 462 | Lₐ₇₃ | L_{b245} |
| 463 | Lₐ₇₅ | L_{b212} | 464 | Lₐ₇₅ | L_{b245} |
| 465 | Lₐ₈₄ | L_{b212} | 466 | Lₐ₈₄ | L_{b245} |
| 467 | Lₐ₈₆ | L_{b212} | 468 | Lₐ₈₆ | L_{b245} |
| 469 | Lₐ₈₇ | L_{b212} | 470 | Lₐ₈₇ | L_{b245} |
| 471 | Lₐ₈₈ | L_{b212} | 472 | Lₐ₈₈ | L_{b245} |
| 473 | Lₐ₈₉ | L_{b212} | 474 | Lₐ₈₉ | L_{b245} |
| 475 | Lₐ₉₄ | L_{b212} | 476 | Lₐ₉₄ | L_{b245} |
| 477 | Lₐ₁₀₀ | L_{b212} | 478 | Lₐ₁₀₀ | L_{b245} |
| 479 | Lₐ₁₄₁ | L_{b212} | 480 | Lₐ₁₄₁ | L_{b245} |
| 481 | Lₐ₁₄₈ | L_{b212} | 482 | Lₐ₁₄₈ | L_{b245} |
| 483 | Lₐ₁₇₆ | L_{b212} | 484 | Lₐ₁₇₆ | L_{b245} |
| 485 | Lₐ₁₈₀ | L_{b212} | 486 | Lₐ₁₈₀ | L_{b245} |
| 487 | Lₐ₁₈₈ | L_{b212} | 488 | Lₐ₁₈₈ | L_{b245} |
| 489 | Lₐ₁₉₇ | L_{b212} | 490 | Lₐ₁₉₇ | L_{b245} |
| 491 | Lₐ₂₀₁ | L_{b212} | 492 | Lₐ₂₀₁ | L_{b245} |
| 493 | Lₐ₂₀₆ | L_{b212} | 494 | Lₐ₂₀₆ | L_{b245} |
| 495 | Lₐ₂₄₃ | L_{b212} | 496 | Lₐ₂₄₃ | L_{b245} |
| 497 | Lₐ₂₄₉ | L_{b212} | 498 | Lₐ₂₄₉ | L_{b245} |
| 499 | Lₐ₂₅₂ | L_{b212} | 500 | Lₐ₂₅₂ | L_{b245} |
| 501 | Lₐ₂₅₉ | L_{b212} | 502 | Lₐ₂₅₉ | L_{b245} |
| 503 | Lₐ₂₉₃ | L_{b212} | 504 | Lₐ₂₉₃ | L_{b245} |
| 505 | Lₐ₃₁₀ | L_{b212} | 506 | Lₐ₃₁₀ | L_{b245} |
| 507 | Lₐ₃₁₃ | L_{b212} | 508 | Lₐ₃₁₃ | L_{b245} |
| 509 | Lₐ₃₆₄ | L_{b212} | 510 | Lₐ₃₆₄ | L_{b245} |
| 511 | Lₐ₃₆₇ | L_{b212} | 512 | Lₐ₃₆₇ | L_{b245} |
| 513 | Lₐ₃₈₂ | L_{b212} | 514 | Lₐ₃₈₂ | L_{b245} |
| 515 | Lₐ₃₉₂ | L_{b212} | 516 | Lₐ₃₉₂ | L_{b245} |
| 517 | Lₐ₄₂₈ | L_{b212} | 518 | Lₐ₄₂₈ | L_{b245} |
| 519 | Lₐ₄₃₂ | L_{b212} | 520 | Lₐ₄₃₂ | L_{b245} |
| 521 | Lₐ₄₃₉ | L_{b212} | 522 | Lₐ₄₃₉ | L_{b245} |
| 523 | Lₐ₄₅₇ | L_{b212} | 524 | Lₐ₄₅₇ | L_{b245} |
| 525 | Lₐ₄₈₂ | L_{b212} | 526 | Lₐ₄₈₂ | L_{b245} |
| 527 | Lₐ₅₄₂ | L_{b212} | 528 | Lₐ₅₄₂ | L_{b245} |
| 529 | Lₐ₅₆₉ | L_{b212} | 530 | Lₐ₅₆₉ | L_{b245} |
| 531 | Lₐ₅₉₃ | L_{b212} | 532 | Lₐ₅₉₃ | L_{b245} |
| 533 | Lₐ₅₉₆ | L_{b212} | 534 | Lₐ₅₉₆ | L_{b245} |
| 535 | Lₐ₆₁₃ | L_{b212} | 536 | Lₐ₆₁₃ | L_{b245} |
| 537 | Lₐ₆₃₆ | L_{b212} | 538 | Lₐ₆₃₆ | L_{b245} |
| 539 | Lₐ₆₄₃ | L_{b212} | 540 | Lₐ₆₄₃ | L_{b245} |
| 541 | Lₐ₆₇₂ | L_{b212} | 542 | Lₐ₆₇₂ | L_{b245} |
| 543 | Lₐ₆₇₈ | L_{b212} | 544 | Lₐ₆₇₈ | L_{b245} |
| 545 | Lₐ₇₀₈ | L_{b212} | 546 | Lₐ₇₀₈ | L_{b245} |
| 547 | Lₐ₇₁₂ | L_{b212} | 548 | Lₐ₇₁₂ | L_{b245} |
| 549 | Lₐ₇₁₄ | L_{b212} | 550 | Lₐ₇₁₄ | L_{b245} |
| 551 | Lₐ₄ | L_{b268} | 552 | Lₐ₄ | L_{b295} |
| 553 | Lₐ₁₁ | L_{b268} | 554 | Lₐ₁₁ | L_{b295} |
| 555 | Lₐ₄₇ | L_{b268} | 556 | Lₐ₄₇ | L_{b295} |
| 557 | Lₐ₅₁ | L_{b268} | 558 | Lₐ₅₁ | L_{b295} |
| 559 | Lₐ₅₃ | L_{b268} | 560 | Lₐ₅₃ | L_{b295} |
| 561 | Lₐ₅₅ | L_{b268} | 562 | Lₐ₅₅ | L_{b295} |
| 563 | Lₐ₅₆ | L_{b268} | 564 | Lₐ₅₆ | L_{b295} |
| 565 | Lₐ₆₁ | L_{b268} | 566 | Lₐ₆₁ | L_{b295} |
| 567 | Lₐ₆₃ | L_{b268} | 568 | Lₐ₆₃ | L_{b295} |
| 569 | Lₐ₆₉ | L_{b268} | 570 | Lₐ₆₉ | L_{b295} |
| 571 | Lₐ₇₃ | L_{b268} | 572 | Lₐ₇₃ | L_{b295} |
| 573 | Lₐ₇₅ | L_{b268} | 574 | Lₐ₇₅ | L_{b295} |
| 575 | Lₐ₈₄ | L_{b268} | 576 | Lₐ₈₄ | L_{b295} |
| 577 | Lₐ₈₆ | L_{b268} | 578 | Lₐ₈₆ | L_{b295} |
| 579 | Lₐ₈₇ | L_{b268} | 580 | Lₐ₈₇ | L_{b295} |
| 581 | Lₐ₈₈ | L_{b268} | 582 | Lₐ₈₈ | L_{b295} |
| 583 | Lₐ₈₉ | L_{b268} | 584 | Lₐ₈₉ | L_{b295} |
| 585 | Lₐ₉₄ | L_{b268} | 586 | Lₐ₉₄ | L_{b295} |
| 587 | Lₐ₁₀₀ | L_{b268} | 588 | Lₐ₁₀₀ | L_{b295} |
| 589 | Lₐ₁₄₁ | L_{b268} | 590 | Lₐ₁₄₁ | L_{b295} |
| 591 | Lₐ₁₄₈ | L_{b268} | 592 | Lₐ₁₄₈ | L_{b295} |
| 593 | Lₐ₁₇₆ | L_{b268} | 594 | Lₐ₁₇₆ | L_{b295} |
| 595 | Lₐ₁₈₀ | L_{b268} | 596 | Lₐ₁₈₀ | L_{b295} |
| 597 | Lₐ₁₈₈ | L_{b268} | 598 | Lₐ₁₈₈ | L_{b295} |
| 599 | Lₐ₁₉₇ | L_{b268} | 600 | Lₐ₁₉₇ | L_{b295} |
| 601 | Lₐ₂₀₁ | L_{b268} | 602 | Lₐ₂₀₁ | L_{b295} |
| 603 | Lₐ₂₀₆ | L_{b268} | 604 | Lₐ₂₀₆ | L_{b295} |
| 605 | Lₐ₂₄₃ | L_{b268} | 606 | Lₐ₂₄₃ | L_{b295} |
| 607 | Lₐ₂₄₉ | L_{b268} | 608 | Lₐ₂₄₉ | L_{b295} |
| 609 | Lₐ₂₅₂ | L_{b268} | 610 | Lₐ₂₅₂ | L_{b295} |
| 611 | Lₐ₂₅₉ | L_{b268} | 612 | Lₐ₂₅₉ | L_{b295} |
| 613 | Lₐ₂₉₃ | L_{b268} | 614 | Lₐ₂₉₃ | L_{b295} |
| 615 | Lₐ₃₁₀ | L_{b268} | 616 | Lₐ₃₁₀ | L_{b295} |
| 617 | Lₐ₃₁₃ | L_{b268} | 618 | Lₐ₃₁₃ | L_{b295} |
| 619 | Lₐ₃₆₄ | L_{b268} | 620 | Lₐ₃₆₄ | L_{b295} |
| 621 | Lₐ₃₆₇ | L_{b268} | 622 | Lₐ₃₆₇ | L_{b295} |
| 623 | Lₐ₃₈₂ | L_{b268} | 624 | Lₐ₃₈₂ | L_{b295} |
| 625 | Lₐ₃₉₂ | L_{b268} | 626 | Lₐ₃₉₂ | L_{b295} |
| 627 | Lₐ₄₂₈ | L_{b268} | 628 | Lₐ₄₂₈ | L_{b295} |
| 629 | Lₐ₄₃₂ | L_{b268} | 630 | Lₐ₄₃₂ | L_{b295} |
| 631 | Lₐ₄₃₉ | L_{b268} | 632 | Lₐ₄₃₉ | L_{b295} |
| 633 | Lₐ₄₅₇ | L_{b268} | 634 | Lₐ₄₅₇ | L_{b295} |
| 635 | Lₐ₄₈₂ | L_{b268} | 636 | Lₐ₄₈₂ | L_{b295} |
| 637 | Lₐ₅₄₂ | L_{b268} | 638 | Lₐ₅₄₂ | L_{b295} |
| 639 | Lₐ₅₆₉ | L_{b268} | 640 | Lₐ₅₆₉ | L_{b295} |
| 641 | Lₐ₅₉₃ | L_{b268} | 642 | Lₐ₅₉₃ | L_{b295} |
| 643 | Lₐ₅₉₆ | L_{b268} | 644 | Lₐ₅₉₆ | L_{b295} |
| 645 | Lₐ₆₁₃ | L_{b268} | 646 | Lₐ₆₁₃ | L_{b295} |
| 647 | Lₐ₆₃₆ | L_{b268} | 648 | Lₐ₆₃₆ | L_{b295} |
| 649 | Lₐ₆₄₃ | L_{b268} | 650 | Lₐ₆₄₃ | L_{b295} |
| 651 | Lₐ₆₇₂ | L_{b268} | 652 | Lₐ₆₇₂ | L_{b295} |
| 653 | Lₐ₆₇₈ | L_{b268} | 654 | Lₐ₆₇₈ | L_{b295} |
| 655 | Lₐ₇₀₈ | L_{b268} | 656 | Lₐ₇₀₈ | L_{b295} |
| 657 | Lₐ₇₁₂ | L_{b268} | 658 | Lₐ₇₁₂ | L_{b295} |
| 659 | Lₐ₇₁₄ | L_{b268} | 660 | Lₐ₇₁₄ | L_{b295} |
| 661 | Lₐ₄ | L_{b268} | 662 | Lₐ₄ | L_{b295} |
| 663 | Lₐ₁₁ | L_{b268} | 664 | Lₐ₁₁ | L_{b295} |
| 665 | Lₐ₄₇ | L_{b268} | 666 | Lₐ₄₇ | L_{b295} |
| 667 | Lₐ₅₁ | L_{b268} | 668 | Lₐ₅₁ | L_{b295} |
| 669 | Lₐ₅₃ | L_{b268} | 670 | Lₐ₅₃ | L_{b295} |
| 671 | Lₐ₅₅ | L_{b268} | 672 | Lₐ₅₅ | L_{b295} |
| 673 | Lₐ₅₆ | L_{b268} | 674 | Lₐ₅₆ | L_{b295} |
| 675 | Lₐ₆₁ | L_{b268} | 676 | Lₐ₆₁ | L_{b295} |
| 677 | Lₐ₆₃ | L_{b268} | 678 | Lₐ₆₃ | L_{b295} |
| 679 | Lₐ₆₉ | L_{b268} | 680 | Lₐ₆₉ | L_{b295} |
| 681 | Lₐ₇₃ | L_{b268} | 682 | Lₐ₇₃ | L_{b295} |
| 683 | Lₐ₇₅ | L_{b268} | 684 | Lₐ₇₅ | L_{b295} |
| 685 | Lₐ₈₄ | L_{b268} | 686 | Lₐ₈₄ | L_{b295} |
| 687 | Lₐ₈₆ | L_{b268} | 688 | Lₐ₈₆ | L_{b295} |
| 689 | Lₐ₈₇ | L_{b268} | 690 | Lₐ₈₇ | L_{b295} |
| 691 | Lₐ₈₈ | L_{b268} | 692 | Lₐ₈₈ | L_{b295} |
| 693 | Lₐ₈₉ | L_{b268} | 694 | Lₐ₈₉ | L_{b295} |
| 695 | Lₐ₉₄ | L_{b268} | 696 | Lₐ₉₄ | L_{b295} |
| 697 | Lₐ₁₀₀ | L_{b268} | 698 | Lₐ₁₀₀ | L_{b295} |
| 699 | Lₐ₁₄₁ | L_{b268} | 700 | Lₐ₁₄₁ | L_{b295} |
| 701 | Lₐ₁₄₈ | L_{b268} | 702 | Lₐ₁₄₈ | L_{b295} |
| 703 | Lₐ₁₇₆ | L_{b268} | 704 | Lₐ₁₇₆ | L_{b295} |
| 705 | Lₐ₁₈₀ | L_{b268} | 706 | Lₐ₁₈₀ | L_{b295} |
| 707 | Lₐ₁₈₈ | L_{b268} | 708 | Lₐ₁₈₈ | L_{b295} |
| 709 | Lₐ₁₉₇ | L_{b268} | 710 | Lₐ₁₉₇ | L_{b295} |
| 711 | Lₐ₂₀₁ | L_{b268} | 712 | Lₐ₂₀₁ | L_{b295} |
| 713 | Lₐ₂₀₆ | L_{b268} | 714 | Lₐ₂₀₆ | L_{b295} |
| 715 | Lₐ₂₄₃ | L_{b268} | 716 | Lₐ₂₄₃ | L_{b295} |
| 717 | Lₐ₂₄₉ | L_{b268} | 718 | Lₐ₂₄₉ | L_{b295} |
| 719 | Lₐ₂₅₂ | L_{b268} | 720 | Lₐ₂₅₂ | L_{b295} |
| 721 | Lₐ₂₅₉ | L_{b268} | 722 | Lₐ₂₅₉ | L_{b295} |
| 723 | Lₐ₂₉₃ | L_{b268} | 724 | Lₐ₂₉₃ | L_{b295} |
| 725 | Lₐ₃₁₀ | L_{b268} | 726 | Lₐ₃₁₀ | L_{b295} |
| 727 | Lₐ₃₁₃ | L_{b268} | 728 | Lₐ₃₁₃ | L_{b295} |
| 729 | Lₐ₃₆₄ | L_{b268} | 730 | Lₐ₃₆₄ | L_{b295} |
| 731 | Lₐ₃₆₇ | L_{b268} | 732 | Lₐ₃₆₇ | L_{b295} |
| 733 | Lₐ₃₈₂ | L_{b268} | 734 | Lₐ₃₈₂ | L_{b295} |
| 735 | Lₐ₃₉₂ | L_{b268} | 736 | Lₐ₃₉₂ | L_{b295} |
| 737 | Lₐ₄₂₈ | L_{b268} | 738 | Lₐ₄₂₈ | L_{b295} |
| 739 | Lₐ₄₃₂ | L_{b268} | 740 | Lₐ₄₃₂ | L_{b295} |
| 741 | Lₐ₄₃₉ | L_{b268} | 742 | Lₐ₄₃₉ | L_{b295} |
| 743 | Lₐ₄₅₇ | L_{b268} | 744 | Lₐ₄₅₇ | L_{b295} |
| 745 | Lₐ₄₈₂ | L_{b268} | 746 | Lₐ₄₈₂ | L_{b295} |
| 747 | Lₐ₅₄₂ | L_{b268} | 748 | Lₐ₅₄₂ | L_{b295} |
| 749 | Lₐ₅₆₉ | L_{b268} | 750 | Lₐ₅₆₉ | L_{b295} |
| 751 | Lₐ₅₉₃ | L_{b268} | 752 | Lₐ₅₉₃ | L_{b295} |
| 753 | Lₐ₅₉₆ | L_{b268} | 754 | Lₐ₅₉₆ | L_{b295} |
| 755 | Lₐ₆₁₃ | L_{b268} | 756 | Lₐ₆₁₃ | L_{b295} |
| 757 | Lₐ₆₃₆ | L_{b268} | 758 | Lₐ₆₃₆ | L_{b295} |
| 759 | Lₐ₆₄₃ | L_{b268} | 760 | Lₐ₆₄₃ | L_{b295} |
| 761 | Lₐ₆₇₂ | L_{b268} | 762 | Lₐ₆₇₂ | L_{b295} |
| 763 | Lₐ₆₇₈ | L_{b268} | 764 | Lₐ₆₇₈ | L_{b295} |
| 765 | Lₐ₇₀₈ | L_{b268} | 766 | Lₐ₇₀₈ | L_{b295} |
| 767 | Lₐ₇₁₂ | L_{b268} | 768 | Lₐ₇₁₂ | L_{b295} |
| 769 | Lₐ₇₁₄ | L_{b268} | 770 | Lₐ₇₁₄ | L_{b295} |
| 771 | Lₐ₃₇₉ | L_{b1} | 772 | Lₐ₃₉₈ | L_{b1} |
| 773 | Lₐ₃₇₉ | L_{b31} | 774 | Lₐ₃₉₈ | L_{b31} |
| 775 | Lₐ₃₇₉ | L_{b57} | 776 | Lₐ₃₉₈ | L_{b57} |
| 777 | Lₐ₃₇₉ | L_{b88} | 778 | Lₐ₃₉₈ | L_{b88} |
| 779 | Lₐ₃₇₉ | L_{b122} | 780 | Lₐ₃₉₈ | L_{b122} |
| 781 | Lₐ₃₇₉ | L_{b126} | 782 | Lₐ₃₉₈ | L_{b126} |
| 783 | Lₐ₃₇₉ | L_{b135} | 784 | Lₐ₃₉₈ | L_{b135} |
| 785 | Lₐ₃₇₉ | L_{b165} | 786 | Lₐ₃₉₈ | L_{b165} |
| 787 | Lₐ₃₇₉ | L_{b212} | 788 | Lₐ₃₉₈ | L_{b212} |
| 789 | Lₐ₃₇₉ | L_{b245} | 790 | Lₐ₃₉₈ | L_{b245} |
| 791 | Lₐ₃₇₉ | L_{b268} | 792 | Lₐ₃₉₈ | L_{b268} |
| 793 | Lₐ₃₇₉ | L_{b295} | 794 | Lₐ₃₉₈ | L_{b295}. |

16. An electroluminescent device, comprising:
an anode,
a cathode, and
an organic layer disposed between the anode and the cathode, wherein the organic layer comprises the metal complex of claim 1.

17. The device of claim 16, wherein the organic layer is an emissive layer, and the metal complex is an emissive material.

18. The device of claim 16, wherein the electroluminescent device emits dark red light, infrared light or white light.

19. The device of claim 17, wherein the emissive layer further comprises at least one host material;
preferably, at least one host material comprises at least one chemical group selected from the group consisting of: benzene, pyridine, pyrimidine, triazine, carbazole, azacarbazole, indolocarbazole, dibenzothiophene, azadibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof;
more preferably, the emissive layer further comprises a first host material and a second host material;
the first host material is selected from the group consisting of Compound 1-1-1 to Compound 1-1-104, Compound 1-2-1 to Compound 1-2-100, and Compound 1-3-1 to Compound Jan. 3, 1962: 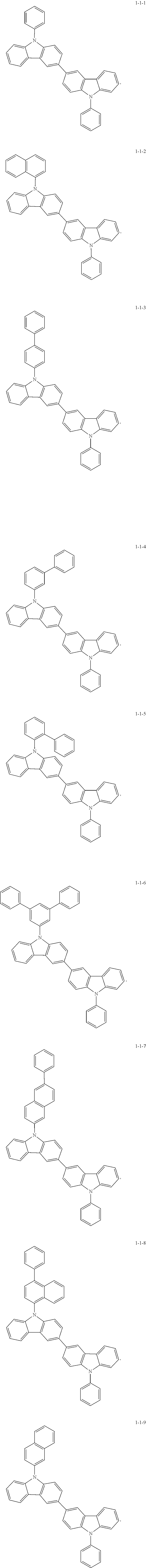 [chemical structure] [chemical structure] [chemical structure] 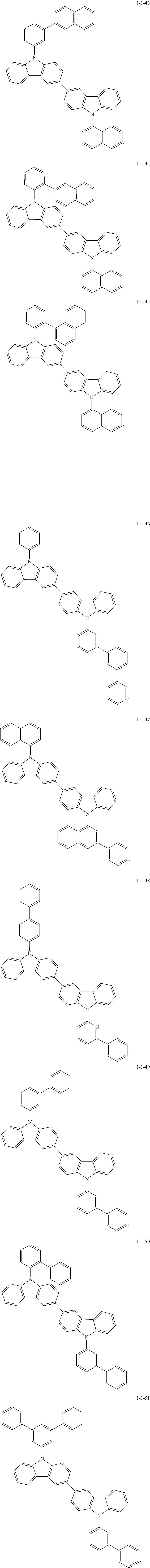 [chemical structure] 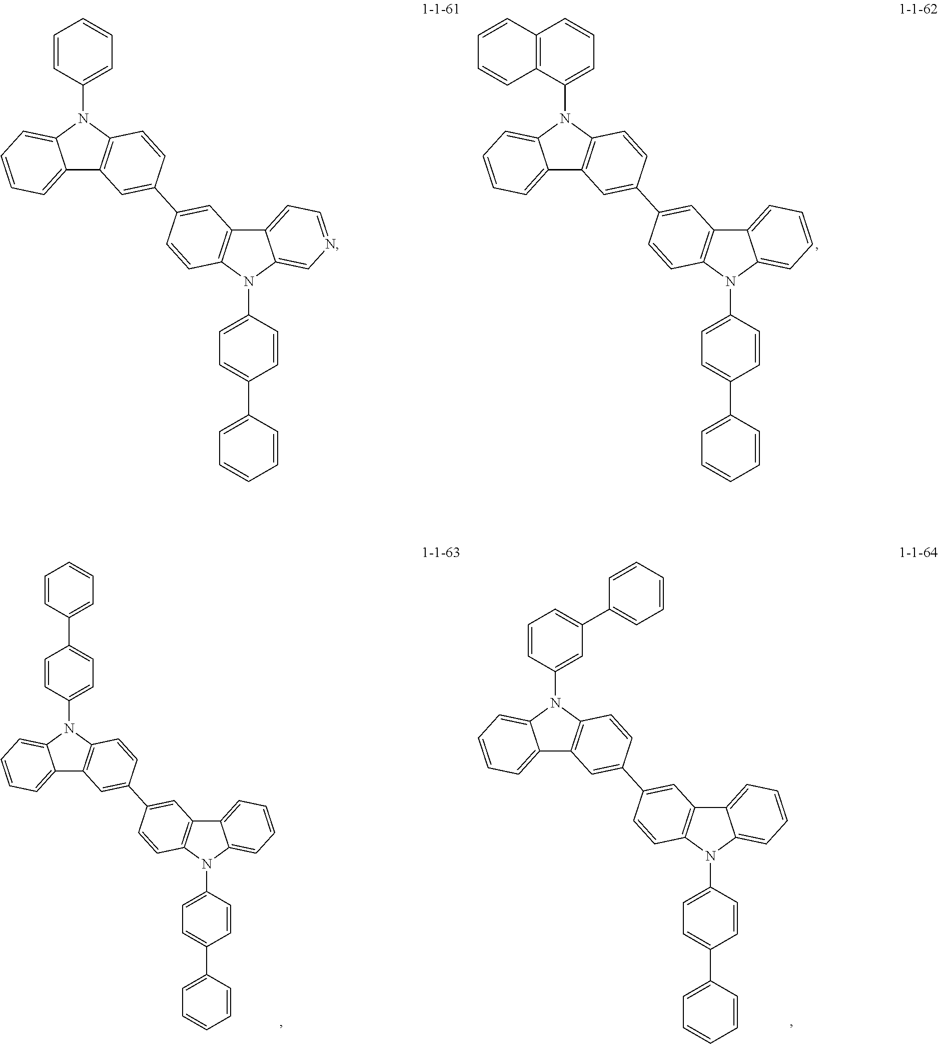 [SMILES: c1ccc(-c2ccc(-n3c4ccc(-c5ccc6c(c5)c5ccccc5n6-c5ccccc5)cc4c4ccncc43)cc2)cc1 ; c1ccc(-c2ccc(-n3c4ccccc4c4cc(-c5ccc6c(c5)c5ccccc5n6-c5cccc6ccccc56)ccc43)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1] 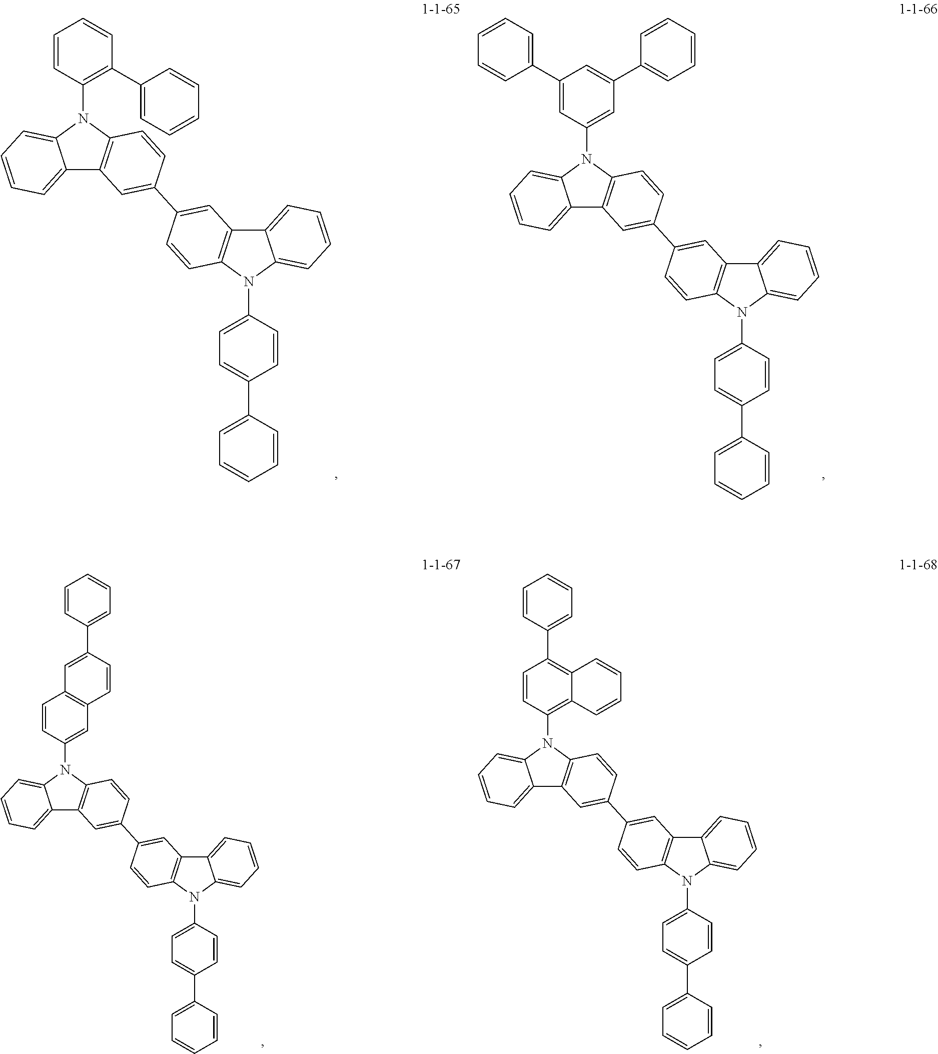 [SMILES: c1ccc(-c2ccc(-n3c4ccccc4c4cc(-c5ccc6c(c5)c5ccccc5n6-c5ccccc5-c5ccccc5)ccc43)cc2)cc1 ; c1ccc(-c2ccc(-n3c4ccccc4c4cc(-c5ccc6c(c5)c5ccccc5n6-c5cc(-c6ccccc6)cc(-c6ccccc6)c5)ccc43)cc2)cc1 ; c1ccc(-c2ccc(-n3c4ccccc4c4cc(-c5ccc6c(c5)c5ccccc5n6-c5ccc6cc(-c7ccccc7)ccc6c5)ccc43)cc2)cc1 ; c1ccc(-c2ccc(-n3c4ccccc4c4cc(-c5ccc6c(c5)c5ccccc5n6-c5ccc(-c6ccccc6)c6ccccc56)ccc43)cc2)cc1] 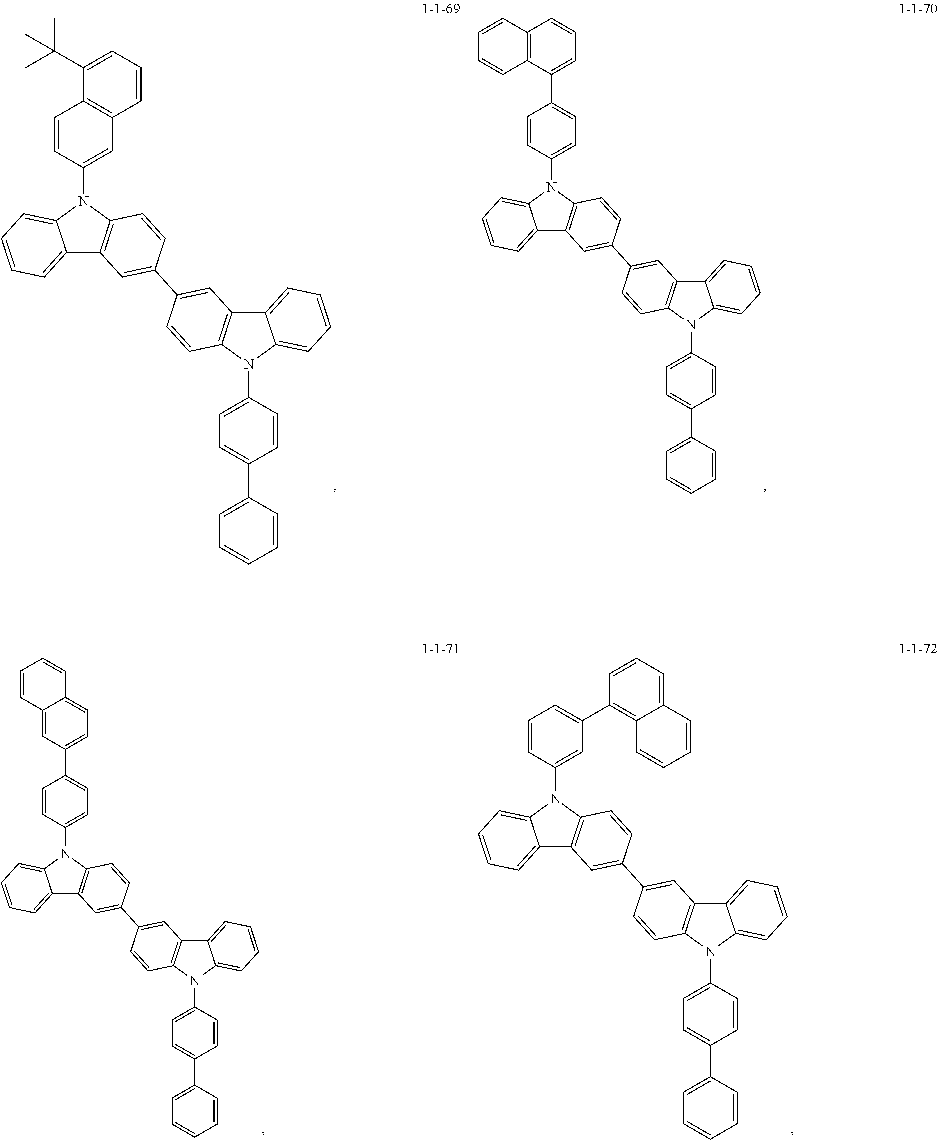 [SMILES: CC(C)(C)c1cccc2cc(-n3c4ccccc4c4cc(-c5ccc6c(c5)c5ccccc5n6-c5ccc(-c6ccccc6)cc5)ccc43)ccc12 ; c1ccc(-c2ccc(-n3c4ccccc4c4cc(-c5ccc6c(c5)c5ccccc5n6-c5ccc(-c6cccc7ccccc67)cc5)ccc43)cc2)cc1 ; c1ccc(-c2ccc(-n3c4ccccc4c4cc(-c5ccc6c(c5)c5ccccc5n6-c5ccc(-c6ccc7ccccc7c6)cc5)ccc43)cc2)cc1 ; c1ccc(-c2ccc(-n3c4ccccc4c4cc(-c5ccc6c(c5)c5ccccc5n6-c5cccc(-c6cccc7ccccc67)c5)ccc43)cc2)cc1] 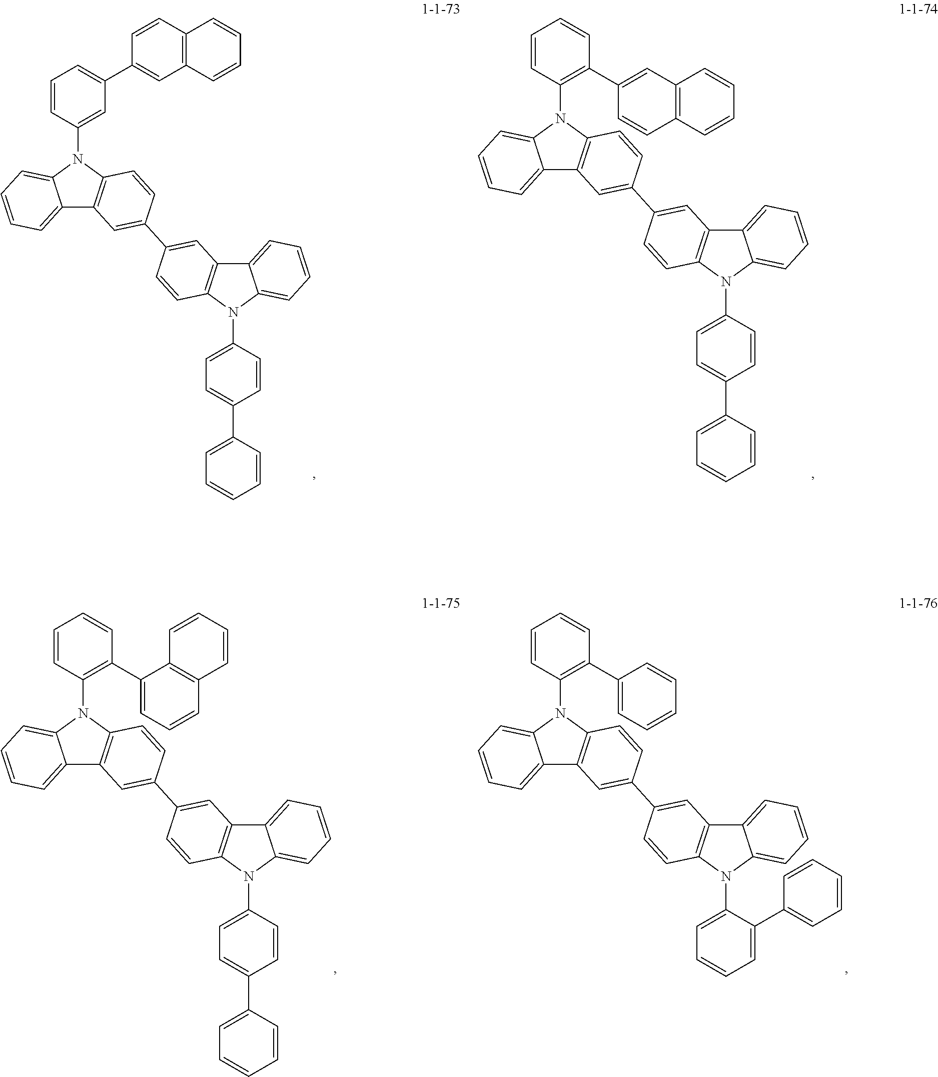 [SMILES: c1ccc(-c2ccc(-n3c4ccccc4c4cc(-c5ccc6c(c5)c5ccccc5n6-c5cccc(-c6ccc7ccccc7c6)c5)ccc43)cc2)cc1 ; c1ccc(-c2ccc(-n3c4ccccc4c4cc(-c5ccc6c(c5)c5ccccc5n6-c5ccccc5-c5ccc6ccccc6c5)ccc43)cc2)cc1 ; c1ccc(-c2ccc(-n3c4ccccc4c4cc(-c5ccc6c(c5)c5ccccc5n6-c5ccccc5-c5cccc6ccccc56)ccc43)cc2)cc1 ; c1ccc(-c2ccccc2-n2c3ccccc3c3cc(-c4ccc5c(c4)c4ccccc4n5-c4ccccc4-c4ccccc4)ccc32)cc1] 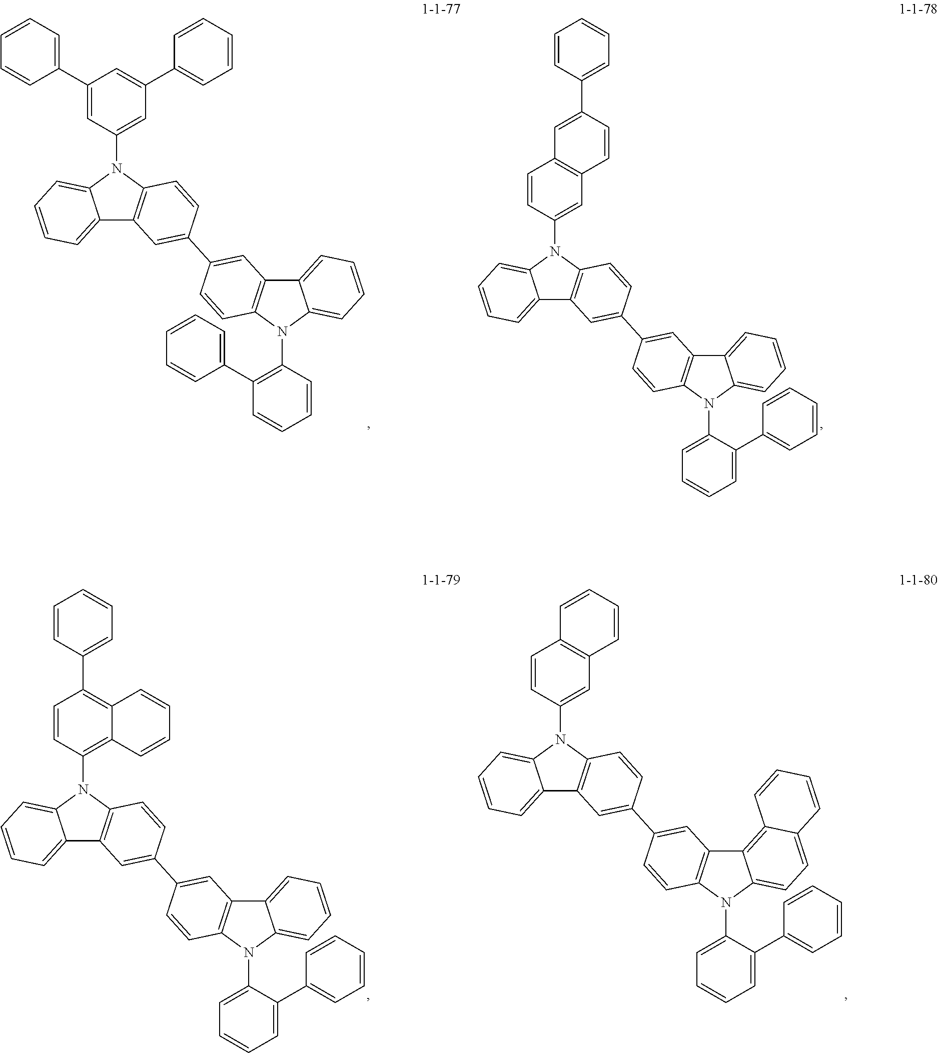 [SMILES: c1ccc(-c2cc(-c3ccccc3)cc(-n3c4ccccc4c4cc(-c5ccc6c(c5)c5ccccc5n6-c5ccccc5-c5ccccc5)ccc43)c2)cc1 ; c1ccc(-c2ccc3cc(-n4c5ccccc5c5cc(-c6ccc7c(c6)c6ccccc6n7-c6ccccc6-c6ccccc6)ccc54)ccc3c2)cc1 ; c1ccc(-c2ccccc2-n2c3ccccc3c3cc(-c4ccc5c(c4)c4ccccc4n5-c4ccc(-c5ccccc5)c5ccccc45)ccc32)cc1 ; c1ccc(-c2ccccc2-n2c3ccc(-c4ccc5c(c4)c4ccccc4n5-c4ccc5ccccc5c4)cc3c3c4ccccc4ccc32)cc1] 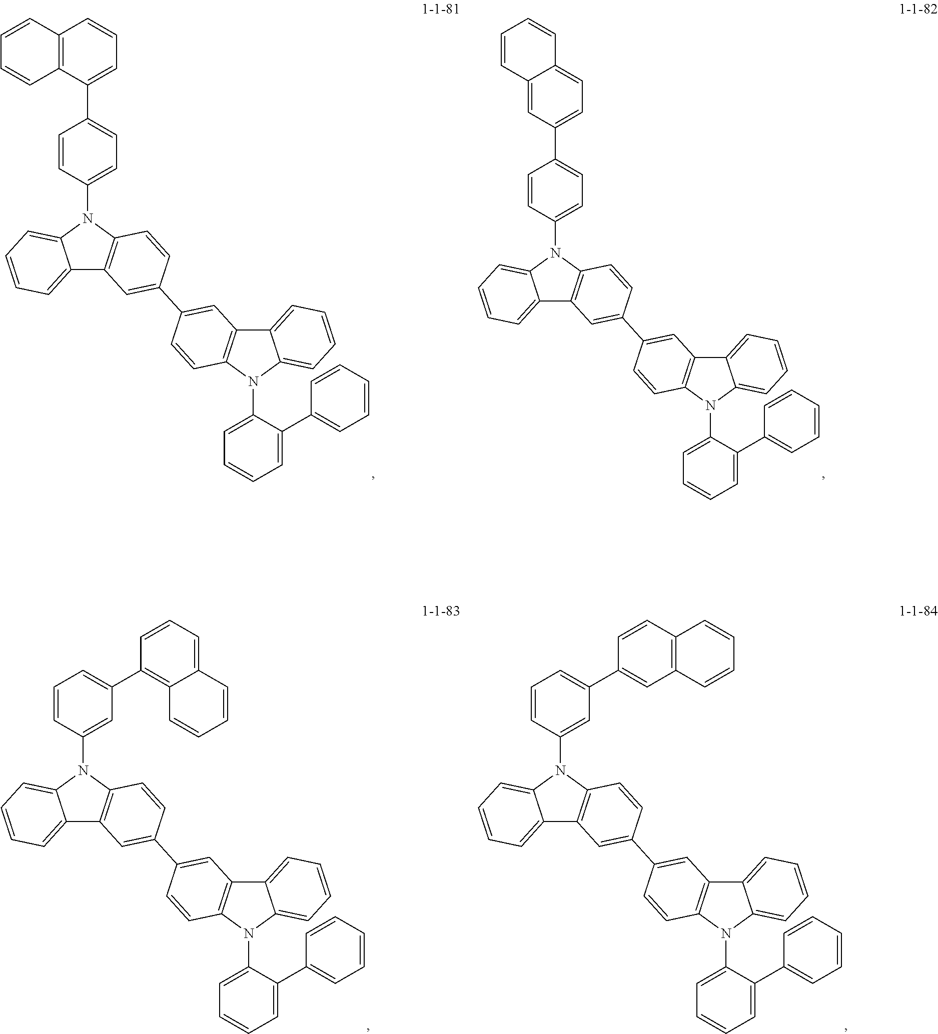 [SMILES: c1ccc(-c2ccccc2-n2c3ccccc3c3cc(-c4ccc5c(c4)c4ccccc4n5-c4ccc(-c5cccc6ccccc56)cc4)ccc32)cc1 ; c1ccc(-c2ccccc2-n2c3ccccc3c3cc(-c4ccc5c(c4)c4ccccc4n5-c4ccc(-c5ccc6ccccc6c5)cc4)ccc32)cc1 ; c1ccc(-c2ccccc2-n2c3ccccc3c3cc(-c4ccc5c(c4)c4ccccc4n5-c4cccc(-c5cccc6ccccc56)c4)ccc32)cc1 ; c1ccc(-c2ccccc2-n2c3ccccc3c3cc(-c4ccc5c(c4)c4ccccc4n5-c4cccc(-c5ccc6ccccc6c5)c4)ccc32)cc1] 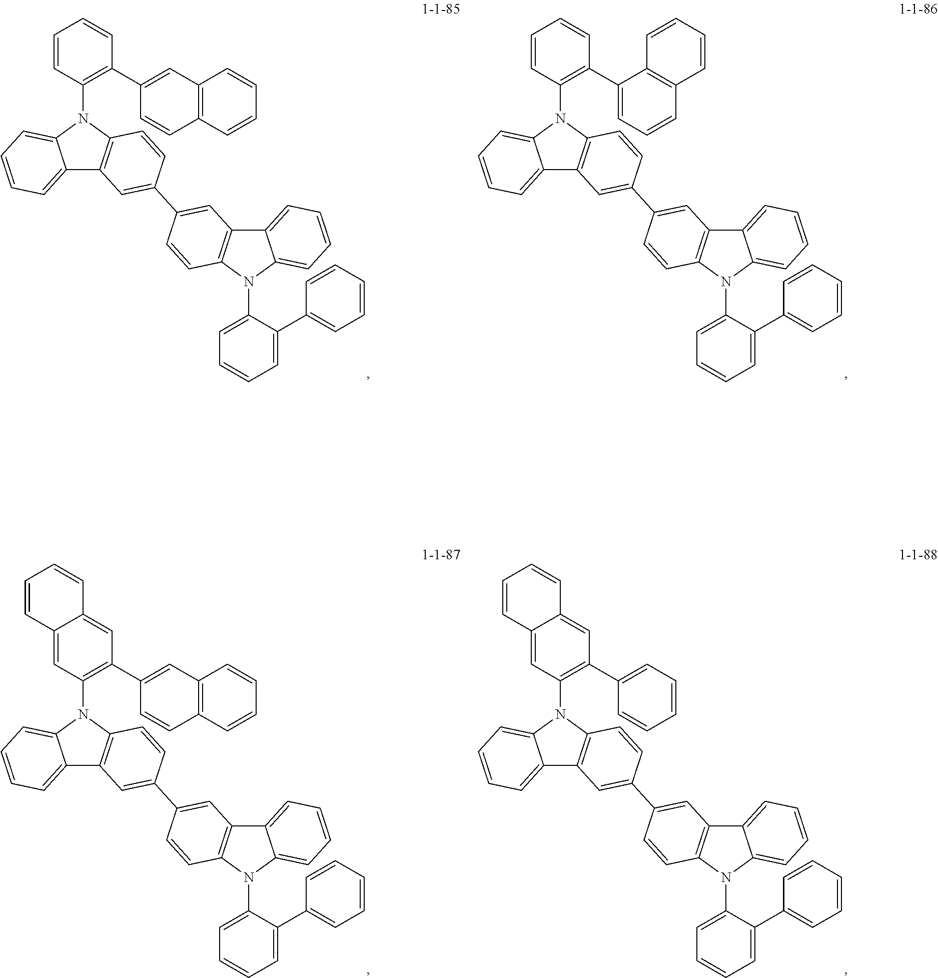 [SMILES: c1ccc(-c2ccccc2-n2c3ccccc3c3cc(-c4ccc5c(c4)c4ccccc4n5-c4ccccc4-c4ccc5ccccc5c4)ccc32)cc1 ; c1ccc(-c2ccccc2-n2c3ccccc3c3cc(-c4ccc5c(c4)c4ccccc4n5-c4ccccc4-c4cccc5ccccc45)ccc32)cc1 ; c1ccc(-c2ccccc2-n2c3ccccc3c3cc(-c4ccc5c(c4)c4ccccc4n5-c4cc5ccccc5cc4-c4ccc5ccccc5c4)ccc32)cc1 ; c1ccc(-c2ccccc2-n2c3ccccc3c3cc(-c4ccc5c(c4)c4ccccc4n5-c4cc5ccccc5cc4-c4ccccc4)ccc32)cc1] 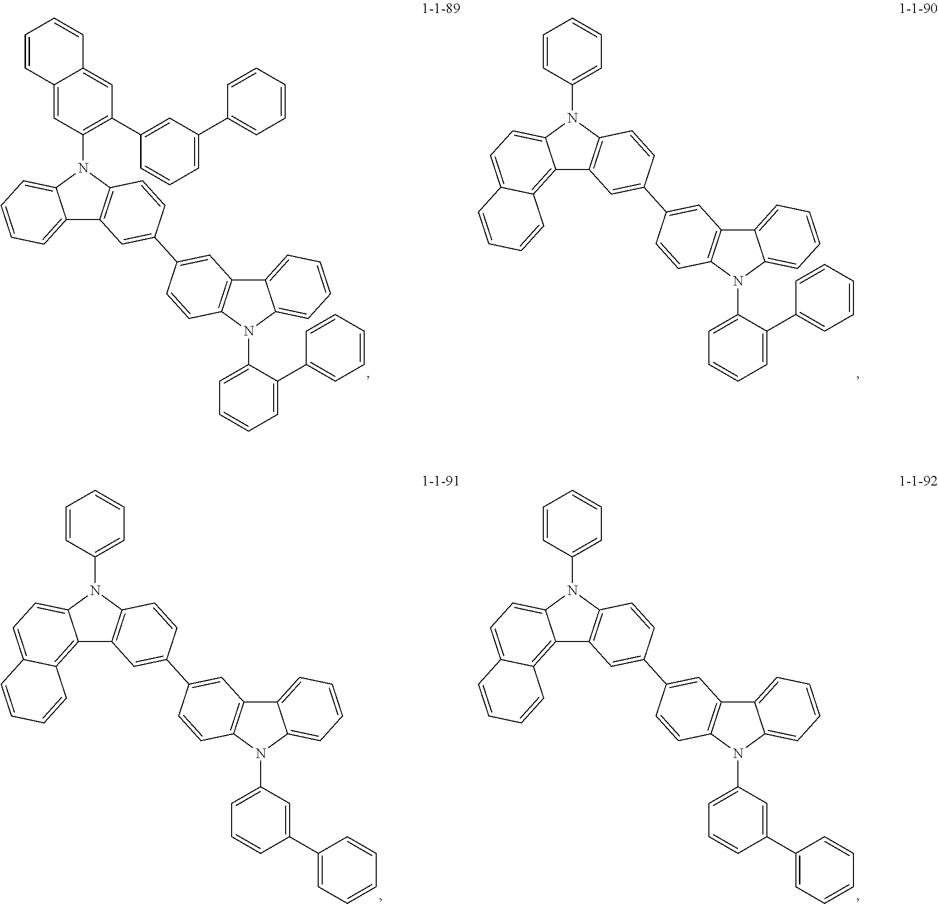 [SMILES: c1ccc(-c2cccc(-c3cc4ccccc4cc3-n3c4ccccc4c4cc(-c5ccc6c(c5)c5ccccc5n6-c5ccccc5-c5ccccc5)ccc43)c2)cc1 ; c1ccc(-c2ccccc2-n2c3ccccc3c3cc(-c4ccc5c(c4)c4c6ccccc6ccc4n5-c4ccccc4)ccc32)cc1 ; c1ccc(-c2cccc(-n3c4ccccc4c4cc(-c5ccc6c(c5)c5c7ccccc7ccc5n6-c5ccccc5)ccc43)c2)cc1 ; c1ccc(-c2cccc(-n3c4ccccc4c4cc(-c5ccc6c(c5)c5c7ccccc7ccc5n6-c5ccccc5)ccc43)c2)cc1] 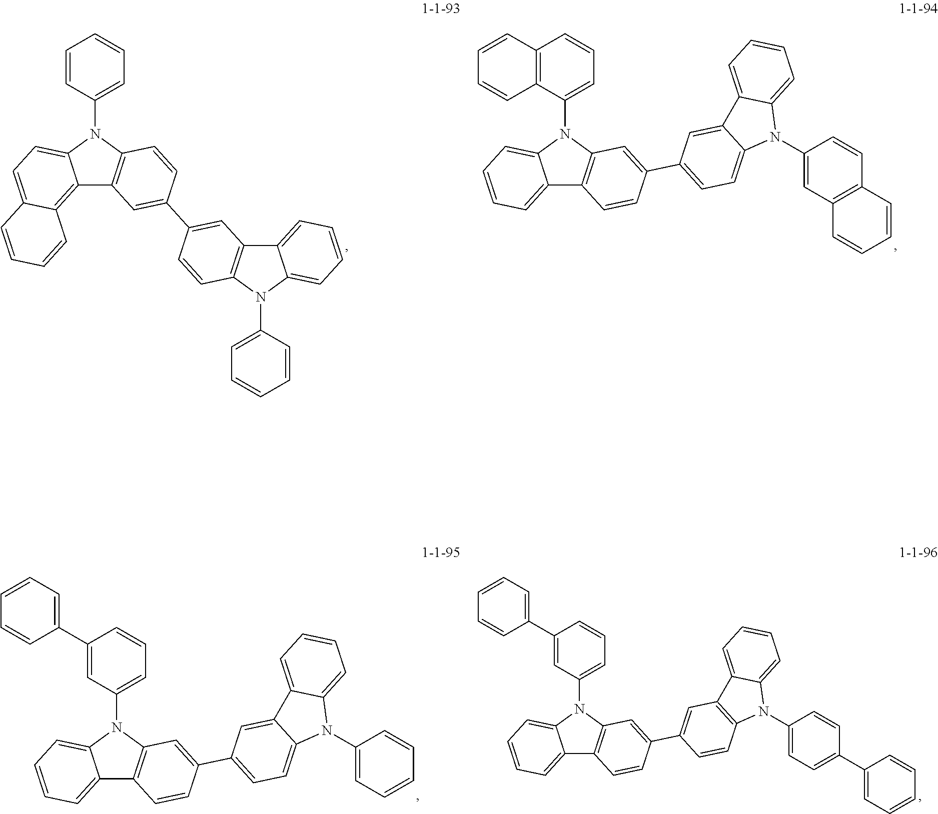 [SMILES: c1ccc(-n2c3ccccc3c3cc(-c4ccc5c(c4)c4c6ccccc6ccc4n5-c4ccccc4)ccc32)cc1 ; c1ccc2cc(-n3c4ccccc4c4cc(-c5ccc6c7ccccc7n(-c7cccc8ccccc78)c6c5)ccc43)ccc2c1 ; c1ccc(-c2cccc(-n3c4ccccc4c4ccc(-c5ccc6c(c5)c5ccccc5n6-c5ccccc5)cc43)c2)cc1 ; c1ccc(-c2ccc(-n3c4ccccc4c4cc(-c5ccc6c7ccccc7n(-c7cccc(-c8ccccc8)c7)c6c5)ccc43)cc2)cc1] 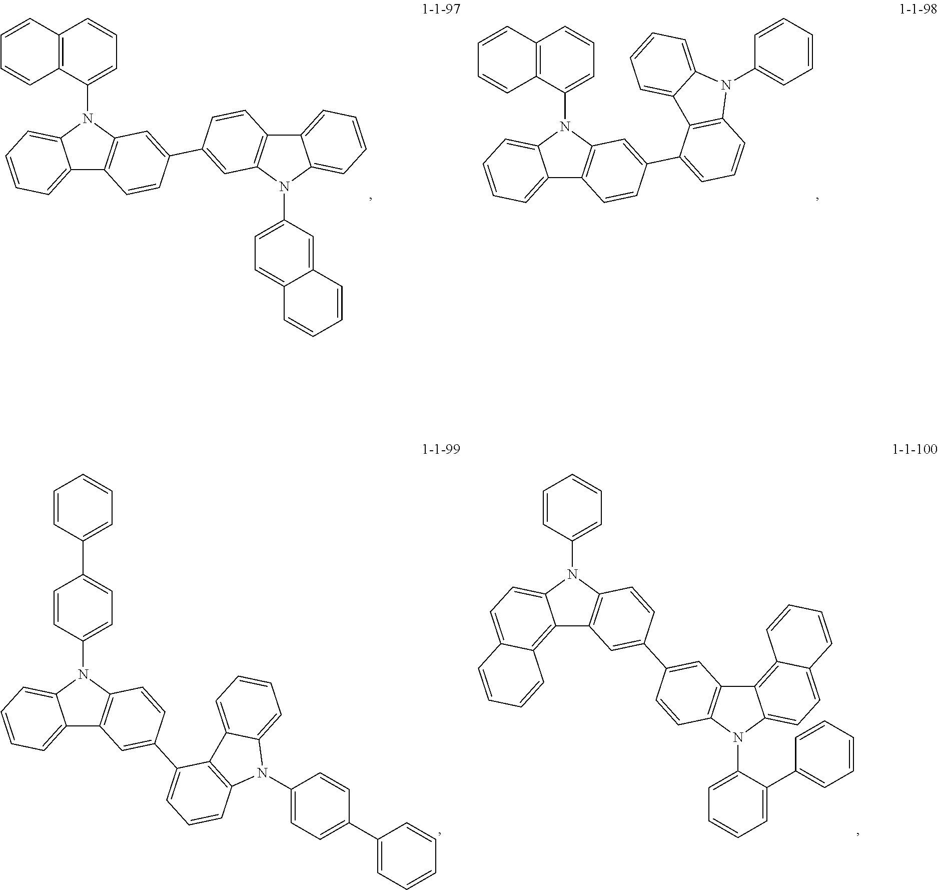 [SMILES: c1ccc2cc(-n3c4ccccc4c4ccc(-c5ccc6c7ccccc7n(-c7cccc8ccccc78)c6c5)cc43)ccc2c1 ; c1ccc(-n2c3ccccc3c3c(-c4ccc5c6ccccc6n(-c6cccc7ccccc67)c5c4)cccc32)cc1 ; c1ccc(-c2ccc(-n3c4ccccc4c4cc(-c5cccc6c5c5ccccc5n6-c5ccc(-c6ccccc6)cc5)ccc43)cc2)cc1 ; c1ccc(-c2ccccc2-n2c3ccc(-c4ccc5c(c4)c4c6ccccc6ccc4n5-c4ccccc4)cc3c3c4ccccc4ccc32)cc1] 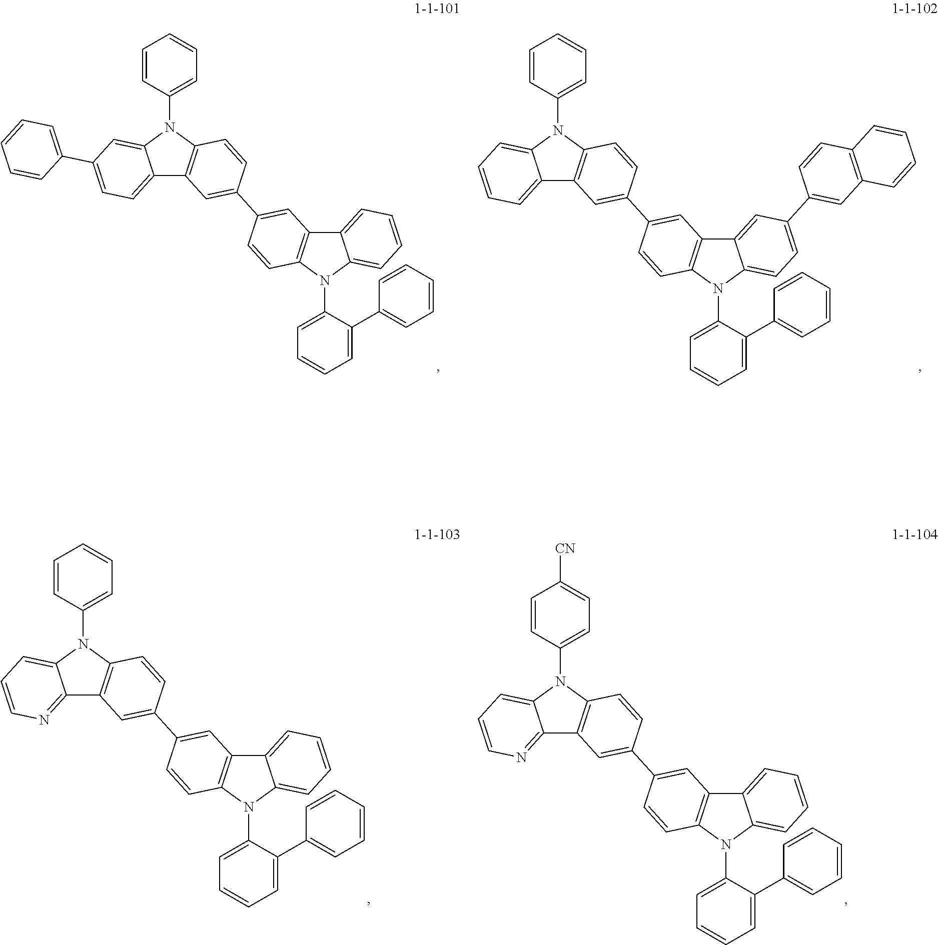 [SMILES: c1ccc(-c2ccc3c4cc(-c5ccc6c(c5)c5ccccc5n6-c5ccccc5-c5ccccc5)ccc4n(-c4ccccc4)c3c2)cc1 ; c1ccc(-c2ccccc2-n2c3ccc(-c4ccc5ccccc5c4)cc3c3cc(-c4ccc5c(c4)c4ccccc4n5-c4ccccc4)ccc32)cc1 ; c1ccc(-c2ccccc2-n2c3ccccc3c3cc(-c4ccc5c(c4)c4ncccc4n5-c4ccccc4)ccc32)cc1 ; N#Cc1ccc(-n2c3ccc(-c4ccc5c(c4)c4ccccc4n5-c4ccccc4-c4ccccc4)cc3c3ncccc32)cc1] 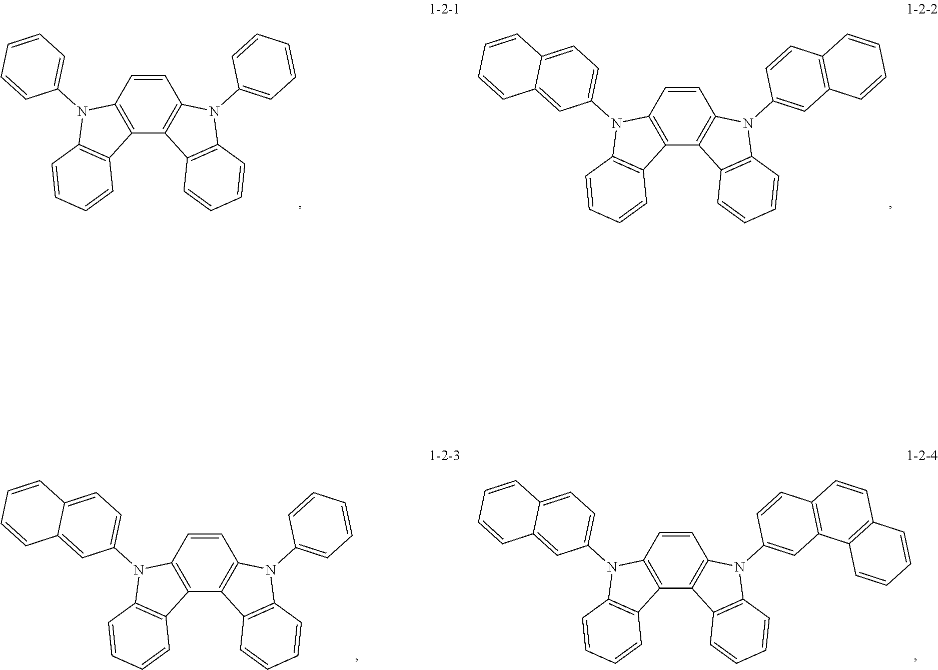 [SMILES: c1ccc(-n2c3ccccc3c3c4c5ccccc5n(-c5ccccc5)c4ccc32)cc1 ; c1ccc2cc(-n3c4ccccc4c4c5c6ccccc6n(-c6ccc7ccccc7c6)c5ccc43)ccc2c1 ; c1ccc(-n2c3ccccc3c3c4c5ccccc5n(-c5ccc6ccccc6c5)c4ccc32)cc1 ; c1ccc2cc(-n3c4ccccc4c4c5c6ccccc6n(-c6ccc7ccc8ccccc8c7c6)c5ccc43)ccc2c1] 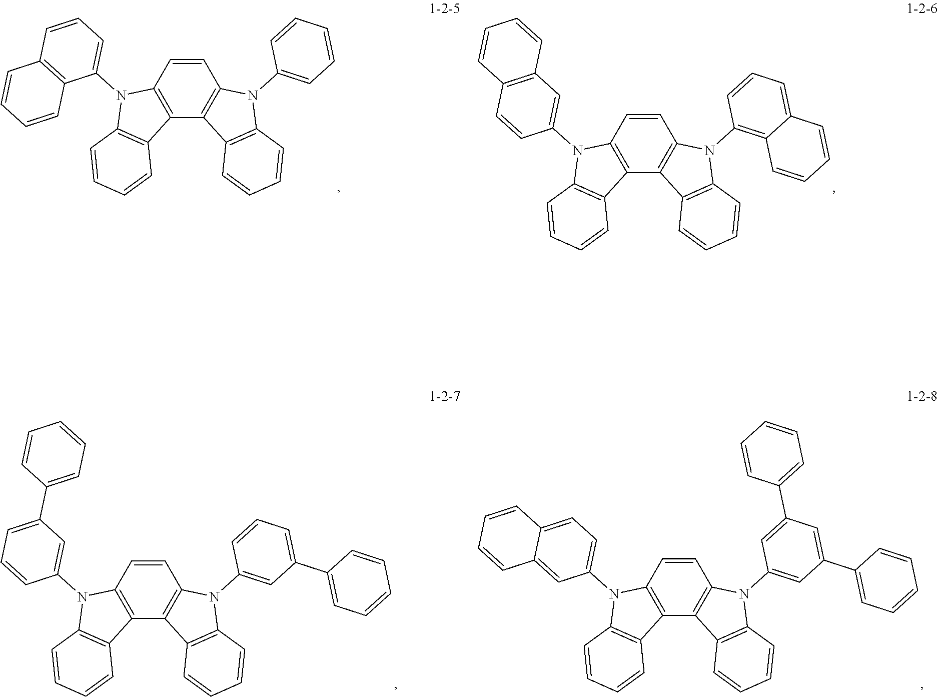 [SMILES: c1ccc(-n2c3ccccc3c3c4c5ccccc5n(-c5cccc6ccccc56)c4ccc32)cc1 ; c1ccc2cc(-n3c4ccccc4c4c5c6ccccc6n(-c6cccc7ccccc67)c5ccc43)ccc2c1 ; c1ccc(-c2cccc(-n3c4ccccc4c4c5c6ccccc6n(-c6cccc(-c7ccccc7)c6)c5ccc43)c2)cc1 ; c1ccc(-c2cc(-c3ccccc3)cc(-n3c4ccccc4c4c5c6ccccc6n(-c6ccc7ccccc7c6)c5ccc43)c2)cc1] 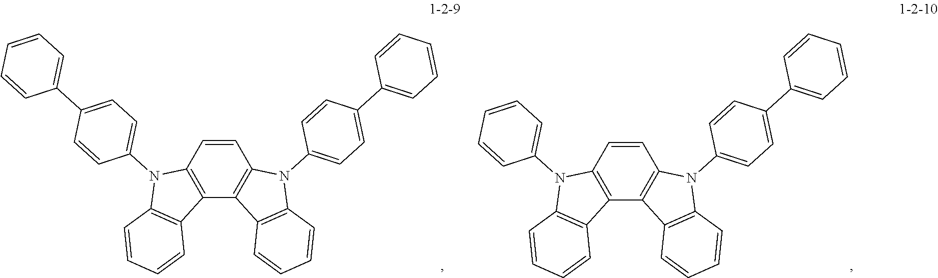 [SMILES: c1ccc(-c2ccc(-n3c4ccccc4c4c5c6ccccc6n(-c6ccc(-c7ccccc7)cc6)c5ccc43)cc2)cc1 ; c1ccc(-c2ccc(-n3c4ccccc4c4c5c6ccccc6n(-c6ccccc6)c5ccc43)cc2)cc1] 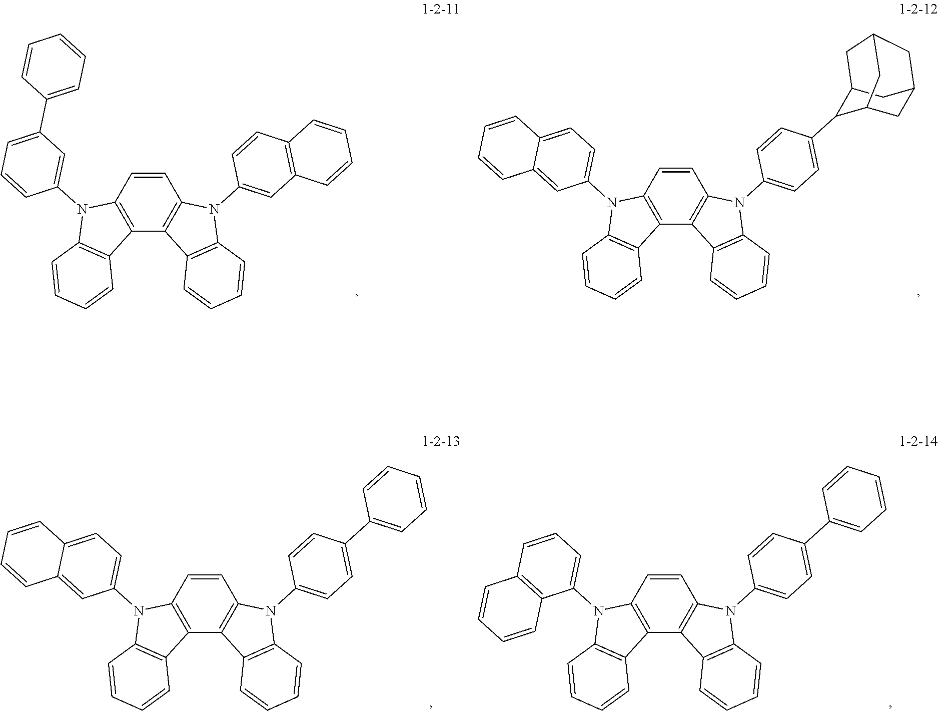 [SMILES: c1ccc(-c2cccc(-n3c4ccccc4c4c5c6ccccc6n(-c6ccc7ccccc7c6)c5ccc43)c2)cc1 ; c1ccc2cc(-n3c4ccccc4c4c5c6ccccc6n(-c6ccc(C7C8CC9CC(C8)CC7C9)cc6)c5ccc43)ccc2c1 ; c1ccc(-c2ccc(-n3c4ccccc4c4c5c6ccccc6n(-c6ccc7ccccc7c6)c5ccc43)cc2)cc1 ; c1ccc(-c2ccc(-n3c4ccccc4c4c5c6ccccc6n(-c6cccc7ccccc67)c5ccc43)cc2)cc1] 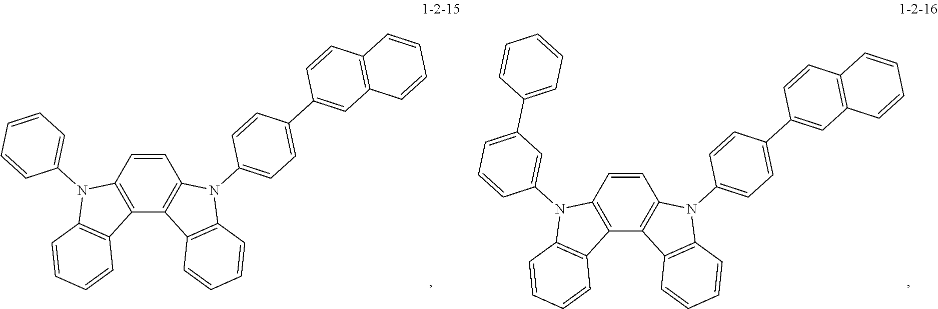 [SMILES: c1ccc(-n2c3ccccc3c3c4c5ccccc5n(-c5ccc(-c6ccc7ccccc7c6)cc5)c4ccc32)cc1 ; c1ccc(-c2cccc(-n3c4ccccc4c4c5c6ccccc6n(-c6ccc(-c7ccc8ccccc8c7)cc6)c5ccc43)c2)cc1] 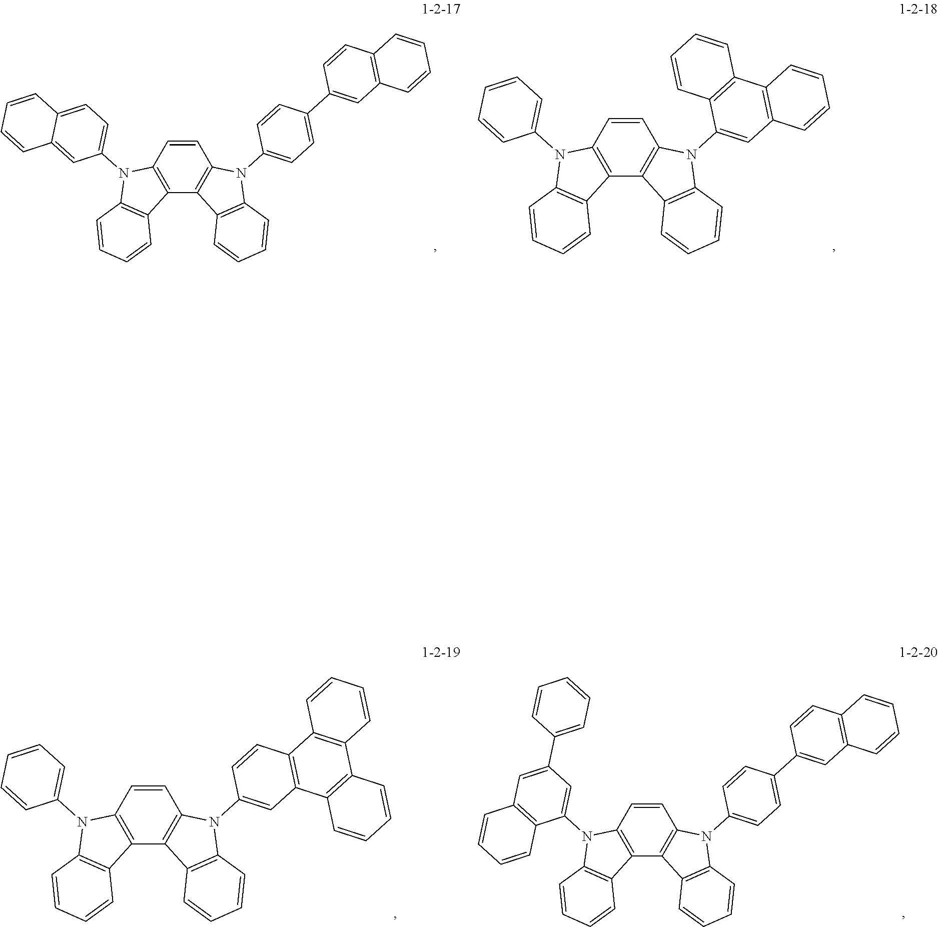 [SMILES: c1ccc2cc(-c3ccc(-n4c5ccccc5c5c6c7ccccc7n(-c7ccc8ccccc8c7)c6ccc54)cc3)ccc2c1 ; c1ccc(-n2c3ccccc3c3c4c5ccccc5n(-c5cc6ccccc6c6ccccc56)c4ccc32)cc1 ; c1ccc(-n2c3ccccc3c3c4c5ccccc5n(-c5ccc6c7ccccc7c7ccccc7c6c5)c4ccc32)cc1 ; c1ccc(-c2cc(-n3c4ccccc4c4c5c6ccccc6n(-c6ccc(-c7ccc8ccccc8c7)cc6)c5ccc43)c3ccccc3c2)cc1] 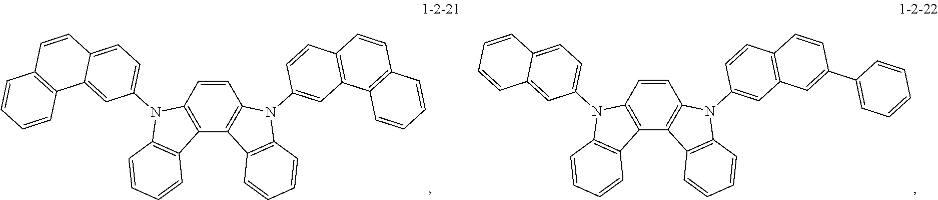 [SMILES: c1ccc2c(c1)ccc1ccc(-n3c4ccccc4c4c5c6ccccc6n(-c6ccc7ccc8ccccc8c7c6)c5ccc43)cc12 ; c1ccc(-c2ccc3ccc(-n4c5ccccc5c5c6c7ccccc7n(-c7ccc8ccccc8c7)c6ccc54)cc3c2)cc1] 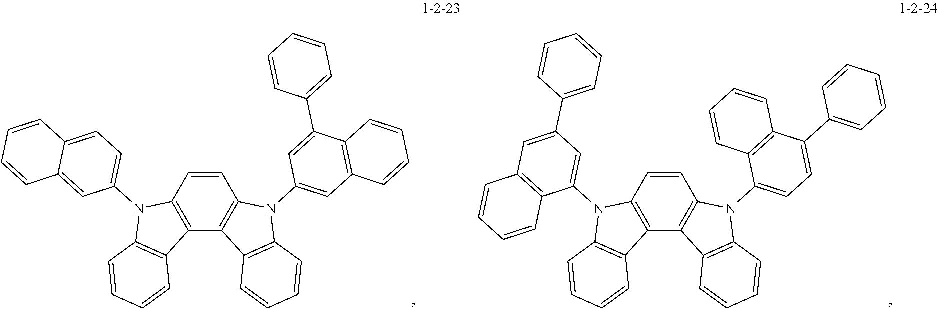 [SMILES: c1ccc(-c2cc(-n3c4ccccc4c4c5c6ccccc6n(-c6ccc7ccccc7c6)c5ccc43)cc3ccccc23)cc1 ; c1ccc(-c2cc(-n3c4ccccc4c4c5c6ccccc6n(-c6ccc(-c7ccccc7)c7ccccc67)c5ccc43)c3ccccc3c2)cc1] 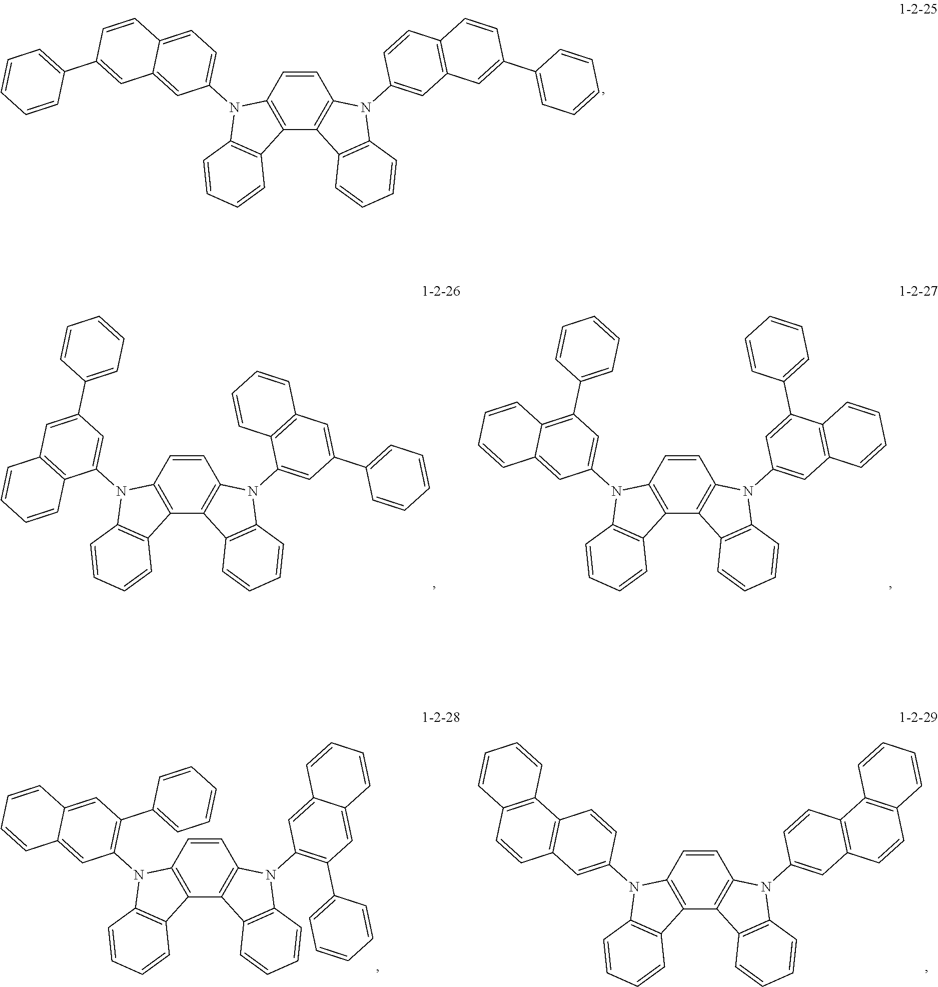 [SMILES: c1ccc(-c2ccc3ccc(-n4c5ccccc5c5c6c7ccccc7n(-c7ccc8ccc(-c9ccccc9)cc8c7)c6ccc54)cc3c2)cc1 ; c1ccc(-c2cc(-n3c4ccccc4c4c5c6ccccc6n(-c6cc(-c7ccccc7)cc7ccccc67)c5ccc43)c3ccccc3c2)cc1 ; c1ccc(-c2cc(-n3c4ccccc4c4c5c6ccccc6n(-c6cc(-c7ccccc7)c7ccccc7c6)c5ccc43)cc3ccccc23)cc1 ; c1ccc(-c2cc3ccccc3cc2-n2c3ccccc3c3c4c5ccccc5n(-c5cc6ccccc6cc5-c5ccccc5)c4ccc32)cc1 ; c1ccc2c(c1)ccc1cc(-n3c4ccccc4c4c5c6ccccc6n(-c6ccc7c(ccc8ccccc87)c6)c5ccc43)ccc12] 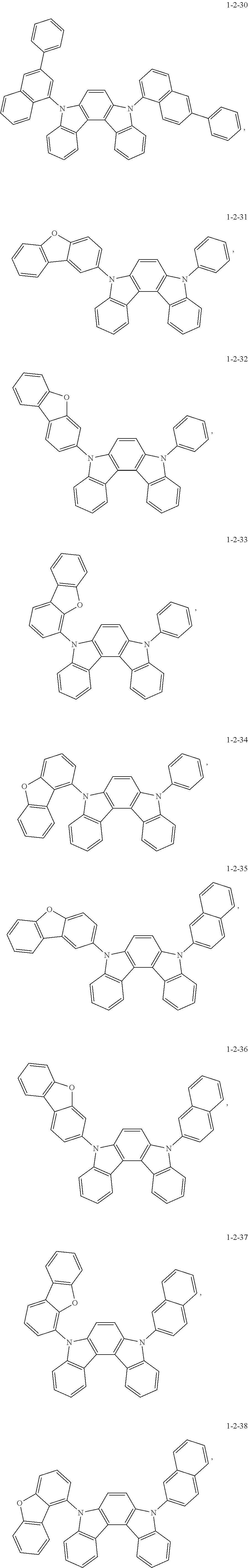 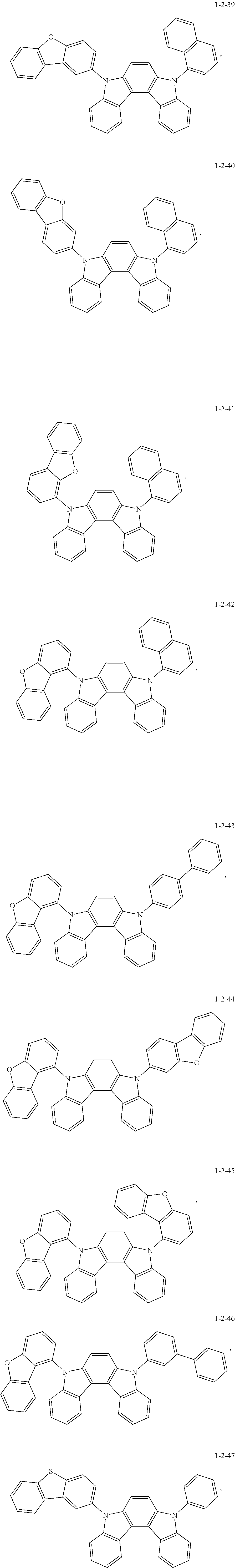 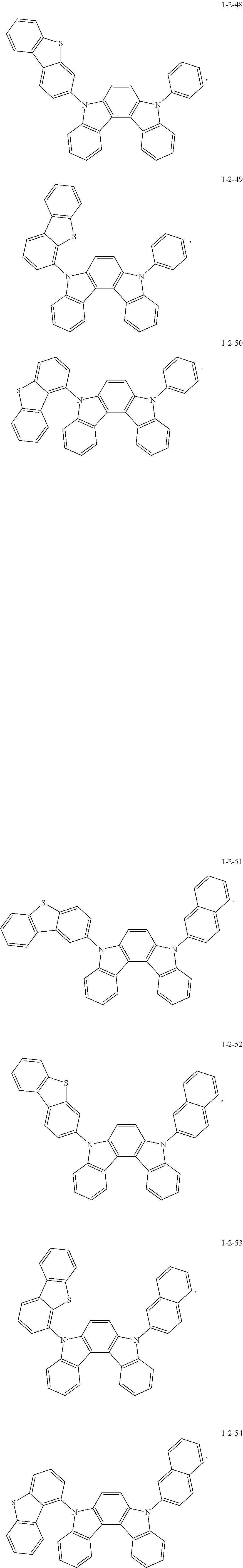 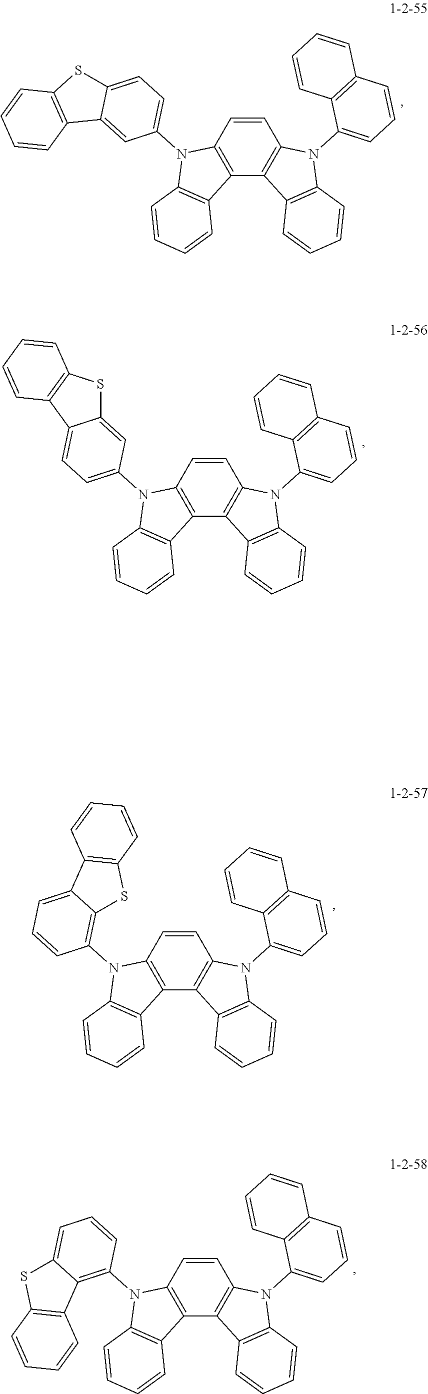 [SMILES: c1ccc2c(-n3c4ccccc4c4c5c6ccccc6n(-c6ccc7sc8ccccc8c7c6)c5ccc43)cccc2c1 ; c1ccc2c(-n3c4ccccc4c4c5c6ccccc6n(-c6ccc7c(c6)sc6ccccc67)c5ccc43)cccc2c1 ; c1ccc2c(-n3c4ccccc4c4c5c6ccccc6n(-c6cccc7c6sc6ccccc67)c5ccc43)cccc2c1 ; c1ccc2c(-n3c4ccccc4c4c5c6ccccc6n(-c6cccc7sc8ccccc8c67)c5ccc43)cccc2c1] 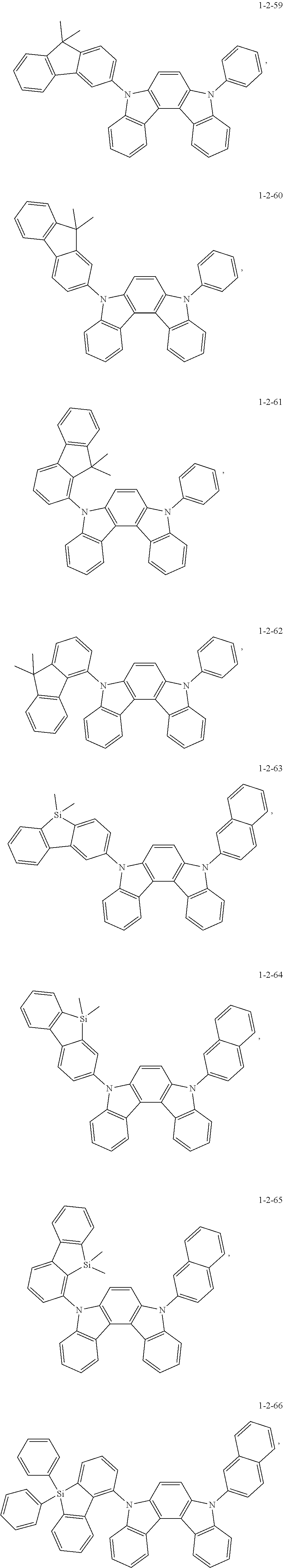 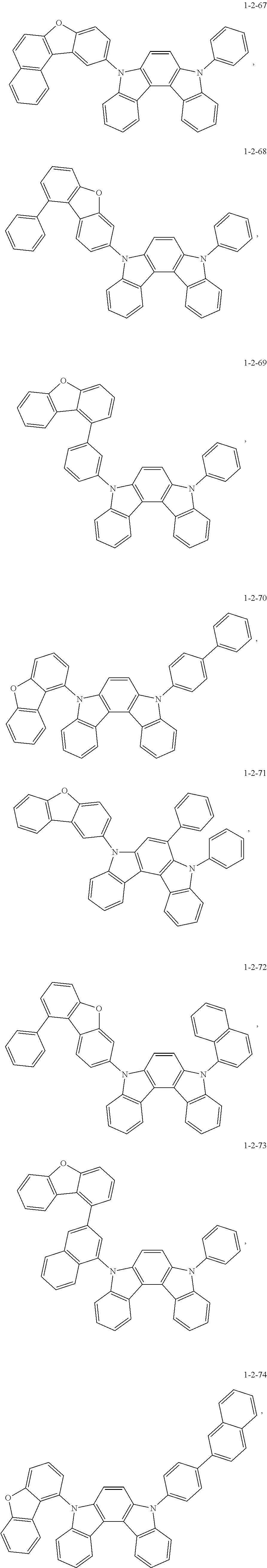 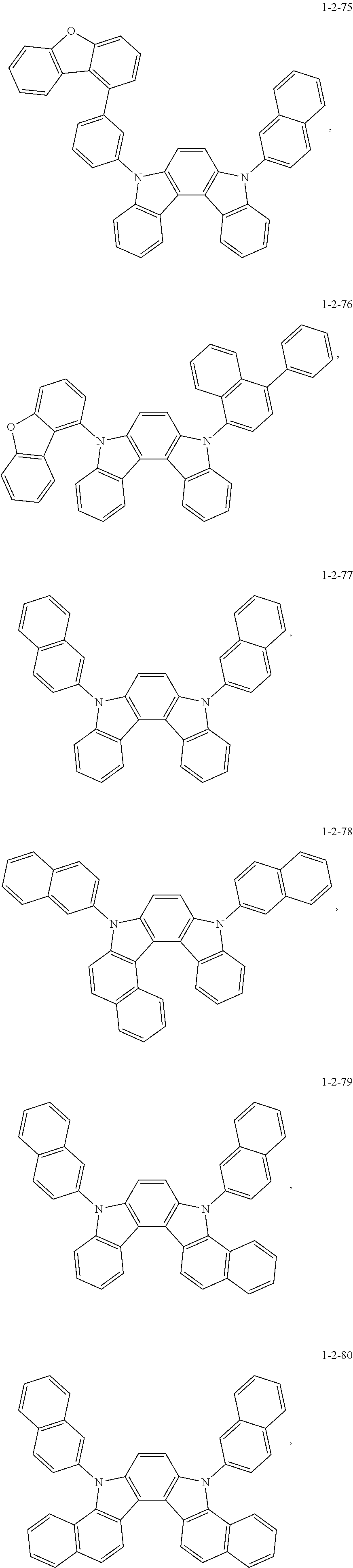 [SMILES: c1cc(-c2cccc3oc4ccccc4c23)cc(-n2c3ccccc3c3c4c5ccccc5n(-c5ccc6ccccc6c5)c4ccc32)c1 ; c1ccc(-c2ccc(-n3c4ccccc4c4c5c6ccccc6n(-c6cccc7oc8ccccc8c67)c5ccc43)c3ccccc23)cc1 ; c1ccc2cc(-n3c4ccccc4c4c5c6ccccc6n(-c6ccc7ccccc7c6)c5ccc43)ccc2c1 ; c1ccc2cc(-n3c4ccccc4c4c5c6c7ccccc7ccc6n(-c6ccc7ccccc7c6)c5ccc43)ccc2c1 ; c1ccc2cc(-n3c4ccccc4c4c5c6ccc7ccccc7c6n(-c6ccc7ccccc7c6)c5ccc43)ccc2c1 ; c1ccc2cc(-n3c4ccc5c(c6ccc7ccccc7c6n5-c5ccc6ccccc6c5)c4c4ccc5ccccc5c43)ccc2c1] 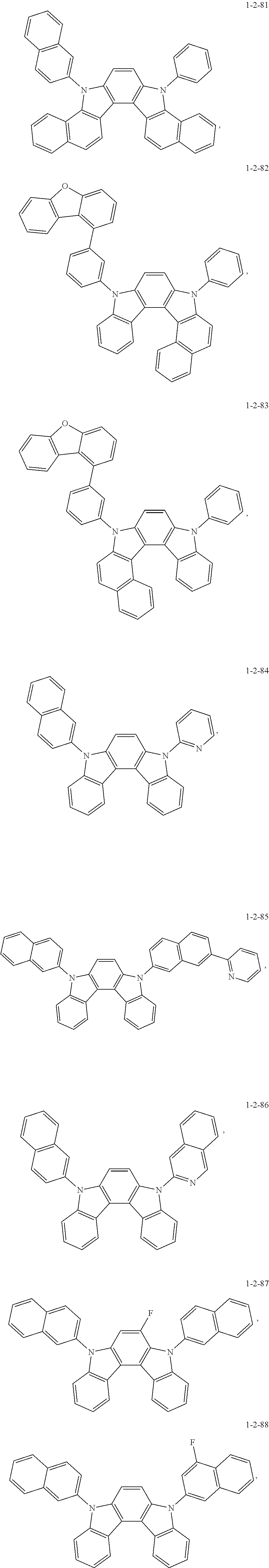 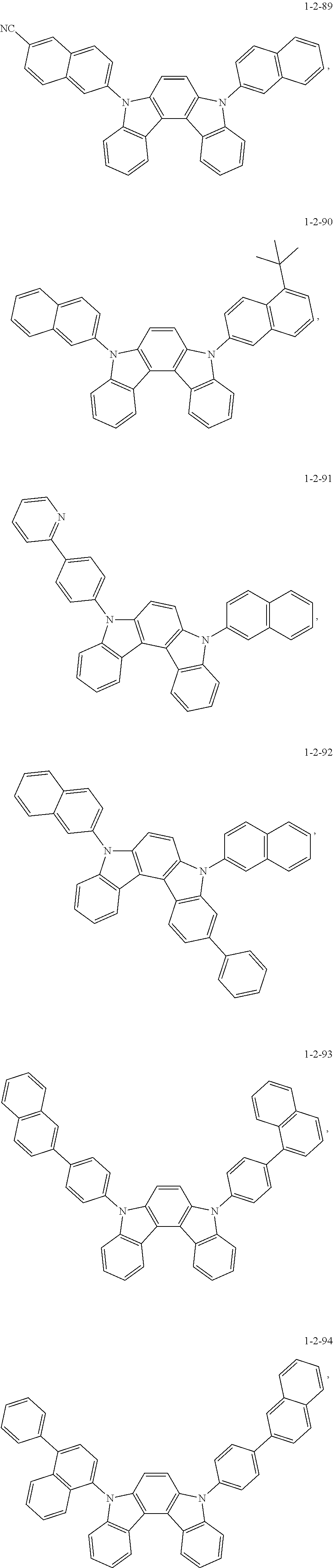 [SMILES: N#Cc1ccc2cc(-n3c4ccccc4c4c5c6ccccc6n(-c6ccc7ccccc7c6)c5ccc43)ccc2c1 ; CC(C)(C)c1cccc2cc(-n3c4ccccc4c4c5c6ccccc6n(-c6ccc7ccccc7c6)c5ccc43)ccc12 ; c1ccc(-c2ccc(-n3c4ccccc4c4c5c6ccccc6n(-c6ccc7ccccc7c6)c5ccc43)cc2)nc1 ; c1ccc(-c2ccc3c4c5c6ccccc6n(-c6ccc7ccccc7c6)c5ccc4n(-c4ccc5ccccc5c4)c3c2)cc1 ; c1ccc2cc(-c3ccc(-n4c5ccccc5c5c6c7ccccc7n(-c7ccc(-c8cccc9ccccc89)cc7)c6ccc54)cc3)ccc2c1 ; c1ccc(-c2ccc(-n3c4ccccc4c4c5c6ccccc6n(-c6ccc(-c7ccc8ccccc8c7)cc6)c5ccc43)c3ccccc23)cc1] 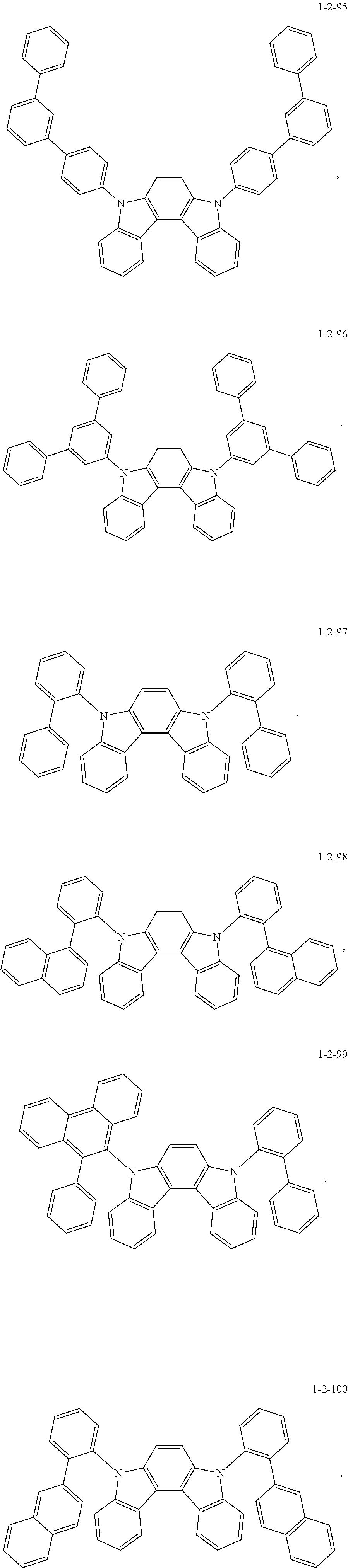 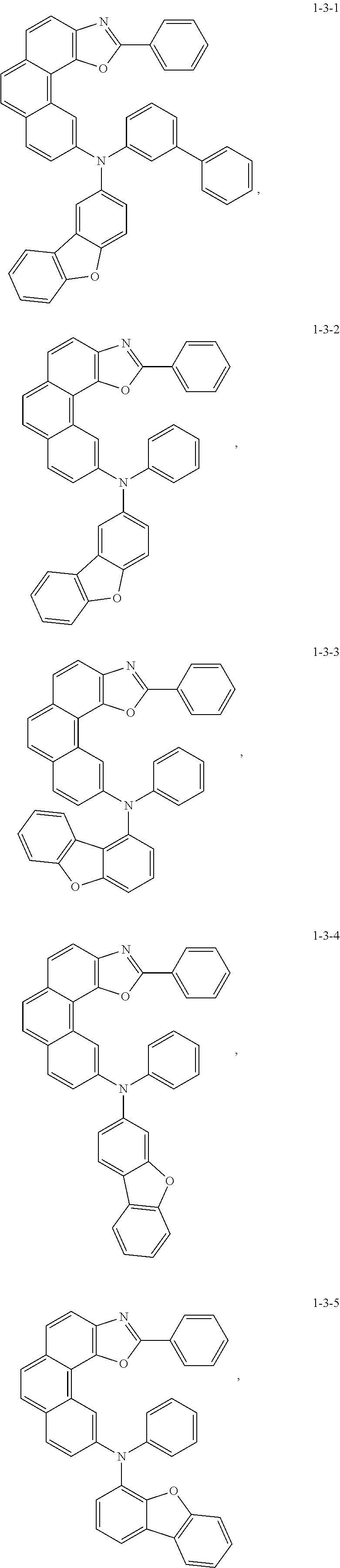 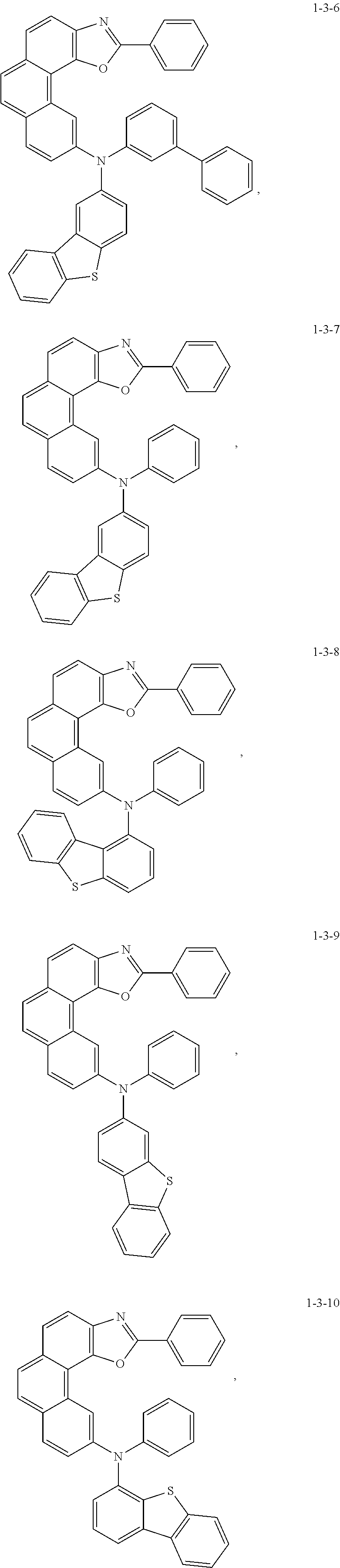 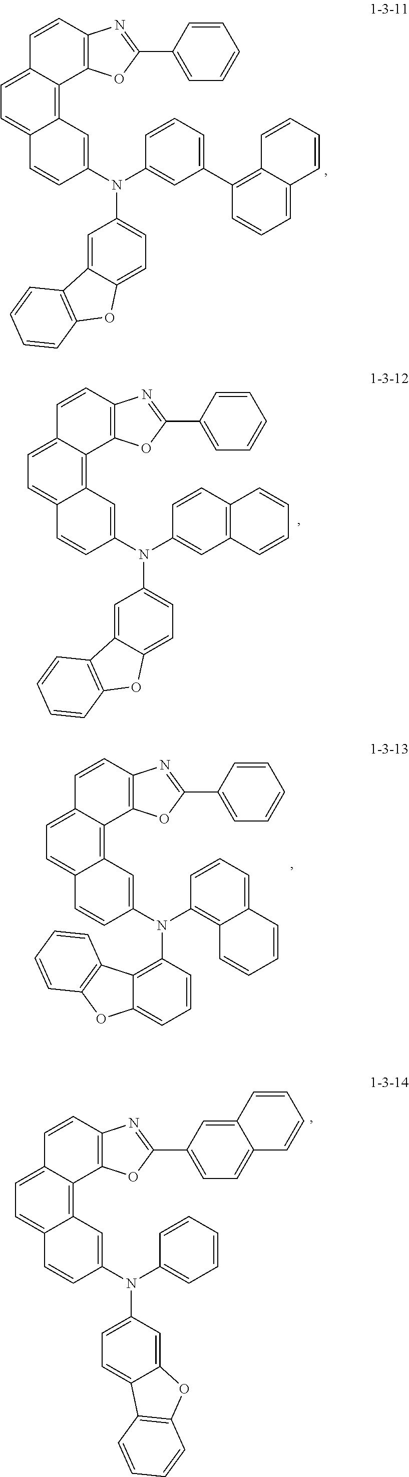 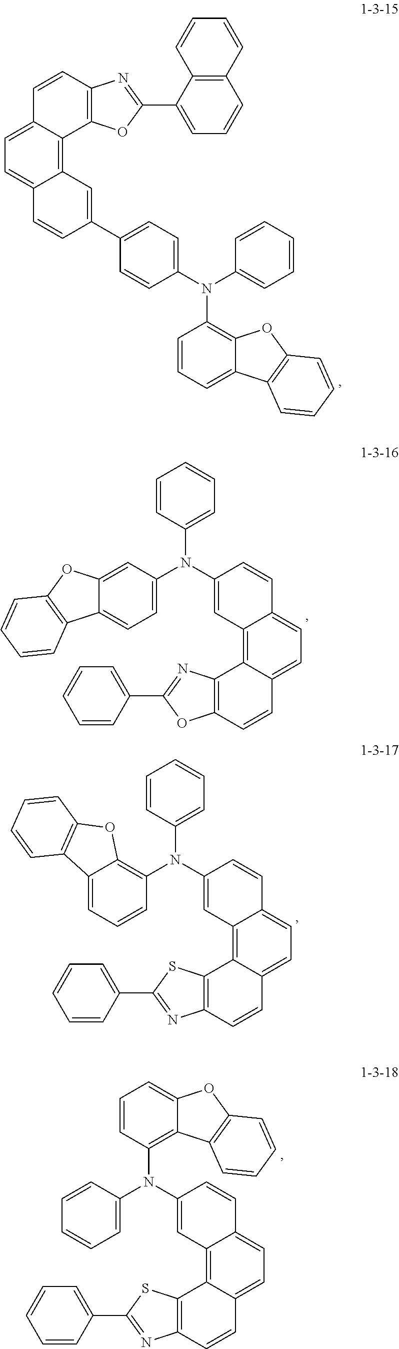 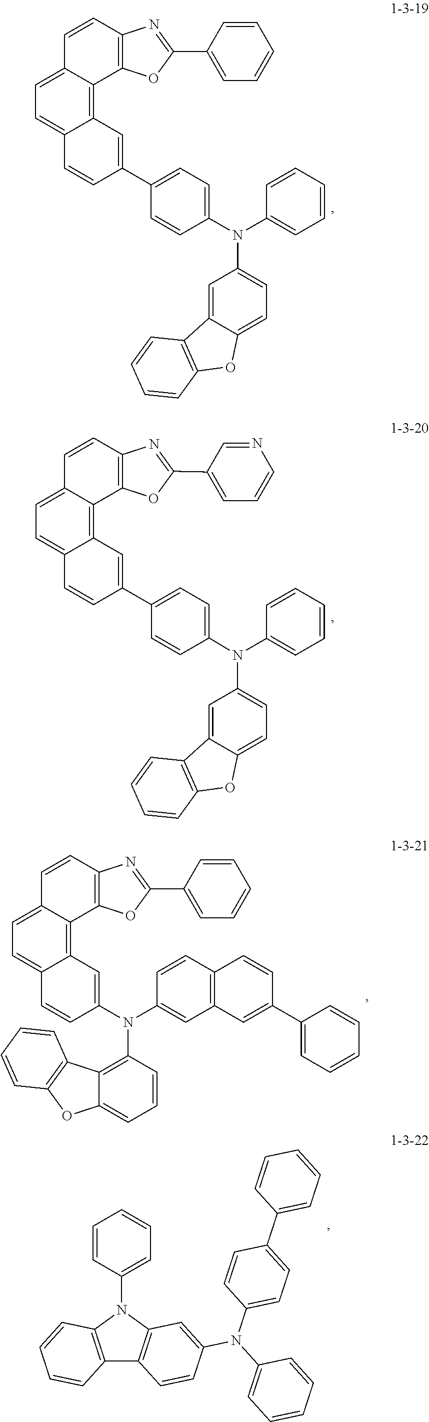 [SMILES: c1ccc(-c2nc3ccc4ccc5ccc(-c6ccc(N(c7ccccc7)c7ccc8oc9ccccc9c8c7)cc6)cc5c4c3o2)cc1 ; c1ccc(N(c2ccc(-c3ccc4ccc5ccc6nc(-c7cccnc7)oc6c5c4c3)cc2)c2ccc3oc4ccccc4c3c2)cc1 ; c1ccc(-c2ccc3ccc(N(c4ccc5ccc6ccc7nc(-c8ccccc8)oc7c6c5c4)c4cccc5oc6ccccc6c45)cc3c2)cc1 ; c1ccc(-c2ccc(N(c3ccccc3)c3ccc4c5ccccc5n(-c5ccccc5)c4c3)cc2)cc1] 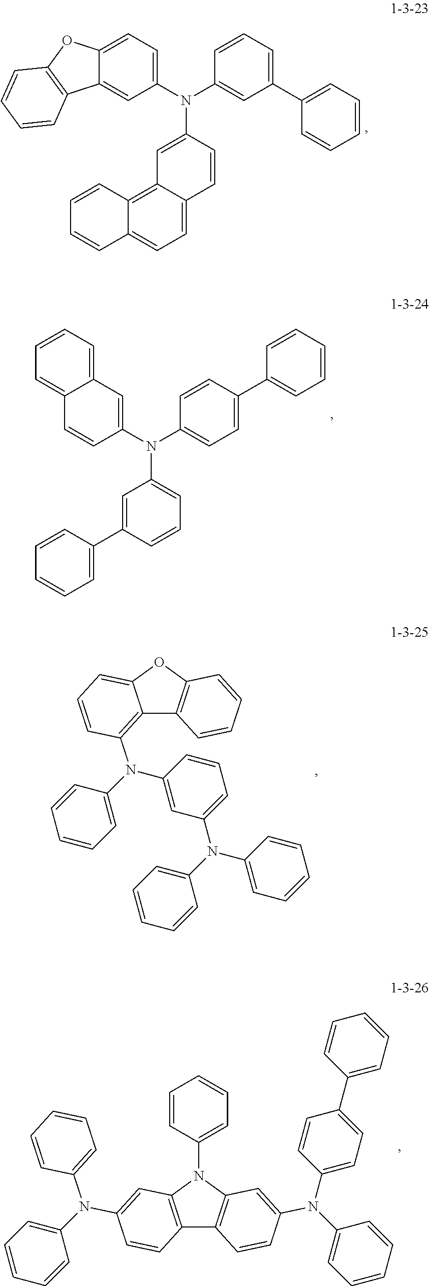 [SMILES: c1ccc(-c2cccc(N(c3ccc4ccc5ccccc5c4c3)c3ccc4oc5ccccc5c4c3)c2)cc1 ; c1ccc(-c2ccc(N(c3cccc(-c4ccccc4)c3)c3ccc4ccccc4c3)cc2)cc1 ; c1ccc(N(c2ccccc2)c2cccc(N(c3ccccc3)c3cccc4oc5ccccc5c34)c2)cc1 ; c1ccc(-c2ccc(N(c3ccccc3)c3ccc4c5ccc(N(c6ccccc6)c6ccccc6)cc5n(-c5ccccc5)c4c3)cc2)cc1] 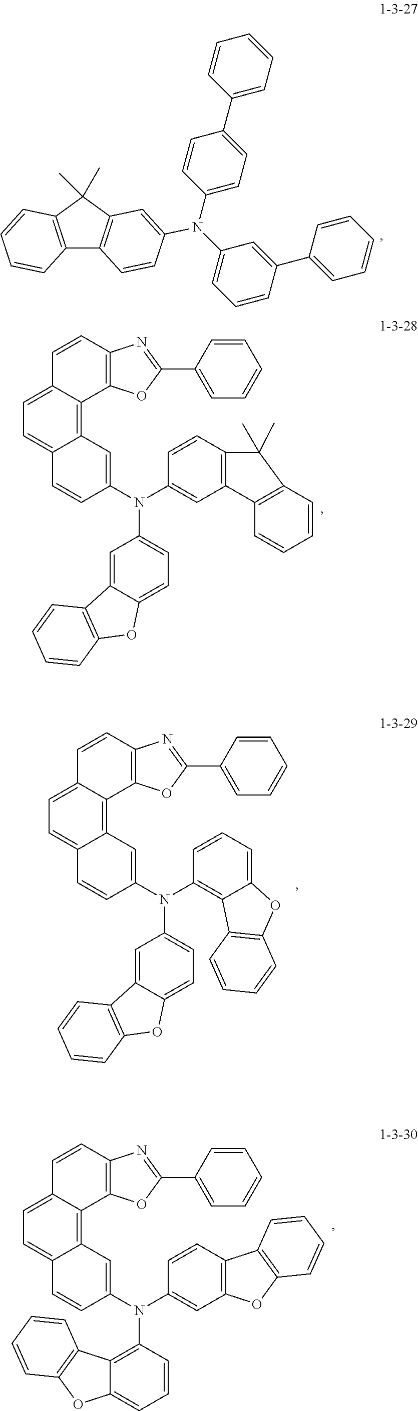 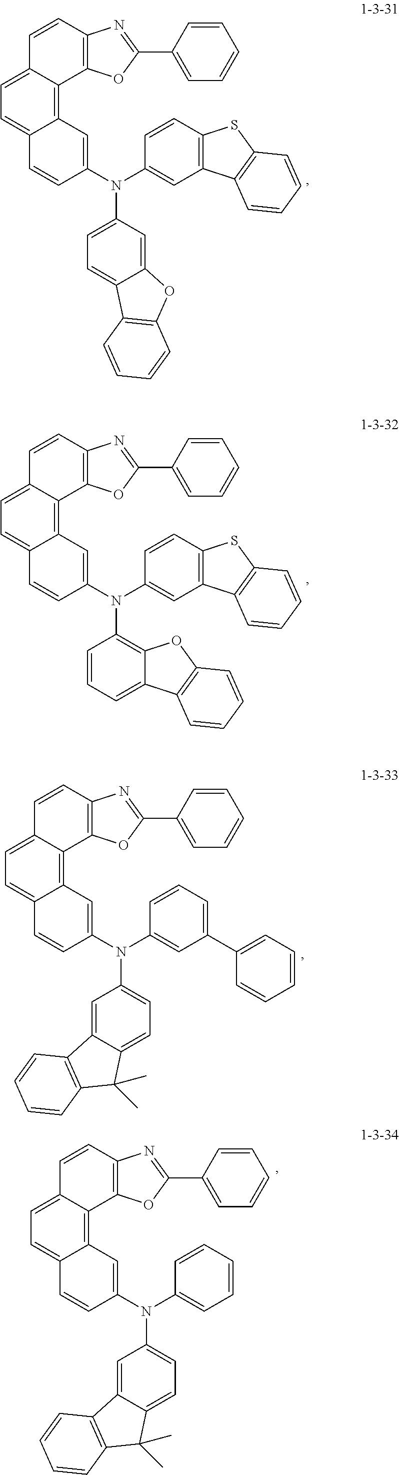 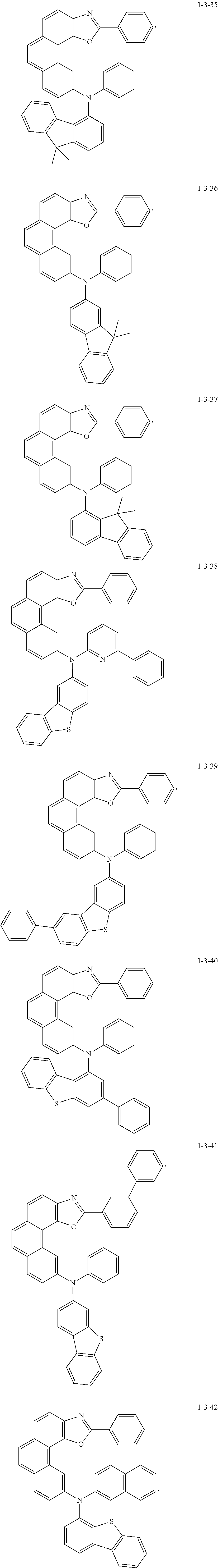 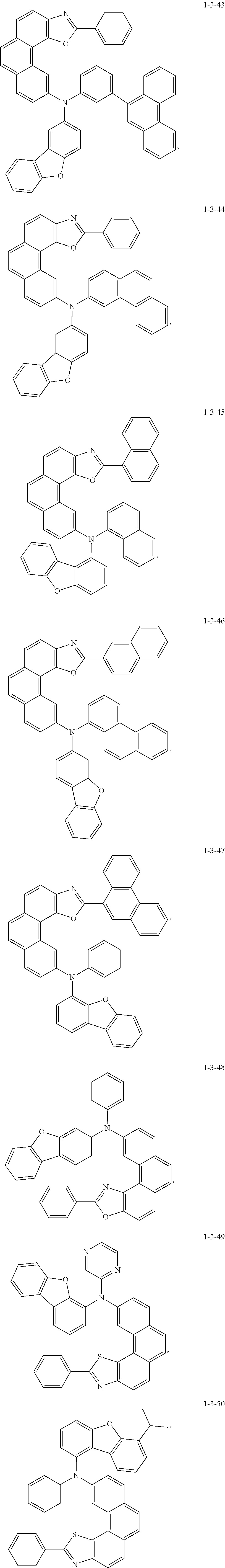 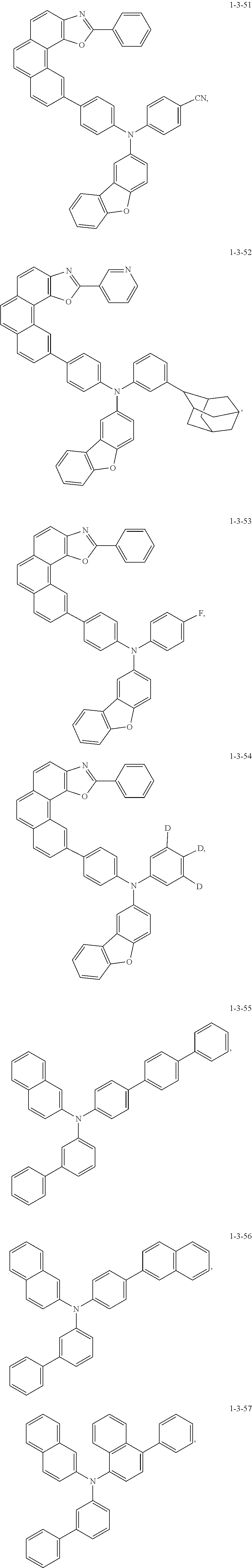 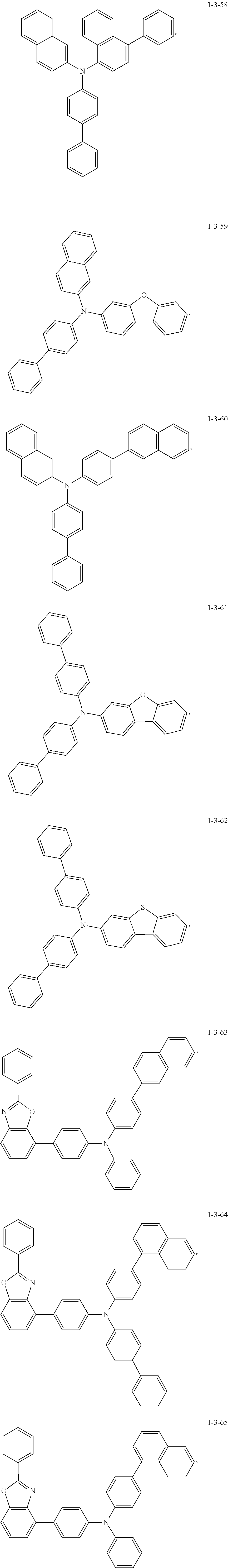 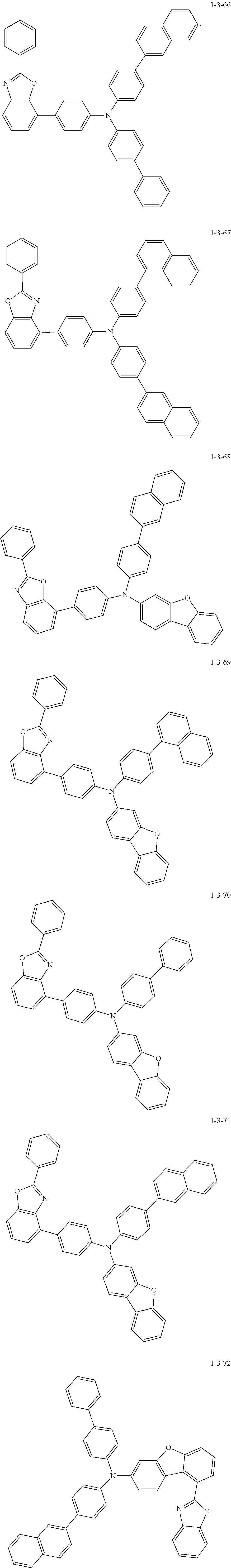 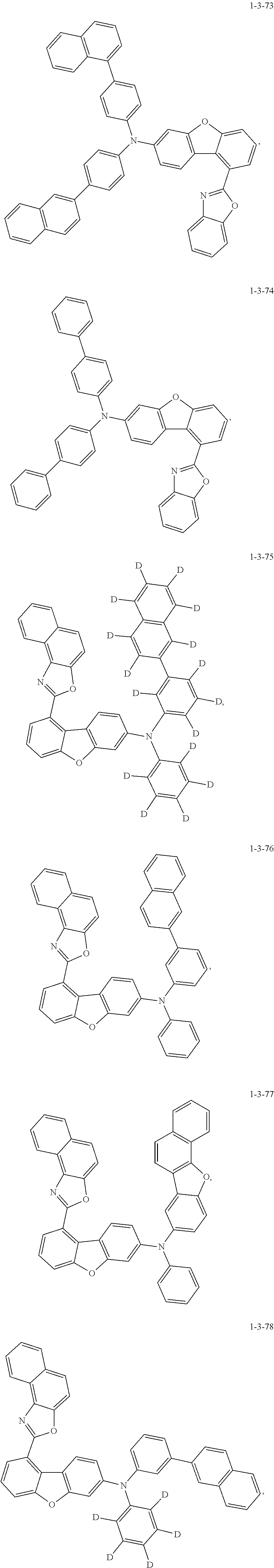 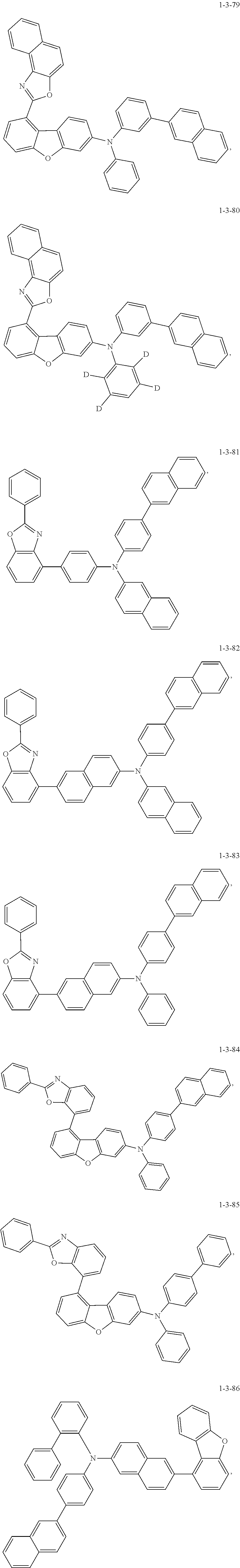 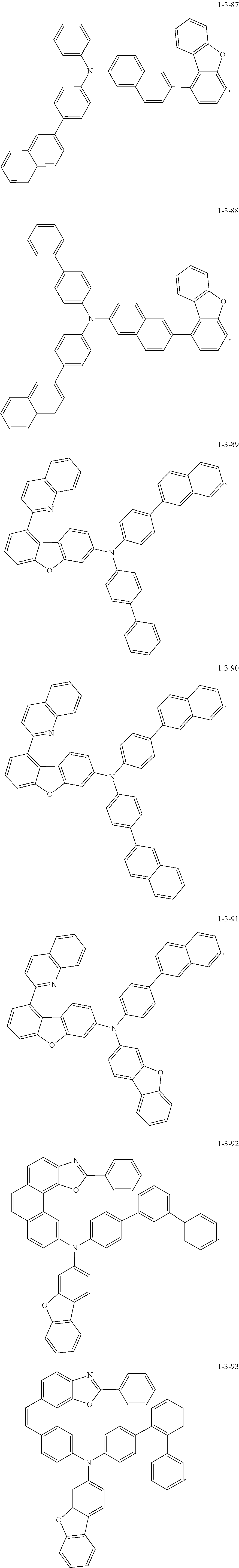 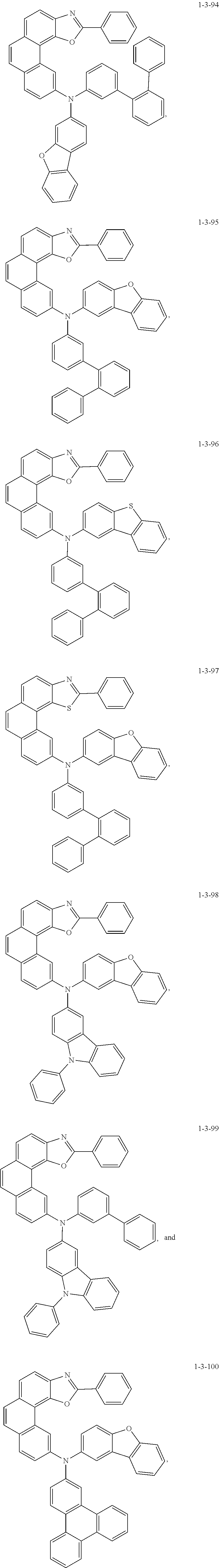
the second host material is selected from the group consisting of Compound B-1 to Compound B-236:

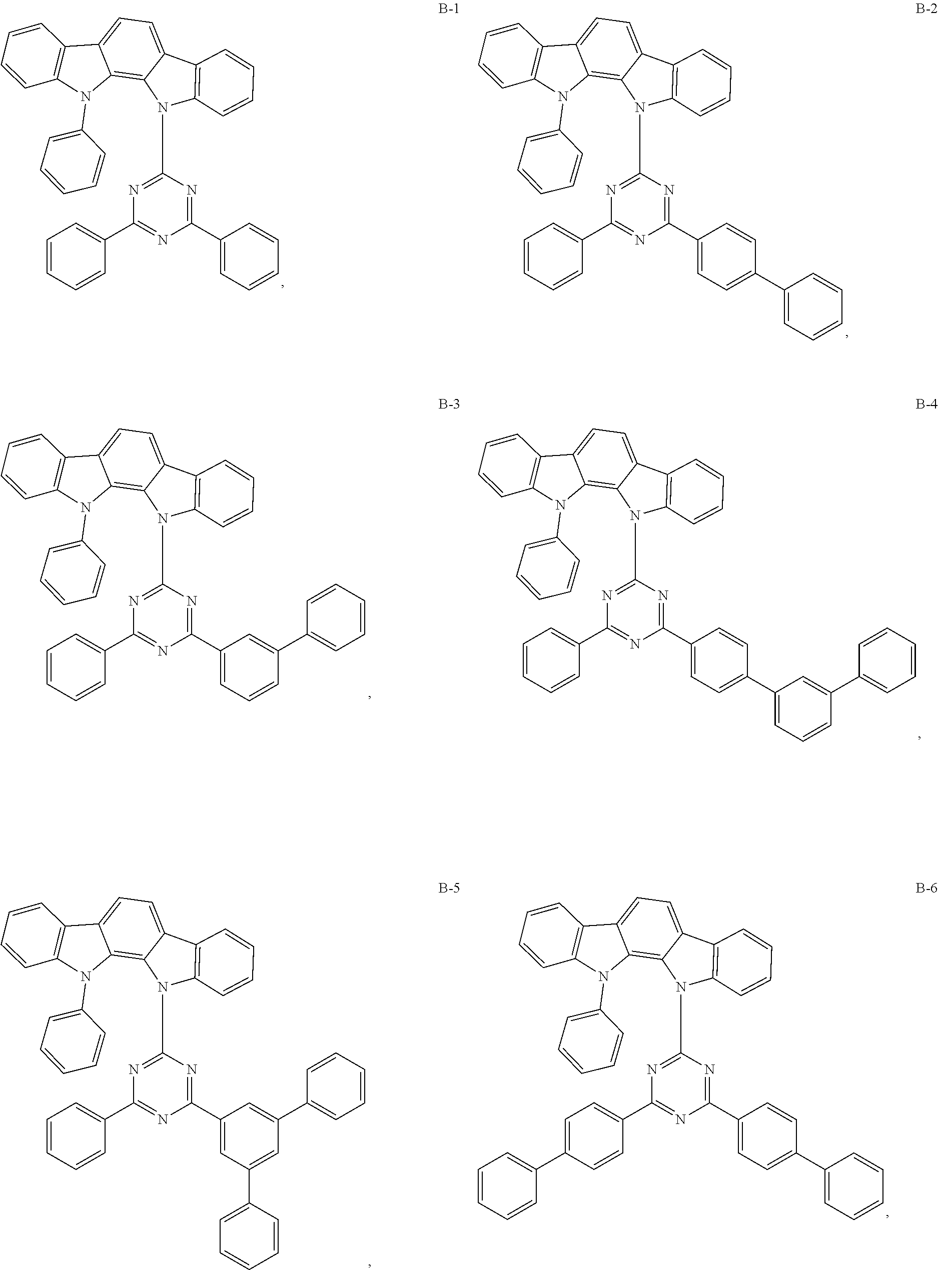

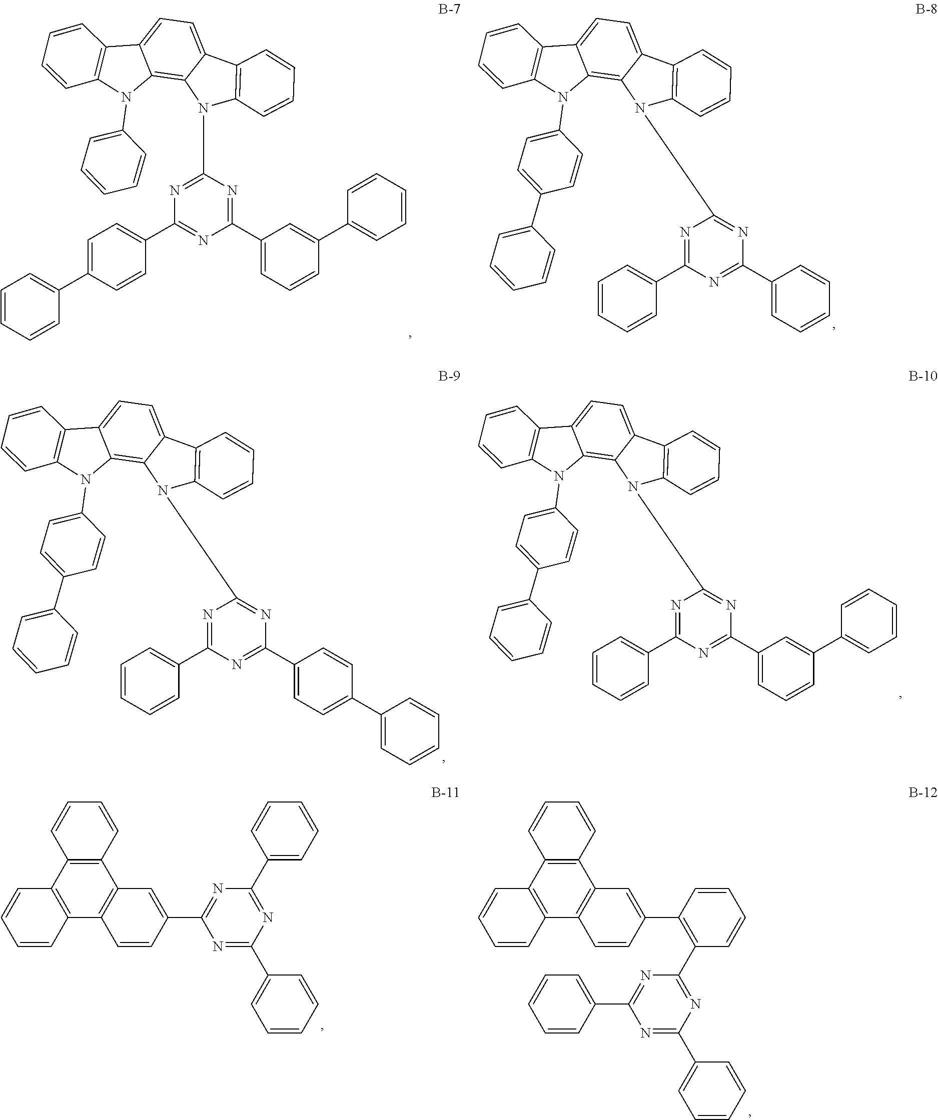

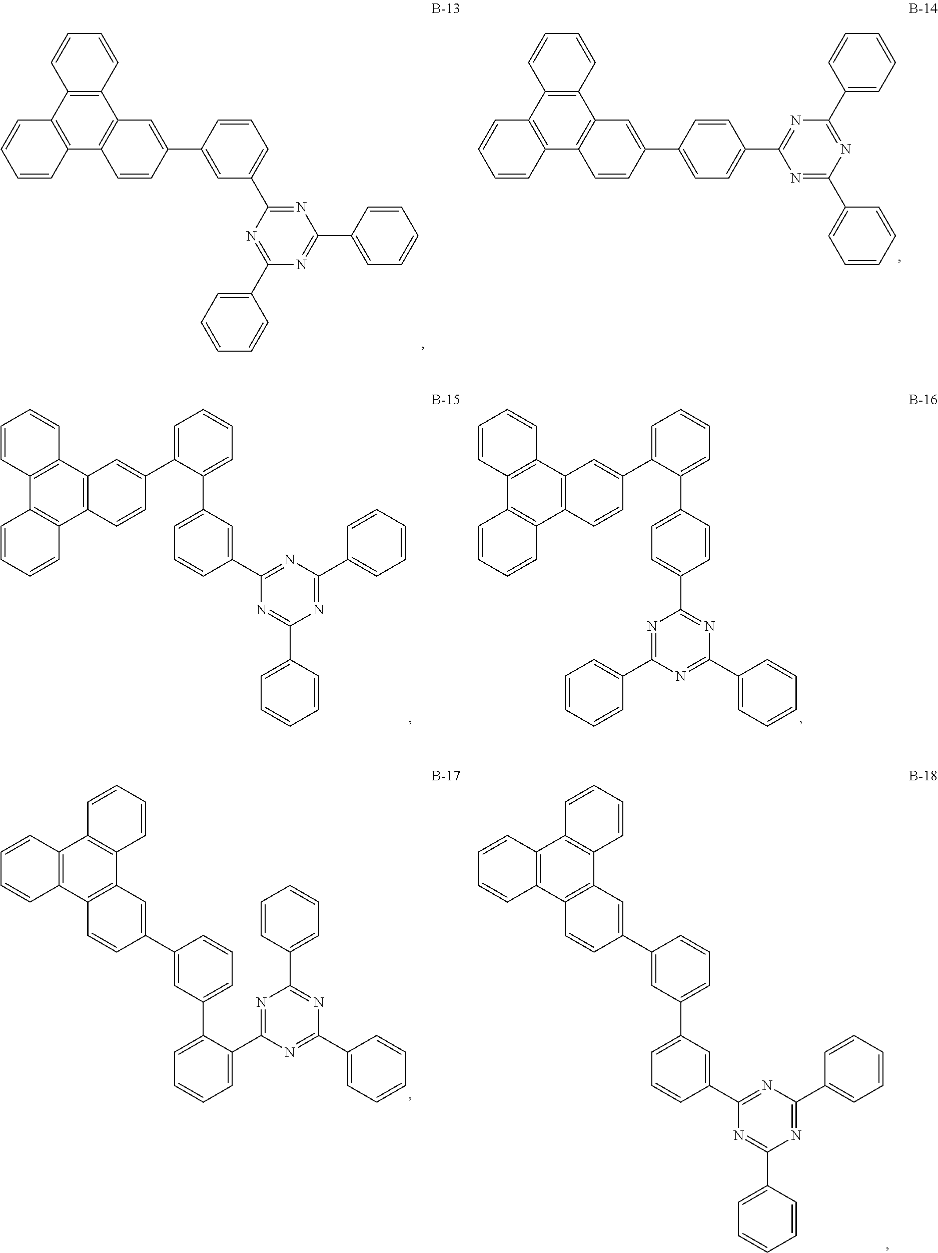 [SMILES: c1ccc(-c2nc(-c3ccccc3)nc(-c3cccc(-c4ccc5c6ccccc6c6ccccc6c5c4)c3)n2)cc1 ; c1ccc(-c2nc(-c3ccccc3)nc(-c3ccc(-c4ccc5c6ccccc6c6ccccc6c5c4)cc3)n2)cc1 ; c1ccc(-c2nc(-c3ccccc3)nc(-c3cccc(-c4ccccc4-c4ccc5c6ccccc6c6ccccc6c5c4)c3)n2)cc1 ; c1ccc(-c2nc(-c3ccccc3)nc(-c3ccc(-c4ccccc4-c4ccc5c6ccccc6c6ccccc6c5c4)cc3)n2)cc1 ; c1ccc(-c2nc(-c3ccccc3)nc(-c3ccccc3-c3cccc(-c4ccc5c6ccccc6c6ccccc6c5c4)c3)n2)cc1 ; c1ccc(-c2nc(-c3ccccc3)nc(-c3cccc(-c4cccc(-c5ccc6c7ccccc7c7ccccc7c6c5)c4)c3)n2)cc1]

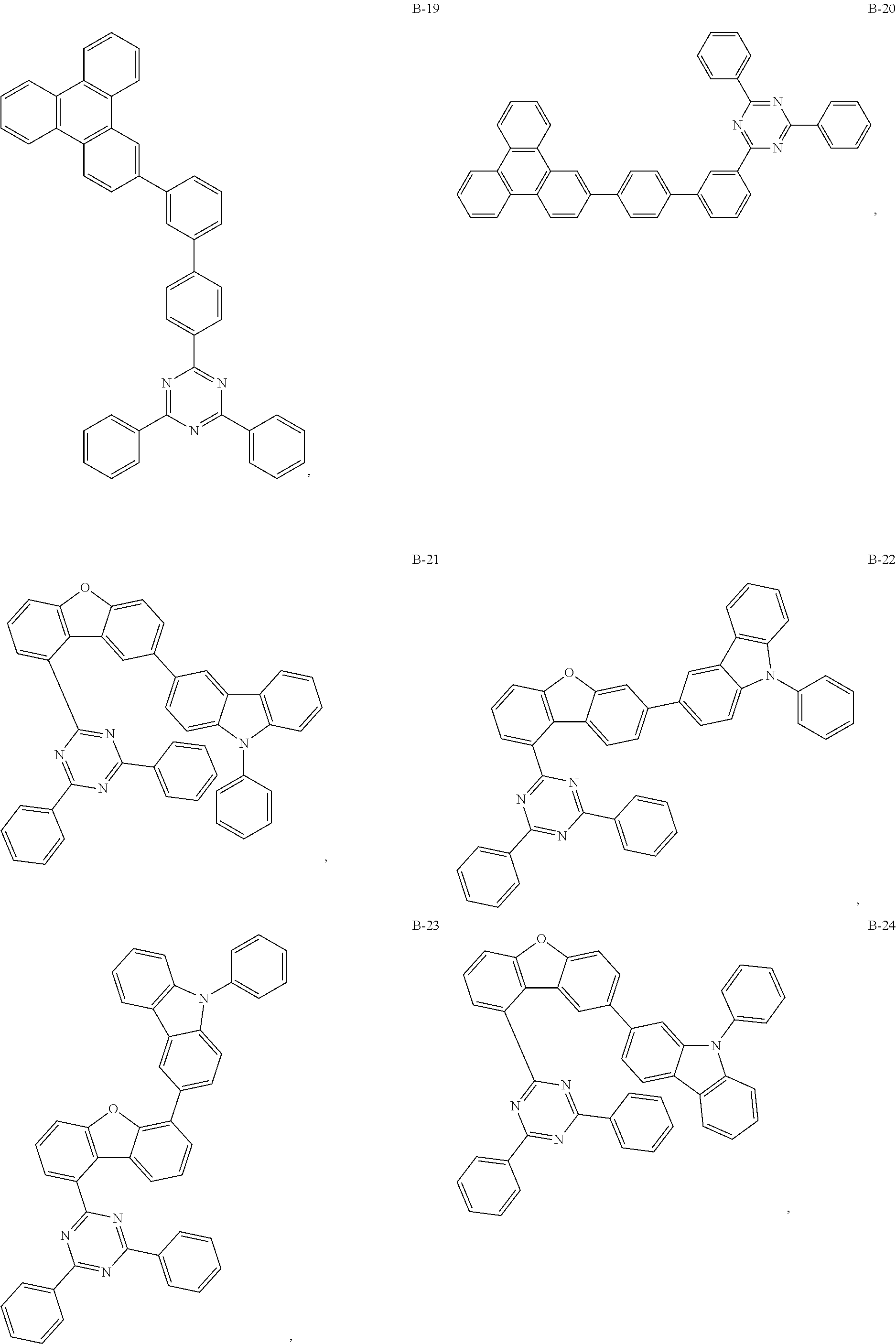

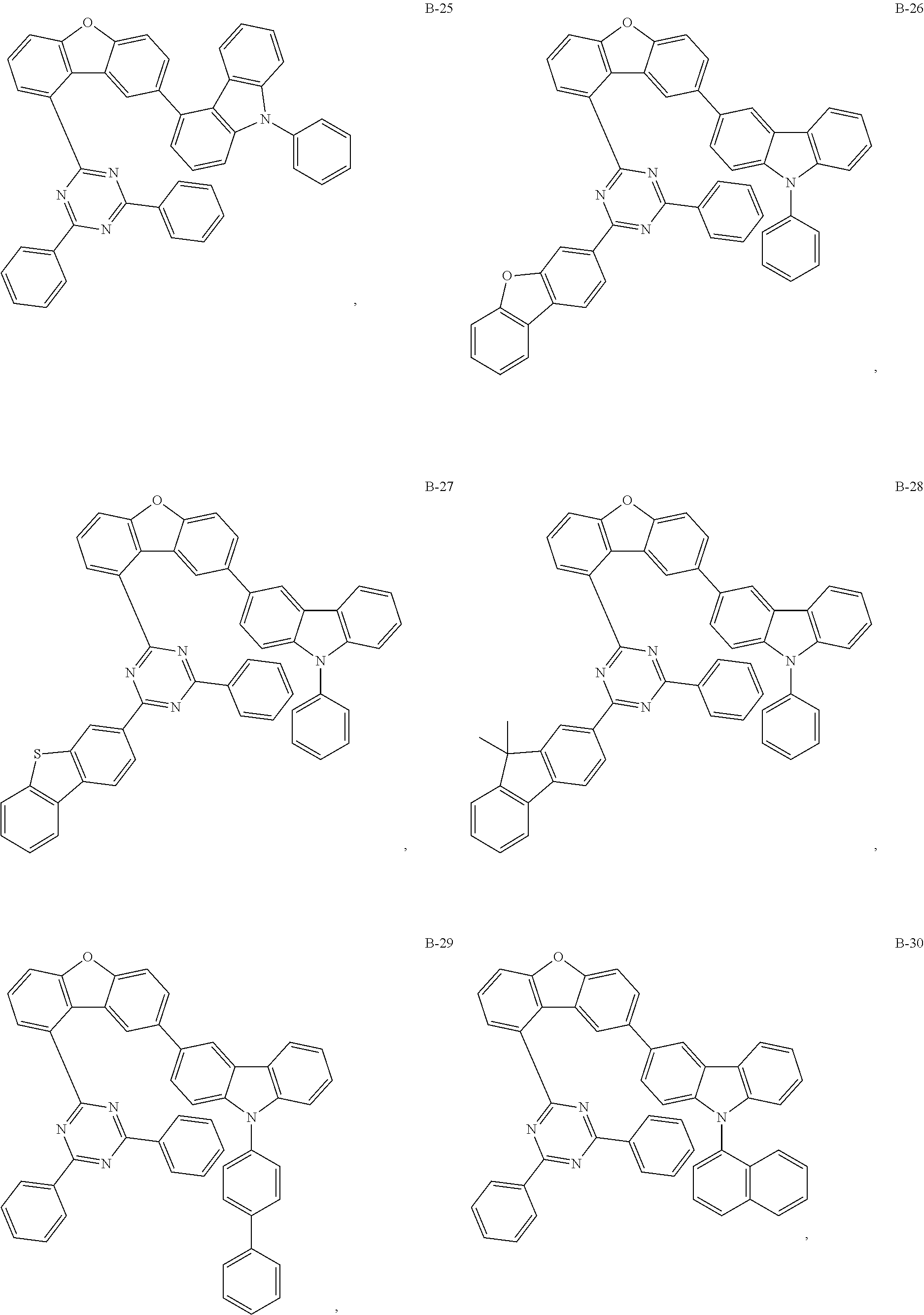

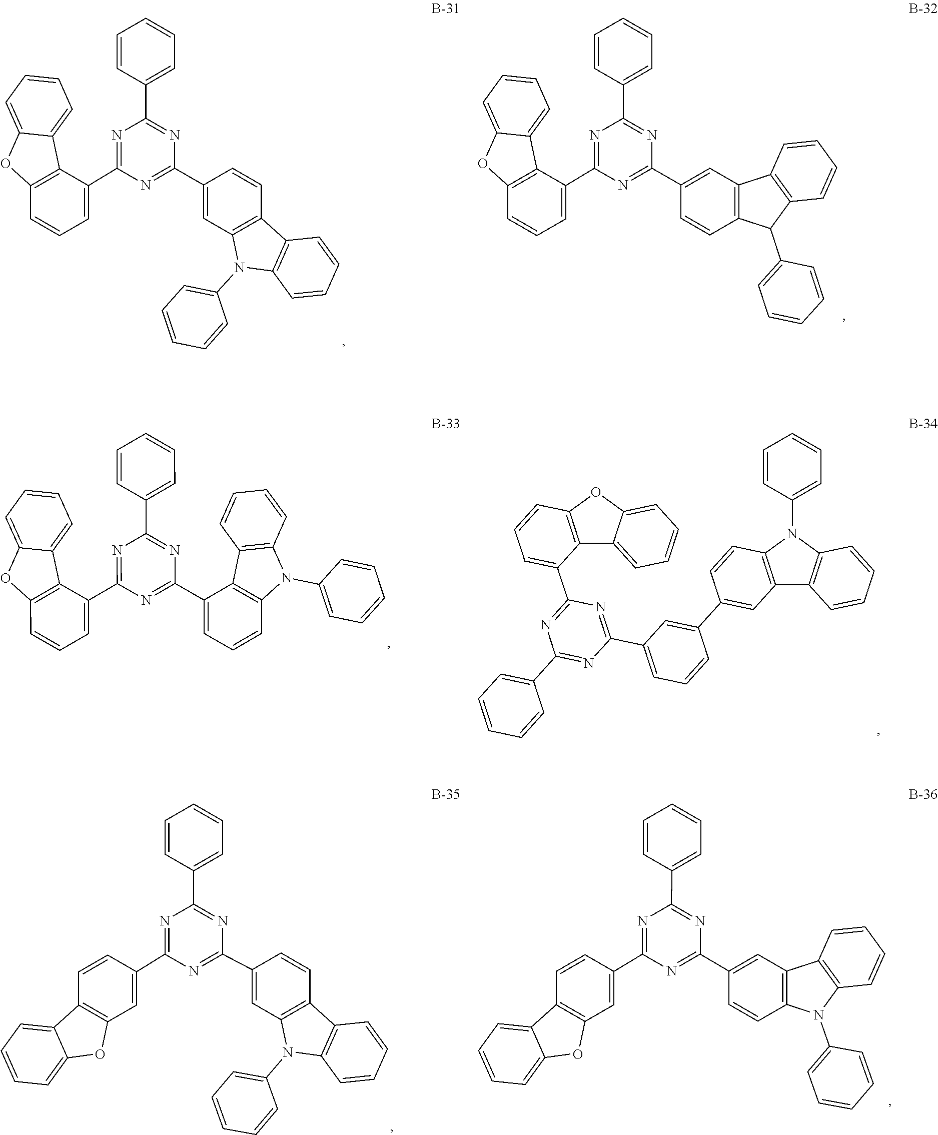 [SMILES: c1ccc(-c2nc(-c3ccc4c5ccccc5n(-c5ccccc5)c4c3)nc(-c3cccc4oc5ccccc5c34)n2)cc1 ; c1ccc(-c2nc(-c3ccc4c(c3)-c3ccccc3C4c3ccccc3)nc(-c3cccc4oc5ccccc5c34)n2)cc1 ; c1ccc(-c2nc(-c3cccc4oc5ccccc5c34)nc(-c3cccc4c3c3ccccc3n4-c3ccccc3)n2)cc1 ; c1ccc(-c2nc(-c3cccc(-c4ccc5c(c4)c4ccccc4n5-c4ccccc4)c3)nc(-c3cccc4oc5ccccc5c34)n2)cc1 ; c1ccc(-c2nc(-c3ccc4c(c3)oc3ccccc34)nc(-c3ccc4c5ccccc5n(-c5ccccc5)c4c3)n2)cc1 ; c1ccc(-c2nc(-c3ccc4c(c3)oc3ccccc34)nc(-c3ccc4c(c3)c3ccccc3n4-c3ccccc3)n2)cc1]

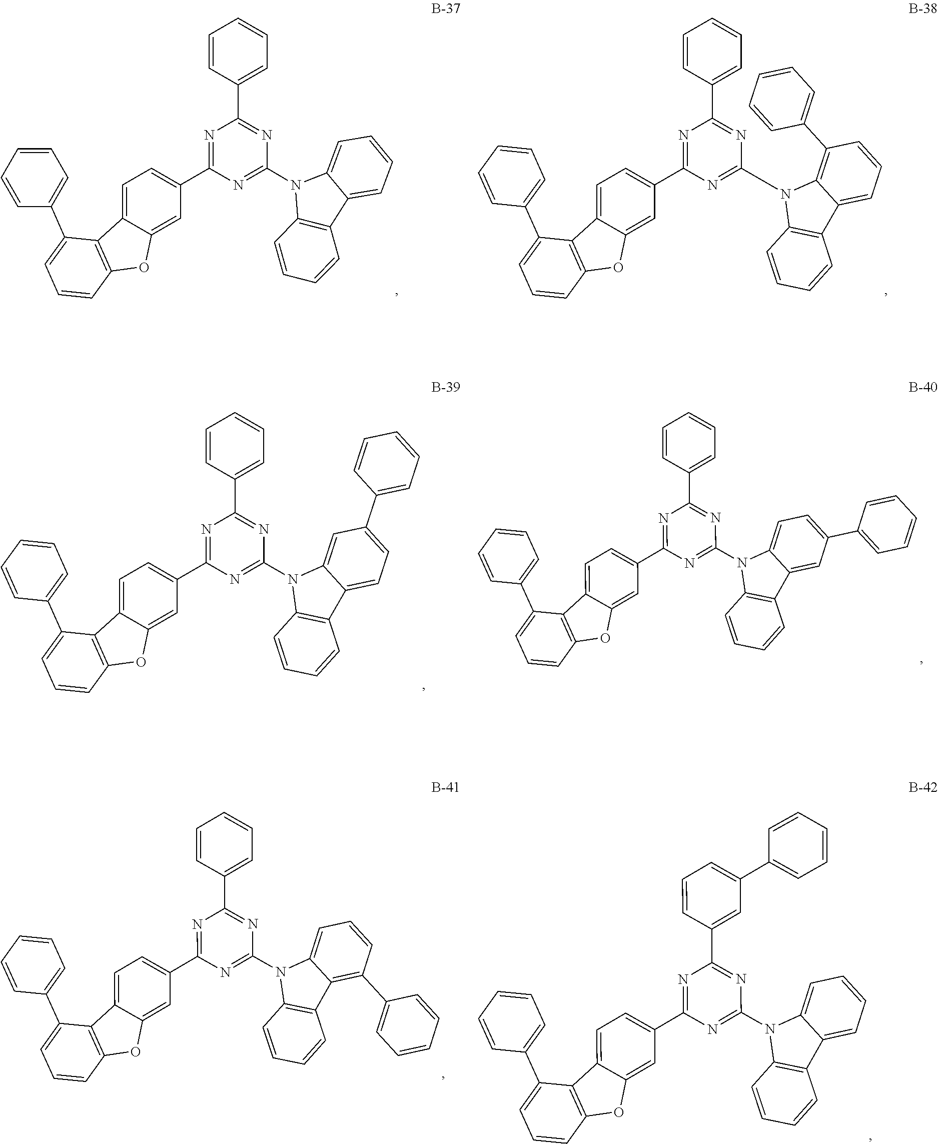

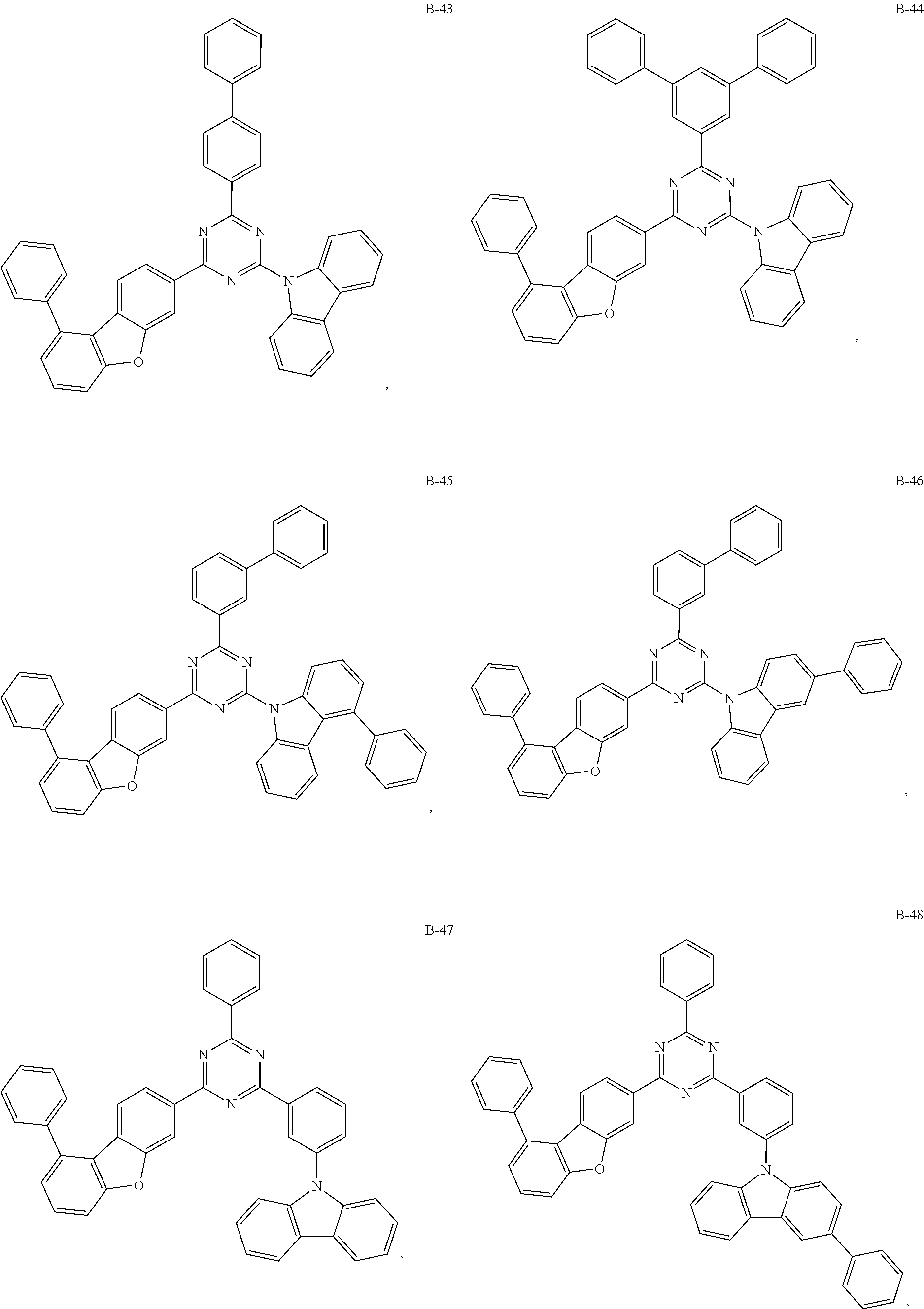

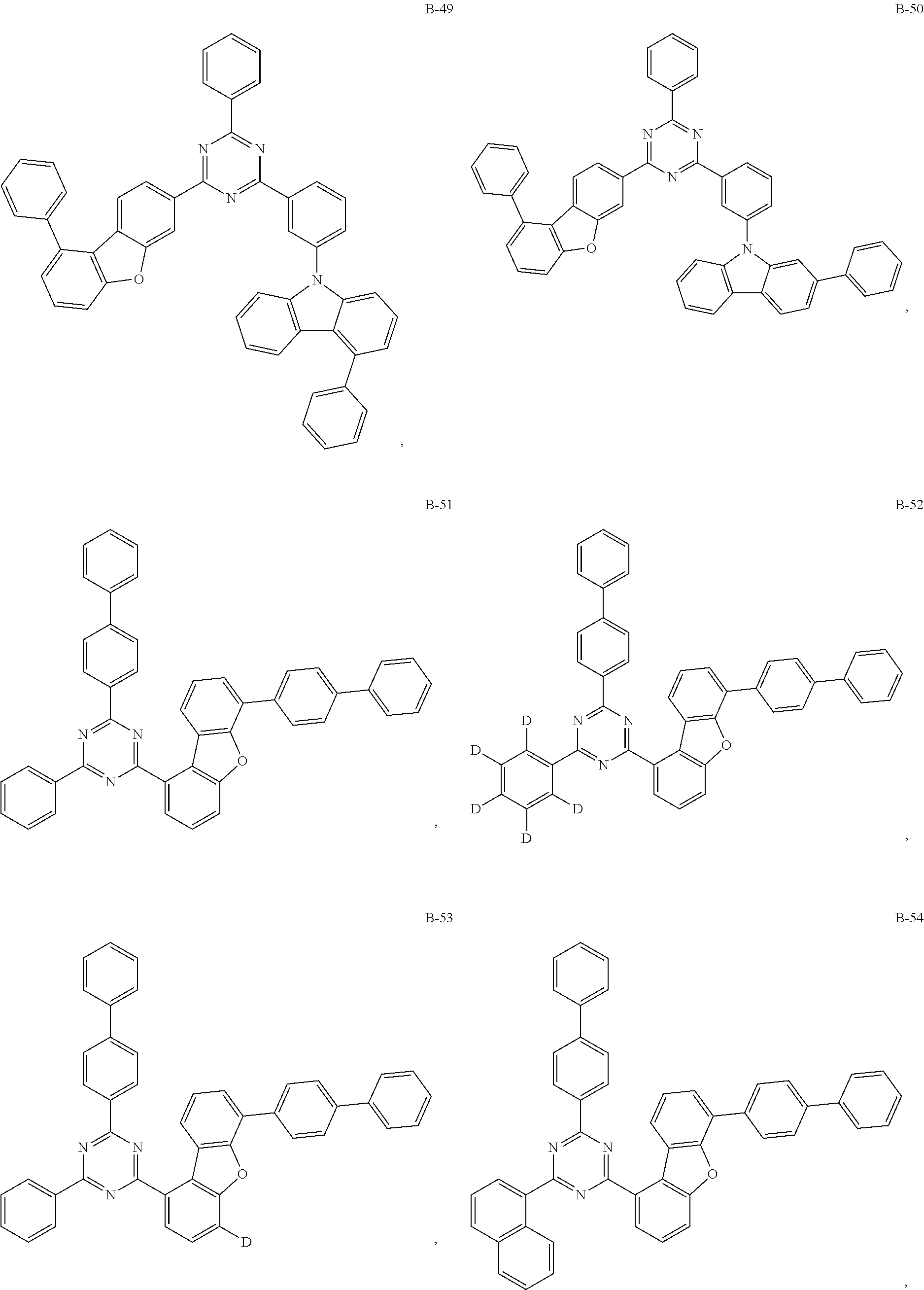

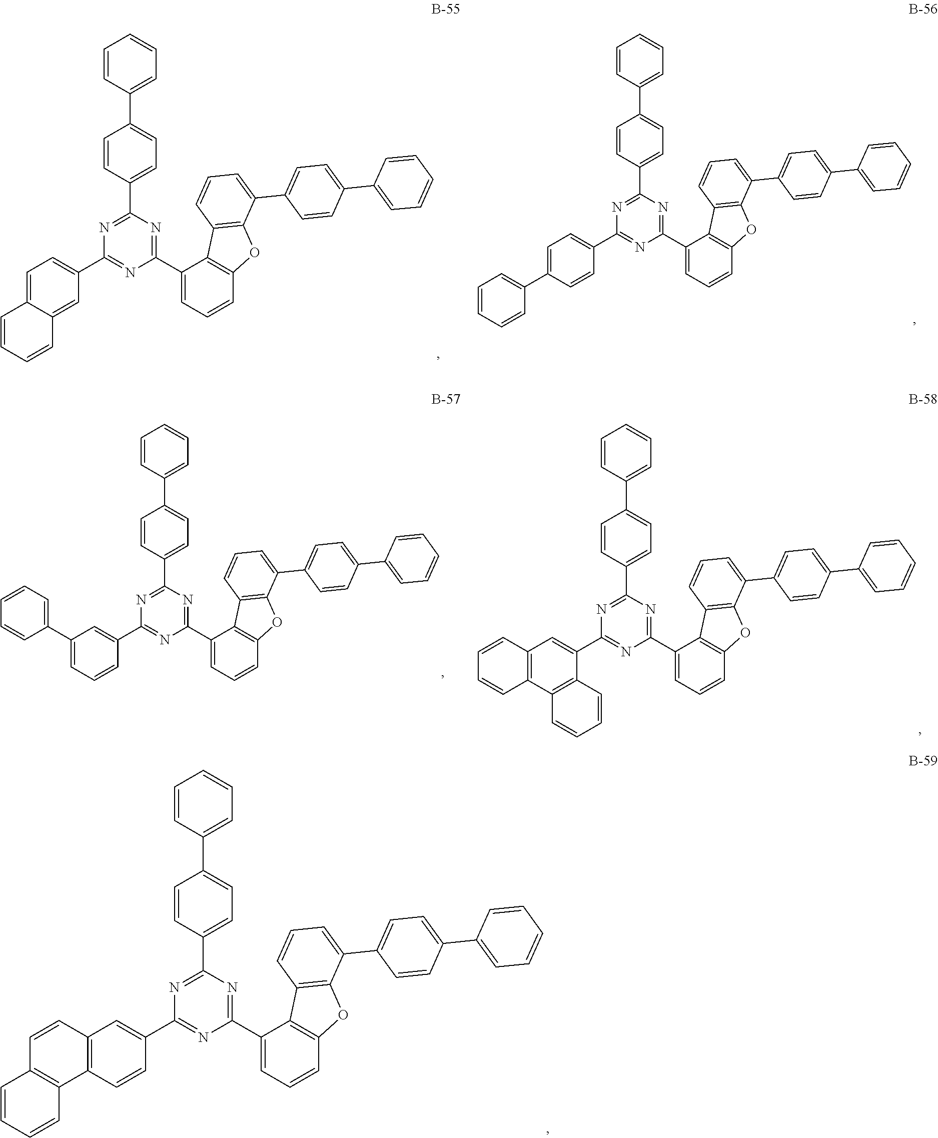 [SMILES: c1ccc(-c2ccc(-c3nc(-c4ccc5ccccc5c4)nc(-c4cccc5oc6c(-c7ccc(-c8ccccc8)cc7)cccc6c45)n3)cc2)cc1 ; c1ccc(-c2ccc(-c3nc(-c4ccc(-c5ccccc5)cc4)nc(-c4cccc5oc6c(-c7ccc(-c8ccccc8)cc7)cccc6c45)n3)cc2)cc1 ; c1ccc(-c2ccc(-c3nc(-c4cccc(-c5ccccc5)c4)nc(-c4cccc5oc6c(-c7ccc(-c8ccccc8)cc7)cccc6c45)n3)cc2)cc1 ; c1ccc(-c2ccc(-c3nc(-c4cc5ccccc5c5ccccc45)nc(-c4cccc5oc6c(-c7ccc(-c8ccccc8)cc7)cccc6c45)n3)cc2)cc1 ; c1ccc(-c2ccc(-c3nc(-c4ccc5c(ccc6ccccc65)c4)nc(-c4cccc5oc6c(-c7ccc(-c8ccccc8)cc7)cccc6c45)n3)cc2)cc1]

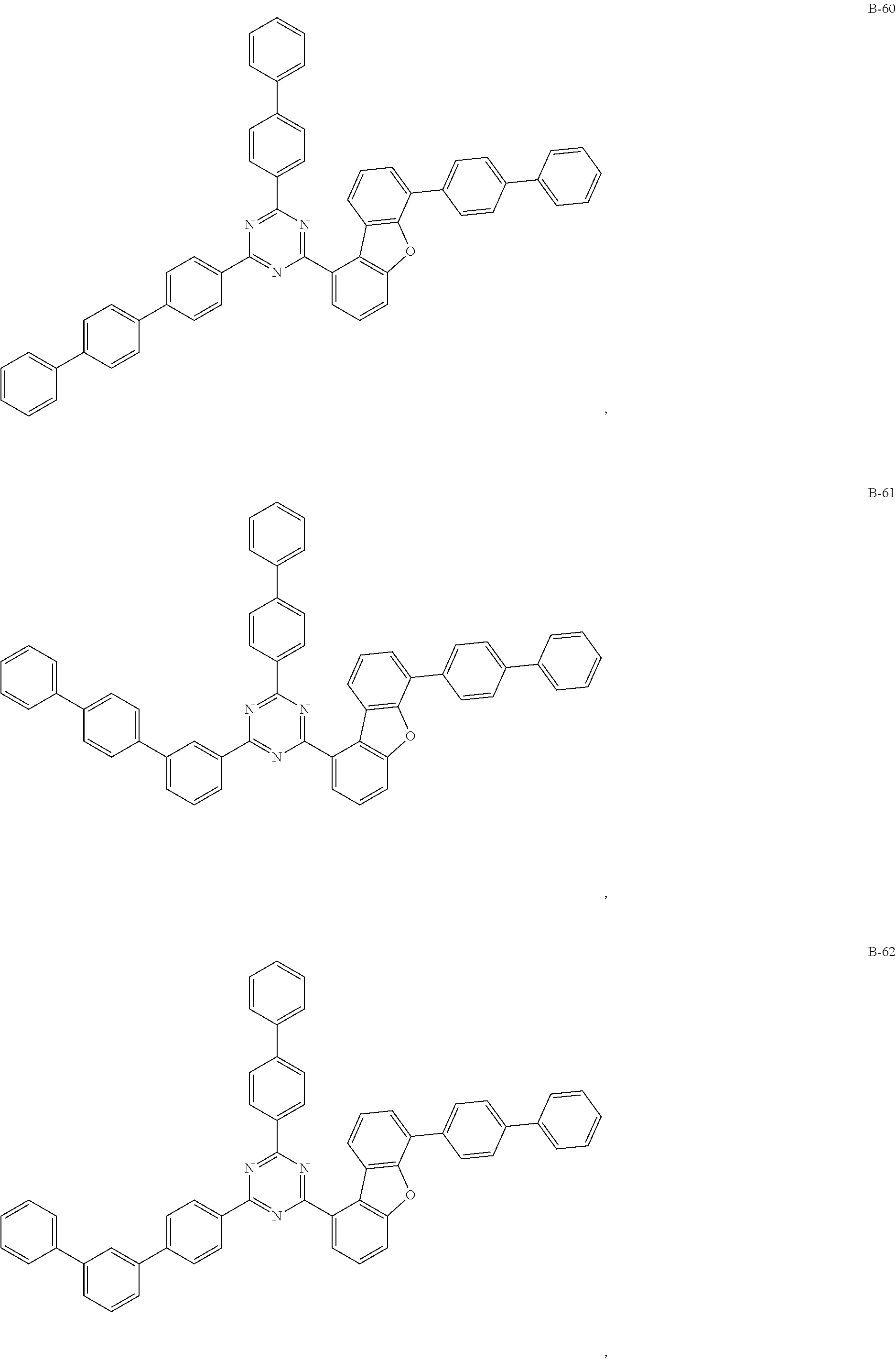 [SMILES: c1ccc(-c2ccc(-c3ccc(-c4nc(-c5ccc(-c6ccccc6)cc5)nc(-c5cccc6oc7c(-c8ccc(-c9ccccc9)cc8)cccc7c56)n4)cc3)cc2)cc1 ; c1ccc(-c2ccc(-c3cccc(-c4nc(-c5ccc(-c6ccccc6)cc5)nc(-c5cccc6oc7c(-c8ccc(-c9ccccc9)cc8)cccc7c56)n4)c3)cc2)cc1 ; c1ccc(-c2ccc(-c3nc(-c4ccc(-c5cccc(-c6ccccc6)c5)cc4)nc(-c4cccc5oc6c(-c7ccc(-c8ccccc8)cc7)cccc6c45)n3)cc2)cc1]

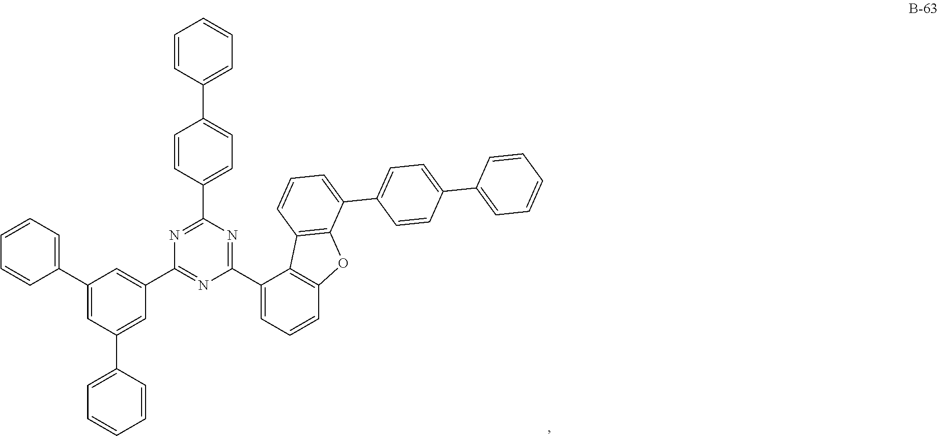 [SMILES: c1ccc(-c2ccc(-c3nc(-c4cc(-c5ccccc5)cc(-c5ccccc5)c4)nc(-c4cccc5oc6c(-c7ccc(-c8ccccc8)cc7)cccc6c45)n3)cc2)cc1]

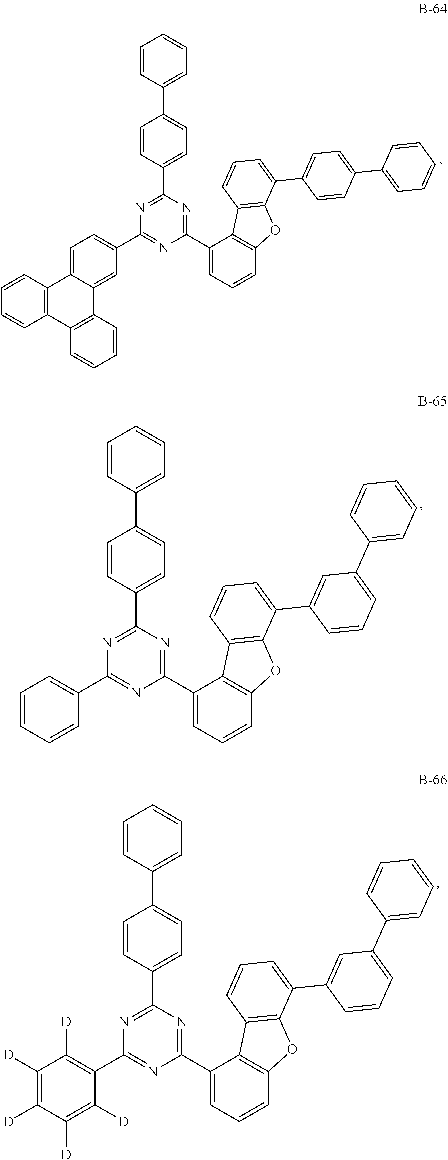 [SMILES: c1ccc(-c2ccc(-c3nc(-c4ccc5c6ccccc6c6ccccc6c5c4)nc(-c4cccc5oc6c(-c7ccc(-c8ccccc8)cc7)cccc6c45)n3)cc2)cc1 ; c1ccc(-c2ccc(-c3nc(-c4ccccc4)nc(-c4cccc5oc6c(-c7cccc(-c8ccccc8)c7)cccc6c45)n3)cc2)cc1 ; [2H]c1c([2H])c([2H])c(-c2nc(-c3ccc(-c4ccccc4)cc3)nc(-c3cccc4oc5c(-c6cccc(-c7ccccc7)c6)cccc5c34)n2)c([2H])c1[2H]]

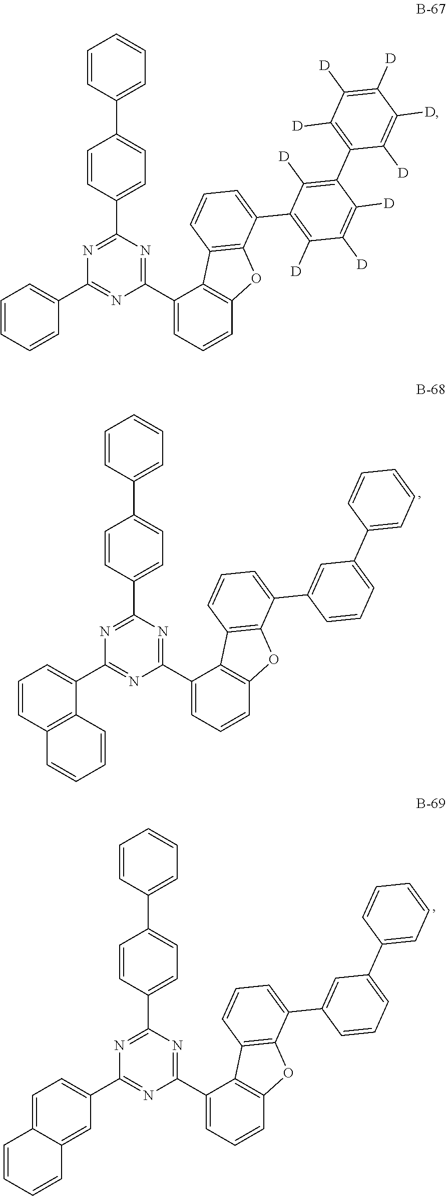

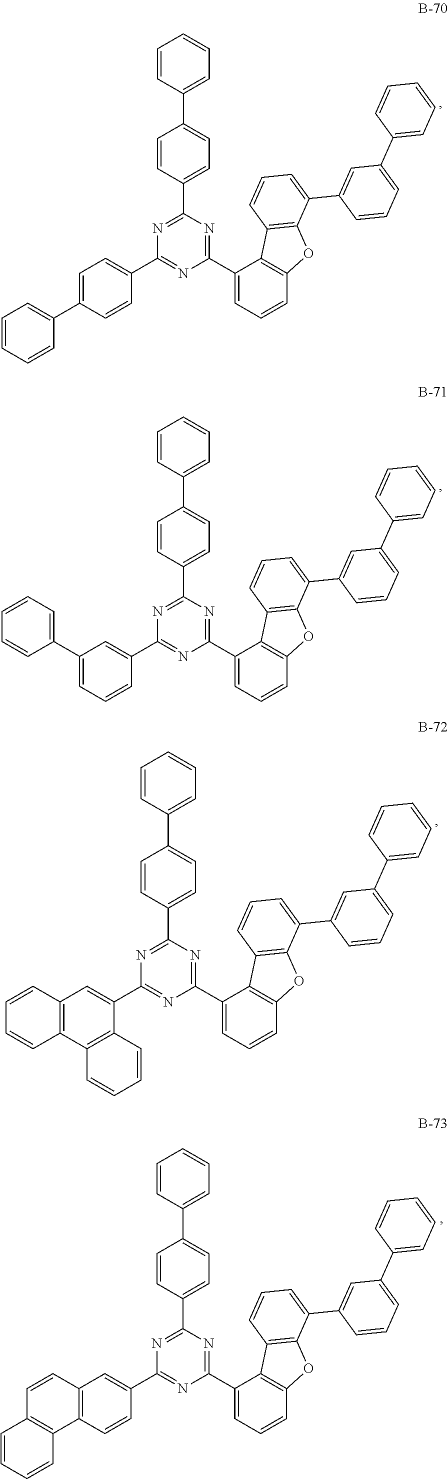 [SMILES: c1ccc(-c2ccc(-c3nc(-c4ccc(-c5ccccc5)cc4)nc(-c4cccc5oc6c(-c7cccc(-c8ccccc8)c7)cccc6c45)n3)cc2)cc1 ; c1ccc(-c2ccc(-c3nc(-c4cccc(-c5ccccc5)c4)nc(-c4cccc5oc6c(-c7cccc(-c8ccccc8)c7)cccc6c45)n3)cc2)cc1 ; c1ccc(-c2ccc(-c3nc(-c4cc5ccccc5c5ccccc45)nc(-c4cccc5oc6c(-c7cccc(-c8ccccc8)c7)cccc6c45)n3)cc2)cc1 ; c1ccc(-c2ccc(-c3nc(-c4ccc5c(ccc6ccccc65)c4)nc(-c4cccc5oc6c(-c7cccc(-c8ccccc8)c7)cccc6c45)n3)cc2)cc1]

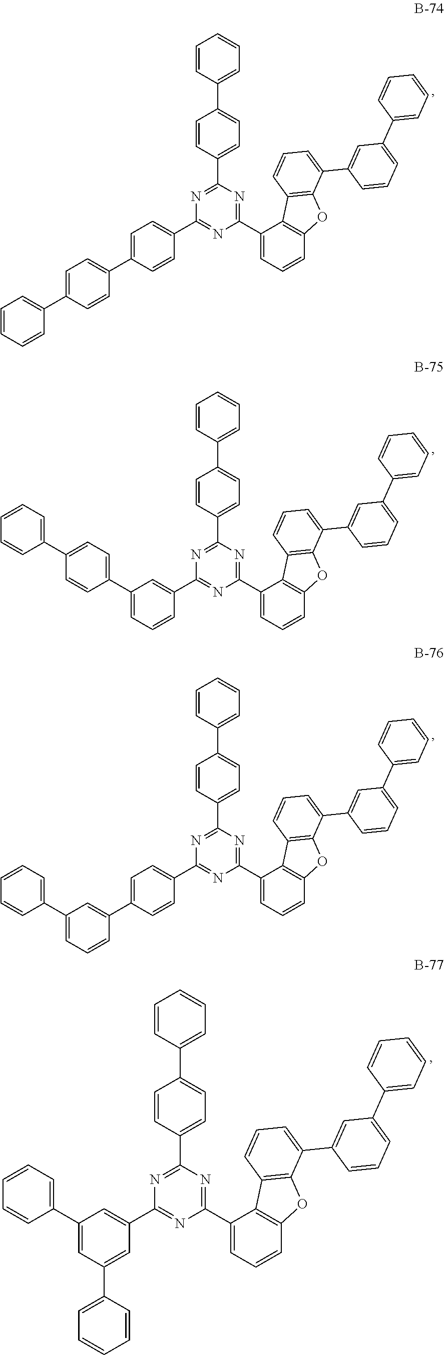 [SMILES: c1ccc(-c2ccc(-c3ccc(-c4nc(-c5ccc(-c6ccccc6)cc5)nc(-c5cccc6oc7c(-c8cccc(-c9ccccc9)c8)cccc7c56)n4)cc3)cc2)cc1 ; c1ccc(-c2ccc(-c3cccc(-c4nc(-c5ccc(-c6ccccc6)cc5)nc(-c5cccc6oc7c(-c8cccc(-c9ccccc9)c8)cccc7c56)n4)c3)cc2)cc1 ; c1ccc(-c2ccc(-c3nc(-c4ccc(-c5cccc(-c6ccccc6)c5)cc4)nc(-c4cccc5oc6c(-c7cccc(-c8ccccc8)c7)cccc6c45)n3)cc2)cc1 ; c1ccc(-c2ccc(-c3nc(-c4cc(-c5ccccc5)cc(-c5ccccc5)c4)nc(-c4cccc5oc6c(-c7cccc(-c8ccccc8)c7)cccc6c45)n3)cc2)cc1]

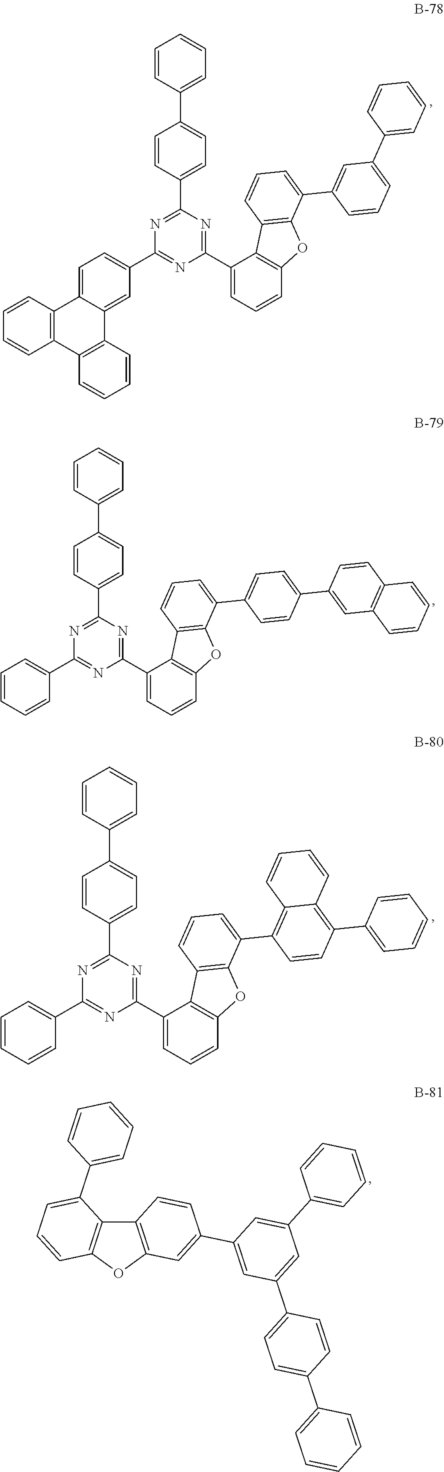 [SMILES: c1ccc(-c2ccc(-c3nc(-c4ccc5c6ccccc6c6ccccc6c5c4)nc(-c4cccc5oc6c(-c7cccc(-c8ccccc8)c7)cccc6c45)n3)cc2)cc1 ; c1ccc(-c2ccc(-c3nc(-c4ccccc4)nc(-c4cccc5oc6c(-c7ccc(-c8ccc9ccccc9c8)cc7)cccc6c45)n3)cc2)cc1 ; c1ccc(-c2ccc(-c3nc(-c4ccccc4)nc(-c4cccc5oc6c(-c7ccc(-c8ccccc8)c8ccccc78)cccc6c45)n3)cc2)cc1 ; c1ccc(-c2ccc(-c3cc(-c4ccccc4)cc(-c4ccc5c(c4)oc4cccc(-c6ccccc6)c45)c3)cc2)cc1]

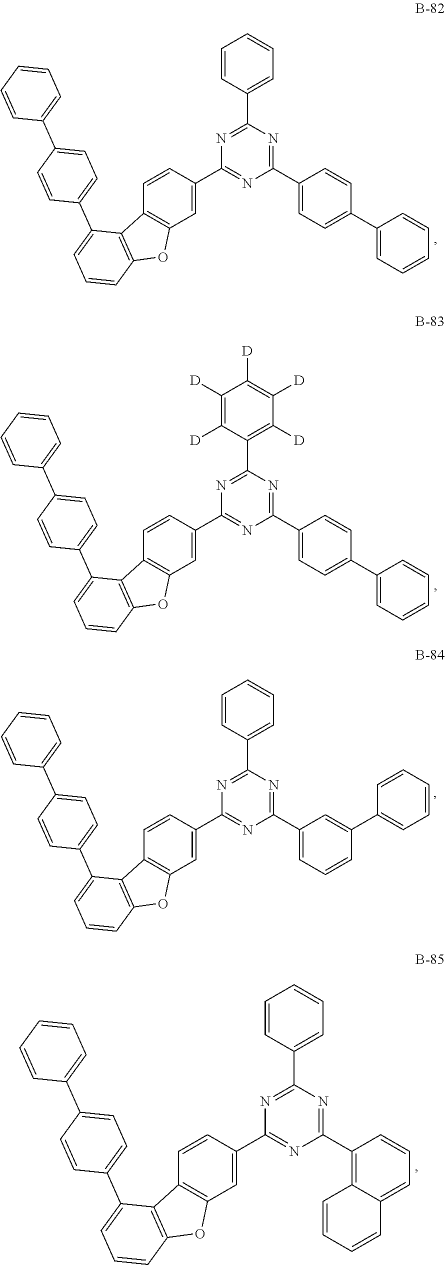 [SMILES: c1ccc(-c2ccc(-c3nc(-c4ccccc4)nc(-c4ccc5c(c4)oc4cccc(-c6ccc(-c7ccccc7)cc6)c45)n3)cc2)cc1 ; [2H]c1c([2H])c([2H])c(-c2nc(-c3ccc(-c4ccccc4)cc3)nc(-c3ccc4c(c3)oc3cccc(-c5ccc(-c6ccccc6)cc5)c34)n2)c([2H])c1[2H] ; c1ccc(-c2ccc(-c3cccc4oc5cc(-c6nc(-c7ccccc7)nc(-c7cccc(-c8ccccc8)c7)n6)ccc5c34)cc2)cc1 ; c1ccc(-c2ccc(-c3cccc4oc5cc(-c6nc(-c7ccccc7)nc(-c7cccc8ccccc78)n6)ccc5c34)cc2)cc1]

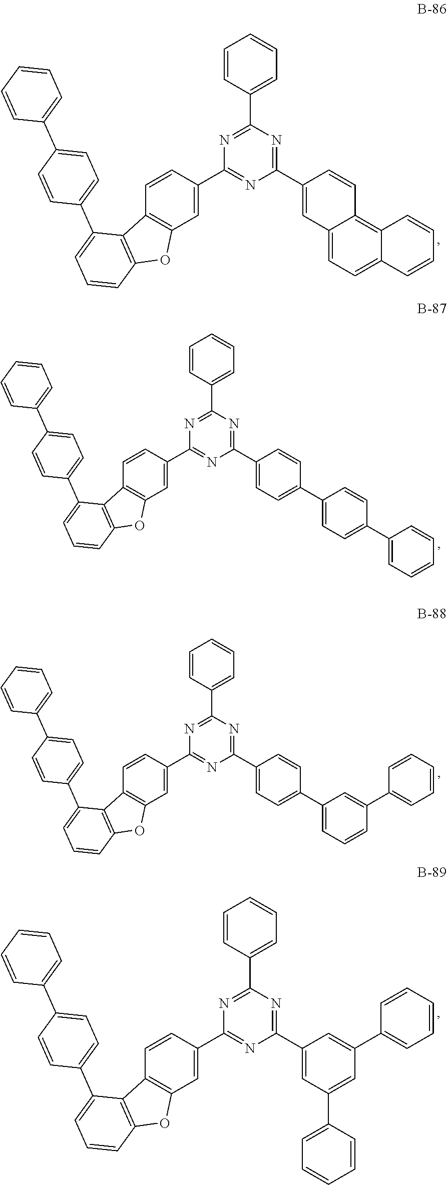 [SMILES: c1ccc(-c2ccc(-c3cccc4oc5cc(-c6nc(-c7ccccc7)nc(-c7ccc8c(ccc9ccccc98)c7)n6)ccc5c34)cc2)cc1 ; c1ccc(-c2ccc(-c3ccc(-c4nc(-c5ccccc5)nc(-c5ccc6c(c5)oc5cccc(-c7ccc(-c8ccccc8)cc7)c56)n4)cc3)cc2)cc1 ; c1ccc(-c2ccc(-c3cccc4oc5cc(-c6nc(-c7ccccc7)nc(-c7ccc(-c8cccc(-c9ccccc9)c8)cc7)n6)ccc5c34)cc2)cc1 ; c1ccc(-c2ccc(-c3cccc4oc5cc(-c6nc(-c7ccccc7)nc(-c7cc(-c8ccccc8)cc(-c8ccccc8)c7)n6)ccc5c34)cc2)cc1]

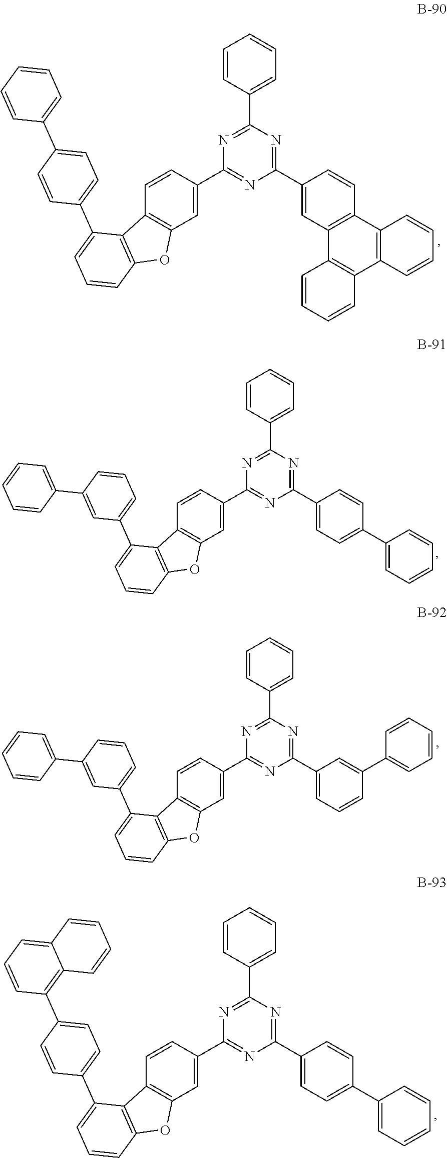 [SMILES: c1ccc(-c2ccc(-c3cccc4oc5cc(-c6nc(-c7ccccc7)nc(-c7ccc8c9ccccc9c9ccccc9c8c7)n6)ccc5c34)cc2)cc1 ; c1ccc(-c2ccc(-c3nc(-c4ccccc4)nc(-c4ccc5c(c4)oc4cccc(-c6cccc(-c7ccccc7)c6)c45)n3)cc2)cc1 ; c1ccc(-c2cccc(-c3nc(-c4ccccc4)nc(-c4ccc5c(c4)oc4cccc(-c6cccc(-c7ccccc7)c6)c45)n3)c2)cc1 ; c1ccc(-c2ccc(-c3nc(-c4ccccc4)nc(-c4ccc5c(c4)oc4cccc(-c6ccc(-c7cccc8ccccc78)cc6)c45)n3)cc2)cc1]

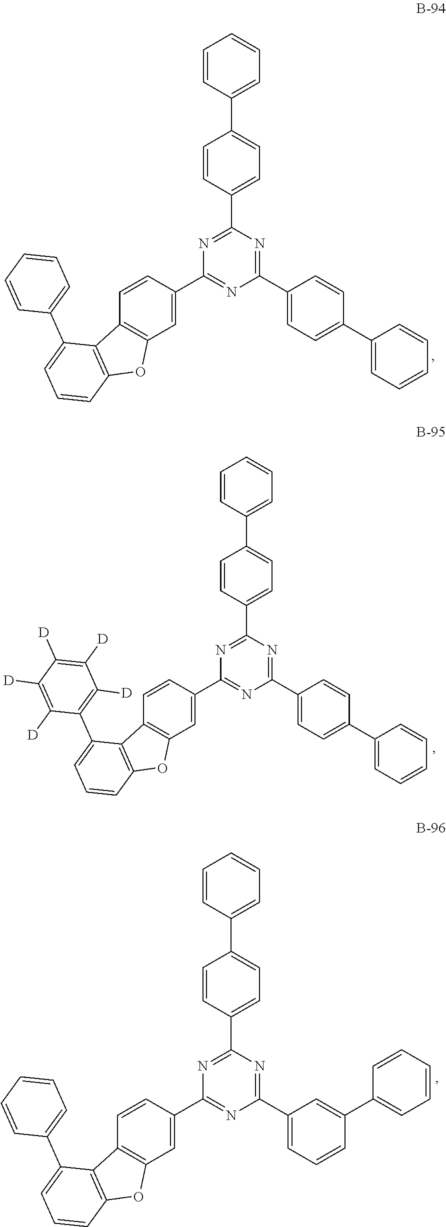 [SMILES: c1ccc(-c2ccc(-c3nc(-c4ccc(-c5ccccc5)cc4)nc(-c4ccc5c(c4)oc4cccc(-c6ccccc6)c45)n3)cc2)cc1 ; [2H]c1c([2H])c([2H])c(-c2cccc3oc4cc(-c5nc(-c6ccc(-c7ccccc7)cc6)nc(-c6ccc(-c7ccccc7)cc6)n5)ccc4c23)c([2H])c1[2H] ; c1ccc(-c2ccc(-c3nc(-c4cccc(-c5ccccc5)c4)nc(-c4ccc5c(c4)oc4cccc(-c6ccccc6)c45)n3)cc2)cc1]

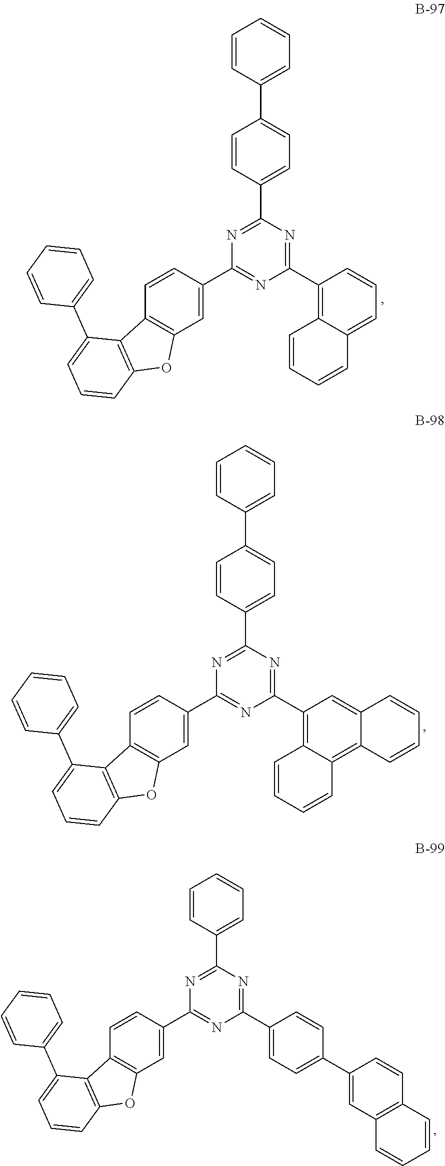 [SMILES: c1ccc(-c2ccc(-c3nc(-c4ccc5c(c4)oc4cccc(-c6ccccc6)c45)nc(-c4cccc5ccccc45)n3)cc2)cc1 ; c1ccc(-c2ccc(-c3nc(-c4ccc5c(c4)oc4cccc(-c6ccccc6)c45)nc(-c4cc5ccccc5c5ccccc45)n3)cc2)cc1 ; c1ccc(-c2nc(-c3ccc(-c4ccc5ccccc5c4)cc3)nc(-c3ccc4c(c3)oc3cccc(-c5ccccc5)c34)n2)cc1]

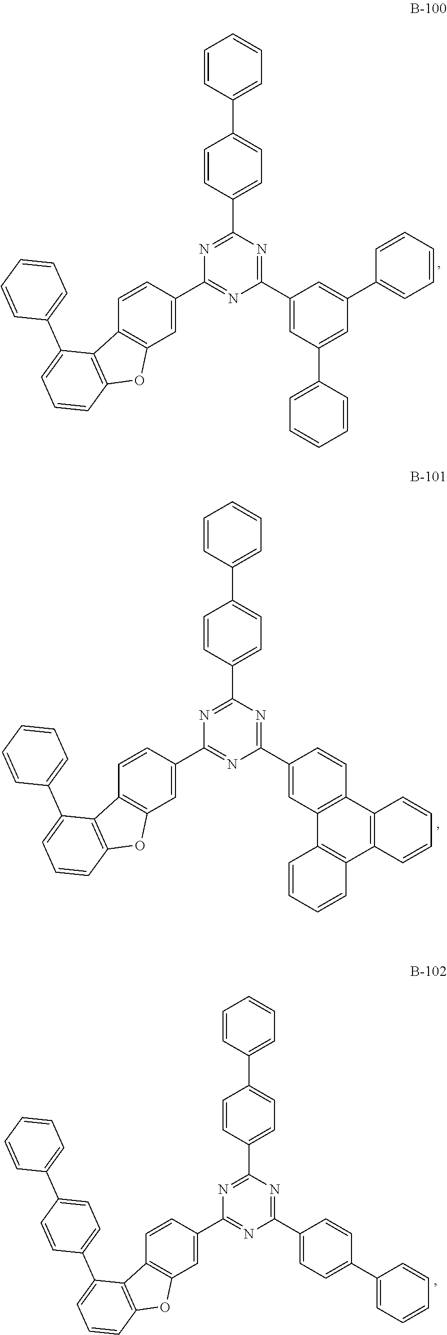 [SMILES: c1ccc(-c2ccc(-c3nc(-c4cc(-c5ccccc5)cc(-c5ccccc5)c4)nc(-c4ccc5c(c4)oc4cccc(-c6ccccc6)c45)n3)cc2)cc1 ; c1ccc(-c2ccc(-c3nc(-c4ccc5c(c4)oc4cccc(-c6ccccc6)c45)nc(-c4ccc5c6ccccc6c6ccccc6c5c4)n3)cc2)cc1 ; c1ccc(-c2ccc(-c3nc(-c4ccc(-c5ccccc5)cc4)nc(-c4ccc5c(c4)oc4cccc(-c6ccc(-c7ccccc7)cc6)c45)n3)cc2)cc1]

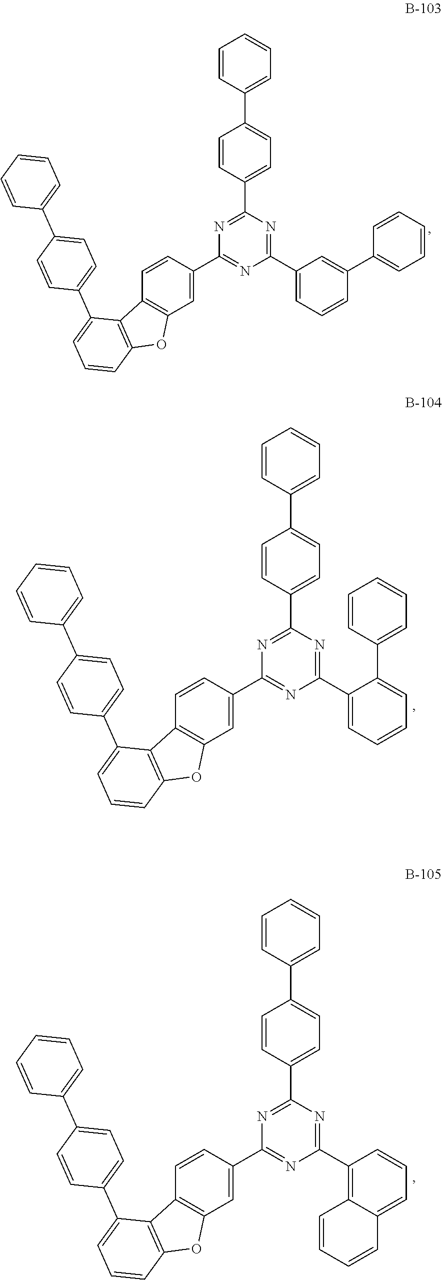 [SMILES: c1ccc(-c2ccc(-c3nc(-c4cccc(-c5ccccc5)c4)nc(-c4ccc5c(c4)oc4cccc(-c6ccc(-c7ccccc7)cc6)c45)n3)cc2)cc1 ; c1ccc(-c2ccc(-c3nc(-c4ccc5c(c4)oc4cccc(-c6ccc(-c7ccccc7)cc6)c45)nc(-c4ccccc4-c4ccccc4)n3)cc2)cc1 ; c1ccc(-c2ccc(-c3nc(-c4ccc5c(c4)oc4cccc(-c6ccc(-c7ccccc7)cc6)c45)nc(-c4cccc5ccccc45)n3)cc2)cc1]

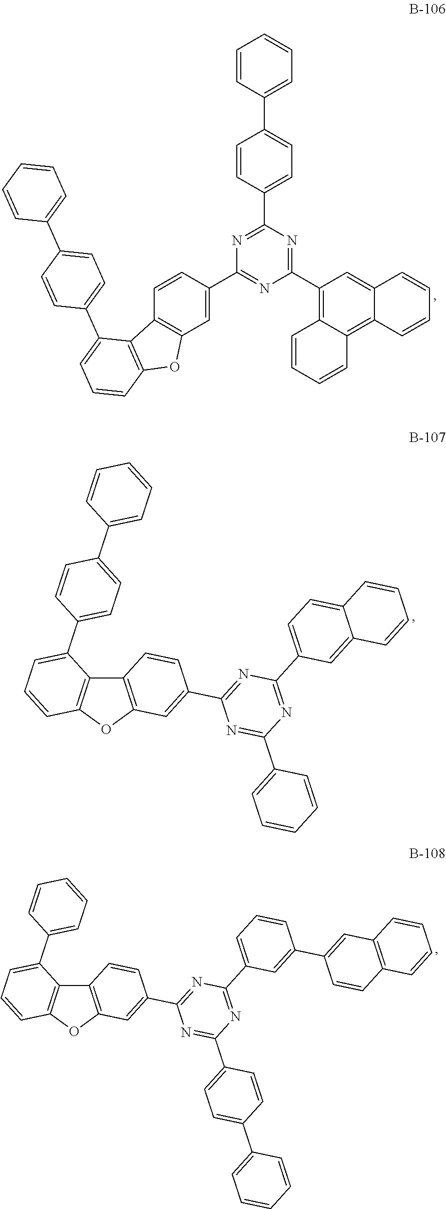 [SMILES: c1ccc(-c2ccc(-c3nc(-c4ccc5c(c4)oc4cccc(-c6ccc(-c7ccccc7)cc6)c45)nc(-c4cc5ccccc5c5ccccc45)n3)cc2)cc1 ; c1ccc(-c2ccc(-c3cccc4oc5cc(-c6nc(-c7ccccc7)nc(-c7ccc8ccccc8c7)n6)ccc5c34)cc2)cc1 ; c1ccc(-c2ccc(-c3nc(-c4cccc(-c5ccc6ccccc6c5)c4)nc(-c4ccc5c(c4)oc4cccc(-c6ccccc6)c45)n3)cc2)cc1]

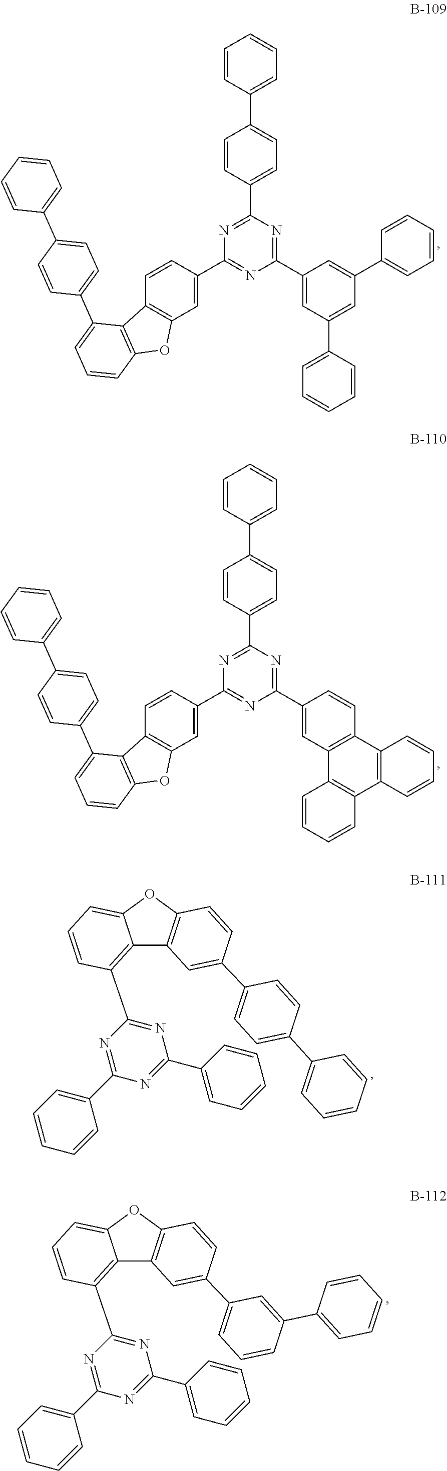 [SMILES: c1ccc(-c2ccc(-c3nc(-c4cc(-c5ccccc5)cc(-c5ccccc5)c4)nc(-c4ccc5c(c4)oc4cccc(-c6ccc(-c7ccccc7)cc6)c45)n3)cc2)cc1 ; c1ccc(-c2ccc(-c3nc(-c4ccc5c(c4)oc4cccc(-c6ccc(-c7ccccc7)cc6)c45)nc(-c4ccc5c6ccccc6c6ccccc6c5c4)n3)cc2)cc1 ; c1ccc(-c2ccc(-c3ccc4oc5cccc(-c6nc(-c7ccccc7)nc(-c7ccccc7)n6)c5c4c3)cc2)cc1 ; c1ccc(-c2cccc(-c3ccc4oc5cccc(-c6nc(-c7ccccc7)nc(-c7ccccc7)n6)c5c4c3)c2)cc1]

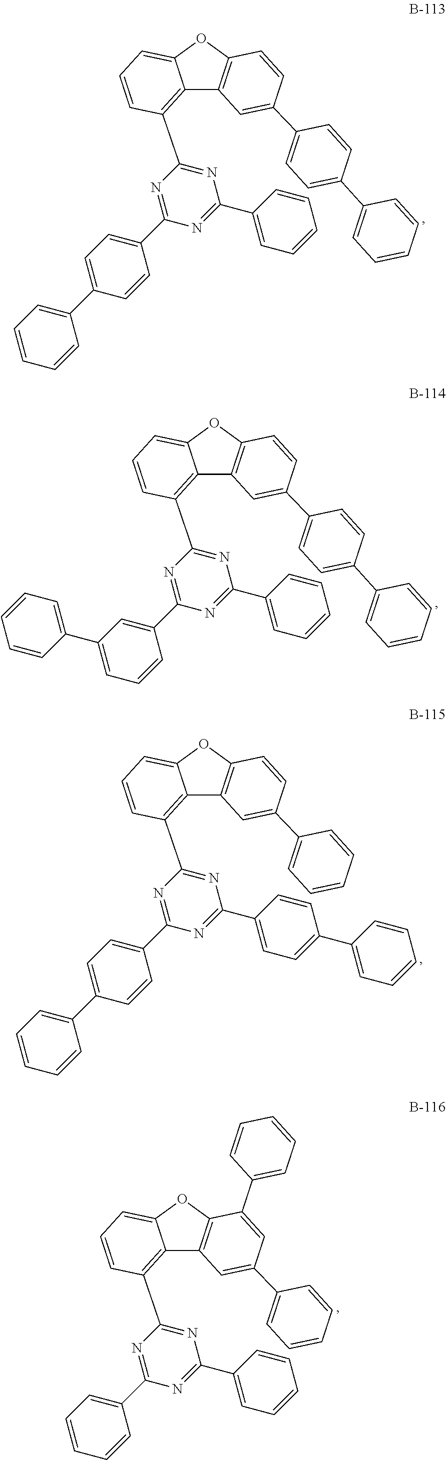 [SMILES: c1ccc(-c2ccc(-c3ccc4oc5cccc(-c6nc(-c7ccccc7)nc(-c7ccc(-c8ccccc8)cc7)n6)c5c4c3)cc2)cc1 ; c1ccc(-c2ccc(-c3ccc4oc5cccc(-c6nc(-c7ccccc7)nc(-c7cccc(-c8ccccc8)c7)n6)c5c4c3)cc2)cc1 ; c1ccc(-c2ccc(-c3nc(-c4ccc(-c5ccccc5)cc4)nc(-c4cccc5oc6ccc(-c7ccccc7)cc6c45)n3)cc2)cc1 ; c1ccc(-c2cc(-c3ccccc3)c3oc4cccc(-c5nc(-c6ccccc6)nc(-c6ccccc6)n5)c4c3c2)cc1]

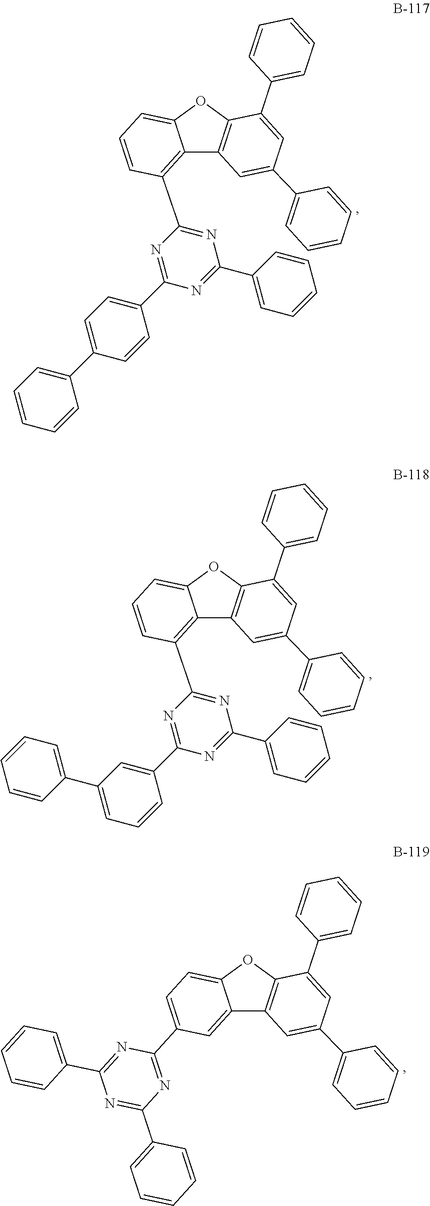 [SMILES: c1ccc(-c2ccc(-c3nc(-c4ccccc4)nc(-c4cccc5oc6c(-c7ccccc7)cc(-c7ccccc7)cc6c45)n3)cc2)cc1 ; c1ccc(-c2cccc(-c3nc(-c4ccccc4)nc(-c4cccc5oc6c(-c7ccccc7)cc(-c7ccccc7)cc6c45)n3)c2)cc1 ; c1ccc(-c2cc(-c3ccccc3)c3oc4ccc(-c5nc(-c6ccccc6)nc(-c6ccccc6)n5)cc4c3c2)cc1]

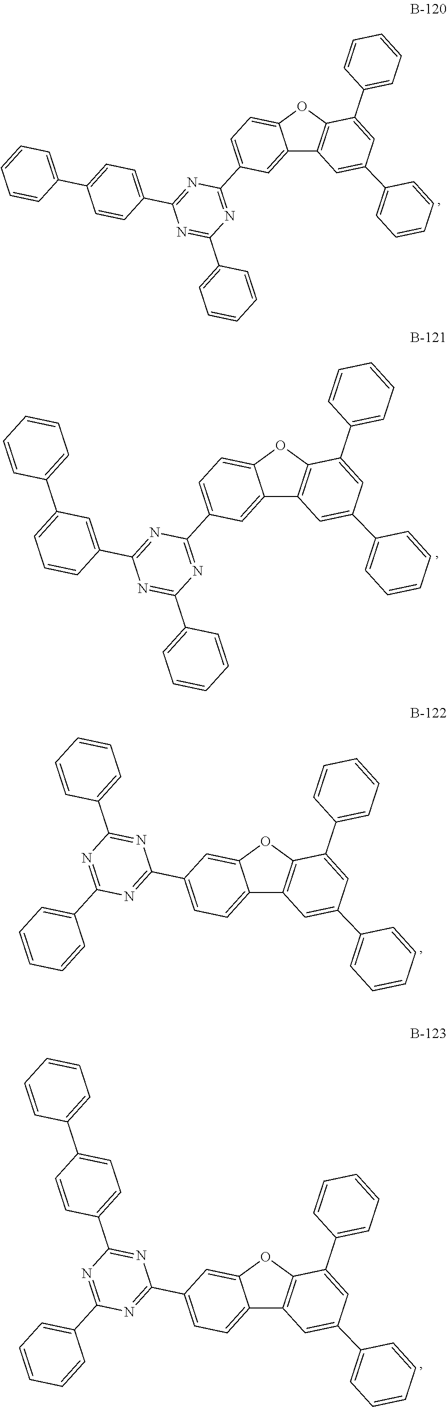 [SMILES: c1ccc(-c2ccc(-c3nc(-c4ccccc4)nc(-c4ccc5oc6c(-c7ccccc7)cc(-c7ccccc7)cc6c5c4)n3)cc2)cc1 ; c1ccc(-c2cccc(-c3nc(-c4ccccc4)nc(-c4ccc5oc6c(-c7ccccc7)cc(-c7ccccc7)cc6c5c4)n3)c2)cc1 ; c1ccc(-c2cc(-c3ccccc3)c3oc4cc(-c5nc(-c6ccccc6)nc(-c6ccccc6)n5)ccc4c3c2)cc1 ; c1ccc(-c2ccc(-c3nc(-c4ccccc4)nc(-c4ccc5c(c4)oc4c(-c6ccccc6)cc(-c6ccccc6)cc45)n3)cc2)cc1]

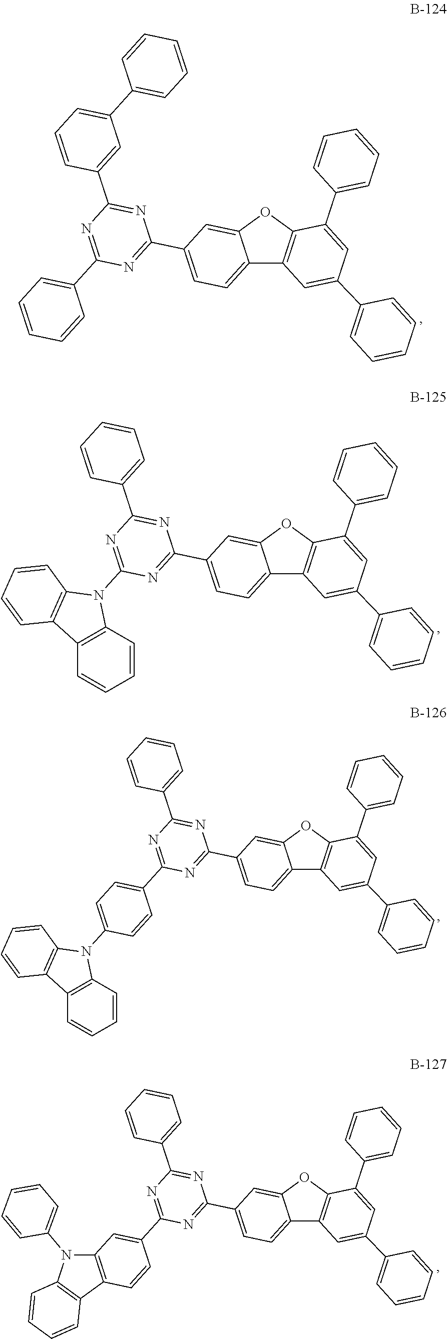 [SMILES: c1ccc(-c2cccc(-c3nc(-c4ccccc4)nc(-c4ccc5c(c4)oc4c(-c6ccccc6)cc(-c6ccccc6)cc45)n3)c2)cc1 ; c1ccc(-c2cc(-c3ccccc3)c3oc4cc(-c5nc(-c6ccccc6)nc(-n6c7ccccc7c7ccccc76)n5)ccc4c3c2)cc1 ; c1ccc(-c2cc(-c3ccccc3)c3oc4cc(-c5nc(-c6ccccc6)nc(-c6ccc(-n7c8ccccc8c8ccccc87)cc6)n5)ccc4c3c2)cc1 ; c1ccc(-c2cc(-c3ccccc3)c3oc4cc(-c5nc(-c6ccccc6)nc(-c6ccc7c8ccccc8n(-c8ccccc8)c7c6)n5)ccc4c3c2)cc1]

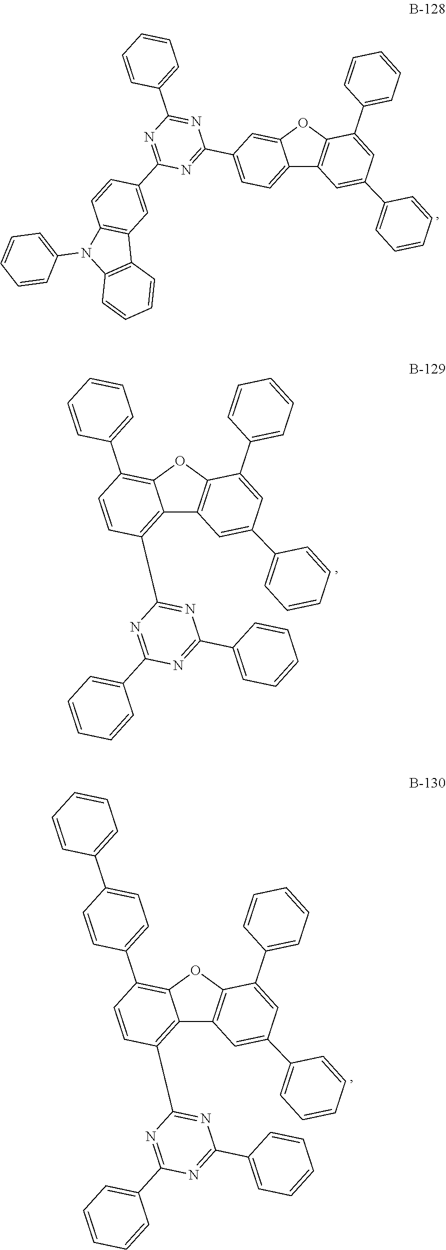 [SMILES: c1ccc(-c2cc(-c3ccccc3)c3oc4cc(-c5nc(-c6ccccc6)nc(-c6ccc7c(c6)c6ccccc6n7-c6ccccc6)n5)ccc4c3c2)cc1 ; c1ccc(-c2cc(-c3ccccc3)c3oc4c(-c5ccccc5)ccc(-c5nc(-c6ccccc6)nc(-c6ccccc6)n5)c4c3c2)cc1 ; c1ccc(-c2ccc(-c3ccc(-c4nc(-c5ccccc5)nc(-c5ccccc5)n4)c4c3oc3c(-c5ccccc5)cc(-c5ccccc5)cc34)cc2)cc1]

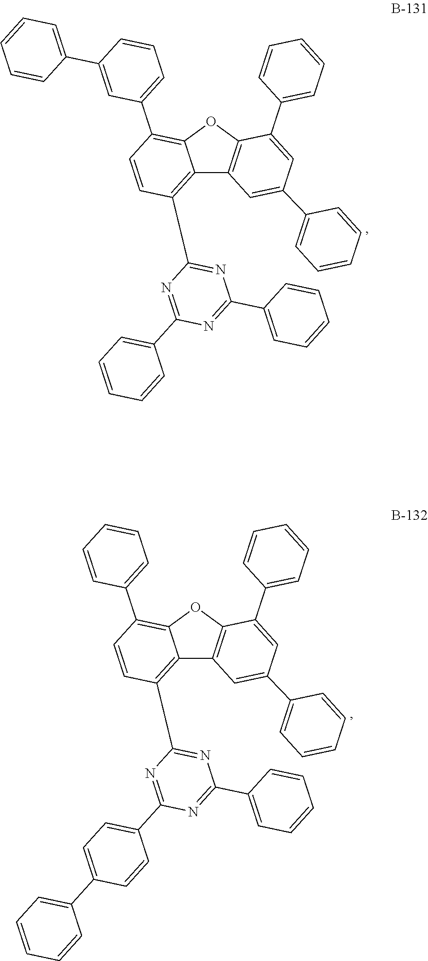 [SMILES: c1ccc(-c2cccc(-c3ccc(-c4nc(-c5ccccc5)nc(-c5ccccc5)n4)c4c3oc3c(-c5ccccc5)cc(-c5ccccc5)cc34)c2)cc1 ; c1ccc(-c2ccc(-c3nc(-c4ccccc4)nc(-c4ccc(-c5ccccc5)c5oc6c(-c7ccccc7)cc(-c7ccccc7)cc6c45)n3)cc2)cc1]

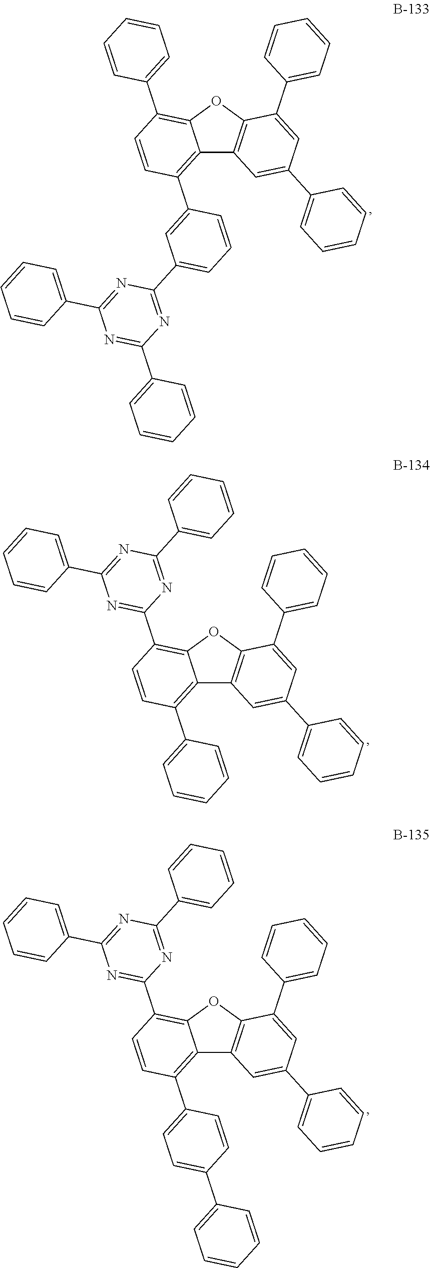

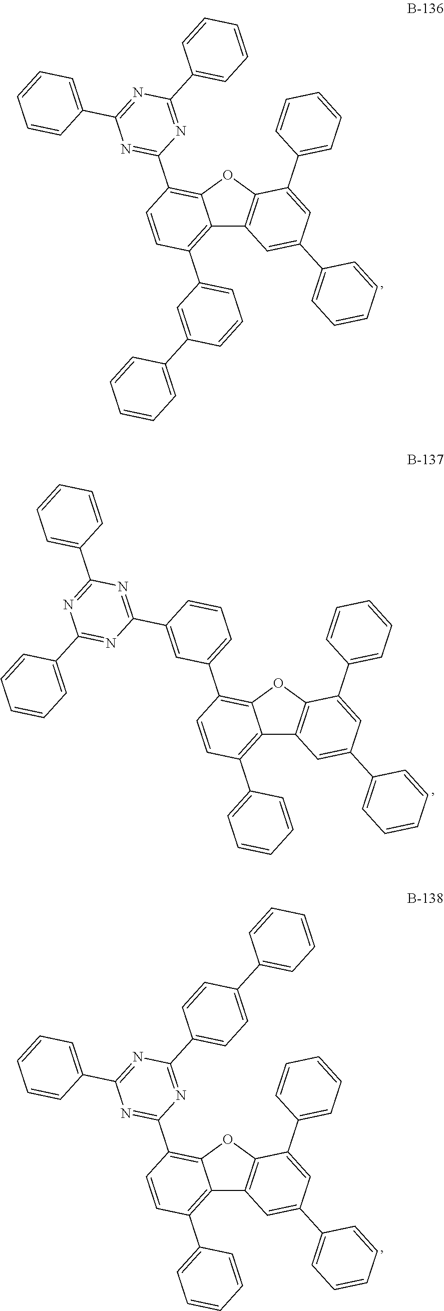 [SMILES: c1ccc(-c2cccc(-c3ccc(-c4nc(-c5ccccc5)nc(-c5ccccc5)n4)c4oc5c(-c6ccccc6)cc(-c6ccccc6)cc5c34)c2)cc1 ; c1ccc(-c2cc(-c3ccccc3)c3oc4c(-c5cccc(-c6nc(-c7ccccc7)nc(-c7ccccc7)n6)c5)ccc(-c5ccccc5)c4c3c2)cc1 ; c1ccc(-c2ccc(-c3nc(-c4ccccc4)nc(-c4ccc(-c5ccccc5)c5c4oc4c(-c6ccccc6)cc(-c6ccccc6)cc45)n3)cc2)cc1]

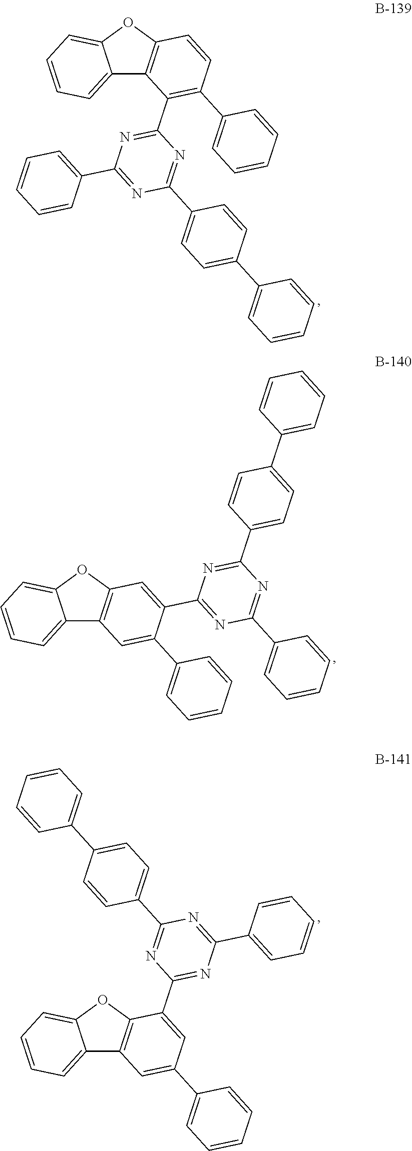

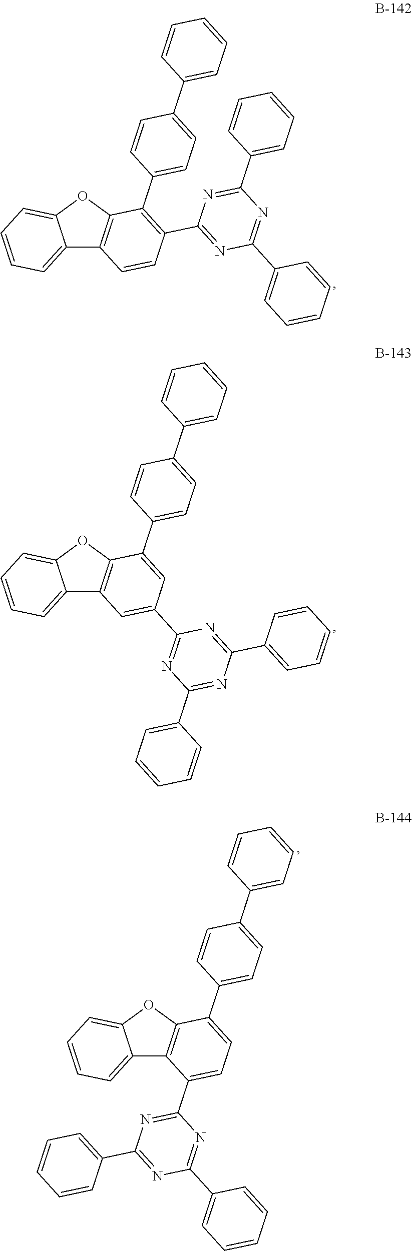 [SMILES: c1ccc(-c2ccc(-c3c(-c4nc(-c5ccccc5)nc(-c5ccccc5)n4)ccc4c3oc3ccccc34)cc2)cc1 ; c1ccc(-c2ccc(-c3cc(-c4nc(-c5ccccc5)nc(-c5ccccc5)n4)cc4c3oc3ccccc34)cc2)cc1 ; c1ccc(-c2ccc(-c3ccc(-c4nc(-c5ccccc5)nc(-c5ccccc5)n4)c4c3oc3ccccc34)cc2)cc1]

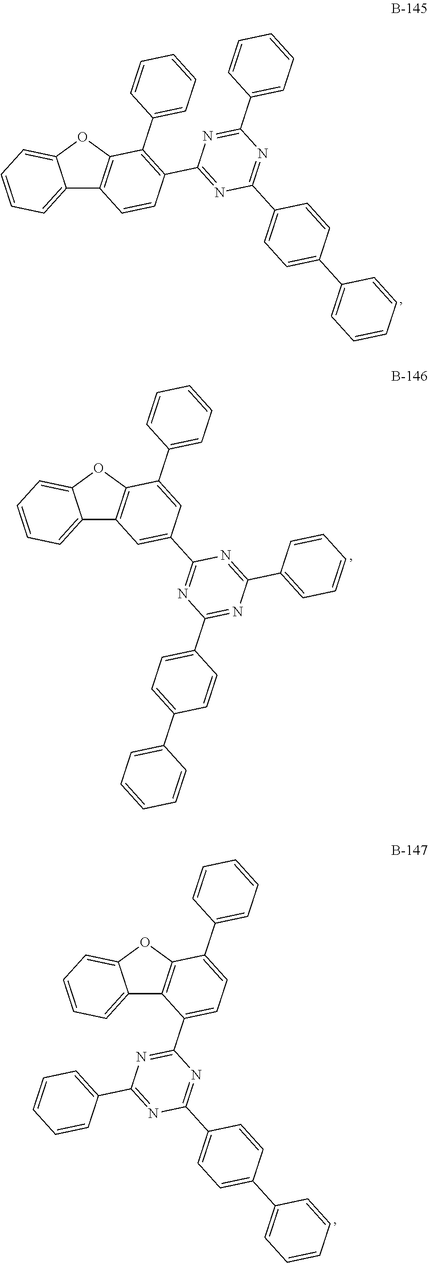 [SMILES: c1ccc(-c2ccc(-c3nc(-c4ccccc4)nc(-c4ccc5c(oc6ccccc65)c4-c4ccccc4)n3)cc2)cc1 ; c1ccc(-c2ccc(-c3nc(-c4ccccc4)nc(-c4cc(-c5ccccc5)c5oc6ccccc6c5c4)n3)cc2)cc1 ; c1ccc(-c2ccc(-c3nc(-c4ccccc4)nc(-c4ccc(-c5ccccc5)c5oc6ccccc6c45)n3)cc2)cc1]

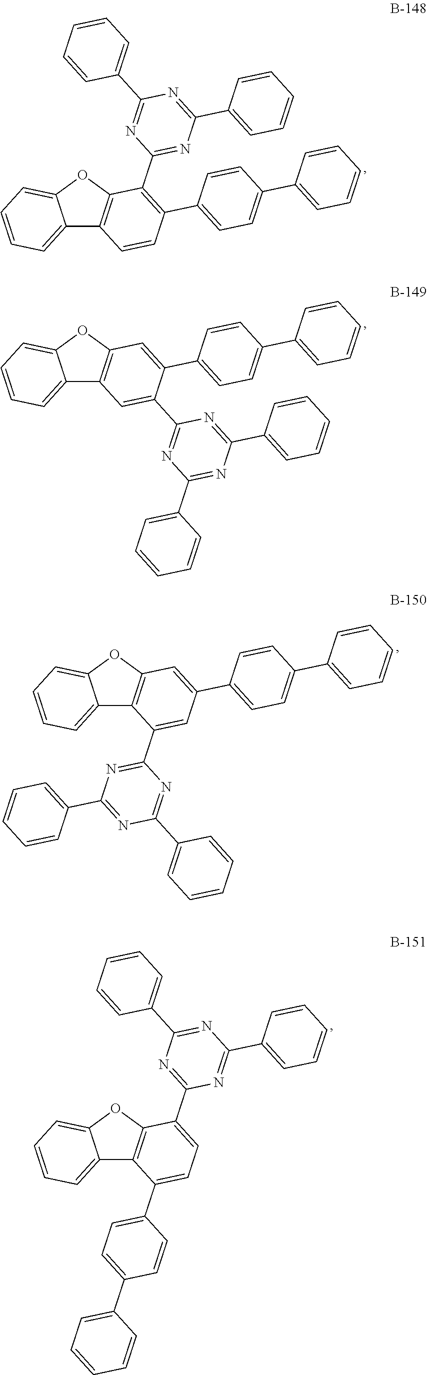 [SMILES: c1ccc(-c2ccc(-c3ccc4c(oc5ccccc54)c3-c3nc(-c4ccccc4)nc(-c4ccccc4)n3)cc2)cc1 ; c1ccc(-c2ccc(-c3cc4oc5ccccc5c4cc3-c3nc(-c4ccccc4)nc(-c4ccccc4)n3)cc2)cc1 ; c1ccc(-c2ccc(-c3cc(-c4nc(-c5ccccc5)nc(-c5ccccc5)n4)c4c(c3)oc3ccccc34)cc2)cc1 ; c1ccc(-c2ccc(-c3ccc(-c4nc(-c5ccccc5)nc(-c5ccccc5)n4)c4oc5ccccc5c34)cc2)cc1]

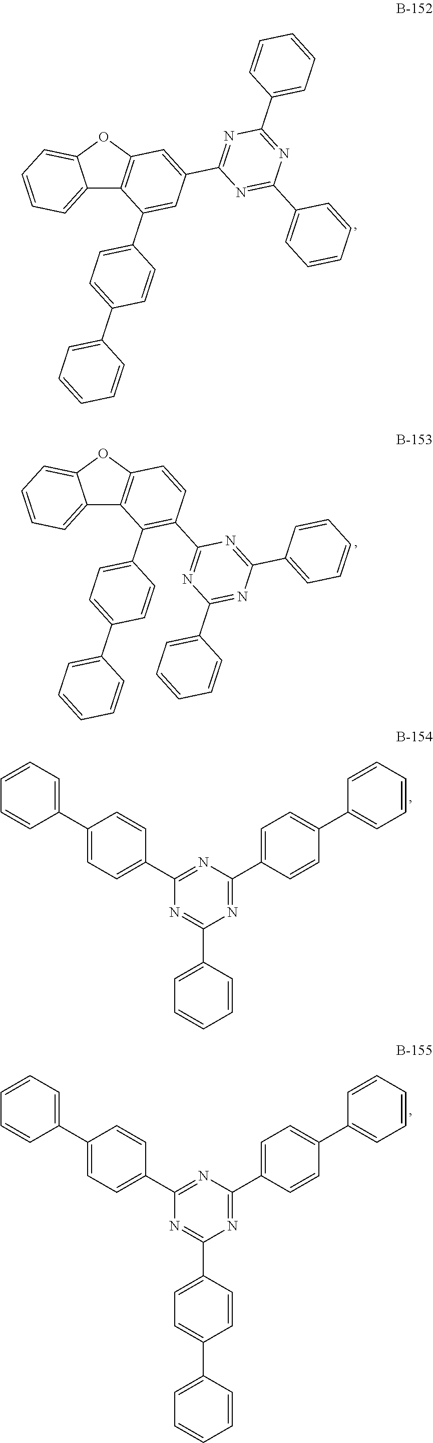 [SMILES: c1ccc(-c2ccc(-c3cc(-c4nc(-c5ccccc5)nc(-c5ccccc5)n4)cc4oc5ccccc5c34)cc2)cc1 ; c1ccc(-c2ccc(-c3c(-c4nc(-c5ccccc5)nc(-c5ccccc5)n4)ccc4oc5ccccc5c34)cc2)cc1 ; c1ccc(-c2ccc(-c3nc(-c4ccccc4)nc(-c4ccc(-c5ccccc5)cc4)n3)cc2)cc1 ; c1ccc(-c2ccc(-c3nc(-c4ccc(-c5ccccc5)cc4)nc(-c4ccc(-c5ccccc5)cc4)n3)cc2)cc1]

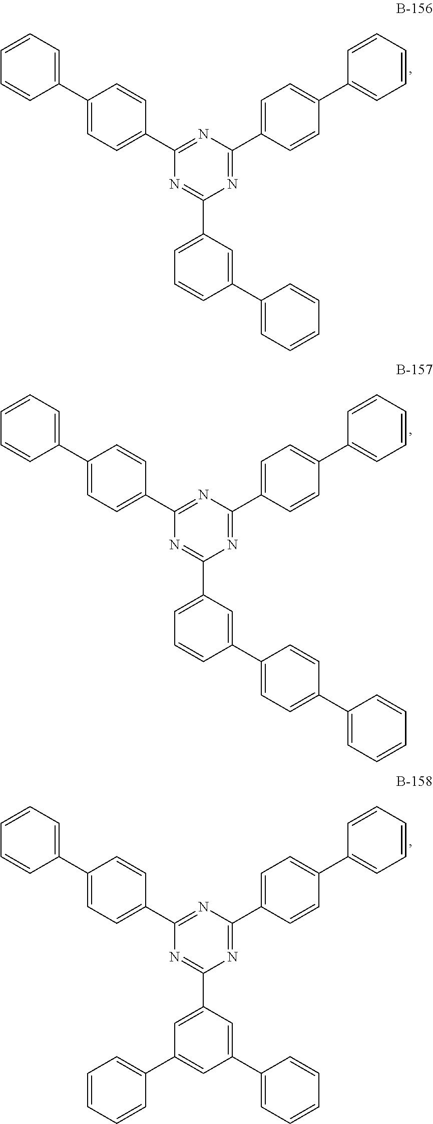

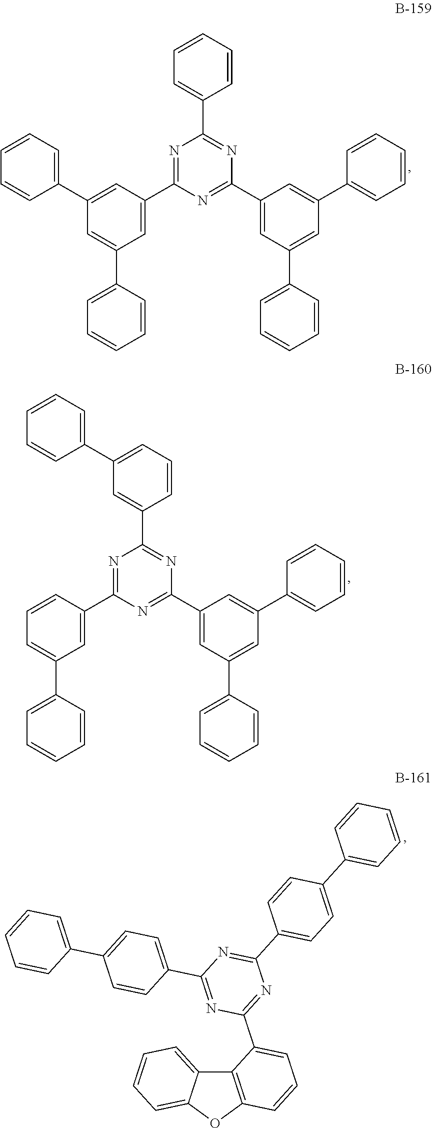 [SMILES: c1ccc(-c2cc(-c3ccccc3)cc(-c3nc(-c4ccccc4)nc(-c4cc(-c5ccccc5)cc(-c5ccccc5)c4)n3)c2)cc1 ; c1ccc(-c2cccc(-c3nc(-c4cccc(-c5ccccc5)c4)nc(-c4cc(-c5ccccc5)cc(-c5ccccc5)c4)n3)c2)cc1 ; c1ccc(-c2ccc(-c3nc(-c4ccc(-c5ccccc5)cc4)nc(-c4cccc5oc6ccccc6c45)n3)cc2)cc1]

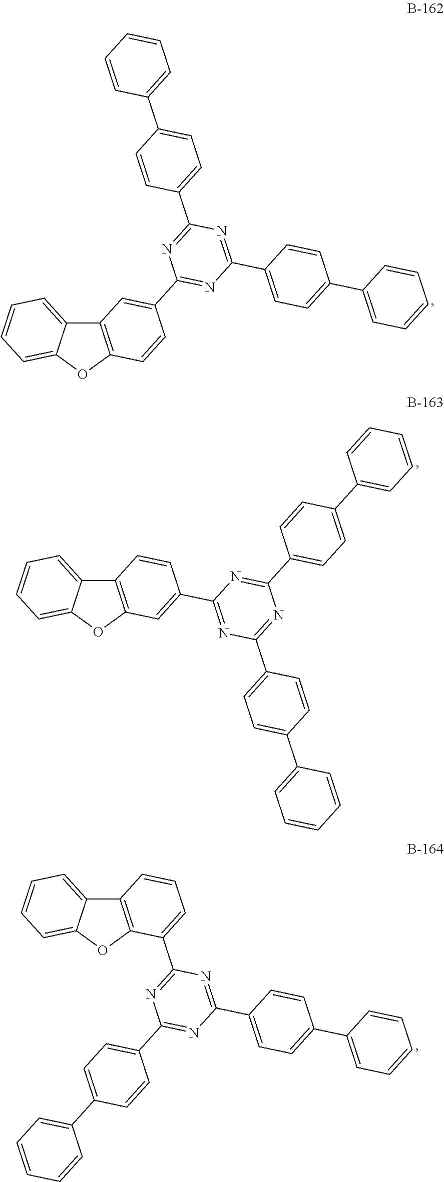 [SMILES: c1ccc(-c2ccc(-c3nc(-c4ccc(-c5ccccc5)cc4)nc(-c4ccc5oc6ccccc6c5c4)n3)cc2)cc1 ; c1ccc(-c2ccc(-c3nc(-c4ccc(-c5ccccc5)cc4)nc(-c4ccc5c(c4)oc4ccccc45)n3)cc2)cc1 ; c1ccc(-c2ccc(-c3nc(-c4ccc(-c5ccccc5)cc4)nc(-c4cccc5c4oc4ccccc45)n3)cc2)cc1]

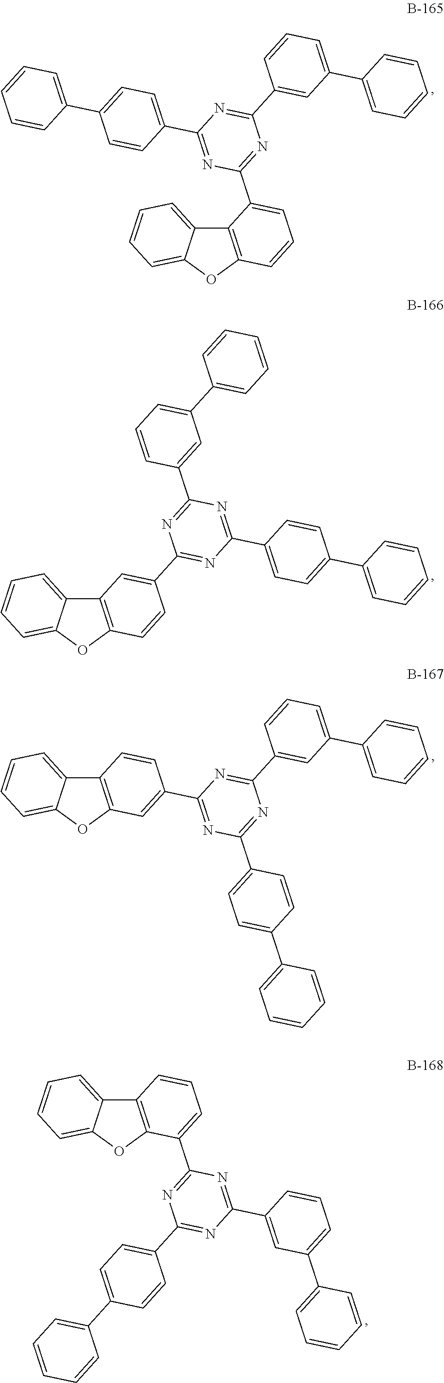 [SMILES: c1ccc(-c2ccc(-c3nc(-c4cccc(-c5ccccc5)c4)nc(-c4cccc5oc6ccccc6c45)n3)cc2)cc1 ; c1ccc(-c2ccc(-c3nc(-c4cccc(-c5ccccc5)c4)nc(-c4ccc5oc6ccccc6c5c4)n3)cc2)cc1 ; c1ccc(-c2ccc(-c3nc(-c4cccc(-c5ccccc5)c4)nc(-c4ccc5c(c4)oc4ccccc45)n3)cc2)cc1 ; c1ccc(-c2ccc(-c3nc(-c4cccc(-c5ccccc5)c4)nc(-c4cccc5c4oc4ccccc45)n3)cc2)cc1]

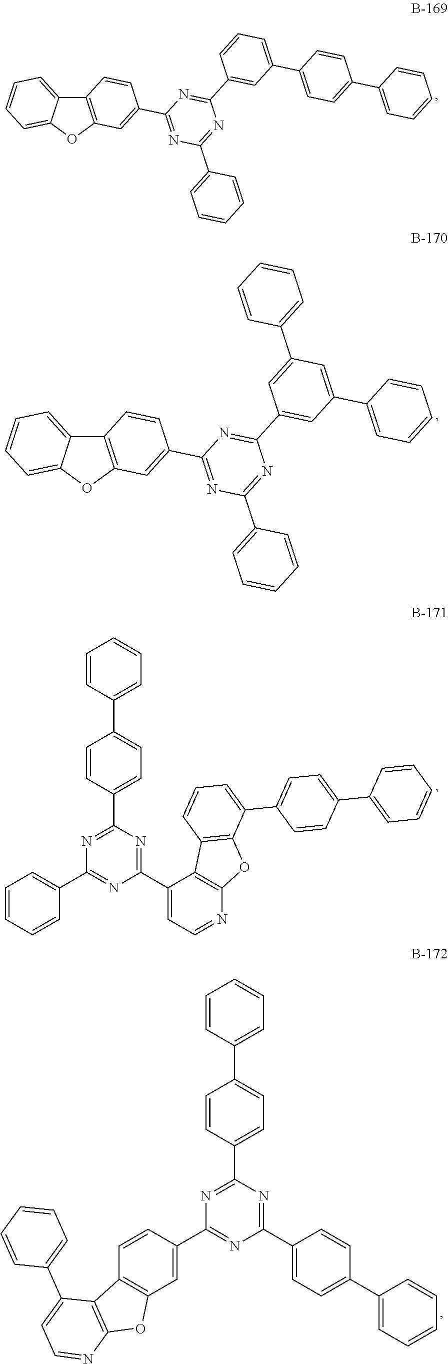 [SMILES: c1ccc(-c2ccc(-c3cccc(-c4nc(-c5ccccc5)nc(-c5ccc6c(c5)oc5ccccc56)n4)c3)cc2)cc1 ; c1ccc(-c2cc(-c3ccccc3)cc(-c3nc(-c4ccccc4)nc(-c4ccc5c(c4)oc4ccccc45)n3)c2)cc1 ; c1ccc(-c2ccc(-c3nc(-c4ccccc4)nc(-c4ccnc5oc6c(-c7ccc(-c8ccccc8)cc7)cccc6c45)n3)cc2)cc1 ; c1ccc(-c2ccc(-c3nc(-c4ccc(-c5ccccc5)cc4)nc(-c4ccc5c(c4)oc4nccc(-c6ccccc6)c45)n3)cc2)cc1]

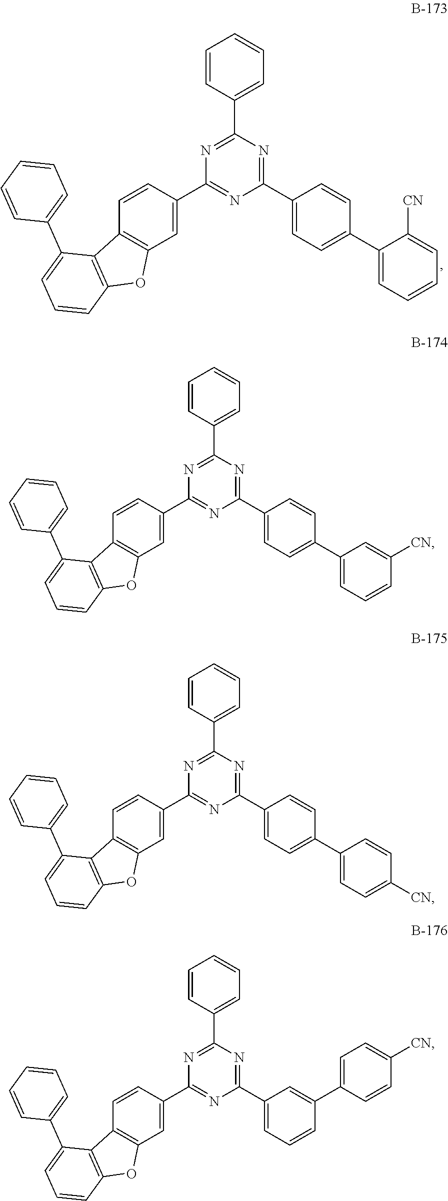 [SMILES: N#Cc1ccccc1-c1ccc(-c2nc(-c3ccccc3)nc(-c3ccc4c(c3)oc3cccc(-c5ccccc5)c34)n2)cc1 ; N#Cc1cccc(-c2ccc(-c3nc(-c4ccccc4)nc(-c4ccc5c(c4)oc4cccc(-c6ccccc6)c45)n3)cc2)c1 ; N#Cc1ccc(-c2ccc(-c3nc(-c4ccccc4)nc(-c4ccc5c(c4)oc4cccc(-c6ccccc6)c45)n3)cc2)cc1 ; N#Cc1ccc(-c2cccc(-c3nc(-c4ccccc4)nc(-c4ccc5c(c4)oc4cccc(-c6ccccc6)c45)n3)c2)cc1]

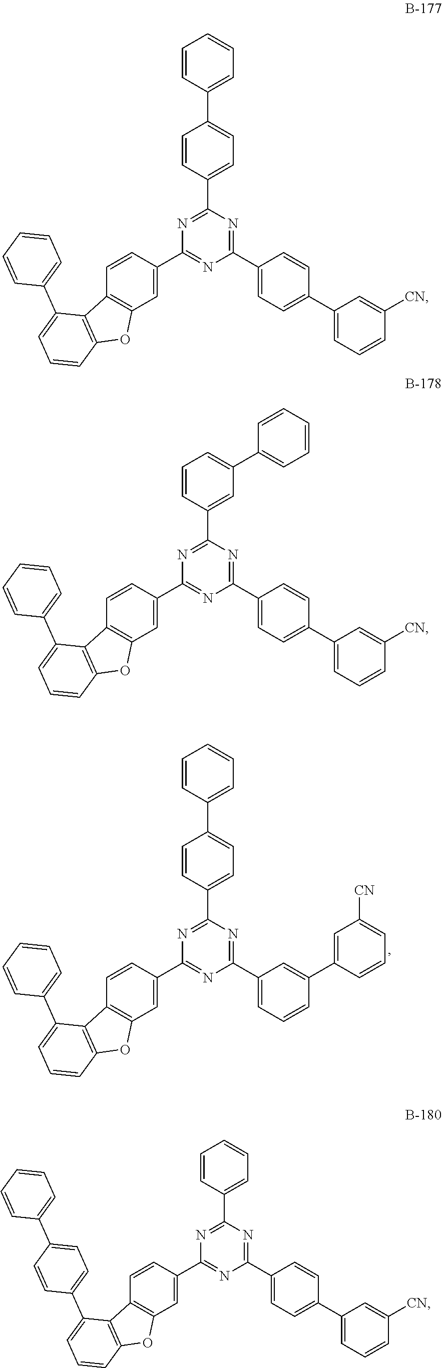 [SMILES: N#Cc1cccc(-c2ccc(-c3nc(-c4ccc(-c5ccccc5)cc4)nc(-c4ccc5c(c4)oc4cccc(-c6ccccc6)c45)n3)cc2)c1 ; N#Cc1cccc(-c2ccc(-c3nc(-c4cccc(-c5ccccc5)c4)nc(-c4ccc5c(c4)oc4cccc(-c6ccccc6)c45)n3)cc2)c1 ; N#Cc1cccc(-c2cccc(-c3nc(-c4ccc(-c5ccccc5)cc4)nc(-c4ccc5c(c4)oc4cccc(-c6ccccc6)c45)n3)c2)c1 ; N#Cc1cccc(-c2ccc(-c3nc(-c4ccccc4)nc(-c4ccc5c(c4)oc4cccc(-c6ccc(-c7ccccc7)cc6)c45)n3)cc2)c1]

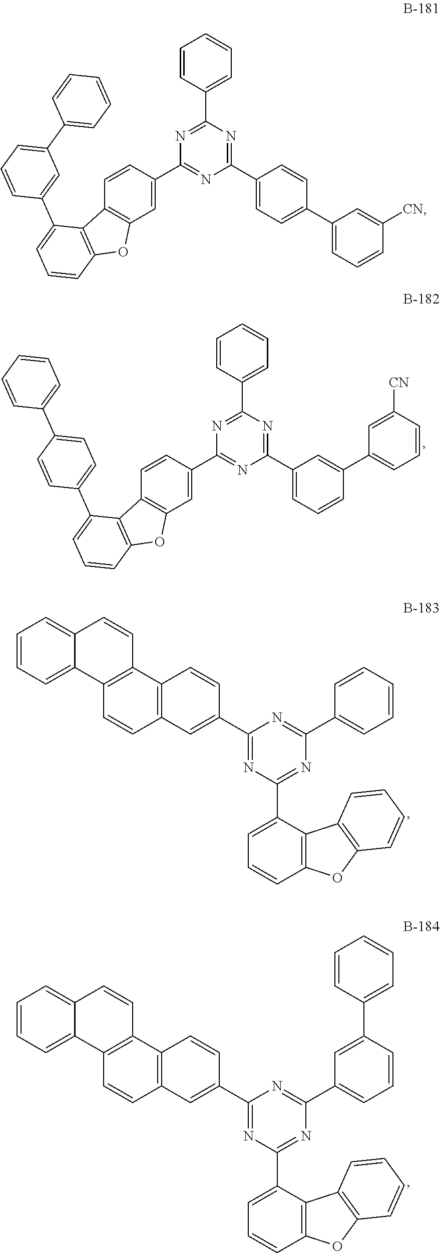 [SMILES: N#Cc1cccc(-c2ccc(-c3nc(-c4ccccc4)nc(-c4ccc5c(c4)oc4cccc(-c6cccc(-c7ccccc7)c6)c45)n3)cc2)c1 ; N#Cc1cccc(-c2cccc(-c3nc(-c4ccccc4)nc(-c4ccc5c(c4)oc4cccc(-c6ccc(-c7ccccc7)cc6)c45)n3)c2)c1 ; c1ccc(-c2nc(-c3ccc4c(ccc5c6ccccc6ccc45)c3)nc(-c3cccc4oc5ccccc5c34)n2)cc1 ; c1ccc(-c2cccc(-c3nc(-c4ccc5c(ccc6c7ccccc7ccc56)c4)nc(-c4cccc5oc6ccccc6c45)n3)c2)cc1]

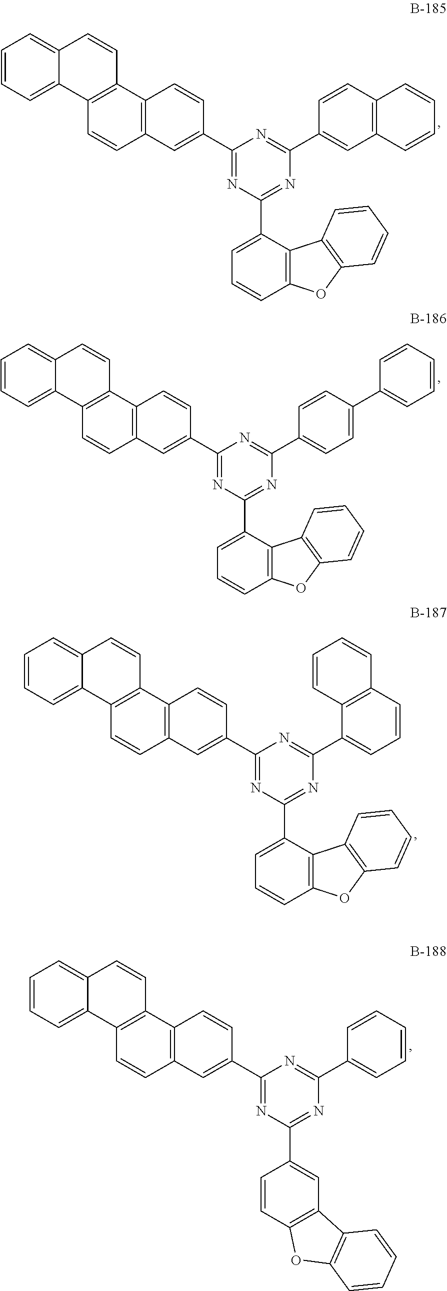 [SMILES: c1ccc2cc(-c3nc(-c4ccc5c(ccc6c7ccccc7ccc56)c4)nc(-c4cccc5oc6ccccc6c45)n3)ccc2c1 ; c1ccc(-c2ccc(-c3nc(-c4ccc5c(ccc6c7ccccc7ccc56)c4)nc(-c4cccc5oc6ccccc6c45)n3)cc2)cc1 ; c1ccc2c(-c3nc(-c4ccc5c(ccc6c7ccccc7ccc56)c4)nc(-c4cccc5oc6ccccc6c45)n3)cccc2c1 ; c1ccc(-c2nc(-c3ccc4c(ccc5c6ccccc6ccc45)c3)nc(-c3ccc4oc5ccccc5c4c3)n2)cc1]

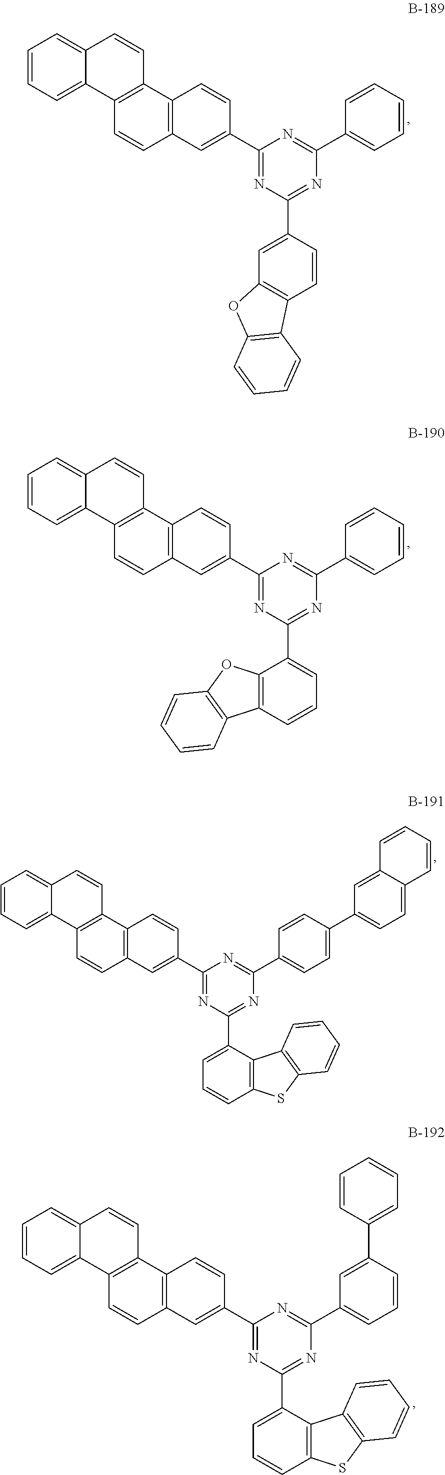 [SMILES: c1ccc(-c2nc(-c3ccc4c(ccc5c6ccccc6ccc45)c3)nc(-c3ccc4c(c3)oc3ccccc34)n2)cc1 ; c1ccc(-c2nc(-c3ccc4c(ccc5c6ccccc6ccc45)c3)nc(-c3cccc4c3oc3ccccc34)n2)cc1 ; c1ccc2cc(-c3ccc(-c4nc(-c5ccc6c(ccc7c8ccccc8ccc67)c5)nc(-c5cccc6sc7ccccc7c56)n4)cc3)ccc2c1 ; c1ccc(-c2cccc(-c3nc(-c4ccc5c(ccc6c7ccccc7ccc56)c4)nc(-c4cccc5sc6ccccc6c45)n3)c2)cc1]

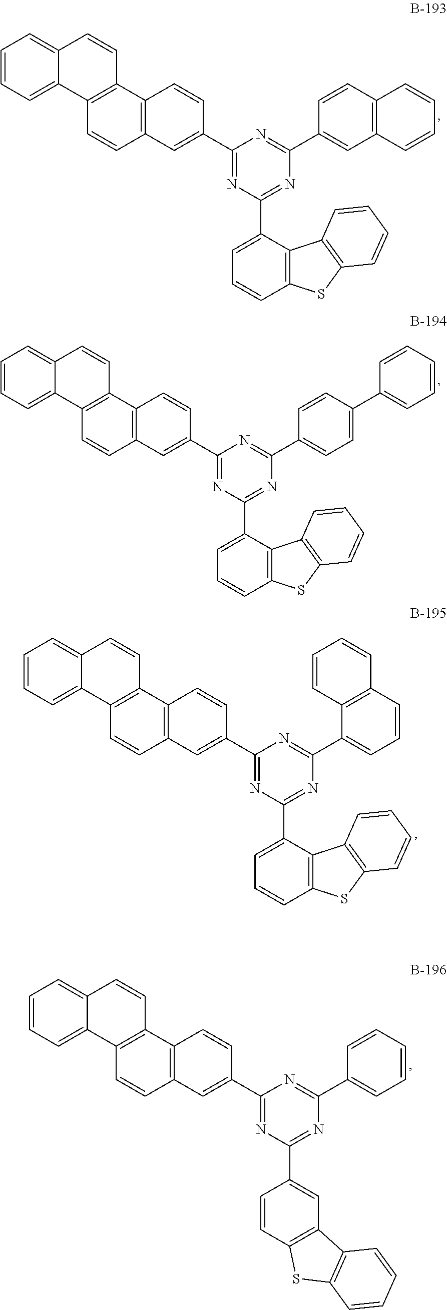 [SMILES: c1ccc2cc(-c3nc(-c4ccc5c(ccc6c7ccccc7ccc56)c4)nc(-c4cccc5sc6ccccc6c45)n3)ccc2c1 ; c1ccc(-c2ccc(-c3nc(-c4ccc5c(ccc6c7ccccc7ccc56)c4)nc(-c4cccc5sc6ccccc6c45)n3)cc2)cc1 ; c1ccc2c(-c3nc(-c4ccc5c(ccc6c7ccccc7ccc56)c4)nc(-c4cccc5sc6ccccc6c45)n3)cccc2c1 ; c1ccc(-c2nc(-c3ccc4c(ccc5c6ccccc6ccc45)c3)nc(-c3ccc4sc5ccccc5c4c3)n2)cc1]

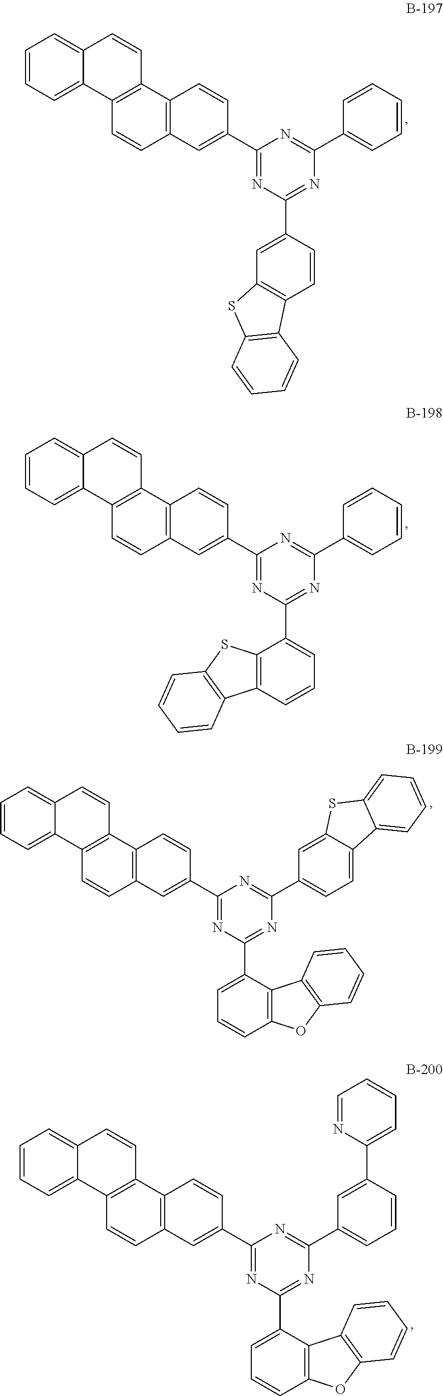 [SMILES: c1ccc(-c2nc(-c3ccc4c(ccc5c6ccccc6ccc45)c3)nc(-c3ccc4c(c3)sc3ccccc34)n2)cc1 ; c1ccc(-c2nc(-c3ccc4c(ccc5c6ccccc6ccc45)c3)nc(-c3cccc4c3sc3ccccc34)n2)cc1 ; c1ccc2c(c1)ccc1c3ccc(-c4nc(-c5ccc6c(c5)sc5ccccc56)nc(-c5cccc6oc7ccccc7c56)n4)cc3ccc21 ; c1ccc(-c2cccc(-c3nc(-c4ccc5c(ccc6c7ccccc7ccc56)c4)nc(-c4cccc5oc6ccccc6c45)n3)c2)nc1]

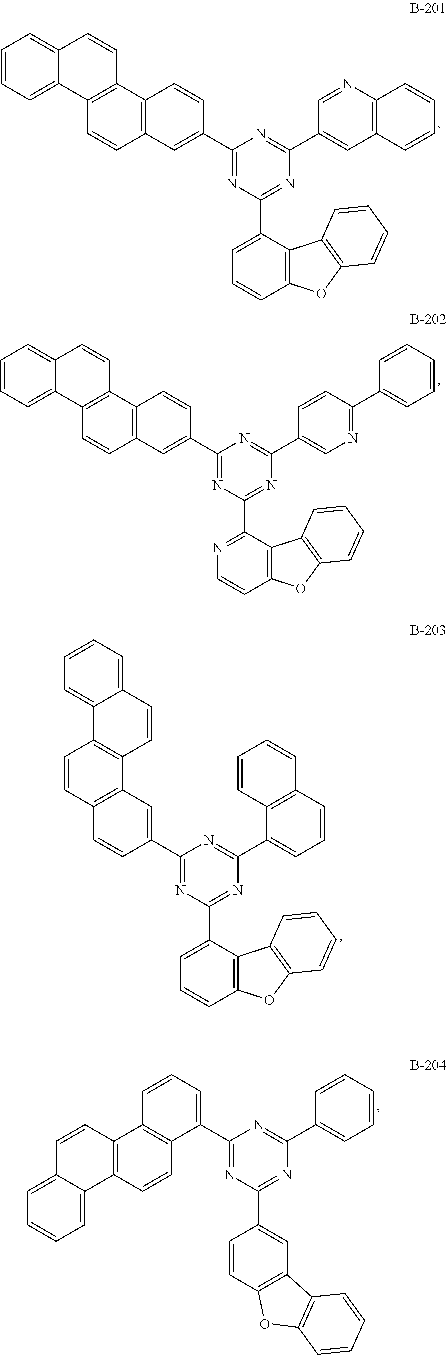 [SMILES: c1ccc2ncc(-c3nc(-c4ccc5c(ccc6c7ccccc7ccc56)c4)nc(-c4cccc5oc6ccccc6c45)n3)cc2c1 ; c1ccc(-c2ccc(-c3nc(-c4ccc5c(ccc6c7ccccc7ccc56)c4)nc(-c4nccc5oc6ccccc6c45)n3)cn2)cc1 ; c1ccc2c(-c3nc(-c4ccc5ccc6c7ccccc7ccc6c5c4)nc(-c4cccc5oc6ccccc6c45)n3)cccc2c1 ; c1ccc(-c2nc(-c3ccc4oc5ccccc5c4c3)nc(-c3cccc4c3ccc3c5ccccc5ccc43)n2)cc1]

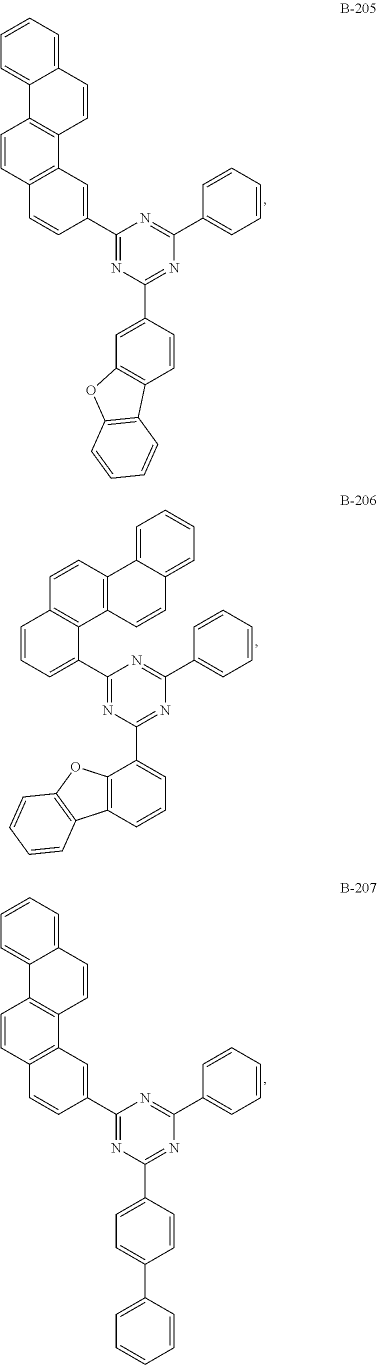

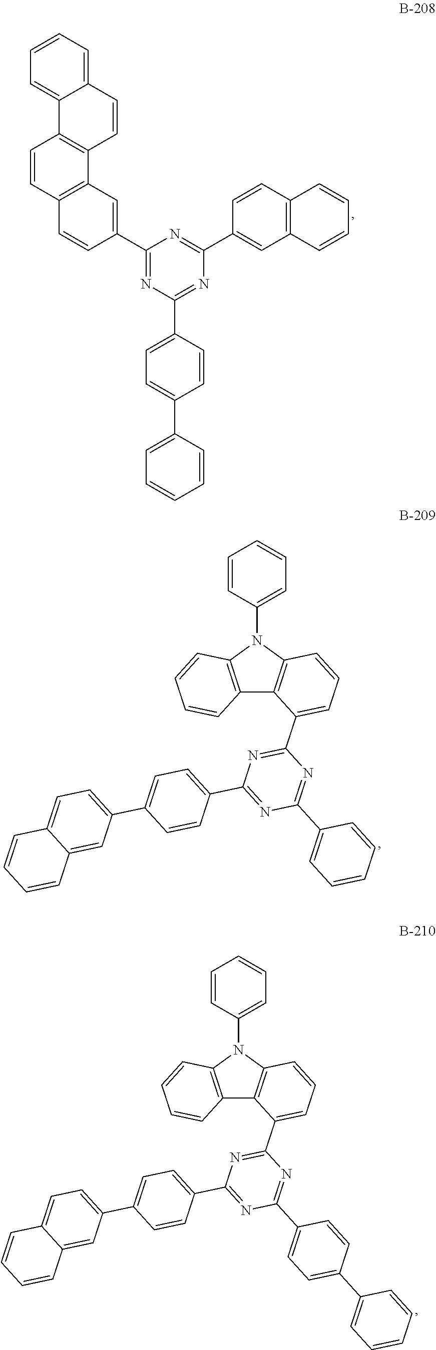 [SMILES: c1ccc(-c2ccc(-c3nc(-c4ccc5ccccc5c4)nc(-c4ccc5ccc6c7ccccc7ccc6c5c4)n3)cc2)cc1 ; c1ccc(-c2nc(-c3ccc(-c4ccc5ccccc5c4)cc3)nc(-c3cccc4c3c3ccccc3n4-c3ccccc3)n2)cc1 ; c1ccc(-c2ccc(-c3nc(-c4ccc(-c5ccc6ccccc6c5)cc4)nc(-c4cccc5c4c4ccccc4n5-c4ccccc4)n3)cc2)cc1]

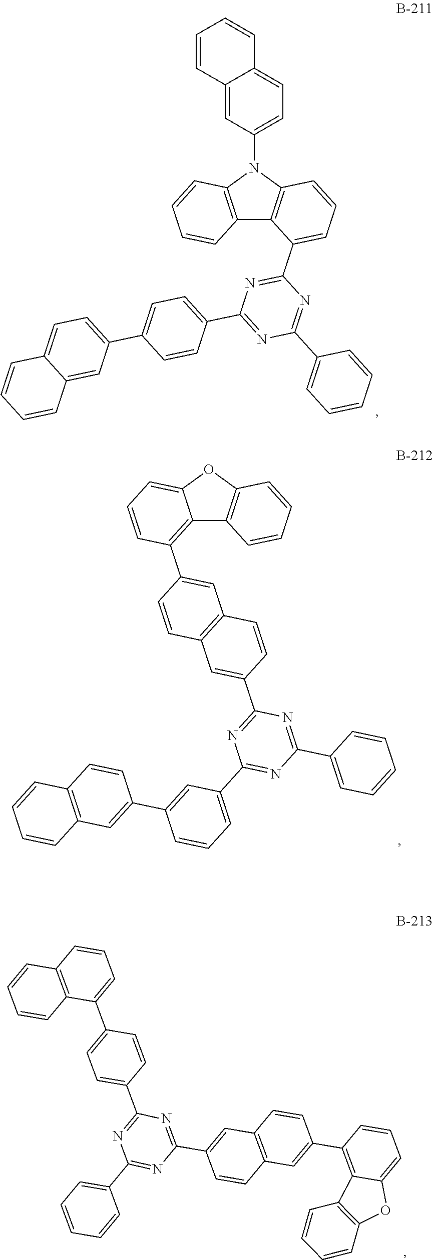 [SMILES: c1ccc(-c2nc(-c3ccc(-c4ccc5ccccc5c4)cc3)nc(-c3cccc4c3c3ccccc3n4-c3ccc4ccccc4c3)n2)cc1 ; c1ccc(-c2nc(-c3cccc(-c4ccc5ccccc5c4)c3)nc(-c3ccc4cc(-c5cccc6oc7ccccc7c56)ccc4c3)n2)cc1 ; c1ccc(-c2nc(-c3ccc(-c4cccc5ccccc45)cc3)nc(-c3ccc4cc(-c5cccc6oc7ccccc7c56)ccc4c3)n2)cc1]

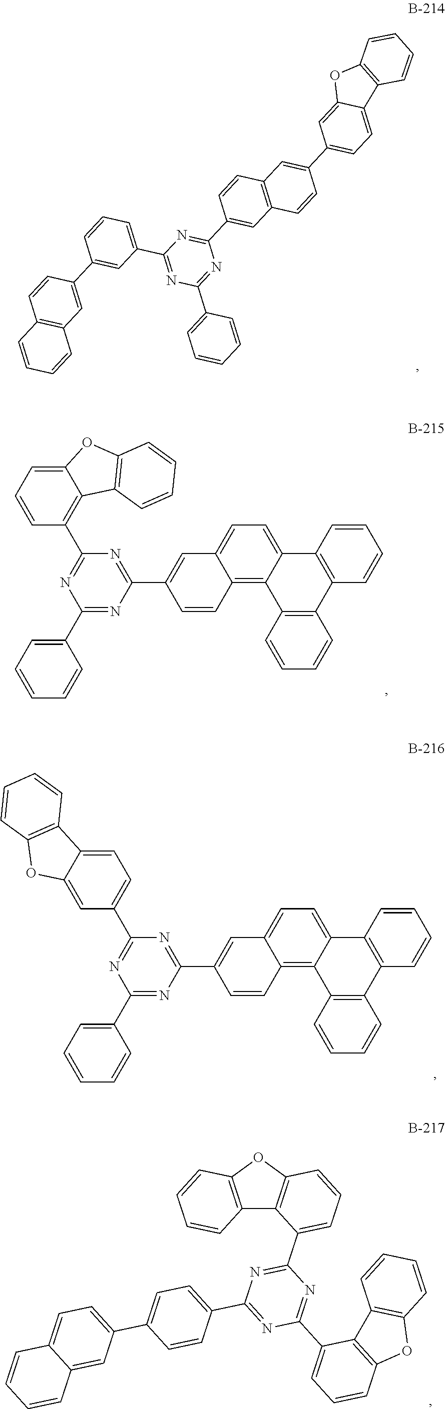 [SMILES: c1ccc(-c2nc(-c3cccc(-c4ccc5ccccc5c4)c3)nc(-c3ccc4cc(-c5ccc6c(c5)oc5ccccc56)ccc4c3)n2)cc1 ; c1ccc(-c2nc(-c3ccc4c(ccc5c6ccccc6c6ccccc6c45)c3)nc(-c3cccc4oc5ccccc5c34)n2)cc1 ; c1ccc(-c2nc(-c3ccc4c(ccc5c6ccccc6c6ccccc6c45)c3)nc(-c3ccc4c(c3)oc3ccccc34)n2)cc1 ; c1ccc2cc(-c3ccc(-c4nc(-c5cccc6oc7ccccc7c56)nc(-c5cccc6oc7ccccc7c56)n4)cc3)ccc2c1]

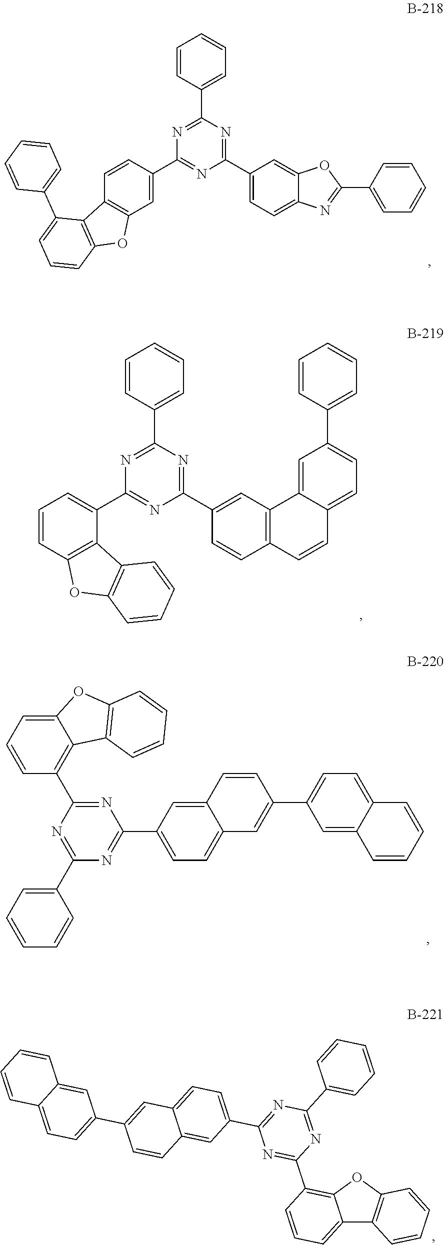 [SMILES: c1ccc(-c2nc(-c3ccc4nc(-c5ccccc5)oc4c3)nc(-c3ccc4c(c3)oc3cccc(-c5ccccc5)c34)n2)cc1 ; c1ccc(-c2ccc3ccc4ccc(-c5nc(-c6ccccc6)nc(-c6cccc7oc8ccccc8c67)n5)cc4c3c2)cc1 ; c1ccc(-c2nc(-c3ccc4cc(-c5ccc6ccccc6c5)ccc4c3)nc(-c3cccc4oc5ccccc5c34)n2)cc1 ; c1ccc(-c2nc(-c3ccc4cc(-c5ccc6ccccc6c5)ccc4c3)nc(-c3cccc4c3oc3ccccc34)n2)cc1]

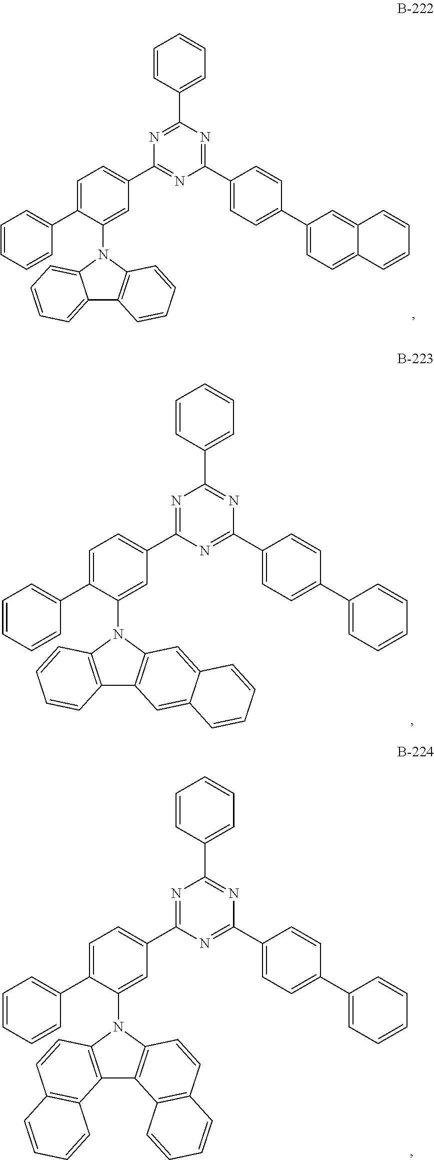 [SMILES: c1ccc(-c2nc(-c3ccc(-c4ccc5ccccc5c4)cc3)nc(-c3ccc(-c4ccccc4)c(-n4c5ccccc5c5ccccc54)c3)n2)cc1 ; c1ccc(-c2ccc(-c3nc(-c4ccccc4)nc(-c4ccc(-c5ccccc5)c(-n5c6ccccc6c6cc7ccccc7cc65)c4)n3)cc2)cc1 ; c1ccc(-c2ccc(-c3nc(-c4ccccc4)nc(-c4ccc(-c5ccccc5)c(-n5c6ccc7ccccc7c6c6c7ccccc7ccc65)c4)n3)cc2)cc1]

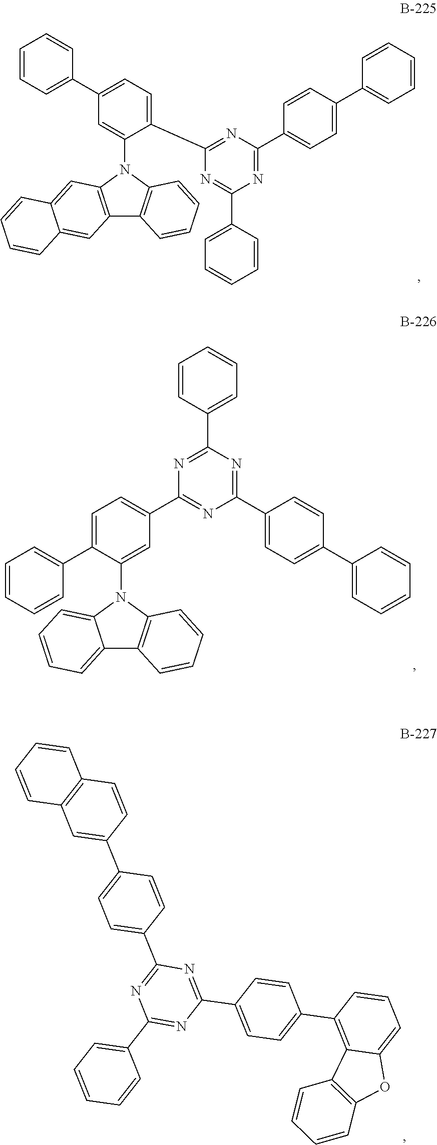 [SMILES: c1ccc(-c2ccc(-c3nc(-c4ccccc4)nc(-c4ccc(-c5ccccc5)cc4-n4c5ccccc5c5cc6ccccc6cc54)n3)cc2)cc1 ; c1ccc(-c2ccc(-c3nc(-c4ccccc4)nc(-c4ccc(-c5ccccc5)c(-n5c6ccccc6c6ccccc65)c4)n3)cc2)cc1 ; c1ccc(-c2nc(-c3ccc(-c4ccc5ccccc5c4)cc3)nc(-c3ccc(-c4cccc5oc6ccccc6c45)cc3)n2)cc1]

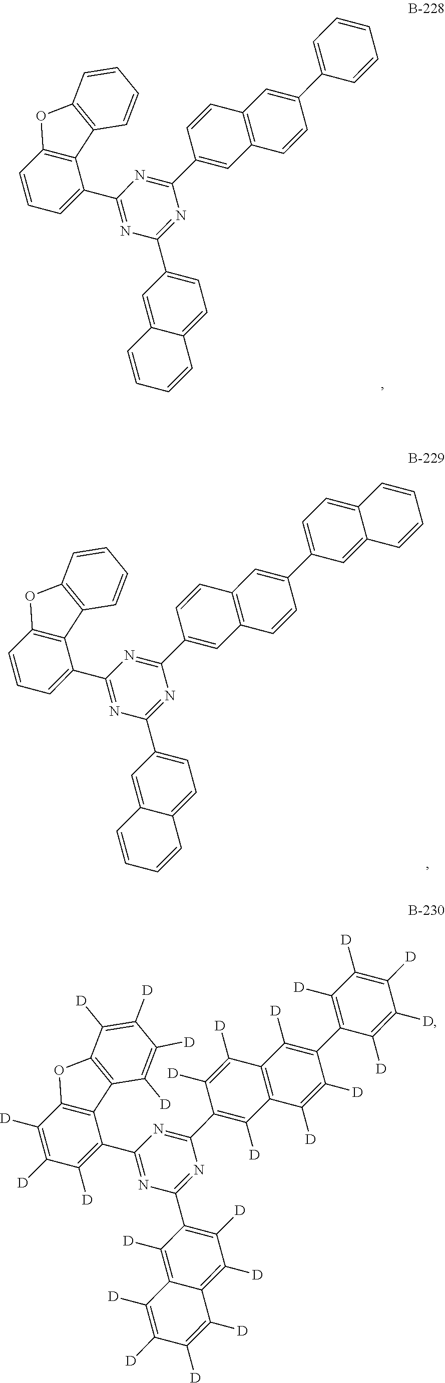

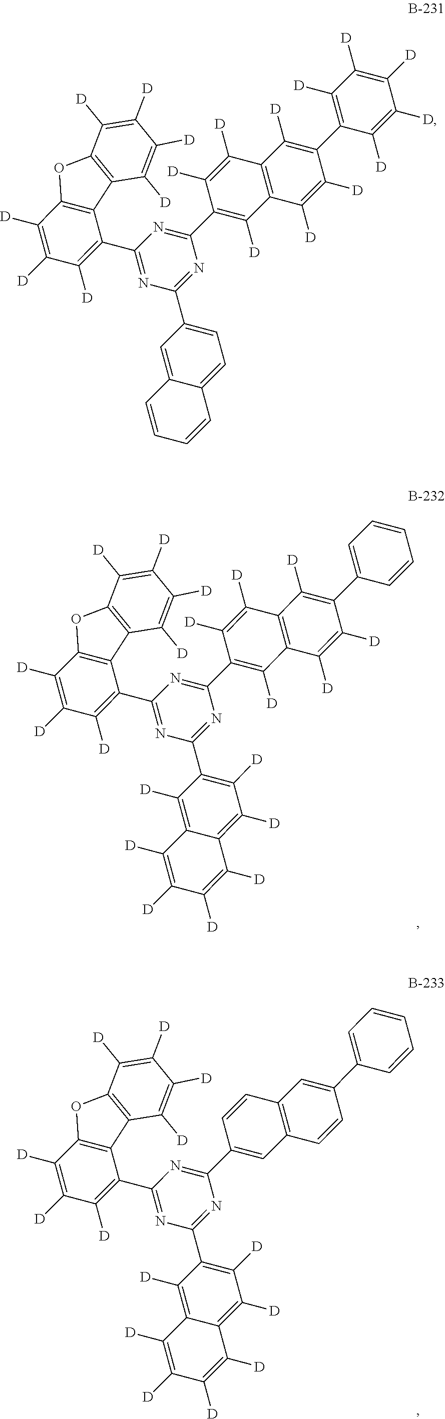

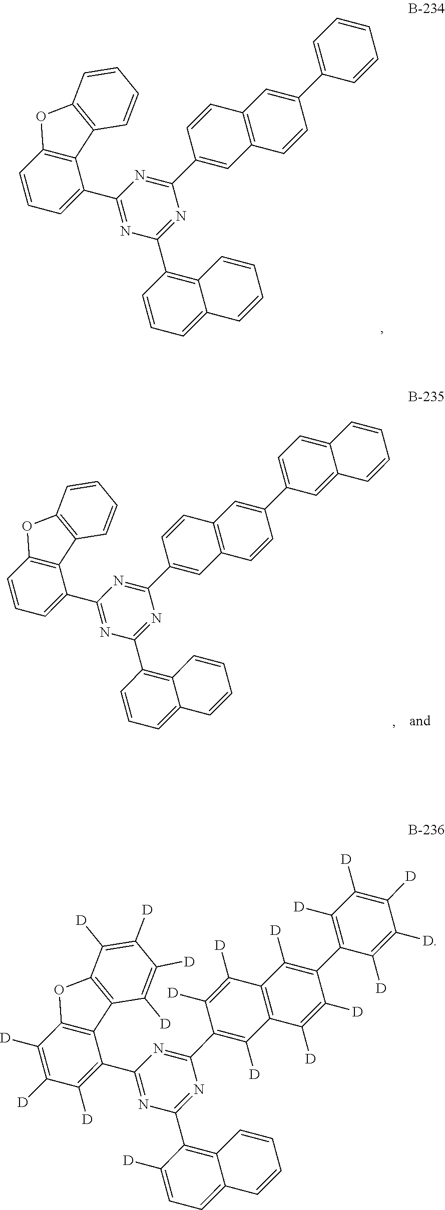

20. A compound composition, comprising the metal complex of claim 1.
